(19) United States
(12) Patent Application Publication
(10) Pub. No.: US 2011/0223536 A1
(43) Pub. Date: Sep. 15, 2011

(54) ACTINIC RAY-SENSITIVE OR RADIATION-SENSITIVE RESIN COMPOSITION, AND RESIST FILM AND PATTERN FORMING METHOD USING THE SAME

(75) Inventors: Akinori SHIBUYA, Shizuoka (JP); Masahiro YOSHIDOME, Shizuoka (JP)

(73) Assignee: FUJIFILM CORPORATION, Tokyo (JP)

(21) Appl. No.: 13/041,694

(22) Filed: Mar. 7, 2011

(30) Foreign Application Priority Data
Mar. 12, 2010 (JP) 2010-056741

(51) Int. Cl. G03F 7/004; G03F 7/20

(52) U.S. Cl. 430/270.1; 430/325

(57) ABSTRACT

An actinic ray-sensitive or radiation-sensitive resin composition, and a resist film and a pattern forming method each using the composition are provided, the composition including: (A) a resin containing a repeating unit having a specific lactone structure and a repeating unit having a specific sulfonamide structure and being capable of increasing the solubility of the resin (A) in an alkali developer by the action of an acid; and (B) a compound capable of generating an acid upon irradiation with an actinic ray or radiation.

### BACKGROUND OF THE INVENTION

1. Field of the Invention

The present invention relates to an actinic ray-sensitive or radiation-sensitive resin composition used in the process of producing a semiconductor such as IC or the production of a liquid crystal device or a circuit board such as thermal head and further in other photo-fabrication processes, and a resist film and a pattern forming method each using the composition. More specifically, the present invention relates to an actinic ray-sensitive or radiation-sensitive resin composition suitable when using an irradiation source having a wavelength of 250 nm or less, such as far ultraviolet ray and electron beam, and a resist film and a pattern forming method each using the composition.

2. Description of the Related Art

A chemical amplification resist composition forms a pattern on a substrate by producing an acid in the exposed area upon irradiation with radiation such as far ultraviolet light and through a reaction using the acid as a catalyst, changing the developer solubility of the area irradiated with an actinic radiation and that of the non-irradiated area.

In the case of using a KrF excimer laser as the exposure light source, a resin having small absorption in the wavelength region of 248 nm and having a basic backbone of poly(hydroxystyrene) is predominantly used as the main component and therefore, this is an excellent system capable of forming a good pattern with high sensitivity and high resolution, compared with the conventional naphthoquinone-diazide/novolak resin system.

On the other hand, in the case where a light source of emitting light at a shorter wavelength, for example, an ArF excimer laser (193 nm), is used as the exposure light source, a satisfactory pattern cannot be formed even by the above-described chemical amplification system, because the compound having an aromatic group substantially has large absorption in the region of 193 nm.

In order to solve this problem, various resist compositions for use with an ArF excimer laser, containing an alicyclic hydrocarbon structure, have been developed. However, in view of overall performance as a resist, it is actually very difficult to find out an appropriate combination of a resin, a photoacid generator, additives, a solvent and the like used.

JP-A-2008-31298 discloses that high resolution and good line edge roughness performance are achieved by using a resin having a specific lactone structure, where a resin obtained by copolymerizing a (meth)acrylic acid so as to enhance the resolution is described as an example, but the resin swells at alkali development and a problem such as pattern collapse is caused.

JP-A-2000-147774 describes a technique of using a resin having a specific sulfonamide structure and thereby improving the iso/dense bias, that is, enabling high-reproducibility resolution of various line patterns such as dense-line area, conversely wide space pattern compared with the line area, and isolated line.

However, in the generation where a latest pattern having a line width of 45 nm or less is formed by applying an immersion process, those related arts are not always sufficient, and more improvements in the depth-of-focus (DOF), pattern collapse and iso/dense bias are demanded.

### SUMMARY OF THE INVENTION

An object of the present invention is to provide an actinic ray-sensitive or radiation-sensitive resin composition suitable not only to a normal dry process but also to an immersion process for a line width of 45 nm or less and improved in the DOF, pattern collapse and iso/dense bias, and a resist film and a pattern forming method each using the composition.

The present inventors have found that the above-described object can be attained by employing a resin copolymerized using, as essential components, a repeating unit having a specific lactone structure and a repeating unit having a specific sulfonamide structure.

The present invention is as follows.

[1] An actinic ray-sensitive or radiation-sensitive resin composition including:

(A) a resin containing a repeating unit represented by formula (I) and a repeating unit having a partial structure represented by formula (II), and being capable of increasing the solubility of the resin (A) in an alkali developer by the action of an acid, and

(B) a compound capable of generating an acid upon irradiation with an actinic ray or radiation:

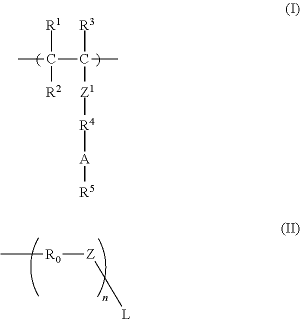

wherein

in formula (I), each of R¹ to R³ independently represents a hydrogen atom, an alkyl group, a halogen atom or a cyano group;

Z¹ represents a single bond, an ether bond, an ester bond, an amide bond, an alkylene group, or a divalent group formed by combining two or more members selected from the group consisting of a single bond, an ether bond, an ester bond, an amide bond and an alkylene group;

R⁴ represents a single bond, an alkylene group, an arylene group, or a divalent group formed by combining two or more members selected from the group consisting of a single bond, an alkylene group and an arylene group;

R⁵ represents an alkyl group, an alicyclic hydrocarbon group-containing group, an aryl group or an aralkyl group; and

A represents any one of functional groups (a1) to (a7), where in the functional groups (a1) to (a7), *1 indicates that the bond is connected to R⁴, and *2 indicates that the bond is connected to R⁵;

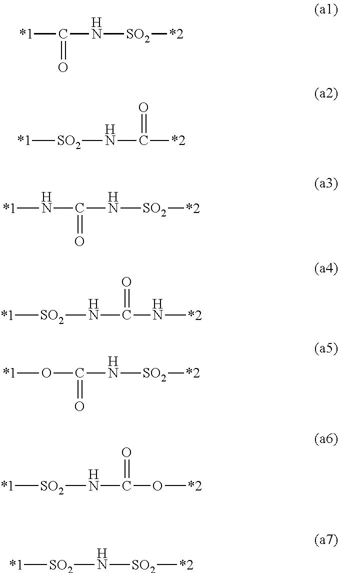

in formula (II), L represents a monovalent organic group having a lactone structure;

R₀ represents an alkylene group, a cycloalkylene group, or a combination of these groups, and when a plurality of R₀'s are present, the plurality of R₀'s may be the same or different;

Z represents an ether bond, an ester bond, an amide bond, a urethane bond or a urea bond, and when a plurality of Z's are present, the plurality of Z's may be the same or different; and

n indicates a repetition number and represents an integer of 1 to 5.

[2] The actinic ray-sensitive or radiation-sensitive resin composition as described in [1] above,

wherein, in the formula (I), A is any one of the functional groups (a1) to (a6).

[3] The actinic ray-sensitive or radiation-sensitive resin composition as described in [1] or [2] above,

wherein, in the formula (I), A is the functional group (a1) or (a2).

[4] The actinic ray-sensitive or radiation-sensitive resin composition as described in any one of [1] to [3] above,

wherein the repeating unit represented by the formula (I) is a repeating unit represented by formula (I-1):

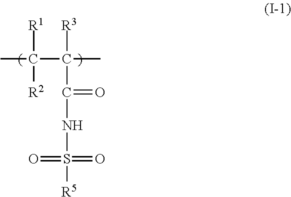

wherein R¹, R², R³ and R⁵ have the same meanings as R¹, R², R³ and R⁵ in the formula (I).

[5] The actinic ray-sensitive or radiation-sensitive resin composition as described in any one of [1] to [4] above,

wherein, in the formula (I) and formula (I-1), each of R¹ and R² represents a hydrogen atom and R³ represents a hydrogen atom or an alkyl group.

[6] The actinic ray-sensitive or radiation-sensitive resin composition as described in any one of [1] to [5] above,

wherein, in the formula (I) and formula (I-1), R⁵ represents an alkyl group or a cycloalkyl group.

[7] The actinic ray-sensitive or radiation-sensitive resin composition as described in any one of [1] to [6] above,

wherein the repeating unit having a partial structure represented by the formula (II) is a repeating unit represented by formula (II-1) or (II-2):

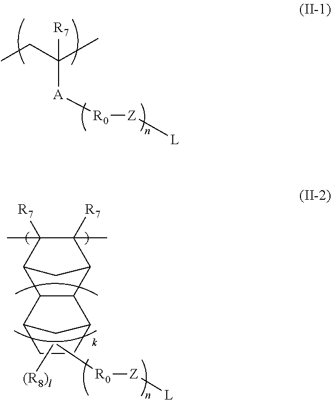

wherein R₇ represents a hydrogen atom, a halogen atom or an alkyl group, and two R₇'s in formula (II-2) may be the same or different;

A represents an ester bond or an amide bond;

R₈ represents a hydrocarbon group, and when a plurality of R₈'s are present, the plurality of R₈'s may be the same or different;

k represents an integer of 0 to 2;

l represents an integer of 0 to 19; and

L, R₀, Z and n have the same meanings as L, R₀, Z and n in the formula (II).

[8] The actinic ray-sensitive or radiation-sensitive resin composition as described in [7] above,

wherein the repeating unit having a partial structure represented by the formula (II) is a repeating unit represented by the formula (II-1).

[9] The actinic ray-sensitive or radiation-sensitive resin composition as described in [8] above,

wherein the repeating unit represented by the formula (II-1) is a repeating unit represented by formula (II-3):

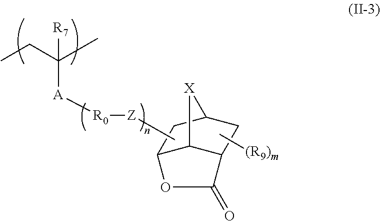

wherein R₇, A, R₀, Z and n have the same meanings as R₇, A, R₀, Z and n in the formula (II-1);

R₉ represents an alkyl group, a cycloalkyl group, an alkoxycarbonyl group or a cyano group, and when a plurality of R₉'s are present, the plurality of R₉'s may be the same or different and two R₉'s may combine to form a ring;

X represents an alkylene group, an oxygen atom or a sulfur atom; and

m indicates the number of substituents and represents an integer of 0 to 5.

[10] The actinic ray-sensitive or radiation-sensitive resin composition as described in any one of [1] to [9] above,

wherein, in the formula (II) and formulae (II-1) to (II-3), R₀ is an alkylene group.

[11] The actinic ray-sensitive or radiation-sensitive resin composition as described in any one of [1] to [10] above,

wherein, in the formula (II) and formulae (II-1) to (II-3), Z is an ether bond or an ester bond.

[12] The actinic ray-sensitive or radiation-sensitive resin composition as described in any one of [1] to [11] above,

wherein, in the formula (II) and formulae (II-1) to (II-3), n is 1.

[13] The actinic ray-sensitive or radiation-sensitive resin composition as described in any one of [1] to [12] above, which further includes:

(C) a hydrophobic resin.

[14] The actinic ray-sensitive or radiation-sensitive resin composition according to [13] above,

wherein the hydrophobic resin (C) contains at least either a fluorine atom or a silicon atom.

[15] A resist film, which is formed from the actinic ray-sensitive or radiation-sensitive resin composition described in any one of [1] to [14] above.

[16] A pattern forming method, including: steps of exposing and developing the resist film described in [15] above.

[17] The pattern forming method as described in [16] above,

wherein the exposure in the step of exposing the resist film is an immersion exposure.

Furthermore, the present invention preferably has the following configurations.

[18] The actinic ray-sensitive or radiation-sensitive resin composition as described in [13] or [14] above,

wherein the hydrophobic resin (C) contains (cy) a repeating unit having (y) at least one group capable of decomposing by the action of an alkali developer to increase the solubility in an alkali developer.

[19] The actinic ray-sensitive or radiation-sensitive resin composition as described in [18] above,

wherein the group (y) is a lactone group.

[20] The actinic ray-sensitive or radiation-sensitive resin composition as described in [18] or [19] above,

wherein the repeating unit (cy) has at least either a fluorine atom or a silicon atom on the same side chain as the group (y).

### DETAILED DESCRIPTION OF THE INVENTION

The mode for carrying out the present invention is described below.

In the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

In the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam. Also, in the present invention, the “light” means an actinic ray or radiation. In the present invention, unless otherwise indicated, the “exposure” includes not only exposure to a mercury lamp, a far ultraviolet ray typified by excimer laser, an X-ray, EUV light or the like but also lithography with a particle beam such as electron beam and ion beam.

The actinic ray-sensitive or radiation-sensitive resin composition of the present invention includes:

(A) a resin containing a repeating unit represented by formula (I) described later and a repeating unit having a partial structure represented by formula (II) described later, and being capable of increasing the solubility for an alkali developer by the action of an acid, and

(B) a compound capable of generating an acid upon irradiation with an actinic ray or radiation.

The actinic ray-sensitive or radiation-sensitive resin composition of the present invention is, for example, a positive composition and is typically a positive resist composition. The configuration of this composition is described below.

### [1] (A) Resin

The resin (A) for use in the present invention contains a repeating unit represented by formula (I) and a repeating unit having a partial structure represented by formula (II) and can increase its solubility in an alkali developer by the action of an acid.

(a1) Repeating Unit Represented by Formula (I)

The repeating unit represented by formula (I) contained in the resin (A) for use in the present invention is described below.

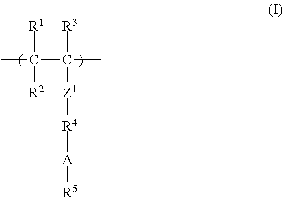

In formula (I), each of R¹ to R³ independently represents a hydrogen atom, an alkyl group (preferably having a carbon number of 1 to 4), a halogen atom or a cyano group.

Z¹ represents a single bond, an ether bond, an ester bond, an amide bond, an alkylene group, or a divalent group (preferably having a total carbon number of 6 or less, more preferably 3 or less) formed by combining two or more members selected from the group consisting of a single bond, an ether bond, an ester bond, an amide bond and an alkylene group.

R⁴ represents a single bond, an alkylene group, an arylene group, or a divalent group (preferably having a total carbon number of 12 or less, more preferably 9 or less) formed by combining two or more members selected from the group consisting of a single bond, an alkylene group and an arylene group.

R⁵ represents an alkyl group, an alicyclic hydrocarbon group-containing group, an aryl group or an aralkyl group.

A represents any one of functional groups (a1) to (a7) shown below. In the functional groups (a1) to (a7), *1 indicates that the bond is connected to R⁴, and *2 indicates that the bond is connected to R⁵.

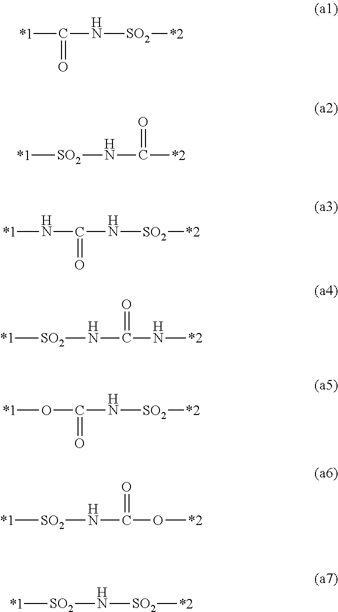

The repeating unit represented by formula (I) is characterized by having a group represented by —Z¹—R⁴-A-R⁵.

In formula (I), examples of the substituent which the alkyl group of R¹ to R³ may have include a hydroxyl group and a halogen atom (preferably fluorine atom). Examples of the halogen atom of R¹ to R³ include a chlorine atom, a bromine atom, a fluorine atom and an iodine atom. Each of R¹ to R³ independently represents preferably a hydrogen atom or an alkyl group, more preferably a hydrogen atom, a methyl group, a hydroxymethyl group or a trifluoromethyl group, still more preferably a hydrogen atom or a methyl group. Each of R¹ and R² is yet still more preferably a hydrogen atom.

The alkylene group of Z¹ and R⁴ includes a group represented by the following formula:

—[C(Ra)(Rb)]ᵣ—

In the formula, each of Ra and Rb independently represents a hydrogen atom, an alkyl group, a halogen atom, a hydroxyl group or an alkoxy group, and these two members may be the same or different. When r is 2 or more, the plurality of Ra's may the same or different, and the plurality of Rb's may be the same or different. Each of Ra and Rb is independently, preferably a hydrogen atom or an alkyl group. The alkyl group is preferably a lower alkyl group such as methyl group, ethyl group, propyl group, isopropyl group and butyl group, more preferably a group selected from a methyl group, an ethyl group, a propyl group and an isopropyl group, still more preferably a methyl group. The alkoxy group includes an alkoxy group having a carbon number of 1 to 4, such as methoxy group, ethoxy group, propoxy group and butoxy group. The substituents which such an alkyl group and an alkoxy group may have include a hydroxyl group, a halogen atom, and an alkoxy group. Examples of the halogen atom include a chlorine atom, a bromine atom, a fluorine atom and an iodine atom. r represents an integer of 1 to 10, preferably an integer of 1 to 6, more preferably an integer of 1 to 3.

The arylene group of R⁴ includes an arylene group having a carbon number of 6 to 10 and may have a substituent. Specific examples of the arylene group of R⁴ include a phenylene group, a tolylene group and a naphthylene group, with a phenylene group being preferred.

Z¹ is preferably a single bond, an ester bond or an amide bond.

R⁴ is preferably a single bond or an alkylene group.

The alkyl group of R⁵ includes a linear or branched alkyl group and may have a substituent. The linear or branched alkyl group is preferably a linear or branched alkyl group having a carbon number of 1 to 12, more preferably a linear or branched alkyl group having a carbon number of 1 to 10, still more preferably a methyl group, an ethyl group, a propyl group, an isopropyl group, an n-butyl group, an isobutyl group, a sec-butyl group, a tert-butyl group, a pentyl group, a hexyl group, a heptyl group, an octyl group, a nonyl group or a decyl group.

The alicyclic hydrocarbon group-containing group of R⁵ is not particularly limited as long as it has an alicyclic hydrocarbon group. The alicyclic hydrocarbon group may have a substituent and may be monocyclic or polycyclic, and the polycyclic hydrocarbon group may be a crosslinked hydrocarbon group. The alicyclic hydrocarbon group-containing group of R⁵ is preferably a group represented by -L⁵-(R⁶)ₙ₅. L⁵ represents a single bond or an (n5+1)-valent hydrocarbon group and when L⁵ is a single bond, n5 is 1. Preferably, n5 is 1 and at the same time, L⁵ is a single bond or an alkylene group (preferably having a carbon number of 1 to 4) and more preferably a single bond or a methylene group. R⁶ represents an alicyclic hydrocarbon group. n5 represents an integer of 1 or more, preferably an integer of 1 to 3, more preferably 1. When n5 is 2 or more, the plurality of R⁶'s may be the same or different.

The alicyclic hydrocarbon group of R⁶ includes a cycloalkyl group having a carbon number of 3 to 30 and may have a substituent. The cycloalkyl group is preferably a cycloalkyl group having a carbon number of 5 to 20, more preferably a carbon number of 5 to 10. Specific examples thereof include a cyclopropyl group, a cyclopentyl group, a cyclohexyl group, an adamantyl group, a norbornyl group, a bornyl group, a tricyclodecanyl group, a dicyclopentenyl group, a menthyl group, an isomenthyl group, a neomenthyl group, a tetracyclododecanyl group and a steroid residue. Among these, a cyclopentyl group, a cyclohexyl group, a norbornyl group and a bornyl group are preferred.

The aryl group of R⁵ includes an aryl group having a carbon number of 6 to 10 and may have a substituent. Specific examples thereof include a phenyl group, a tolyl group and a naphthyl group, with a phenyl group being preferred.

The aralkyl group of R³ includes an aralkyl group having a carbon number of 7 to 20 and may have a substituent. Specific examples thereof include a benzyl group, a phenethyl group and a cumyl group, with a benzyl group being preferred.

R⁵ is preferably an alkyl group or an alicyclic hydrocarbon group-containing group.

Examples of the further substituent for the arylene group of R⁴ and the alkyl group, the alicyclic hydrocarbon group in the alicyclic hydrocarbon group-containing group, the aryl group and the aralkyl group of R⁵ include a carboxyl group, an oxo group, an acyloxy group (preferably having a carbon number of 2 to 10), a cyano group, an alkyl group (preferably having a carbon number of 1 to 10), a cycloalkyl group (preferably having a carbon number of 3 to 10), a halogen atom, a hydroxyl group, an alkoxy group (preferably having a carbon number of 1 to 10), an acetylamide group, an alkoxycarbonyl group (preferably having a carbon number of 2 to 20), and an acyl group (preferably having a carbon number of 2 to 20).

The alkyl group here is preferably a lower alkyl group such as methyl group, ethyl group, propyl group, isopropyl group and butyl group. Preferred examples of the cycloalkyl group include a cyclopropyl group, a cyclobutyl group, a cyclopentyl group, a cyclohexyl group, a norbornyl group and an adamantyl group. Examples of the further substituent for these alkyl and cycloalkyl groups include a hydroxyl group, a halogen atom, an alkoxy group, an oxo group, an alkyl group (preferably having a carbon number of 1 to 10), and a cycloalkyl group (preferably having a carbon number of 3 to 10). The alkoxy group and the alkoxy group in the alkoxycarbonyl group are preferably an alkoxy group having a carbon number of 1 to 4 such as methoxy group, ethoxy group, propoxy group and butoxy group. Examples of the acyloxy group include an acetoxy group; examples of the acyl group include an acetyl group; and examples of the halogen atom include a chlorine atom, a bromine atom, a fluorine atom and an iodine atom.

Specific examples of the monomer corresponding to the repeating unit represented by formula (I) include Monomers (1) to (76), (78) and (95) to (110) illustrated in paragraphs [0021] to [0034] of JP-A-2000-147774, and monomers shown below, but the present invention is not limited thereto.

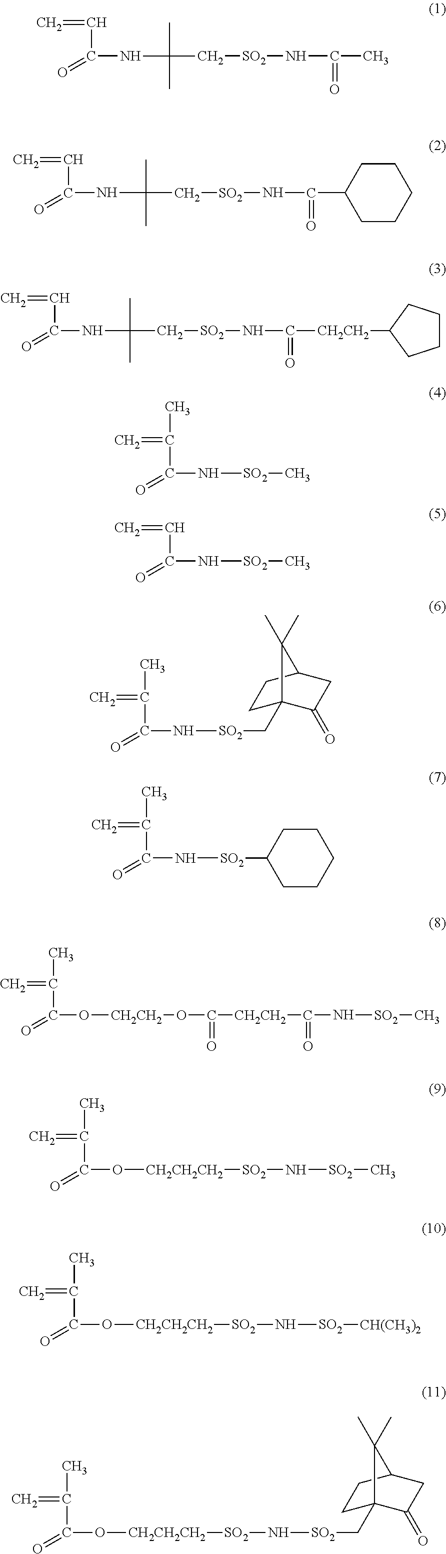

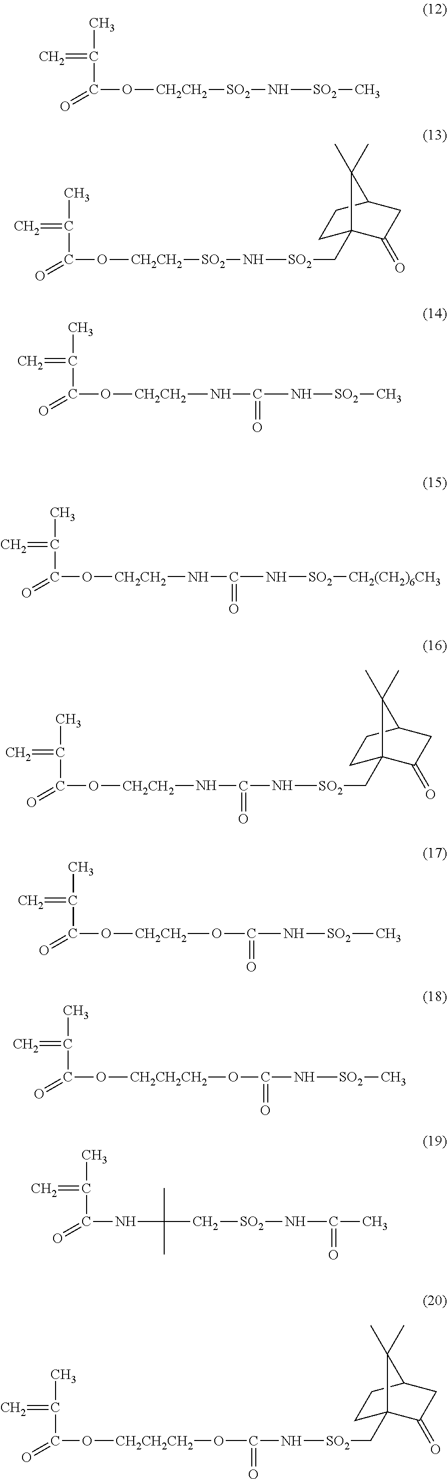

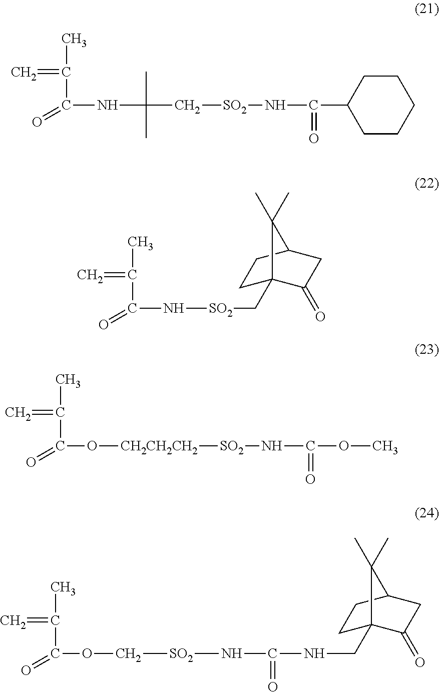

In formula (I), in view of acid strength, A is preferably any one of the functional groups (a1) to (a6), more preferably the functional group (a1) or (a2).

The repeating unit represented by formula (I) is preferably a repeating unit represented by the following formula (I-1):

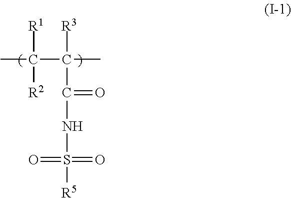

In formula (I-1), R¹, R², R³ and R⁵ have the same meanings as R¹, R², R³ and R⁵ in formula (I).

The repeating unit represented by formula (I) is expected to act as a repeating unit having an alkali-soluble group. Compared with a (meth)acrylic acid unit usually used for increasing the alkali solubility, in the repeating unit represented by formula (I), the alkali-soluble group, that is, the acid group (the —NH— moiety between the sulfonyl group and the carbonyl group or between two sulfonyl groups) of formulae (a1) to (a7), is present inside the molecule and structurally shielded and therefore, the pattern is presumed to be prevented from swelling with an alkali developer at the development. In the present invention, a repeating unit represented by formula (I) having such a property and a repeating unit having a partial structure represented by formula (II) exhibiting high alkali solubility are combined, and this is considered to effectively function particularly for improving the pattern collapse.

In order to increase the effects of the present invention, two or more kinds of repeating units represented by formula (I) may also be used in combination.

The content of the repeating unit represented by formula (I) in the resin (A) is, in the case of containing a plurality of kinds of the repeating unit, their total amount is, preferably from 1 to 20 mol %, more preferably from 3 to 20 mol %, still more preferably from 3 to 15 mol %, based on all repeating units in the resin (A).

(a2) Repeating Unit Having a Partial Structure Represented by Formula (II)

The resin (A) for use in the present invention further contains a repeating unit having a partial structure represented by formula (II). As for the partial structure represented by formula (II), the structure is entirely contained in either one side chain of the main chain of the resin and does not constitute a part of the main chain of the polymer or the side chain structure opposite the side chain containing the partial structure above.

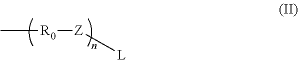

In formula (II), L represents a monovalent organic group having a lactone structure.

R₀ represents an alkylene group, a cycloalkylene group, or a combination of these groups (the total carbon number is preferably 20 or less), and when a plurality of R₀'s are present, the plurality of R₀'s may be the same or different.

Z represents an ether bond, an ester bond, an amide bond, a urethane bond (a group represented by

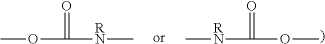

or a urea bond (a group represented by

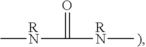

wherein each R independently represents a hydrogen atom, an alkyl group, a cycloalkyl group or an aryl group. When a plurality of Z's are present, the plurality of Z's may be the same or different.

n indicates a repetition number of the structure represented by —R₀—Z— and represents an integer of 1 to 5, preferably an integer of 1 to 3, more preferably 1.

The group represented by R₀ is not particularly limited as long as it is an alkylene group, a cycloalkylene group or a combination thereof, but the alkylene group is preferably a chain alkylene group, more preferably a chain alkylene group having a carbon number of 1 to 10, still more preferably a carbon number of 1 to 5, yet still more preferably a carbon number of 1 to 3. Examples thereof include a methylene group, an ethylene group, a propylene group and an isopropylene group. The cycloalkylene is preferably a cycloalkylene having a carbon number of 3 to 20, more preferably a carbon number of 5 to 10, and examples thereof include a cyclohexylene group, a cyclopentylene group, a norbornylene group and an adamantylene group. For bringing out the effects of the present invention, an alkylene group is preferred, a chain alkylene group is more preferred, and a methylene group is still more preferred.

The alkylene group and cycloalkylene group of R₀ may be substituted, and examples of the substituent include a halogen atom such as fluorine atom, chlorine atom and bromine atom, a mercapto group, a hydroxyl group, an alkoxy group such as methoxy group, ethoxy group, isopropoxy group, tert-butoxy group and benzyloxy group, and an acyloxy group such as acetyloxy group and propionyloxy group.

Z is preferably an ether bond or an ester bond, more preferably an ester bond.

The lactone structure-containing monovalent organic group represented by L is not limited as long as it has a lactone structure, and any lactone structure may be used, but a 5- to 7-membered ring lactone structure is preferred, and a 5- to 7-membered ring lactone structure to which another ring structure is fused in the form of forming a bicyclo structure or a spiro structure is preferred. Specific examples include a lactone structure represented by any of the following formulae (LC1-1) to (LC1-17).

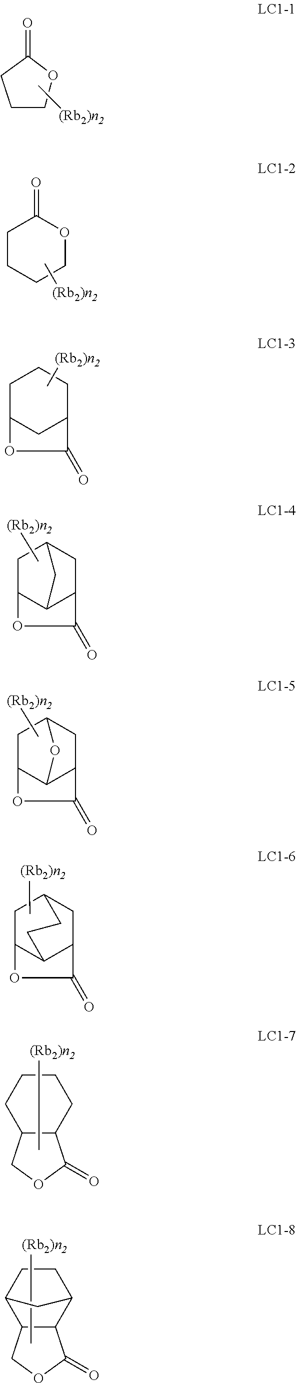

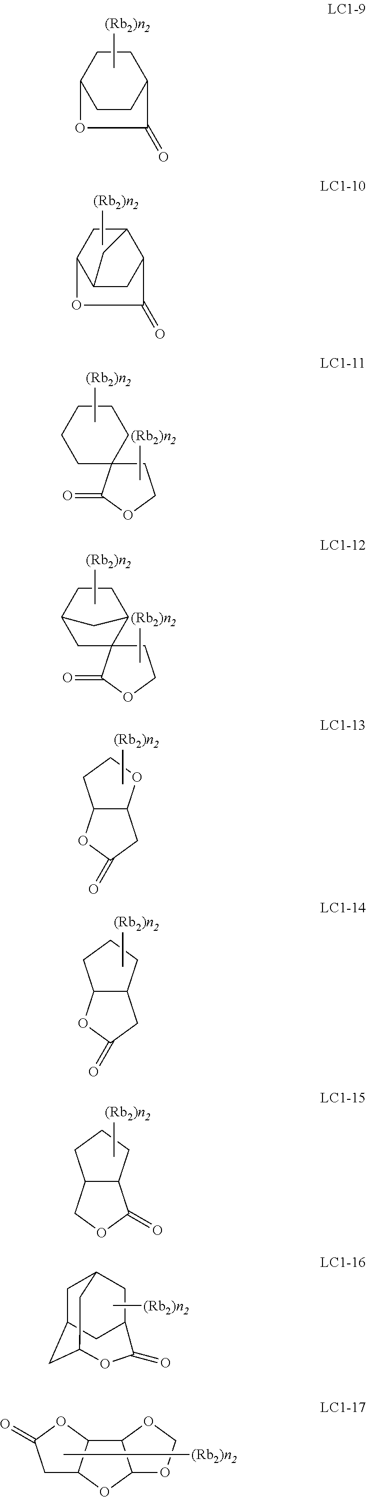

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group and an acid-decomposable group. Among these, an alkyl group having a carbon number of 1 to 4, a cyano group, an alkoxycarbonyl group and an acid-decomposable group are more preferred. n₂ represents an integer of 0 to 4. When n₂ is an integer of 2 or more, the plurality of substituents (Rb₂) may be the same or different and also, the plurality of substituents (Rb₂) may combine with each other to form a ring.

Among these lactone structures, a structure represented by any one of (LC1-1), (LC1-4), (LC1-5), (LC1-6), (LC1-13), (LC1-14) and (LC1-17) is preferred, and a structure represented by (LC1-4) is more preferred. By using a specific lactone structure, LWR and development defect are improved. In (LC1-1) to (LC1-17), n₂ is preferably 2 or less. L is preferably a monovalent organic group having an unsubstituted lactone structure, or a monovalent organic group having a lactone structure containing a methyl group, a cyano group or an alkoxycarbonyl group as the substituent, more preferably a monovalent organic group having a lactone structure containing a cyano group as the substituent (cyanolactone).

The repeating unit having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more, more preferably 95% or more.

The repeating unit having a partial structure represented by formula (II) is preferably a repeating unit represented by the following formula (II-1) or (II-2):

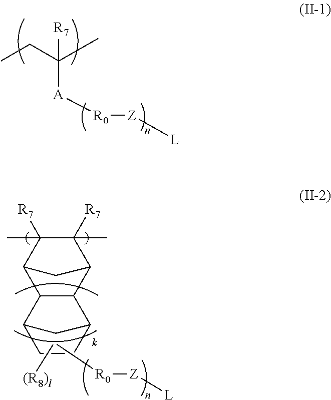

In formulae (II-1) and (II-2), R₇ represents a hydrogen atom, a halogen atom or an alkyl group, and two R₇'s in formula (II-2) may be the same or different.

A represents an ester bond (a group represented by —COO—) or an amide bond (a group represented by —CONH—).

R₈ represents a hydrocarbon group, and when a plurality of R₈'s are present, the plurality of R₈'s may be the same or different.

k represents an integer of 0 to 2 and is preferably 0 or 1, more preferably 1.

l represents an integer of 0 to 19 and is preferably an integer of 0 to 13, more preferably an integer of 0 to 7, still more preferably 0 or 1, and most preferably 0.

R₀, Z, L and n have the same meanings as R₀, Z, L and n in formula (II), and preferred examples thereof are also the same as those described above.

The alkyl group represented by R₇ is preferably an alkyl group having a carbon number of 1 to 4, more preferably a methyl group or an ethyl group, still more preferably a methyl group. Examples of the halogen atom of R₇ include a chlorine atom, a bromine atom, a fluorine atom and an iodine atom. R₇ may further have a substituent, and examples of the substituent on R₇ are the same as those of the substituent which the alkylene group and cycloalkylene group of R₀ in formula (II) may have.

R₇ is preferably a hydrogen atom, a methyl group, a trifluoromethyl group or a hydroxymethyl group, more preferably a hydrogen atom or a methyl group.

The hydrocarbon group of R₈ is preferably a saturated hydrocarbon group and includes an alkyl group (preferably having a carbon number of 1 to 8, more preferably from 1 to 4) and a monocyclic or polycyclic, cyclic hydrocarbon group (preferably having a carbon number of 3 to 20).

Specific examples of the repeating unit having a partial structure represented by formula (II) are illustrated blow, but the present invention is not limited thereto. In specific examples, each R independently represents a hydrogen atom, an alkyl group which may have a substituent, or a halogen atom, preferably a hydrogen atom, a methyl group, a hydroxymethyl group or an acetyloxymethyl group.

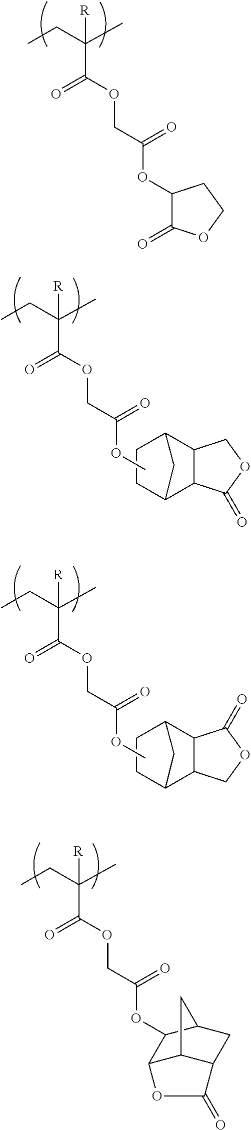

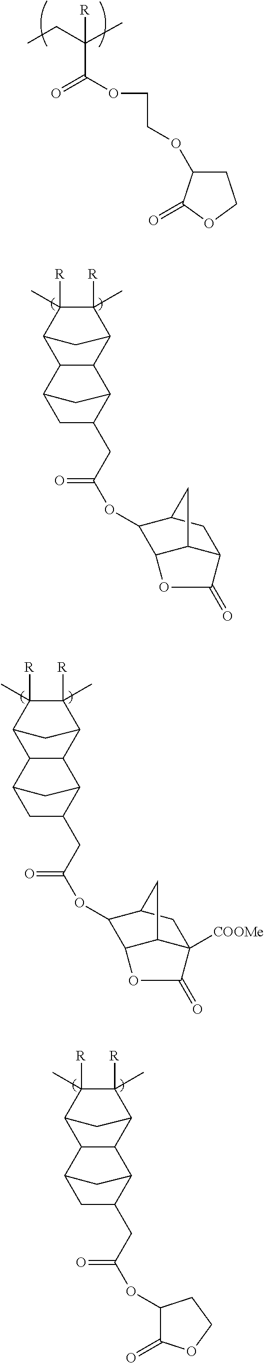

The repeating unit having a partial structure represented by formula (II) is preferably a repeating unit represented by formula (II-1) in view of flexibility of the side chain, and the repeating unit is more preferably a repeating unit represented by formula (II-3) because of excellent dry etching resistance.

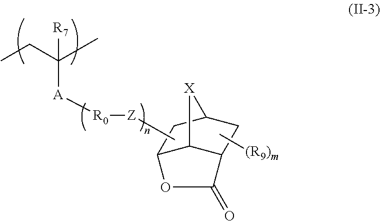

In formula (II-3), R₇, A, R₀, Z and n have the same meanings as R₇, A, R₀, Z and n in formula (II-1), and preferred examples thereof are also the same as those described above.

R₉ represents an alkyl group, a cycloalkyl group, an alkoxycarbonyl group or a cyano group, and when a plurality of R₉'s are present, the plurality of R₉'s may be the same or different and two R₉'s may combine to form a ring.

X represents an alkylene group, an oxygen atom or a sulfur atom.

m indicates the number of substituents and represents an integer of 0 to 5. m is preferably 0 or 1.

The alkyl group of R₉ is preferably an alkyl group having a carbon number of 1 to 4, more preferably a methyl group or an ethyl group, and most preferably a methyl group. The cycloalkyl group is preferably a cycloalkyl group having a carbon number of 3 to 10 and includes a cyclopropyl group, a cyclobutyl group, a cyclopentyl group and a cyclohexyl group. The alkoxycarbonyl group is preferably an alkoxycarbonyl group having a carbon number of 2 to 5, and examples thereof include a methoxycarbonyl group, an ethoxycarbonyl group, an n-butoxycarbonyl group and a tert-butoxycarbonyl group. These groups may have a substituent, and the substituent includes a hydroxyl group, an alkoxy group such as methoxy group and ethoxy group, a cyano group, and a halogen atom such as fluorine atom. R₉ is preferably an alkyl group, an alkoxycarbonyl group or a cyano group, more preferably a cyano group.

Examples of the alkylene group of X include a methylene group and an ethylene group. X is preferably an oxygen atom or an alkylene group, more preferably a methylene group.

When m is an integer of 1 or more, it is preferable that at least one R₉ substitutes on the α-position or β-position, more preferably on the α-position, of the carbonyl group of lactone.

Specific examples of the repeating unit represented by formula (II-3) are illustrated blow, but the present invention is not limited thereto. In specific examples, R represents a hydrogen atom, an alkyl group which may have a substituent, or a halogen atom, preferably a hydrogen atom, a methyl group, a hydroxymethyl group or an acetyloxymethyl group.

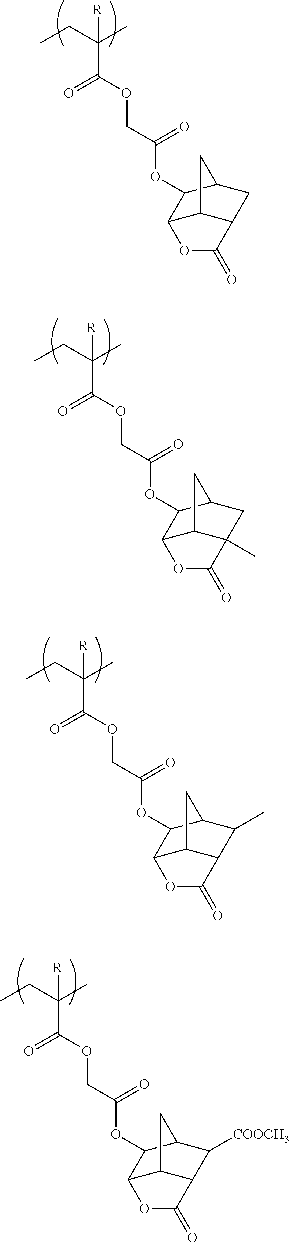

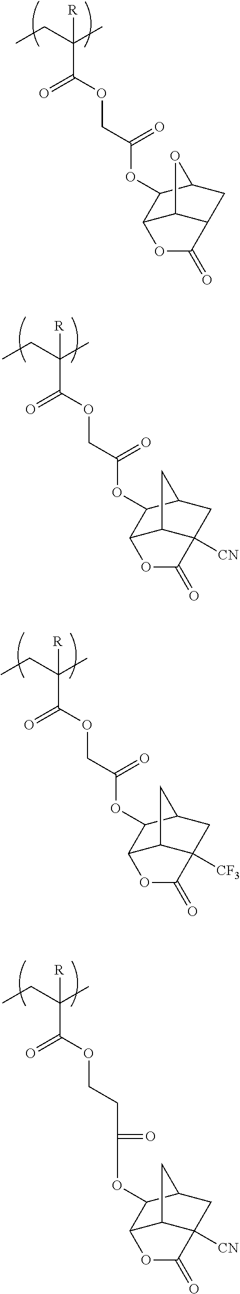

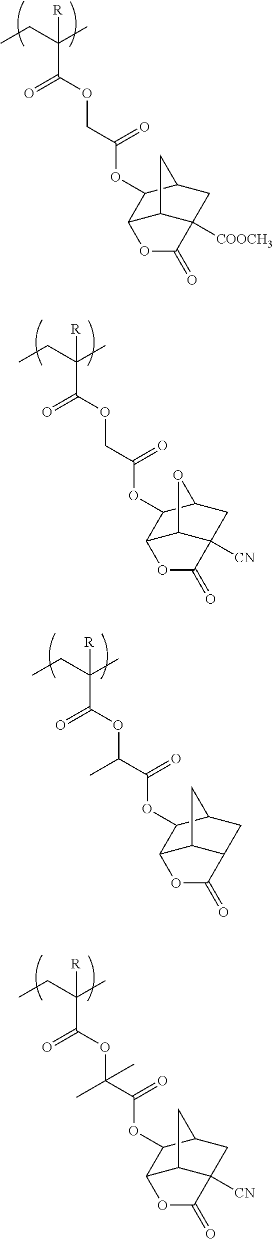

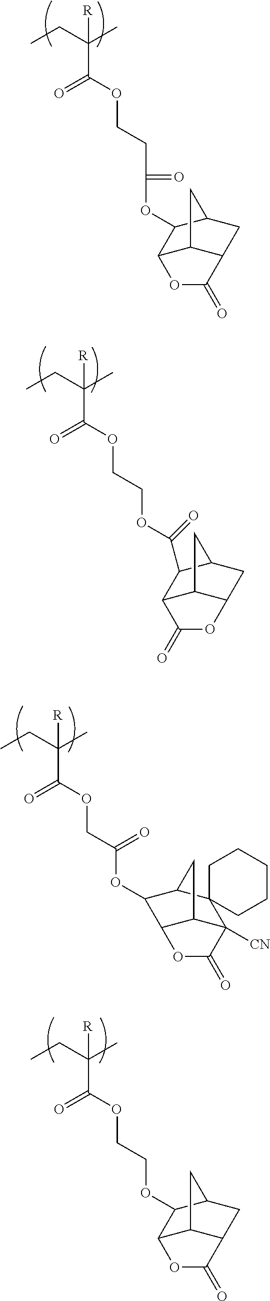

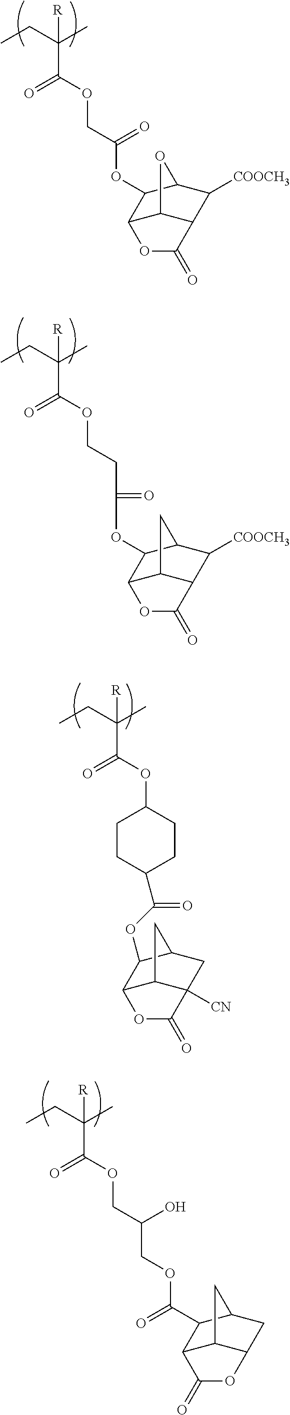

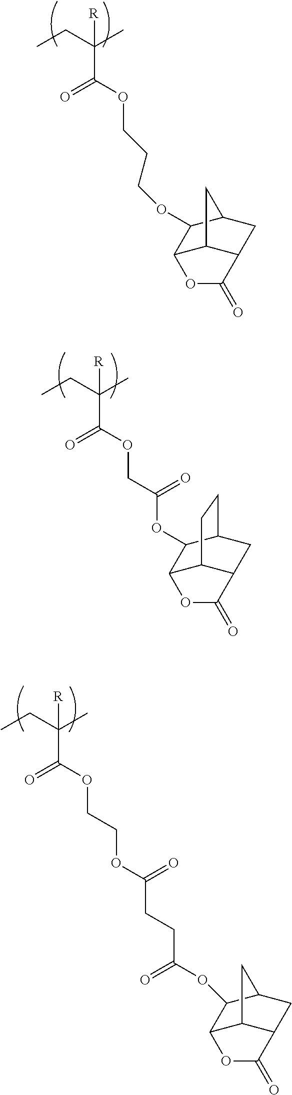

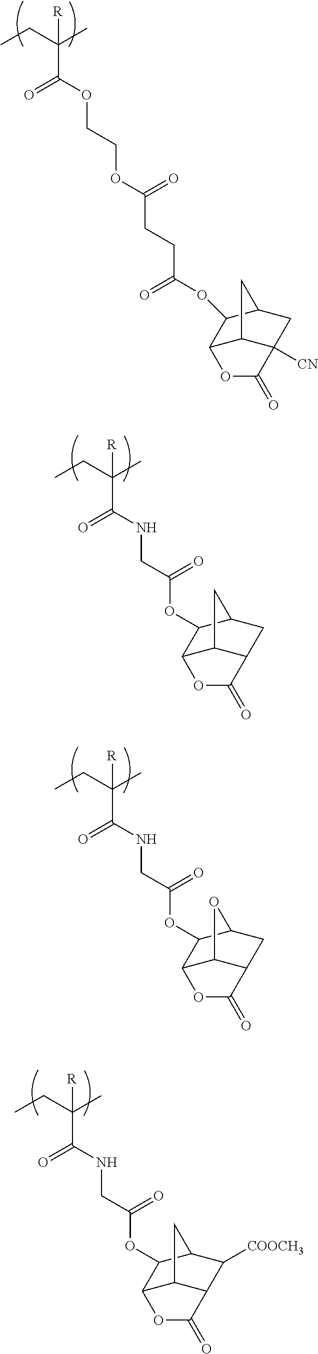

Two or more kinds of repeating units having a partial structure represented by formula (II) may also be used in combination so as to increase the effects of the present invention. In the case of a combination use, it is also preferred that out of formula (II-1), two or more kinds of lactone repeating units where n is 1 are selected and used in combination.

The content of the repeating unit having a partial structure represented by formula (II) in the resin (A) is, in the case of containing a plurality of kinds of the repeating unit, their total amount is, preferably from 15 to 60 mol %, more preferably from 20 to 60 mol %, still more preferably from 30 to 50 mol %, based on all repeating units in the resin (A).

(a3) Repeating Unit Having a Lactone Structure Except for the Repeating Unit Having a Partial Structure Represented by Formula (II)

The resin (A) may contain a repeating unit having a lactone structure, other than the repeating unit having a partial structure represented by formula (II).

Any lactone structure may be used, but a 5- to 7-membered ring lactone structure is preferred, and a 5- to 7-membered ring lactone structure to which another ring structure is fused in the form of forming a bicyclo structure or a spiro structure is preferred. It is more preferred to contain a repeating unit having a lactone structure represented by any of formulae (LC1-1) to (LC1-17). The lactone structure may be bonded directly to the main chain. Among these lactone structures, (LC1-1), (LC1-4), (LC1-5), (LC1-6), (LC1-13), (LC1-14) and (LC1-17) are preferred. By using a specific lactone structure, LWR and development defect are improved.

As for the repeating unit having a lactone structure except for the repeating unit having a partial structure represented by formula (II), a repeating unit represented by the following formula (AII′) is preferred.

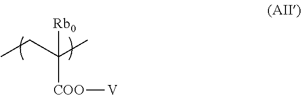

In formula (AII′), Rb₀ represents a hydrogen atom, a halogen atom or an alkyl group (preferably having a carbon number of 1 to 4). Preferred substituents which the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, more preferably a hydrogen atom or a methyl group.

V represents a group having a lactone structure represented by any of formulae (LC1-1) to (LC1-17). V is preferably a group represented by —Rᵥ₀-Lᵥ, wherein Rᵥ₀ represents a single bond, an alkylene group (preferably having a carbon number of 1 to 4), or a cycloalkylene group (preferably having a carbon number of 3 to 10), and Lᵥ represents a lactone structure represented by any of formulae (LC1-1) to (LC1-17). Rᵥ₀ is preferably a single bond or an alkylene group, more preferably a single bond.

Specific examples of the repeating unit having a lactone structure except for the repeating unit having a partial structure represented by formula (II) are illustrated below, but the present invention is not limited thereto.

(In the formulae, Rx represents H, CH₃, CH₂OH or CF₃.)

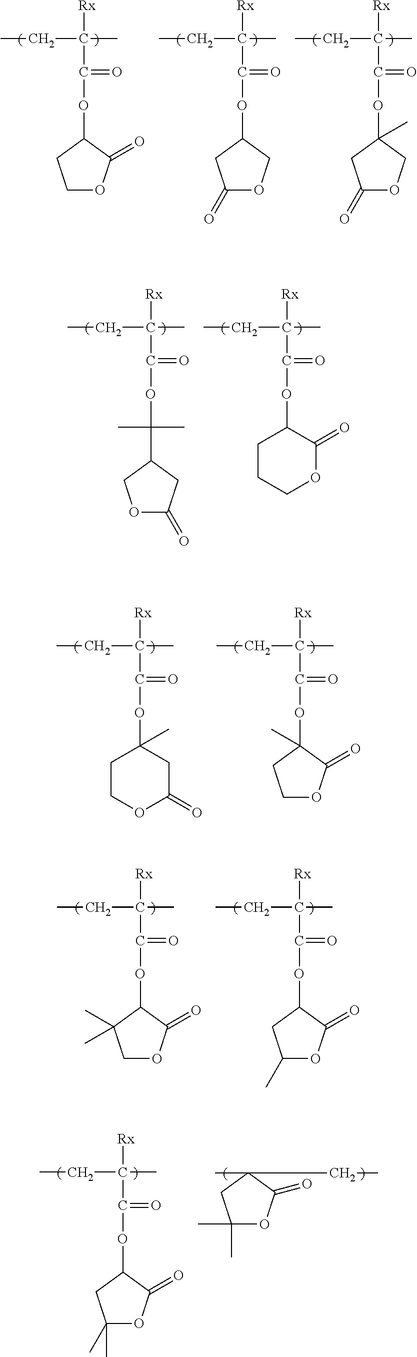

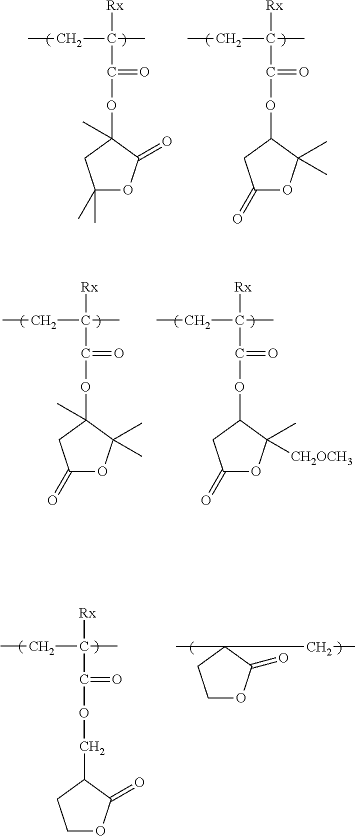

(In the formulae, Rx represents H, CH₃, CH₂OH or CF₃.)

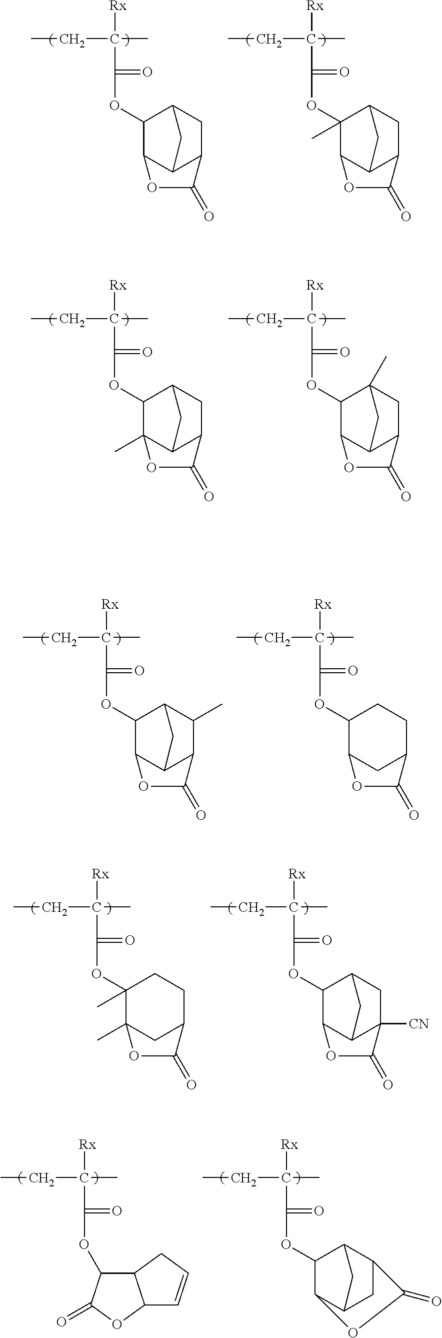

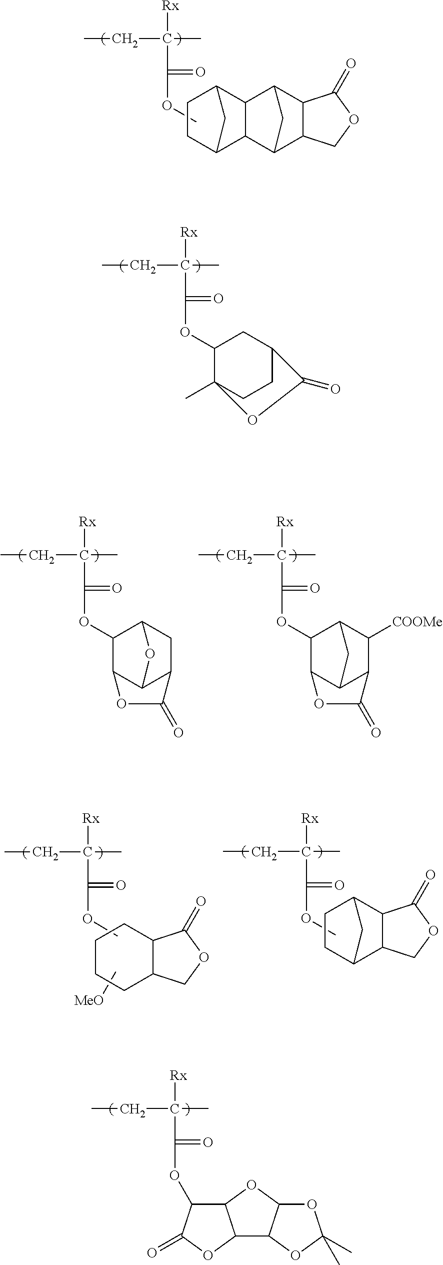

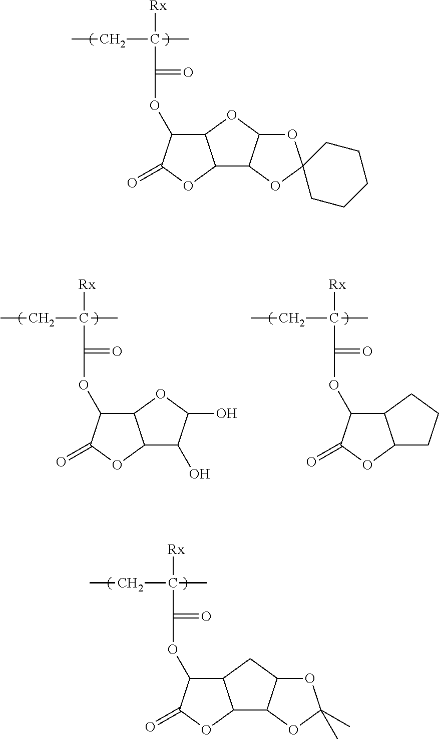

(In the formulae, Rx represents H, CH₃, CH₂OH or CF₃.)

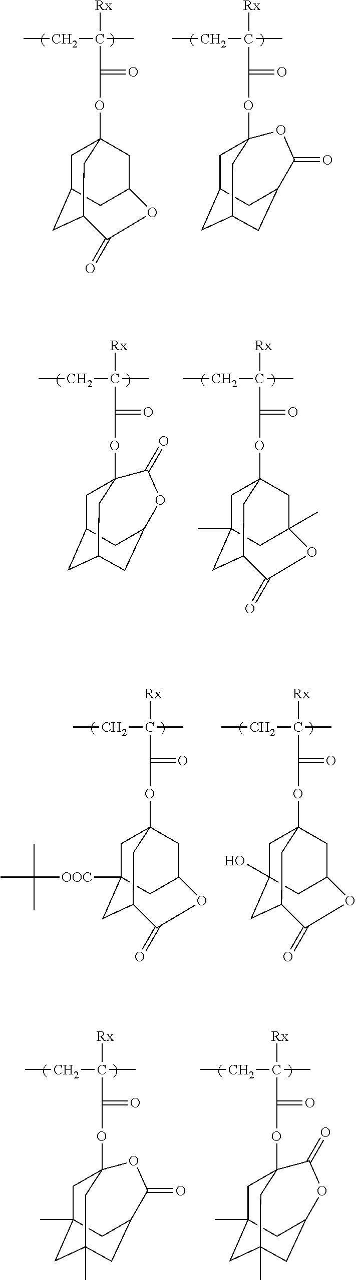

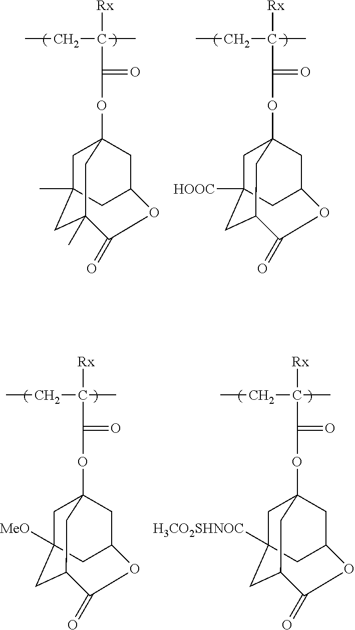

Particularly preferred repeating units having a lactone structure except for the repeating unit having a partial structure represented by formula (II) include the following repeating units. By selecting an optimal lactone structure, the pattern profile and the iso/dense bias are improved.

(In the formulae, Rx represents H, CH₃, CH₂OH or CF₃.)

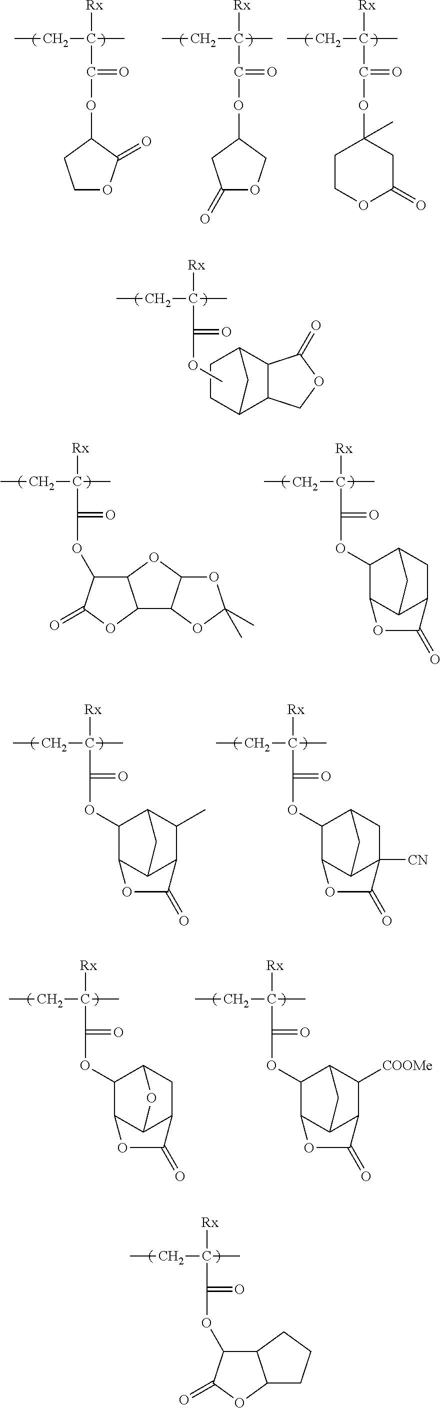

As for the repeating unit having a lactone group, any optical isomer may be used, and usage examples and preferred optical purity thereof are the same as those of the repeating unit having a partial structure represented by formula (II).

As for the repeating unit having a lactone structure except for the repeating unit having a partial structure represented by formula (II), two or more kinds of repeating units may be used in combination. The resin (A) may or may not contain a repeating unit having a lactone structure except for the repeating unit having a partial structure represented by formula (II), but in the case of containing the repeating unit, the content of this repeating unit is, in the case of containing a plurality of kinds of the repeating unit, their total amount is, preferably from 5 to 60 mol %, more preferably from 15 to 50 mol %, still more preferably from 20 to 50 mol %, based on all repeating units in the resin (A).

(a4) Repeating Unit Having an Acid-Decomposable Group

The resin (A) is a resin capable of increasing its solubility in an alkali developer by the action of an acid (acid-decomposable resin), and this resin contains a group capable of decomposing by the action of an acid to produce an alkali-soluble group (hereinafter sometimes referred to as an “acid-decomposable group”), on either one or both of the main chain and the side chain of the resin.

The resin (A) is preferably insoluble or sparingly soluble in an alkali developer.

The acid-decomposable group preferably has a structure where the alkali-soluble group is protected by a group capable of decomposing and leaving by the action of an acid.

Examples of the alkali-soluble group include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyemethylene group and a tris(alkylsulfonyl)methylene group.

Preferred alkali-soluble groups include a carboxyl group, a fluorinated alcohol group (preferably hexafluoroisopropanol) and a sulfonic acid group.

The group preferred as the acid-decomposable group is a group where a hydrogen atom of the alkali-soluble group above is replaced by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like, more preferably a tertiary alkyl ester group.

The resin (A) preferably contains a monocyclic or polycyclic acid-decomposable group. The monocyclic or polycyclic acid-decomposable group preferably has a structure where any of R₃₆ to R₃₉ is a cycloalkyl group or where R₃₆ and R₃₇ are combined with each other to form a ring.

The acid-decomposable group-containing repeating unit is preferably a repeating unit represented by the following formula (AI):

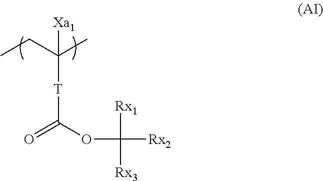

In formula (AI), Xa₁ represents a hydrogen atom, a methyl group which may have a substituent, or a group represented by —CH₂—R₉. R₉ represents a hydroxyl group or a monovalent organic group. Examples of the monovalent organic group include an alkyl group having a carbon number of 5 or less and an acyl group having a carbon number of 5 or less. Of these, an alkyl group having a carbon number of 3 or less is preferred, and a methyl group is more preferred. Xa₁ is preferably a hydrogen atom, a methyl group, a trifluoromethyl group or a hydroxymethyl group.

T represents a single bond or a divalent linking group.

Each of Rx₁ to Rx₃ independently represents an alkyl group (linear or branched) or a cycloalkyl group (monocyclic or polycyclic).

Rx₂ and Rx₃ may combine to form a cycloalkyl group (monocyclic or polycyclic).

Examples of the divalent linking group of T include an alkylene group, a —COO—Rt— group, a —O-Rt— group, and a group formed by combining two or more thereof. In the formulae, Rt represents an alkylene group or a cycloalkylene group. The total carbon number of the divalent linking group of T is preferably from 1 to 20, more preferably from 1 to 15, still more preferably from 2 to 10.

T is preferably a single bond or a —COO—Rt— group. Rt is preferably an alkylene group having a carbon number of 1 to 5, more preferably a —CH₂— group, —(CH₂)₂— group or a —(CH₂)₃— group.

The alkyl group of Rx₁ to Rx₃ is preferably an alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group formed by combining Rx₂ and Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group. Above all, a monocyclic cycloalkyl group having a carbon number of 5 to 6 is preferred.

An embodiment where Rx₁ is a methyl group or an ethyl group and Rx₂ and Rx₃ are combined to form the above-described cycloalkyl group is preferred.

Each of the groups above may have a substituent, and examples of the substituent include an alkyl group (having a carbon number of 1 to 4), a cycloalkyl group (having a carbon number of 3 to 15), a halogen atom, a hydroxyl group, an alkoxy group (having a carbon number of 1 to 4), a carboxyl group and an alkoxycarbonyl group (having a carbon number of 2 to 6). The carbon number is preferably 8 or less.

The content of the repeating unit having an acid-decomposable group is preferably from 20 to 70 mol %, more preferably from 30 to 50 mol %, based on all repeating units constituting the resin (A).

Specific preferred examples of the repeating unit having an acid-decomposable group are illustrated below, but the present invention is not limited thereto.

In specific examples, each of Rx and Xa₁ represents a hydrogen atom, CH₃, CF₃ or CH₂OH, and each of Rxa and Rxb represents an alkyl group having a carbon number of 1 to 4. Z represents a substituent containing a polar group, and when a plurality of Z's are present, each is independent from every others. p represents 0 or a positive integer. Specific examples and preferred examples of Z are the same as specific examples and preferred examples of R₁₀ in formula (2-1) described later.

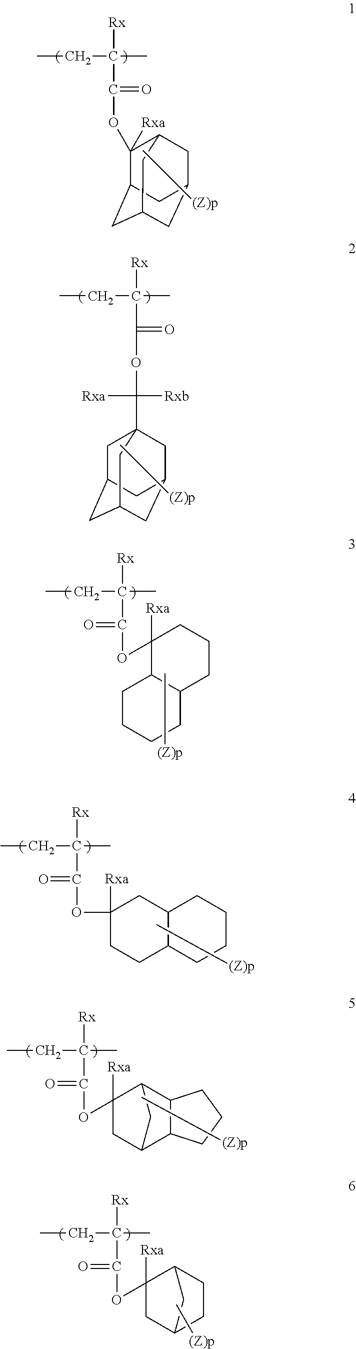

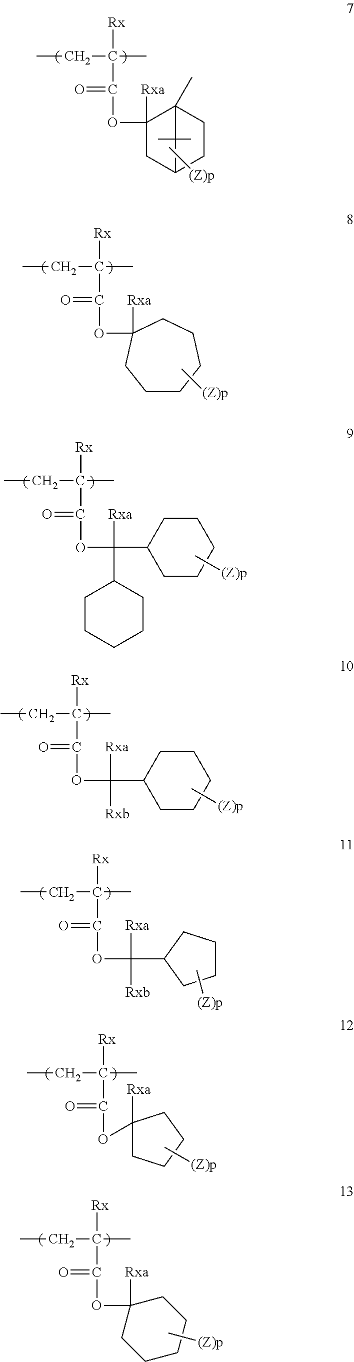

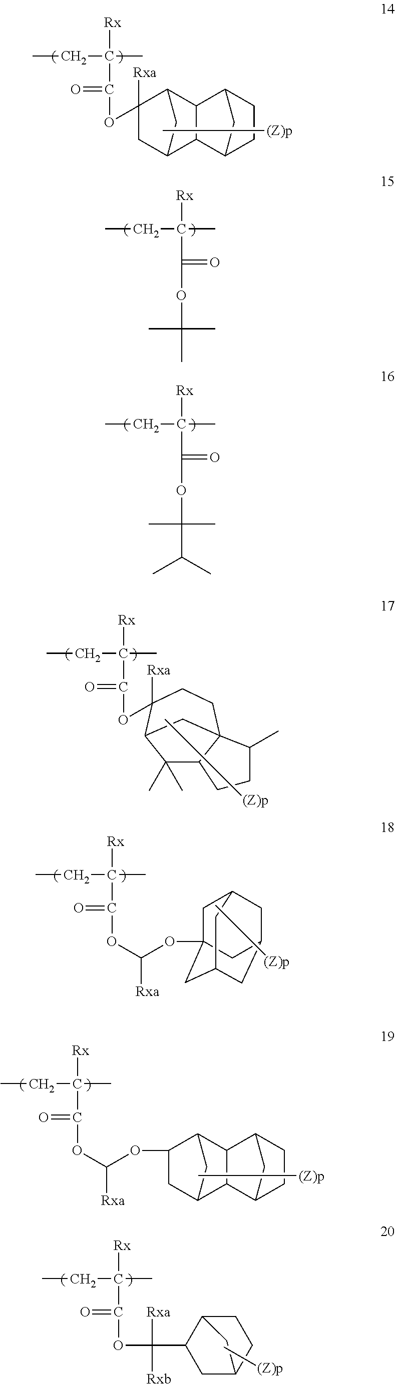

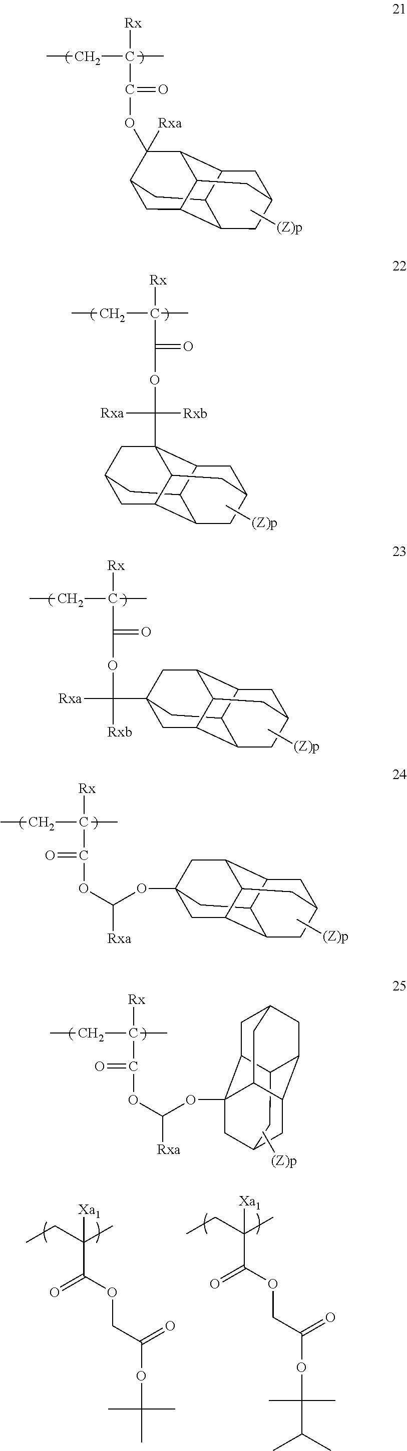

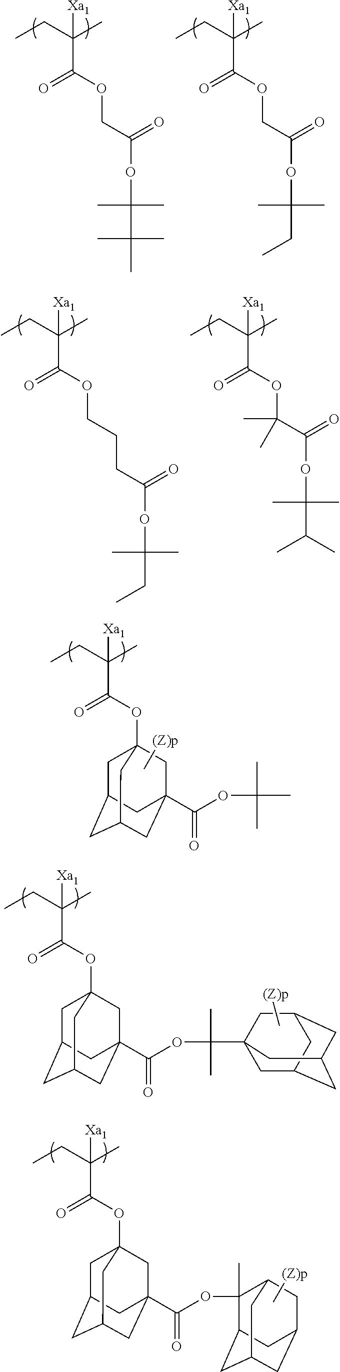

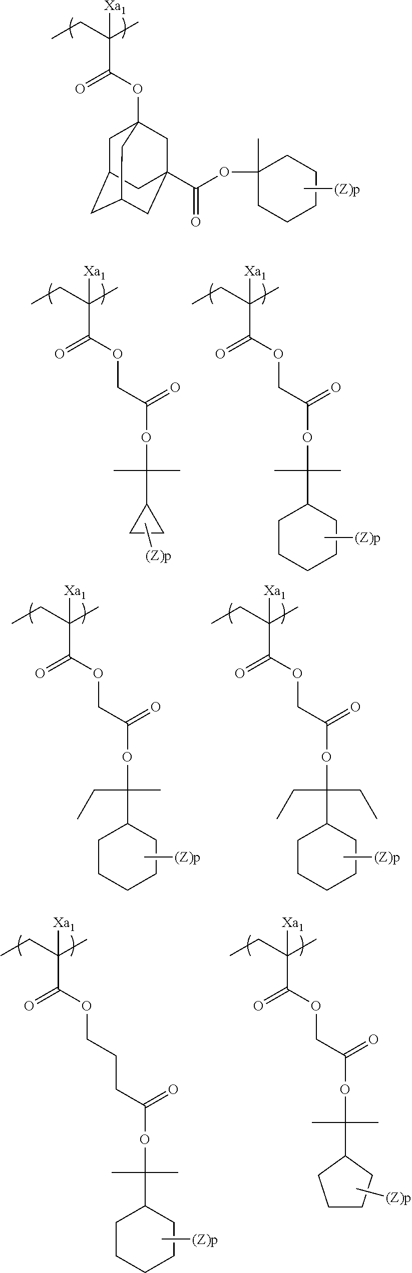

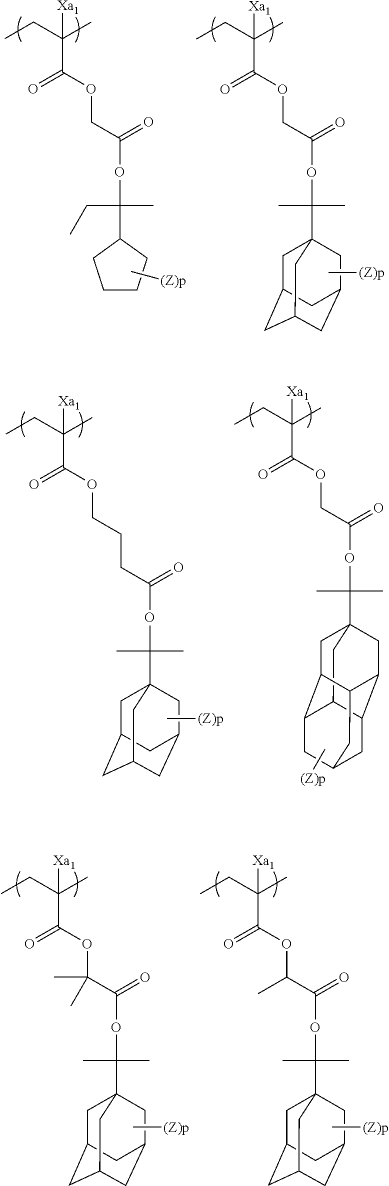

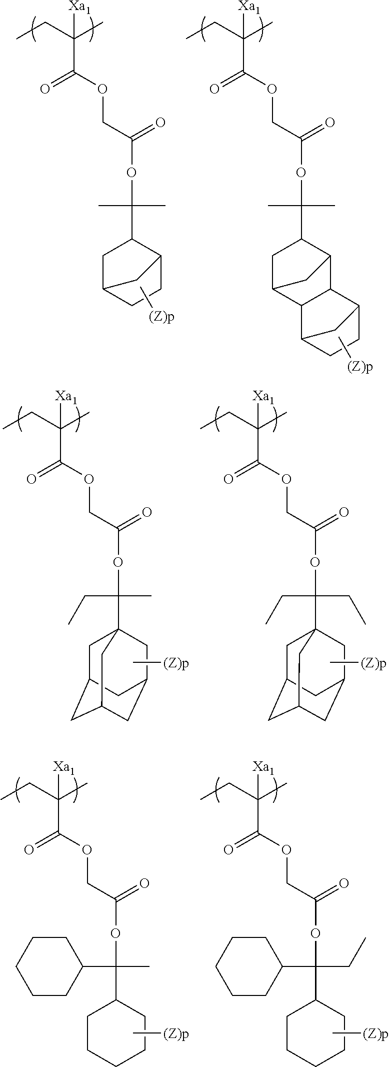

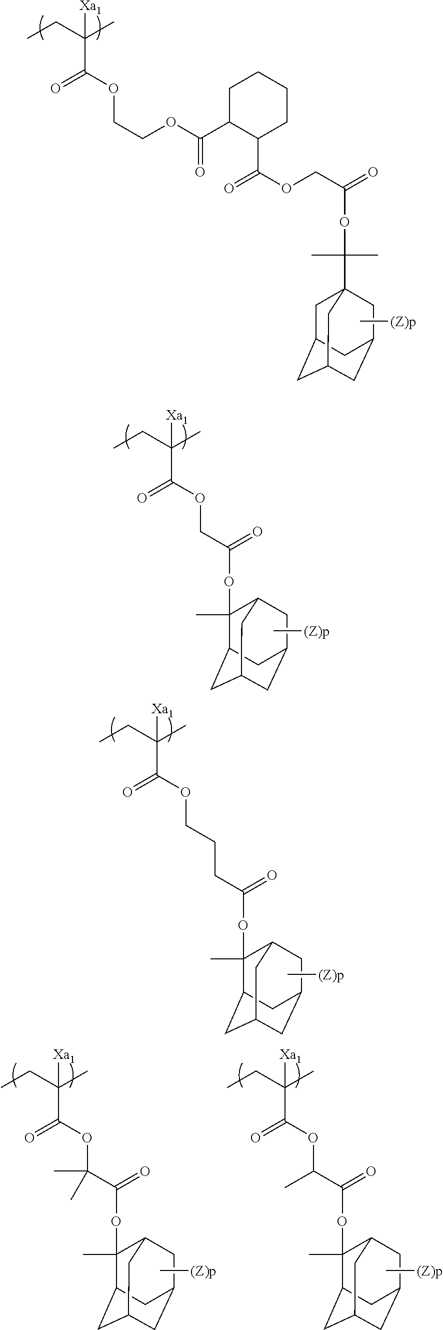

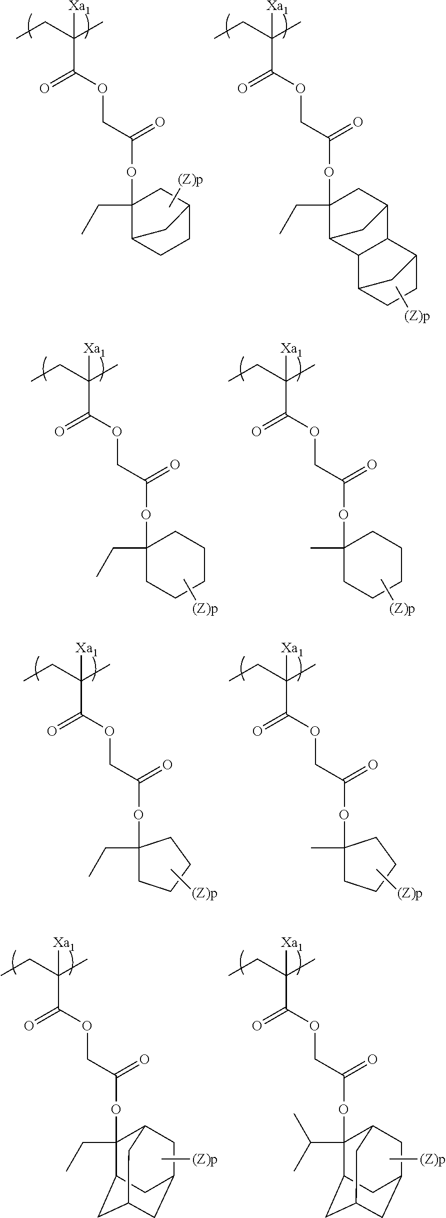

The resin (A) is more preferably a resin containing, as the repeating unit represented by formula (AI), at least either a repeating unit represented by the following formula (1) or a repeating unit represented by the following formula (2).

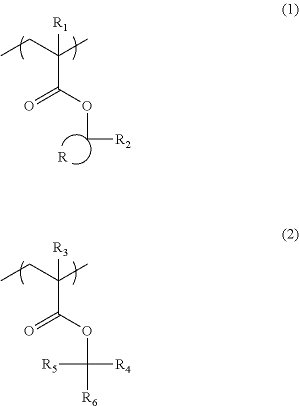

In formulae (1) and (2), each of R₁ and R₃ independently represents a hydrogen atom, a methyl group which may have a substituent, or a group represented by —CH₂—R₉. R₉ represents a monovalent organic group. Specific examples and preferred examples of the monovalent organic group in R₉ are the same as those described for R₉ in formula (AI).

Each of R₂, R₄, R₅ and R₆ independently represents an alkyl group or a cycloalkyl group.

R represents an atomic group necessary for forming an alicyclic structure together with the carbon atom.

Each of R₁ and R₃ is independently, preferably a hydrogen atom, a methyl group, a trifluoromethyl group or a hydroxymethyl group, more preferably a hydrogen atom or a methyl group, still more preferably a methyl group.

The alkyl group in R₂ may be linear or branched and may have a substituent.

The cycloalkyl group in R₂ may be monocyclic or polycyclic and may have a substituent.

R₂ is preferably an alkyl group, more preferably an alkyl group having a carbon number of 1 to 10, still more preferably an alkyl group having a carbon number of 1 to 5, and examples thereof include a methyl group and an ethyl group.

R represents an atomic group necessary for forming an alicyclic structure together with the carbon atom. The alicyclic structure formed by R together with the carbon atom is preferably a monocyclic alicyclic structure, and the carbon number thereof is preferably from 3 to 7, more preferably 5 or 6.

The alkyl group in R₄, R₅ and R₆ may be linear or branched and may have a substituent. The alkyl group is preferably an alkyl group having a carbon number of 1 to 4, such as methyl group, ethyl group, n-propyl group, isopropyl group, n-butyl group, isobutyl group and tert-butyl group.

The cycloalkyl group in R₄, R₅ and R₆ may be monocyclic or polycyclic and may have a substituent. The cycloalkyl group is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

Examples of the repeating unit represented by formula (1) include a repeating unit represented by the following formula (1-a):

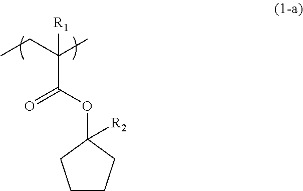

In the formula, R₁ and R₂ have the same meanings as those in formula (1).

The repeating unit represented by formula (2) is preferably a repeating unit represented by the following formula (2-1):

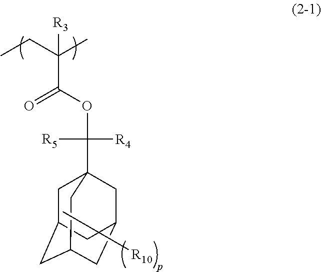

In formula (2-1), R₃ to R₅ have the same meanings as those in formula (2).

R₁₀ represents a polar group-containing substituent. In the case where a plurality of R₁₀'s are present, these may be the same or different. Examples of the polar group-containing substituent include a hydroxyl group, a cyano group, an amino group, an alkylamide group, a sulfonamide group itself, and a linear or branched alkyl group or cycloalkyl group having at least one of the groups above. An alkyl group having a hydroxyl group is preferred, and a branched alkyl group having a hydroxyl group is more preferred. The branched alkyl group is preferably an isopropyl group.

p represents an integer of 0 to 15. p is preferably an integer of 0 to 2, more preferably 0 or 1.

The resin (A) may contain a plurality of repeating units having an acid-decomposable group.

The resin (A) is preferably a resin containing, as the repeating unit represented by formula (AI), a repeating unit represented by formula (1) and a repeating unit represented by formula (2). In another embodiment, the resin is preferably a resin containing, as the repeating unit represented by formula (AI), at least two kinds of repeating units represented by formula (1).

It is also possible that the composition of the present invention contains a plurality of kinds of resins (A) and the acid-decomposable group-containing repeating units in the plurality of resins (A) differ from each other. For example, a resin (A) containing a repeating unit represented by formula (1) and a resin (A) containing a repeating unit represented by formula (2) may be used in combination.

In the case where the resin (A) contains a plurality of acid-decomposable group-containing repeating units or where a plurality of resins (A) have different acid-decomposable group-containing repeating units, preferred examples of the combination are illustrated below. In the formulae below, each R independently represents a hydrogen atom or a methyl group.

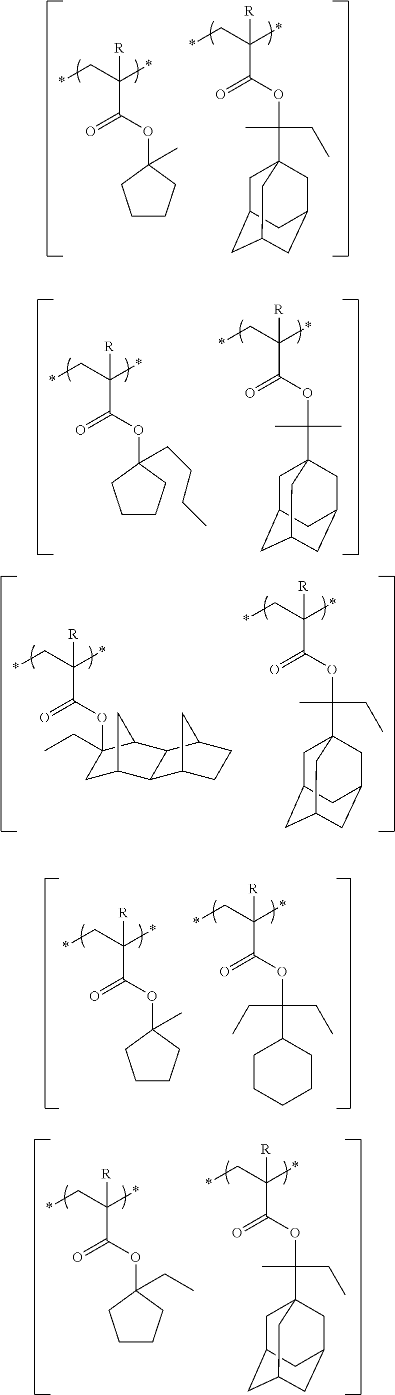

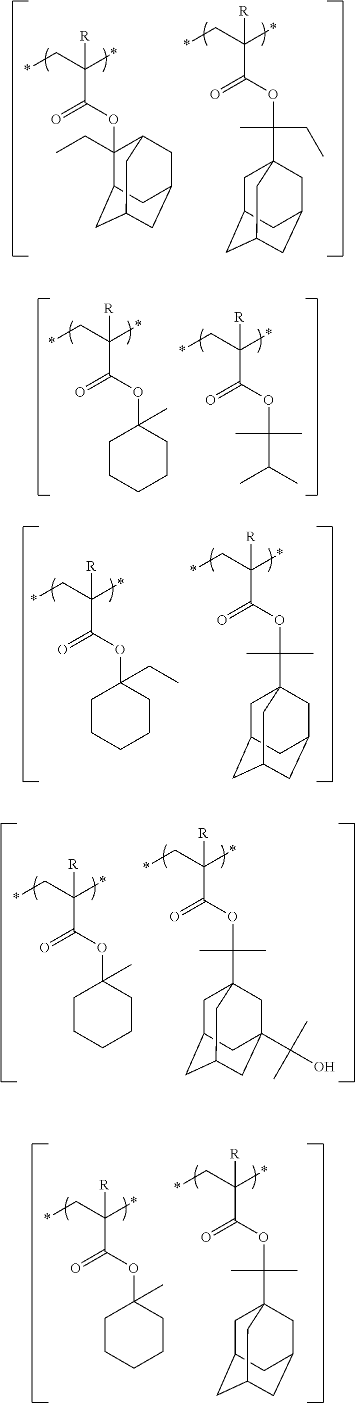

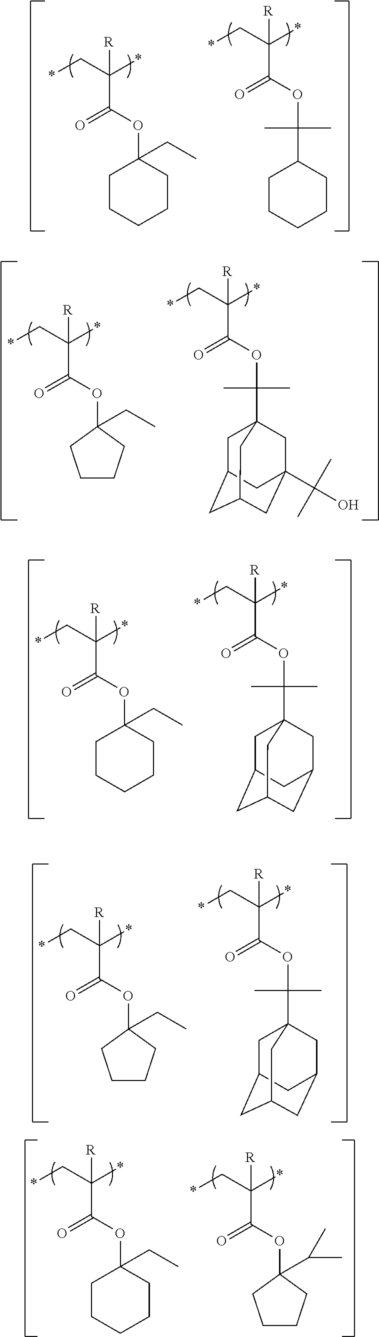

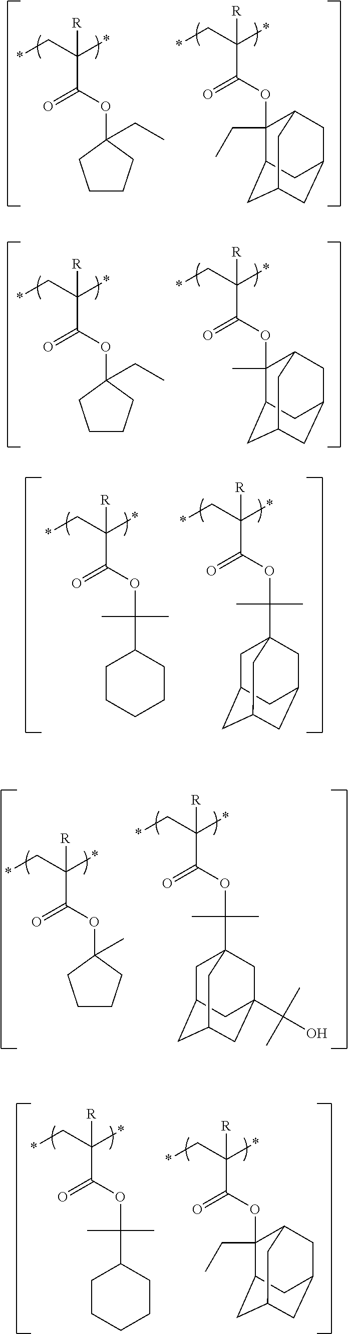

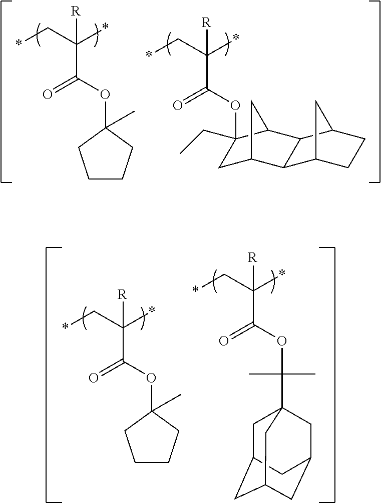

The resin (A) preferably contains a repeating unit having a hydroxyl group or a cyano group, separately from the repeating units (a1) to (a4) described above (when these repeating units have a hydroxyl group or a cyano group). Thanks to this repeating unit, the adherence to substrate and the affinity for developer can be enhanced. The repeating unit having a hydroxyl group or a cyano group is preferably a repeating unit having an alicyclic hydrocarbon structure substituted with a hydroxyl group or a cyano group and preferably has no acid-decomposable group. The alicyclic hydrocarbon structure in the alicyclic hydrocarbon structure substituted with a hydroxyl group or a cyano group is preferably an adamantyl group, a diamantyl group or a norbornane group.

Preferred examples of the alicyclic hydrocarbon structure substituted with a hydroxyl group or a cyano group include a monohydroxyadamantyl group, a dihydroxyadamantyl group, a monohydroxydiamantyl group, a dihydroxydiamantyl group, and a cyano group-substituted norbornyl group. The alicyclic hydrocarbon structure substituted with a hydroxyl group or a cyano group is preferably a partial structure represented by the following formulae (VIIa) to (VIId):

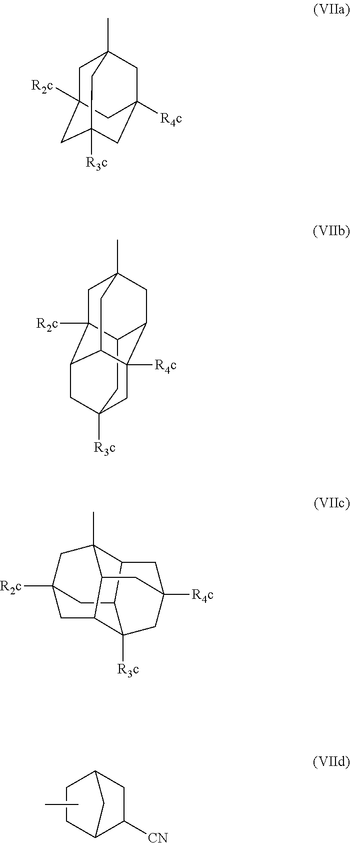

In formulae (VIIa) to (VIIc), each of R₂c to R₄c independently represents a hydrogen atom, a hydroxyl group or a cyano group. However, at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (AIIa) to (AIId):

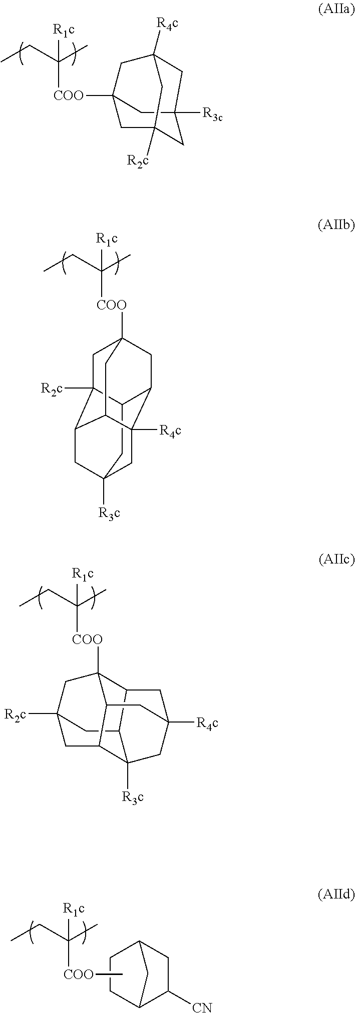

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc).

In the case where the resin (A) for use in the present invention contains a repeating unit having a hydroxy group or a cyano group, the content thereof is preferably from 5 to 40 mol %, more preferably from 5 to 30 mol %, still more preferably from 10 to 25 mol %, based on all repeating units in the resin (A).

Specific examples of the repeating unit having a hydroxy group or a cyano group are illustrated below, but the present invention is not limited thereto.

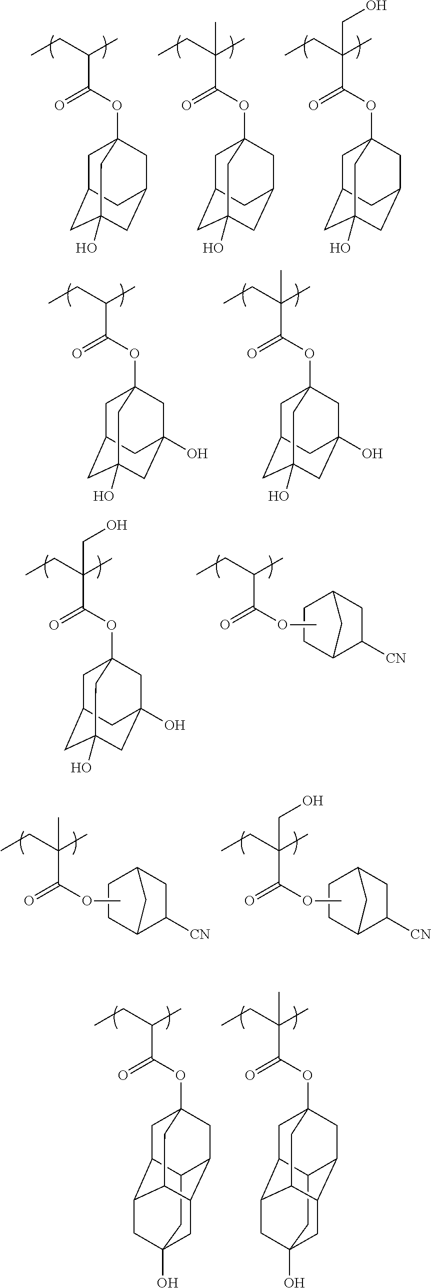

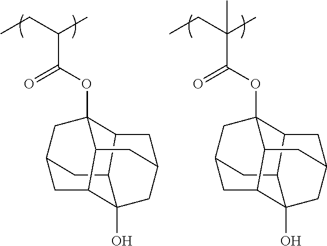

The resin (A) for use in the composition of the present invention may or may not contain a repeating unit having an alkali-soluble group, other than the repeating unit represented by formula (I). Examples of the alkali-soluble group include a carboxyl group and an aliphatic alcohol substituted with an electron-withdrawing group at the α-position (e.g., hexafluoroisopropanol). In the case of containing an alkali-soluble group-containing repeating unit other than the repeating unit represented by formula (I), it is preferred to contain a repeating unit having a carboxy group. By virtue of containing a repeating unit having such an alkali-soluble group, the resolution increases in the usage of forming contact holes. The repeating unit having an alkali-soluble group may be any of a repeating unit where the alkali-soluble group is directly bonded to the main chain of the resin, such as repeating unit by an acrylic acid or a methacrylic acid, a repeating unit where the alkali-soluble group is bonded to the main chain of the resin through a linking group, and a repeating unit where the alkali-soluble group is introduced into the terminal of the polymer chain by using a polymerization initiator or chain transfer agent having the alkali-soluble group at the polymerization. The linking group may have a monocyclic or polycyclic, cyclic hydrocarbon structure. A repeating unit by an acrylic acid or a methacrylic acid is more preferred.

In the case where the resin (A) contains a repeating unit having an alkali-soluble group other than the repeating unit represented by formula (I), the content of the repeating unit having an alkali-soluble group is preferably from 0.1 to 20 mol %, more preferably from 3 to 15 mol %, still more preferably from 5 to 10 mol %, based on all repeating units in the resin (A).

From the standpoint of improving the DOF, pattern collapse and iso/dense bias and providing a composition suitable for the immersion process, it is also preferred that the resin (A) contains substantially no alkali-soluble group-containing repeating unit (specifically, the ratio of the alkali-soluble group-containing repeating unit is, based on all repeating units in the resin (A), preferably 5 mol % or less, more preferably 3 mol % or less, and ideally 0 mol %, that is, the resin does not contain the alkali-soluble group-containing repeating unit), other than the repeating unit represented by formula (I).

Specific examples of the repeating unit having an alkali-soluble group are illustrated below, but the present invention is not limited thereto.

In specific examples, Rx represents H, CH₃, CH₂OH or CF₃.

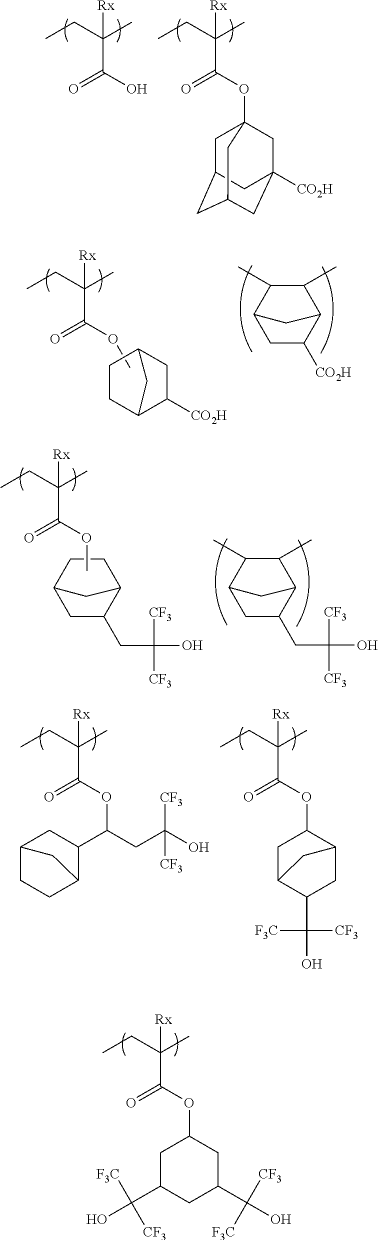

The resin (A) preferably further contains a repeating unit having an alicyclic hydrocarbon structure free from a polar group (for example, the above-described alkali-soluble group, a hydroxyl group or a cyano group) and not exhibiting acid decomposability. Such a repeating unit includes a repeating unit represented by the following formula (IV):

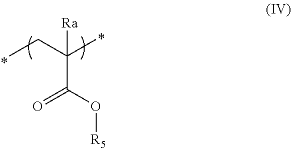

In formula (IV), R₅ represents a hydrocarbon group having at least one cyclic structure and having no polar group. The polar group includes specific examples of R₁₀ in formula (2-1).

Ra represents a hydrogen atom, an alkyl group, or a —CH₂—O—Ra₂ group, wherein Ra₂ represents a hydrogen atom, an alkyl group or an acyl group. The alkyl group represented by Ra may have a substituent such as hydroxyl group and halogen atom. Ra is preferably a hydrogen atom, a methyl group, a hydroxymethyl group or a trifluoromethyl group, more preferably a hydrogen atom or a methyl group.

The cyclic structure contained in R₅ includes a monocyclic hydrocarbon group and a polycyclic hydrocarbon group. Examples of the monocyclic hydrocarbon group include a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. The monocyclic hydrocarbon group is preferably a monocyclic hydrocarbon group having a carbon number of 3 to 7, more preferably a cyclopentyl group or a cyclohexyl group.

The polycyclic hydrocarbon group includes a ring assembly hydrocarbon group and a crosslinked cyclic hydrocarbon group. Examples of the ring assembly hydrocarbon group include a bicyclohexyl group and a perhydronaphthalenyl group. Examples of the crosslinked cyclic hydrocarbon ring include a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}.1^{7,10}]dodecane ring and perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as perhydronaphthalene (decalin) ring, perhydroanthracene ring, perhydrophenathrene ring, perhydroacenaphthene ring, perhydrofluorene ring, perhydroindene ring and perhydrophenalene ring.

Preferred examples of the crosslinked cyclic hydrocarbon ring include a norbornyl group, an adamantyl group, a bicyclooctanyl group and a tricycle[5,2,1,0^{2,6}]decanyl group. Of these crosslinked cyclic hydrocarbon rings, a norbornyl group and an adamantyl group are more preferred.

These alicyclic hydrocarbon groups may have a substituent, and preferred examples of the substituent include a halogen atom, an alkyl group, a hydroxyl group protected by a protective group, and an amino group protected by a protective group. The halogen atom is preferably bromine atom, chlorine atom or fluorine atom, and the alkyl group is preferably a methyl group, an ethyl group, a butyl group or a tert-butyl group. This alkyl group may further have a substituent, and the substituent which the alkyl group may further have includes a halogen atom, an alkyl group, a hydroxyl group protected by a protective group, and an amino group protected by a protective group.

Examples of the protective group include an alkyl group, a cycloalkyl group, an aralkyl group, a substituted methyl group, a substituted ethyl group, an acyl group, an alkoxycarbonyl group and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group is, for example, an alkoxycarbonyl group having a carbon number of 2 to 4.

The resin (A) for use in the present invention may or may not contain a repeating unit having a polar group-free alicyclic hydrocarbon structure and not exhibiting acid decomposability, but in the case of containing the repeating unit, the content thereof is preferably from 1 to 40 mol %, more preferably from 5 to 20 mol %, based on all repeating units in the resin (A).

Specific examples of the repeating unit having a polar group-free alicyclic hydrocarbon structure and not exhibiting acid decomposability are illustrated below, but the present invention is not limited thereto. In the formulae, Ra represents H, CH₃, CH₂OH or CF₃.

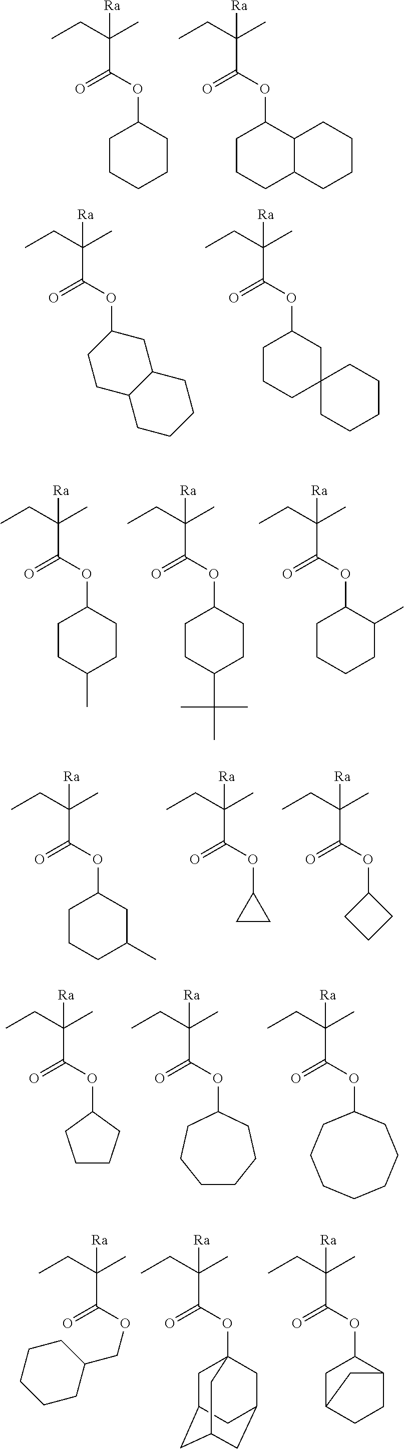

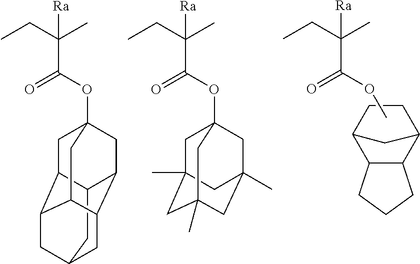

The resin (A) for use in the composition of the present invention may contain, in addition to the above-described repeating structural units, various repeating structural units for the purpose of controlling the dry etching resistance, suitability for standard developer, adherence to substrate, resist profile and properties generally required of a resist, such as resolution, heat resistance and sensitivity.

Examples of such a repeating structural unit include, but are not limited to, repeating structural units corresponding to the monomers described below.

Thanks to these repeating units, the performance required of the resin (A), particularly

(1) solubility in coating solvent,

(2) film-forming property (glass transition temperature),

(3) alkali developability,

(4) film loss (selection of hydrophilic, hydrophobic or alkali-soluble group),

(5) adherence of unexposed area to substrate,

(6) dry etching resistance and the like, can be subtly controlled.

Examples of the monomer include a compound having one addition-polymerizable unsaturated bond selected from acrylic acid esters, methacrylic acid esters, acrylamides, methacrylamides, allyl compounds, vinyl ethers and vinyl esters.

Other than these, an addition-polymerizable unsaturated compound copolymerizable with the monomers corresponding to the above-described various repeating structural units may be copolymerized.

In the resin (A) for use in the composition of the present invention, the molar ratio of respective repeating structural units contained can be appropriately set to control the dry etching resistance of resist, suitability for standard developer, adherence to substrate, resist profile and performances generally required of a resist, such as resolution, heat resistance and sensitivity.

In the case where the composition of the present invention is used for ArF exposure, in view of transparency to ArF light, the resin (A) preferably has substantially no aromatic group (specifically, the ratio of an aromatic group-containing repeating unit in the resin (A) is preferably 5 mol % or less, more preferably 3 mol % or less, and ideally 0 mol %, that is, the resin does not have an aromatic group), and the resin (A) preferably has a monocyclic or polycyclic alicyclic hydrocarbon structure. Incidentally, the resin (A) preferably contains no fluorine atom and no silicon atom in view of compatibility with the later-described hydrophobic resin (C).

The resin (A) for use in the composition of the present invention is preferably a resin where all repeating units are composed of a (meth)acrylate-based repeating unit. In this case, all repeating units may be a methacrylate-based repeating unit, all repeating units may be an acrylate-based repeating unit, or all repeating units may be composed of a methacrylate-based repeating unit and an acrylate-based repeating unit, but the content of the acrylate-based repeating unit is preferably 50 mol % or less based on all repeating units. A copolymerized polymer containing from 20 to 50 mol % of an acid decomposable group-containing (meth)acrylate-based repeating unit, from 20 to 50 mol % of a lactone group-containing (meth)acrylate-based repeating unit, from 5 to 30 mol % of a (meth)acrylate-based repeating unit having an alicyclic hydrocarbon structure substituted with a hydroxyl group or a cyano group, and from 0 to 20 mol % of other (meth)acrylate-based repeating units, is also preferred.

In the case of irradiating the composition of the present invention with KrF excimer laser light, electron beam, X-ray or high-energy beam at a wavelength of 50 nm or less (e.g., EUV), the resin (A) preferably further contains a hydroxystyrene-based repeating unit. It is more preferred to contain a hydroxystyrene-based repeating unit, a hydroxystyrene-based repeating unit protected by an acid-decomposable group, and an acid-decomposable repeating unit such as tertiary alkyl (meth)acrylate.

Preferred examples of the hydroxystyrene-based repeating unit having an acid-decomposable group include repeating units composed of a tert-butoxycarbonyloxystyrene, a 1-alkoxyethoxystyrene or a tertiary alkyl (meth)acrylate. Repeating units composed of a 2-alkyl-2-adamantyl (meth)acrylate or a dialkyl(1-adamantyl)methyl (meth)acrylate are more preferred.

The resin (A) for use in the present invention can be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include ethers such as tetrahydrofuran, 1,4-dioxane, diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate (PGMEA, another name: 1-methoxy-2-acetoxypropane), propylene glycol monomethyl ether (PGME, another name: 1-methoxy-2-propanol) and cyclohexanone. The polymerization is more preferably performed using the same solvent as the solvent used in the actinic ray-sensitive or radiation-sensitive resin composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methylpropionate). The initiator is added additionally or in parts, if desired. After the completion of reaction, the reaction product is poured in a solvent, and the desired polymer is collected by a method such as powder or solid recovery. The concentration at the reaction is from 5 to 50 mass %, preferably from 10 to 30 mass %, and the reaction temperature is usually from 10 to 150° C., preferably from 30 to 120° C., more preferably from 60 to 100° C. (In this specification, mass ratio is equal to weight ratio.)

After the completion of reaction, the reaction solution is allowed to cool to room temperature and purified. The purification may be performed by a normal method, for example, a liquid-liquid extraction method of applying water washing or combining an appropriate solvent to remove residual monomers or oligomer components; a purification method in a solution state, such as ultrafiltration of removing by extraction only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent for the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing such a solvent, and the like, according to the kind of the polymer. Among these solvents, a solvent containing at least an alcohol (particularly, methanol or the like) or water is preferred as the precipitation or reprecipitation solvent.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by taking into consideration the efficiency or operability but is usually on the order of 0 to 50° C., preferably in the vicinity of room temperature (for example, approximately from 20 to 35° C.). The precipitation or reprecipitation operation may be performed using a commonly employed mixing vessel such as stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C., preferably on the order of 30 to 50° C.

Incidentally, after the resin is once precipitated and separated, the resin may be again dissolved in a solvent and then put into contact with a solvent in which the resin is sparingly soluble or insoluble. That is, there may be used a method comprising, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

The weight average molecular weight of the resin (A) for use in the present invention is preferably from 1,000 to 200,000, more preferably from 2,000 to 20,000, still more preferably from 3,000 to 15,000, yet still more preferably from 5,000 to 13,000, in terms of polystyrene by the GPC method. When the weight average molecular weight is from 1,000 to 200,000, reduction in the heat resistance and dry etching resistance can be more avoided and at the same time, the film-forming property can be prevented from deterioration due to impairment of developability or increase in the viscosity.

The dispersity (molecular weight distribution) is usually from 1.0 to 3.0, preferably from 1.0 to 2.6, more preferably from 1.0 to 2.0, still more preferably from 1.4 to 2.0. As the molecular weight distribution is smaller, the resolution and resist profile are more excellent, the side wall of the resist pattern is smoother, and the roughness is more improved.

In the actinic ray-sensitive or radiation-sensitive resin composition of the present invention, the blending ratio of the resin (A) in the entire composition is preferably from 30 to 99 mass %, more preferably from 60 to 95 mass %, based on the entire solid content.

As for the resin (A) used in the present invention, one kind of a resin may be used or a plurality of kinds of resins may be used in combination (polymer blend).

Also, a resin (A′) other than the resin (A) for use in the present invention may be used in combination within the range not impairing the effects of the present invention. In this case, the resin (A) preferably accounts for 50 mass % or more in the resins (A) and (A′). The resin (A′) other than the resin (A) for use in the present invention is not particularly limited as long as it is not an acid-decomposable resin containing a repeating unit represented by formula (I) and a repeating unit having a partial structure represented by formula (II), and such a resin includes an acid-decomposable resin that may contain a repeating unit which may be contained in the resin (A), and other known acid-decomposable resins.

In the resin (A) for use in the present invention, the content of monomer components contained in the resin is 1.0 mass % or less, preferably 0.8 mass % or less, more preferably 0.5 mass % or less, based on the entire resin. Considering the production suitability, an excessive purification step of completely eliminating monomer components is inappropriate, and the monomer component preferably remains in an amount of 0.01 mass % or more, more preferably 0.05 mass % or more. The amount of monomer components in the resin (A) can be analyzed by subjecting the resin to high-performance liquid chromatography (HPLC). If the monomer component content exceeds 1.0 mass %, the depth-of-focus (DOF) range characteristics are seriously deteriorated and at the formation of a resist pattern, the defocus latitude tends to decrease. The monomer component is an unreacted monomer at the production of the resin and can be removed, for example, by a chemical purification method such as water washing and liquid-liquid extraction or by a combination of such a chemical purification method and a physical purification method such as ultrafiltration and centrifugal separation. Among these purification methods, in view of production suitability, a reprecipitation method of adding the reaction solution after reaction to a poor solvent to obtain a powder is preferred, and a purification method using a re-slurrying step where the powder obtained in the reprecipitation step is further added to a poor solvent and then washed, is more preferred. Out of the monomer components, the components responsible for a large degree of performance deterioration are the monomer having a group capable of decomposing by the action of an acid to produce an alkali-soluble group and the monomer having a lactone group, and the more influential monomer component is the monomer having a lactone group. The lactone group-containing monomer component is high in the polarity and generally liable to remain because of its low solvent solubility, and the residual amount of this monomer component in the resin must be controlled. Above all, the monomer component exerting a large influence is a monomer component represented by the following formula (II-1a):

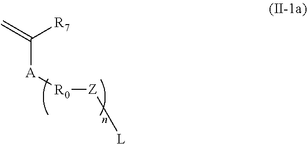

In formula (II-1a), R₇, A, R₀, Z, L and n have the same meanings as R₇, A, R₀, Z, L and n in formula (II-1).

Specific examples of the monomer component represented by formula (II-1a) are illustrated blow. In specific examples, R has the same meaning as R in specific examples of formula (II-3).

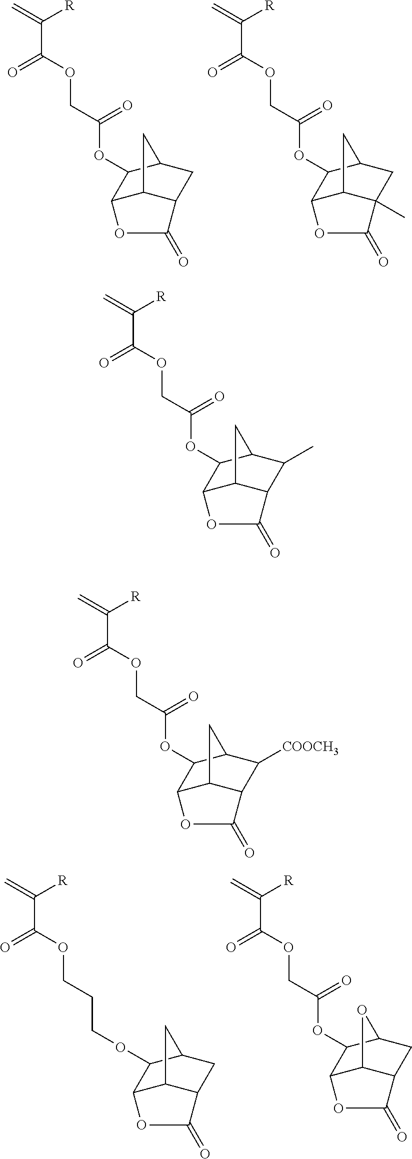

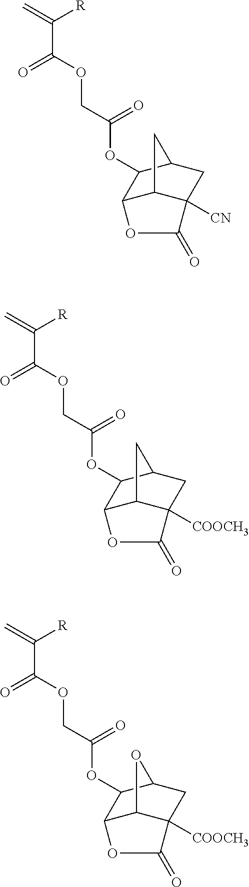

[2] (B) Compound Capable of Generating an Acid Upon Irradiation with an Actinic Ray or Radiation

The actinic ray-sensitive or radiation-sensitive resin composition of the present invention contains a compound capable of generating an acid upon irradiation with an actinic ray or radiation (hereinafter, sometimes referred to as an “acid generator”).

The acid generator which can be used may be appropriately selected from a photo-initiator for cationic photopolymerization, a photo-initiator for radical photopolymerization, a photo-decoloring agent for dyes, a photo-discoloring agent, a known compound that generates an acid upon irradiation with an actinic ray or radiation and is used for microresist or the like, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Also, a compound where such a group or compound capable of generating an acid upon irradiation with an actinic ray or radiation is introduced into the main or side chain of the polymer, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853 and JP-A-63-146029, may be used.

Furthermore, compounds capable of generating an acid by the action of light described, for example, in U.S. Pat. No. 3,779,778 and European Patent 126,712 may also be used.

Out of the acid generators, preferred compounds are compounds represented by the following formulae (ZI), (ZII) and (ZIII):

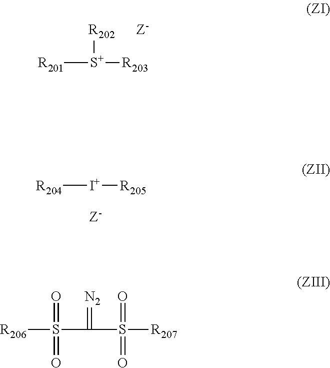

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., butylene, pentylene).

Z⁻ represents a non-nucleophilic anion.

Examples of the non-nucleophilic anion as Z⁻ include a sulfonate anion, a carboxylate anion, a sulfonylimide anion, a bis(alkylsulfonyl)imide anion and a tris(alkylsulfonyl)methide anion.

The non-nucleophilic anion is an anion having an extremely low ability of causing a nucleophilic reaction, and this anion can suppress the decomposition with aging due to an intramolecular nucleophilic reaction. Thanks to this anion, the aging stability of the resist is enhanced.

Examples of the sulfonate anion include an aliphatic sulfonate anion, an aromatic sulfonate anion and a camphorsulfonate anion.

Examples of the carboxylate anion include an aliphatic carboxylate anion, an aromatic carboxylate anion and an aralkylcarboxylate anion.

The aliphatic moiety in the aliphatic sulfonate anion may be an alkyl group or a cycloalkyl group but is preferably an alkyl group having a carbon number of 1 to 30 or a cycloalkyl group having a carbon number of 3 to 30, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a bornyl group.

The aromatic group in the aromatic sulfonate anion is preferably an aryl group having a carbon number of 6 to 14, and examples thereof include a phenyl group, a tolyl group and a naphthyl group.

The alkyl group, cycloalkyl group and aryl group in the aliphatic sulfonate anion and aromatic sulfonate anion may have a substituent. Examples of the substituent of the alkyl group, cycloalkyl group and aryl group in the aliphatic sulfonate anion and aromatic sulfonate anion include a nitro group, a halogen atom (e.g., fluorine, chlorine, bromine, iodine), a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 1 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). As for the aryl group or ring structure in each group, examples of the further substituent include an alkyl group (preferably having a carbon number of 1 to 15) and a cycloalkyl group (preferably having a carbon number of 3 to 15).

Examples of the aliphatic moiety in the aliphatic carboxylate anion include the same alkyl groups and cycloalkyl groups as those in the aliphatic sulfonate anion.

Examples of the aromatic group in the aromatic carboxylate anion include the same aryl groups as those in the aromatic sulfonate anion.

The aralkyl group in the aralkylcarboxylate anion is preferably an aralkyl group having a carbon number of 7 to 12, and examples thereof include a benzyl group, a phenethyl group, a naphthylmethyl group, a naphthylethyl group and a naphthylbutyl group.

The alkyl group, cycloalkyl group, aryl group and aralkyl group in the aliphatic carboxylate anion, aromatic carboxylate anion and aralkylcarboxylate anion may have a substituent. Examples of the substituent of the alkyl group, cycloalkyl group, aryl group and aralkyl group in the aliphatic carboxylate anion, aromatic carboxylate anion and aralkylcarboxylate anion include the same halogen atoms, alkyl groups, cycloalkyl groups, alkoxy groups and alkylthio groups as those in the aromatic sulfonate anion.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group. Examples of the substituent of such an alkyl group include a halogen atom, a halogen atom-substituted alkyl group, an alkoxy group, an alkylthio group, an alkyloxysulfonyl group, an aryloxysulfonyl group and a cycloalkylaryloxysulfonyl group, with a fluorine atom-substituted alkyl group being preferred.

Incidentally, two alkyl groups in the bis(alkylsulfonyl)imide anion may be the same or different. Similarly, the plurality of alkyl groups in the tris(alkylsulfonyl)methide anion may be the same or different.

In particular, the bis(alkylsulfonyl)imide anion and tris(alkylsulfonyl)methyl anion include anions represented by the following formulae (A3) and (A4):

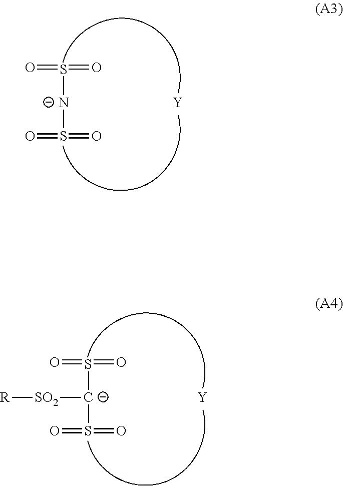

In formulae (A3) and (A4), Y is an alkylene group substituted with at least one fluorine atom, preferably an alkylene group having a carbon number of 2 to 4. The alkylene chain may contain an oxygen atom. Y is more preferably a perfluoroalkylene group having a carbon number of 2 to 4, and most preferably a tetrafluoroethylene group, a hexafluoropropylene group or an octafluorobutylene group.

In formula (A4), R represents an alkyl group or a cycloalkyl group. The alkylene chain in the alkyl or cycloalkyl group may contain an oxygen atom.

Examples of the compound having an anion represented by formula (A3) or (A4) include those described as specific examples in JP-A-2005-221721.

Other examples of the non-nucleophilic anion include fluorinated phosphorus, fluorinated boron and fluorinated antimony.

The non-nucleophilic anion of Z⁻ is preferably an aliphatic sulfonate anion substituted with a fluorine atom at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having a carbon number of 4 to 8, or a fluorine atom-containing benzenesulfonate anion, still more preferably nonafluorobutanesulfonate anion, perfluorooctanesulfonate anion, pentafluorobenzenesulfonate anion or 3,5-bis(trifluoromethyl)benzenesulfonate anion.

Furthermore, an anion capable of producing an acid represented by the following formula (I) is also preferred as the sulfonate anion.

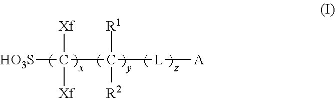

In the formula, each Xf independently represents a fluorine atom or an alkyl group substituted with at least one fluorine atom. Each of R¹ and R² independently represents a group selected from a hydrogen atom, a fluorine atom and an alkyl group, and when a plurality of R¹'s or R²'s are present, each R¹ or R² may be the same as or different from every other R¹ or R². L represents a divalent linking group, and when a plurality of L's are present, these may be the same or different. A represents a cyclic organic group. x represents an integer of 1 to 20, y represents an integer of 0 to 10, and z represents an integer of 0 to 10.

Formula (I) is described in more detail below.

The alkyl group in the fluorine atom-substituted alkyl group of Xf is preferably an alkyl group having a carbon number of 1 to 10, more preferably a carbon number of 1 to 4. Also, the fluorine atom-substituted alkyl group of Xf is preferably a perfluoroalkyl group.

Xf is preferably a fluorine atom or a perfluoroalkyl group having a carbon number of 1 to 4. Specific examples of Xf include a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with a fluorine atom and CF₃ being preferred. In particular, it is preferred that both Xf s are a fluorine atom.

The alkyl group of R¹ and R² may have a substituent (preferably fluorine atom) and is preferably an alkyl group having a carbon number of 1 to 4, more preferably a perfluoroalkyl group having a carbon number of 1 to 4. Specific examples of the alkyl group of R¹ and R² having a substituent include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

Each of R₁ and R₂ is preferably a fluorine atom or CF₃.

y is preferably from 0 to 4, more preferably 0. x is preferably from 1 to 8, more preferably from 1 to 4. z is preferably from 0 to 8, more preferably from 0 to 4. The divalent linking group of L is not particularly limited and includes —COO—, —COO—, —CO—, —O—, —S—, —SO—, —SO₂—, an alkylene group, a cycloalkylene group, an alkenylene group, and a linking group formed by connecting a plurality of these members, and a linking group having a total carbon number of 12 or less is preferred. Above all, —COO—, —COO—, —CO—, —O— and —SO₂— are preferred, and —COO—, —COO— and —SO₂— are more preferred.

The cyclic organic group of A is not particularly limited, and examples thereof include an alicyclic group, an aryl group and a heterocyclic group (including not only those having aromaticity but also those having no aromaticity).

The alicyclic group may be monocyclic or polycyclic and is preferably a monocyclic cycloalkyl group such as cyclopentyl group, cyclohexyl group and cyclooctyl group, or a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint that diffusion in the film at the PEB (post-exposure baking) step can be suppressed and MEEF (mask error enhancement factor) can be improved.

The aryl group includes a benzene ring, a naphthalene ring, a phenanthrene ring and an anthracene ring. Among these, naphthalene having low absorbance is preferred in view of absorbance for light at a wavelength of 193 nm.

The heterocyclic group includes those derived from a furan ring, a thiophene ring, a benzofuran ring, a benzothiophene ring, a dibenzofuran ring, a dibenzothiophene ring, a pyridine ring and a piperidine ring. In particular, those derived from a furan ring, a thiophene ring, a pyridine ring and a piperidine ring are preferred.

The cyclic organic group also includes a lactone structure, and specific examples thereof include lactone structures represented by formulae (LC1-1) to (LC1-17), which the resin (A) may have.

The above-described cyclic organic group may have a substituent, and examples of the substituent include an alkyl group (may be either linear or branched, preferably having a carbon number of 1 to 12), a cycloalkyl group (may be any of monocyclic, polycyclic or spirocyclic, preferably having a carbon number of 3 to 20), an aryl group (preferably having a carbon number of 6 to 14), a hydroxyl group, an alkoxy group, an ester group, an amide group, a urethane group, a ureido group, a thioether group, a sulfonamide group, and a sulfonic acid ester group. Incidentally, the carbon constituting the cyclic organic group (the carbon contributing to ring formation) may be carbonyl carbon.

The organic group as R₂₀₁, R₂₀₂ and R₂₀₃ in formula (ZI) includes, for example, corresponding groups in the compounds (ZI-1) to (ZI-4) described later.

The compound may be a compound having a plurality of structures represented by formula (ZI). For example, the compound may be a compound having a structure where at least one of R₂₀₁ to R₂₀₃ in a compound represented by formula (ZI) is bonded to at least one of R₂₀₁ to R₂₀₃ in another compound represented by formula (ZI).

Compounds (ZI-1) to (ZI-4) described below are more preferred as the component (ZI).

The compound (ZI-1) is an arylsulfonium compound where at least one of R₂₀₁ to R₂₀₃ in formula (ZI) is an aryl group, that is, a compound having an arylsulfonium as the cation.

In the arylsulfonium compound, all of R₂₀₁ to R₂₀₃ may be an aryl group or a part of R₂₀₁ to R₂₀₃ may be an aryl group with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound.

The aryl group in the arylsulfonium compound is preferably a phenyl group or a naphthyl group, more preferably a phenyl group. The aryl group may be an aryl group having a heterocyclic structure containing an oxygen atom, a nitrogen atom, a sulfur atom or the like. Examples of the heterocyclic structure include pyrrole, furan, thiophene, indole, benzofuran and benzothiophene structures. In the case where the arylsulfonium compound has two or more aryl groups, these two or more aryl groups may be the same or different.

The alkyl or cycloalkyl group which is present, if desired, in the arylsulfonium compound is preferably a linear or branched alkyl group having a carbon number of 1 to 15 or a cycloalkyl group having a carbon number of 3 to 15, and examples thereof include a methyl group, an ethyl group, a propyl group, an n-butyl group, a sec-butyl group, a tert-butyl group, a cyclopropyl group, a cyclobutyl group and a cyclohexyl group.

The aryl group, alkyl group and cycloalkyl group of R₂₀₁ to R₂₀₃ may have, as the substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4, or an alkoxy group having a carbon number of 1 to 4. The substituent may substitute on any one of three members R₂₀₁ to R₂₀₃ or may substitute on all of these three members. In the case where R₂₀₁ to R₂₀₃ are an aryl group, the substituent preferably substitute at the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein includes an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ independently represents preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10 (e.g., methyl, ethyl, propyl, butyl, pentyl), and a cycloalkyl group having a carbon number of 3 to 10 (e.g., cyclopentyl, cyclohexyl, norbornyl). The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5 (e.g., methoxy, ethoxy, propoxy, butoxy, pentoxy).

R₂₀₁ to R₂₀₃ may be further substituted with a halogen atom, an alkoxy group (for example, having a carbon number of 1 to 5), a hydroxyl group, a cyano group or a nitro group.

The compound (ZI-3) is a compound represented by the following formula (ZI-3), and this is a compound having a phenacylsulfonium salt structure.

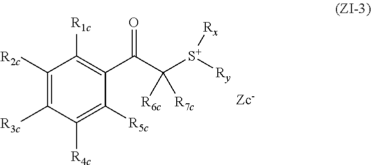

In formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Each of R_{6c} and R_{7c} independently represents a hydrogen atom, an alkyl group, a cycloalkyl group, a halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more members out of R_{1c} to R_{5c}, a pair of R_{5c} and R_{6c}, a pair of R_{6c} and R_{7c}, a pair of R_{5c} and Rₓ, or a pair of Rₓ and R_{y} may combine together to form a ring structure. This ring structure may contain an oxygen atom, a sulfur atom, a ketone group, an ester bond or an amide bond.

The ring structure includes an aromatic or non-aromatic hydrocarbon ring, an aromatic or non-aromatic heterocyclic ring, and a polycyclic condensed ring formed by combining two or more of these rings. The ring structure is a 3- to 10-membered ring, preferably a 4- to 8-membered ring, more preferably a 5- or 6-membered ring.

Examples of the group formed by combining any two or more members out of R_{1c} to R_{5c}, a pair of R_{6c} and R_{7c}, or a pair of Rₓ and R_{y} include a butylene group and a pentylene group.

The group formed by combining a pair of R_{5c} and R_{6c} or a pair of R_{5c} and Rₓ is preferably a single bond or an alkylene group, and examples of the alkylene group include a methylene group and an ethylene group.

Zc⁻ represents a non-nucleophilic anion, and examples thereof are the same as those of the non-nucleophilic anion of Z⁻ in formula (ZI).

The alkyl group as R_{1c} to R_{7c} may be either linear or branched and is, for example, an alkyl group having a carbon number of 1 to 20, preferably a linear or branched alkyl group having a carbon number of 1 to 12 (e.g., methyl group, ethyl group, linear or branched propyl group, linear or branched butyl group, linear or branched pentyl group). The cycloalkyl group is, for example, a cycloalkyl group having a carbon number of 3 to 10 (e.g., cyclopentyl, cyclohexyl).

The aryl group as R_{1c} to R_{7c} is preferably an aryl group having a carbon number of 5 to 15, and examples thereof include a phenyl group and a naphthyl group.

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (e.g., methoxy, ethoxy, linear or branched propoxy, linear or branched butoxy, linear or branched pentoxy), or a cyclic alkoxy group having a carbon number of 3 to 10 (e.g., cyclopentyloxy, cyclohexyloxy).

Specific examples of the alkoxy group in the alkoxycarbonylalkyl group of R_{1c} to R_{5c} are the same as specific examples of the alkoxy group of R_{1c} to R_{5c}.

Specific examples of the alkyl group in the alkylcarbonyloxy group and alkylthio group of R_{1c} to R_{5c} are the same as specific examples of the alkyl group of R_{1c} to R_{5c}.

Specific examples of the cycloalkyl group in the cycloalkylcarbonyloxy group of R_{1c} to R_{5c} are the same as specific examples of the cycloalkyl group of R_{1c} to R_{5c}.

Specific examples of the aryl group in the aryloxy group and arylthio group of R_{1c} to R_{5c} are the same as specific examples of the aryl group of R_{1c} to R_{5c}.

A compound where any one of R_{1c} to R_{5c} is a linear or branched alkyl group, a cycloalkyl group or a linear, branched or cyclic alkoxy group is preferred, and a compound where the sum of carbon numbers of R_{1c} to R_{5c} is from 2 to 15 is more preferred. Thanks to such a compound, the solvent solubility is more enhanced and production of particles during storage can be suppressed.

The ring structure which may be formed by combining any two or more members out of R_{1c} to R_{5c} with each other is preferably a 5- or 6-membered ring, more preferably a 6-membered ring (for example, a phenyl ring).

The ring structure which may be formed by combining R_{5c} and R_{6c} with each other includes a 4- or higher-membered ring (preferably a 5- or 6-membered ring) formed together with the carbonyl carbon atom and carbon atom in formula (ZI-3) by combining R_{5c} and R_{6c} with each other to constitute a single bond or an alkylene group (for example, a methylene group or an ethylene group).

In the case where R_{6c} and R_{7c} are combined to form a ring, the group formed by combining R_{6c} and R_{7c} is preferably an alkylene group having a carbon number of 2 to 10, and examples thereof include an ethylene group, a propylene group, a butylene group, a pentylene group and a hexylene group. Also, the ring formed by combining R_{6c} and R_{7c} may contain a heteroatom such as oxygen atom in the ring.

Examples of the alkyl group and cycloalkyl group as Rₓ and R_{y} are the same as those of the alkyl group and cycloalkyl group in R_{1c} to R_{7c}.

Examples of the 2-oxoalkyl group and 2-oxocycloalkyl group as Rₓ and R_{y} include a group having >C═O at the 2-position of the alkyl group or cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}. The alkyl group is, for example, an alkyl group having a carbon number of 1 to 12, preferably a linear alkyl group having a carbon number of 1 to 5 (e.g., methyl, ethyl).

The allyl group as Rₓ and R_{y} is not particularly limited but is preferably an unsubstituted allyl group or an allyl group substituted with a monocyclic or polycyclic cycloalkyl group (preferably a cycloalkyl group having a carbon number of 3 to 10).

The vinyl group as Rₓ and R_{y} is not particularly limited but is preferably an unsubstituted vinyl group or a vinyl group substituted with a monocyclic or polycyclic cycloalkyl group (preferably a cycloalkyl group having a carbon number of 3 to 10).

The ring structure which may be formed by combining R_{5c} and Rₓ with each other includes a 5- or higher-membered ring (preferably a 5-membered ring) formed together with the sulfur atom and carbonyl carbon atom in formula (ZI-3) by combining R_{5c} and Rₓ to constitute a single bond or an alkylene group (for example, a methylene group or an ethylene group).

The ring structure which may be formed by combining Rₓ and R_{y} with each other includes a 5- or 6-membered ring formed by divalent Rₓ and R_{y} (for example, a methylene group, an ethylene group or a propylene group) together with the sulfur atom in formula (ZI-3), and a 5-membered ring (that is, a tetrahydrothiophene ring) is particularly preferred.

Each of Rₓ and R_{y} is an alkyl or cycloalkyl group having a carbon number of preferably 4 or more, more preferably 6 or more, still more preferably 8 or more.

R_{1c} to R_{7c}, Rₓ and R_{y} may further have a substituent, and examples of the substituent include a halogen atom (e.g., fluorine), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group and an aryloxycarbonyloxy group.

Examples of the alkyl group above include a linear or branched alkyl group having a carbon number of 1 to 12, such as methyl group, ethyl group, n-propyl group, i-propyl group, n-butyl group, 2-methylpropyl group, 1-methylpropyl group and tert-butyl group.

Examples of the cycloalkyl group above include a cycloalkyl group having a carbon number of 3 to 10, such as cyclopentyl group and cyclohexyl group.

Examples of the aryl group above include an aryl group having a carbon number of 6 to 15, such as phenyl group and naphthyl group.

Examples of the alkoxy group above include a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

Examples of the aryloxy group above include an aryloxy group having a carbon number of 6 to 10, such as phenyloxy group and naphthyloxy group.

Examples of the acyl group above include a linear or branched acyl group having a carbon number of 2 to 12, such as acetyl group, propionyl group, n-butanoyl group, i-butanoyl group, n-heptanoyl group, 2-methylbutanoyl group, 1-methylbutanoyl group and tert-heptanoyl group.

Examples of the arylcarbonyl group above include an arylcarbonyl group having a carbon number of 6 to 10, such as phenylcarbonyl group and naphthylcarbonyl group.

Examples of the alkoxyalkyl group above include a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

Examples of the aryloxyalkyl group above include an aryloxyalkyl group having a carbon number of 7 to 12, such as phenyloxymethyl group, phenyloxyethyl group, naphthyloxymethyl group and naphthyloxyethyl group.

Examples of the alkoxycarbonyl group above include a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

Examples of the aryloxycarbonyl group above include an aryloxycarbonyl group having a carbon number of 7 to 11, such as phenyloxycarbonyl group and naphthyloxycarbonyl group.

Examples of the alkoxycarbonyloxy group above include a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

Examples of the aryloxycarbonyloxy group above include an aryloxycarbonyloxy group having a carbon number of 7 to 11, such as phenyloxycarbonyloxy group and naphthyloxycarbonyloxy group.

In formula (ZI-3), it is more preferred that each of R_{1c}, R_{2c}, R_{4c} and R_{5c} independently represents a hydrogen atom and R_{3c} represents a group except for a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Specific examples of the cation of the compound represented by formula (ZI-3) include those illustrated below.

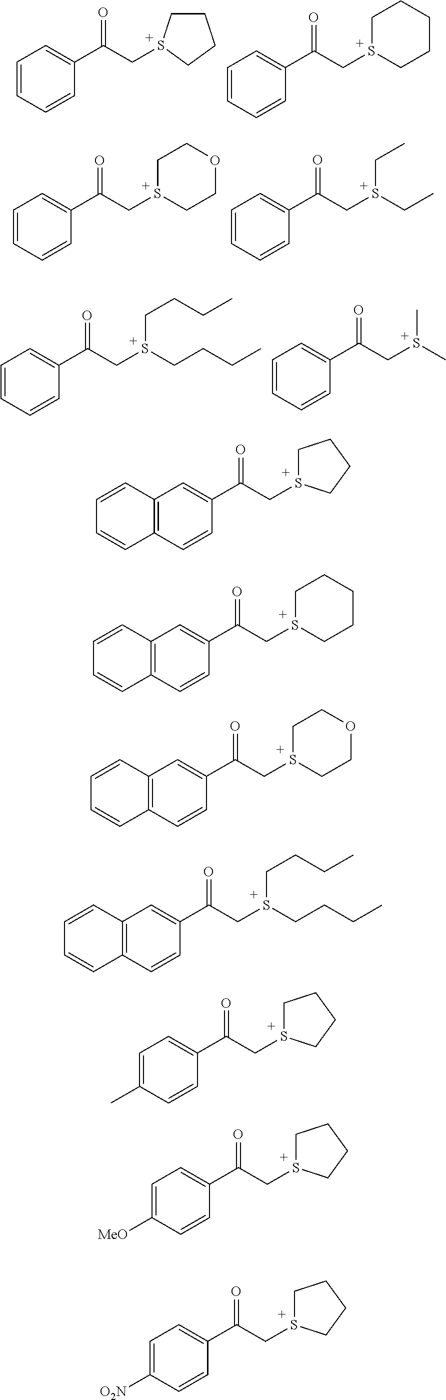

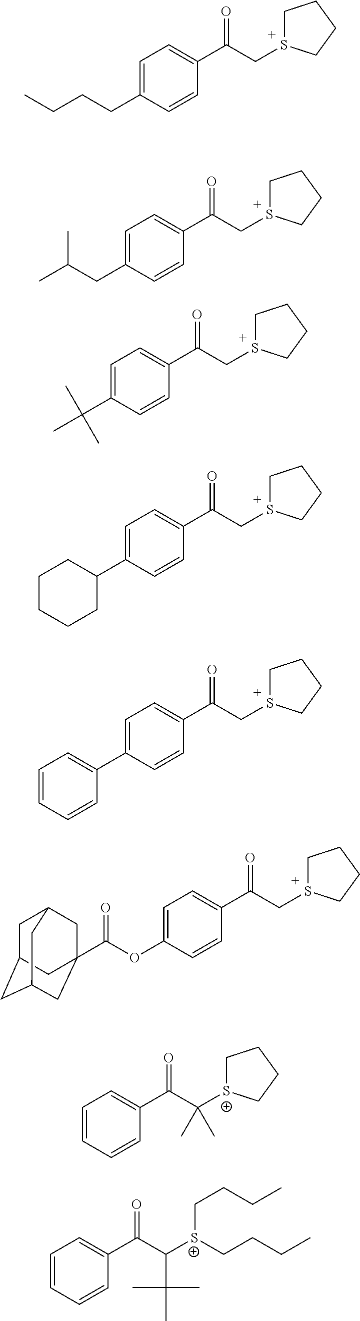

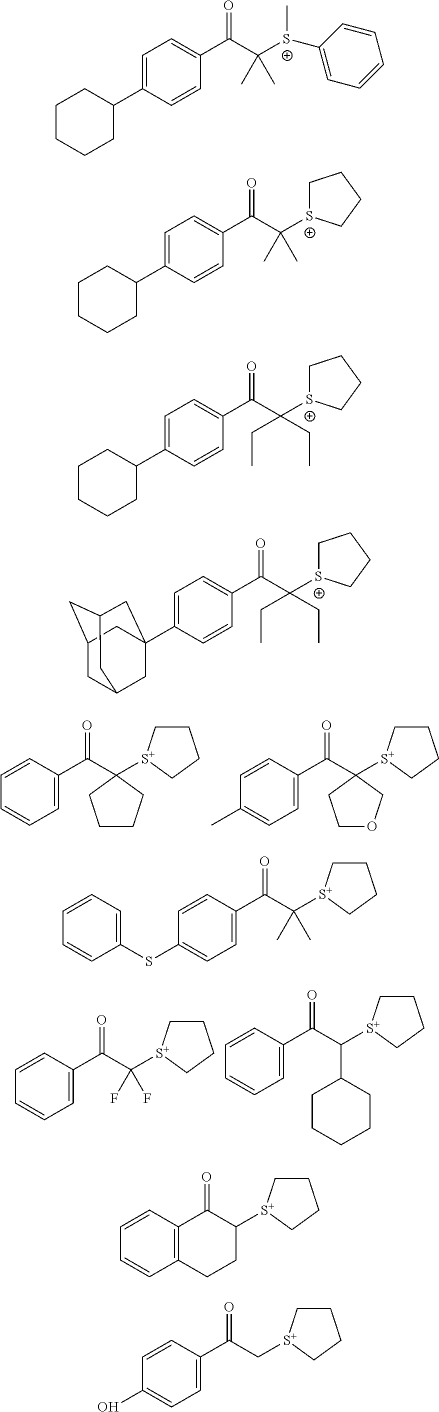

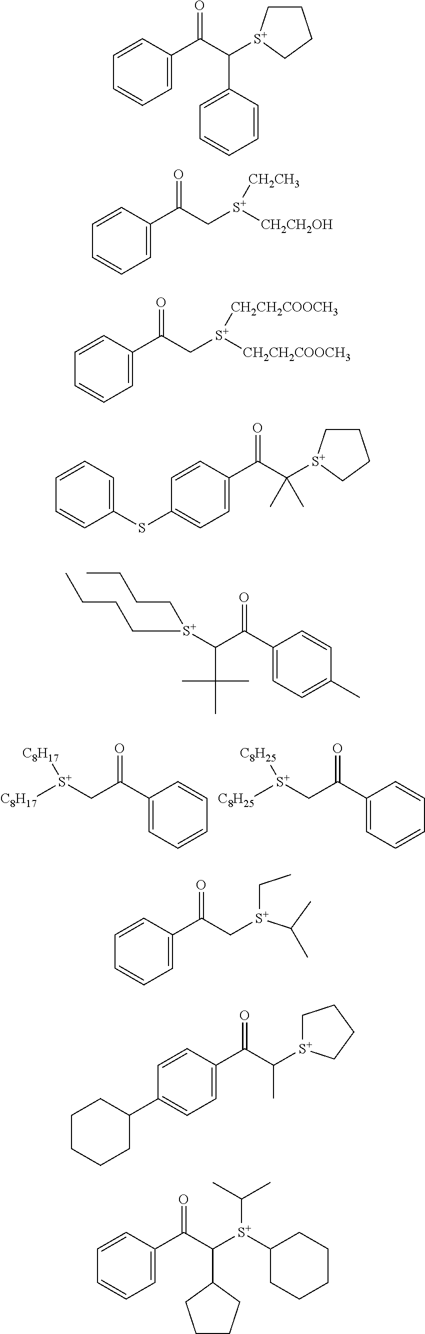

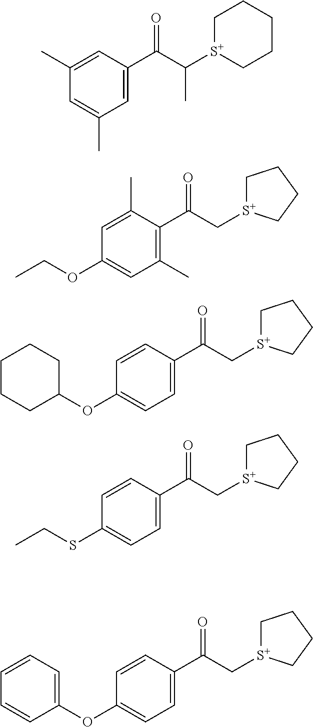

The compound (ZI-4) is a compound represented by the following formula (ZI-4):

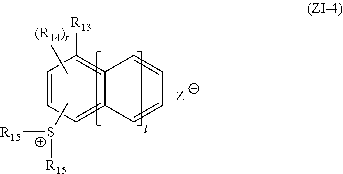

In formula (ZI-4), R₁₃ represents a hydrogen atom, a fluorine atom, a hydroxyl group, an alkyl group, a cycloalkyl group, an alkoxy group, an alkoxycarbonyl group, or a cycloalkyl group-containing group. These groups may have a substituent.

R₁₄ represents, when a plurality of R₁₄'s are present, each independently represents, a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group-containing group. These groups may have a substituent.

Each R₁₅ independently represents an alkyl group, a cycloalkyl group or a naphthyl group. Two R₁₅'s may combine with each other to form a ring. These groups may have a substituent.

l represents an integer of 0 to 2.

r represents an integer of 0 to 8.

Z⁻ represents a non-nucleophilic anion, and examples thereof are the same as those of the non-nucleophilic anion of Z⁻ in formula (ZI).

In formula (ZI-4), the alkyl group of R₁₃, R₁₄ and R₁₅ is preferably a linear or branched alkyl group having a carbon number of 1 to 10, and examples thereof include a methyl group, an ethyl group, an n-propyl group, an i-propyl group, an n-butyl group, a 2-methylpropyl group, a 1-methylpropyl group, a tert-butyl group, an n-pentyl group, a neopentyl group, an n-hexyl group, an n-heptyl group, an n-octyl group, a 2-ethylhexyl group, an n-nonyl group and an n-decyl group. Among these alkyl groups, a methyl group, an ethyl group, an n-butyl group and a tert-butyl group are preferred.

The cycloalkyl group of R₁₃, R₁₄ and R₁₅ includes a monocyclic or polycyclic cycloalkyl group (preferably a cycloalkyl group having a carbon number of 3 to 20), and examples thereof include cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl and adamantyl. Above all, cyclopropyl, cyclopentyl, cyclohexyl, cycloheptyl and cyclooctyl are preferred.

The alkoxy group of R₁₃ and R₁₄ is preferably a linear or branched alkoxy group having a carbon number of 1 to 10, and examples thereof include a methoxy group, an ethoxy group, an n-propoxy group, an i-propoxy group, an n-butoxy group, a 2-methylpropoxy group, a 1-methylpropoxy group, a tert-butoxy group, an n-pentyloxy group, a neopentyloxy group, an n-hexyloxy group, an n-heptyloxy group, an n-octyloxy group, a 2-ethylhexyloxy group, an n-nonyloxy group and an n-decyloxy group. Among these alkoxy groups, a methoxy group, an ethoxy group, an n-propoxy group and an n-butoxy group are preferred.

The alkoxycarbonyl group of R₁₃ and R₁₄ is preferably a linear or branched alkoxycarbonyl group having a carbon number of 2 to 11, and examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a tert-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group and an n-decyloxycarbonyl group. Among these alkoxycarbonyl groups, a methoxycarbonyl group, an ethoxycarbonyl group and an n-butoxycarbonyl group are preferred.

The cycloalkyl group-containing group of R₁₃ and R₁₄ includes a group having a monocyclic or polycyclic cycloalkyl group (preferably a cycloalkyl group having a carbon number of 3 to 20), and examples thereof include a monocyclic or polycyclic cycloalkyloxy group and an alkoxy group containing a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and preferably contains a monocyclic cycloalkyl group. The monocyclic cycloalkyloxy group having a total carbon number of 7 or more indicates a monocyclic cycloalkyloxy group where a cycloalkyloxy group such as cyclopropyloxy group, cyclobutyloxy group, cyclopentyloxy group, cyclohexyloxy group, cyclobutyloxy group, cyclooctyloxy group and cyclododecanyloxy group arbitrarily has a substituent such as alkyl group (e.g., methyl, ethyl, propyl, butyl, pentyl, hexyl, heptyl, octyl, dodecyl, 2-ethylhexyl, isopropyl, sec-butyl, tert-butyl, isoamyl), hydroxyl group, halogen atom (e.g., fluorine, chlorine, bromine, iodine), nitro group, cyano group, amido group, sulfonamido group, alkoxy group (e.g., methoxy, ethoxy, hydroxyethoxy, propoxy, hydroxypropoxy, butoxy), alkoxycarbonyl group (e.g., methoxycarbonyl, ethoxycarbonyl), acyl group (e.g., formyl, acetyl, benzoyl), acyloxy group (e.g., acetoxy, butyryloxy) and carboxy group and where the total carbon number inclusive of the carbon number of an arbitrary substituent on the cycloalkyl group is 7 or more.

Examples of the polycyclic cycloalkyloxy group having a total carbon number of 7 or more include a norbornyloxy group, a tricyclodecanyloxy group, a tetracyclodecanyloxy group and an adamantyloxy group.

The alkoxy group having a monocyclic or polycyclic cycloalkyl group of R₁₃ and R₁₄ preferably has a total carbon number of 7 or more, more preferably a total carbon number of 7 to 15, and is preferably alkoxy group having a monocyclic cycloalkyl group. The alkoxy group having a total carbon number of 7 or more and having a monocyclic cycloalkyl group indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, tert-butoxy and isoamyloxy and where the total carbon number inclusive of the carbon number of the substituent is 7 or more. Examples thereof include a cyclohexylmethoxy group, a cyclopentylethoxy group and a cyclohexylethoxy group, with a cyclohexylmethoxy group being preferred.

Examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group and an adamantylethoxy group, with a norbornylmethoxy group and a norbornylethoxy group being preferred.

Specific examples of the alkyl group in the alkylcarbonyl group of R₁₄ are the same as those of the alkyl group of R₁₃ to R₁₅ above.

The alkylsulfonyl and cycloalkylsulfonyl group of R₁₄ are preferably a linear, branched or cyclic alkylsulfonyl group having a carbon number of 1 to 10, and examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group and a cyclohexanesulfonyl group. Among these alkylsulfonyl groups and cycloalkylsulfonyl groups, a methanesulfonyl group, an ethanesulfonyl group, an n-propanesulfonyl group, an n-butanesulfonyl group, a cyclopentanesulfonyl group and a cyclohexanesulfonyl group are preferred.

Examples of the substituent which each of the groups of R₁₃, R₁₄ and R₁₅ may have include a halogen atom (e.g., fluorine), a hydroxyl group, a carboxyl group, a cyano group, a nitro group, an alkoxy group, an alkoxyalkyl group, an alkoxycarbonyl group and an alkoxycarbonyloxy group.

Examples of the alkoxy group include a linear, branched or cyclic alkoxy group having a carbon number of 1 to 20, such as methoxy group, ethoxy group, n-propoxy group, i-propoxy group, n-butoxy group, 2-methylpropoxy group, 1-methylpropoxy group, tert-butoxy group, cyclopentyloxy group and cyclohexyloxy group.

Examples of the alkoxyalkyl group include a linear, branched or cyclic alkoxyalkyl group having a carbon number of 2 to 21, such as methoxymethyl group, ethoxymethyl group, 1-methoxyethyl group, 2-methoxyethyl group, 1-ethoxyethyl group and 2-ethoxyethyl group.

Examples of the alkoxycarbonyl group include a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl group.

Examples of the alkoxycarbonyloxy group include a linear, branched or cyclic alkoxycarbonyloxy group having a carbon number of 2 to 21, such as methoxycarbonyloxy group, ethoxycarbonyloxy group, n-propoxycarbonyloxy group, i-propoxycarbonyloxy group, n-butoxycarbonyloxy group, tert-butoxycarbonyloxy group, cyclopentyloxycarbonyloxy group and cyclohexyloxycarbonyloxy group.

The ring structure which may be formed by combining two R₁₅'s with each other includes a 5- or 6-membered ring, preferably a 5-membered ring (that is, tetrahydrothiophene ring), formed by two divalent R₁₅'s together with the sulfur atom in formula (ZI-4) and may be fused with an aryl group or a cycloalkyl group. This divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group and an alkoxycarbonyloxy group.

In formula (ZI-4), R₁₅ is preferably, for example, a methyl group, an ethyl group, a naphthyl group, or a divalent group capable of forming a tetrahydrothiophene ring structure together with the sulfur atom when two R₁₅'s are combined.

The substituent which R₁₃ and R₁₄ may have is preferably a hydroxyl group, an alkoxy group, an alkoxycarbonyl group or a halogen atom (particularly a fluorine atom).

l is preferably 0 or 1, more preferably 1.

r is preferably from 0 to 2.

Specific examples of the cation in the compound represented by formula (ZI-4) include those illustrated below.

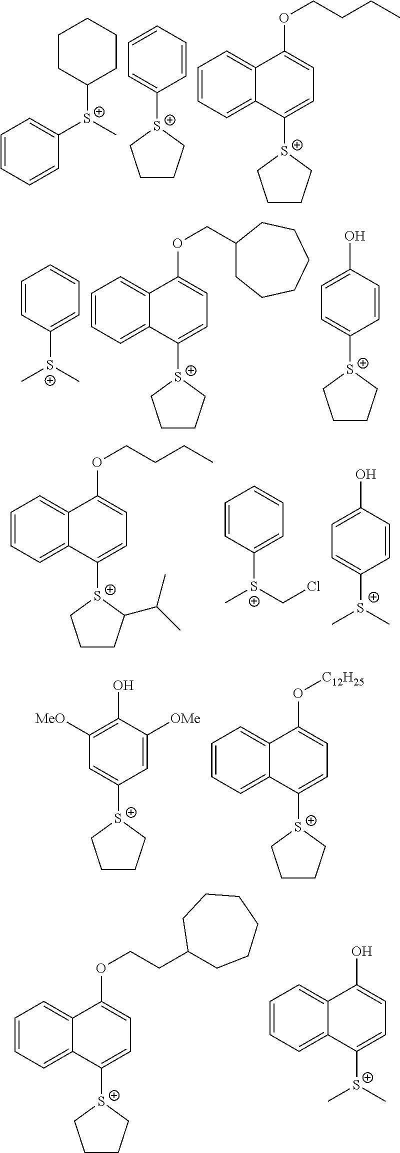

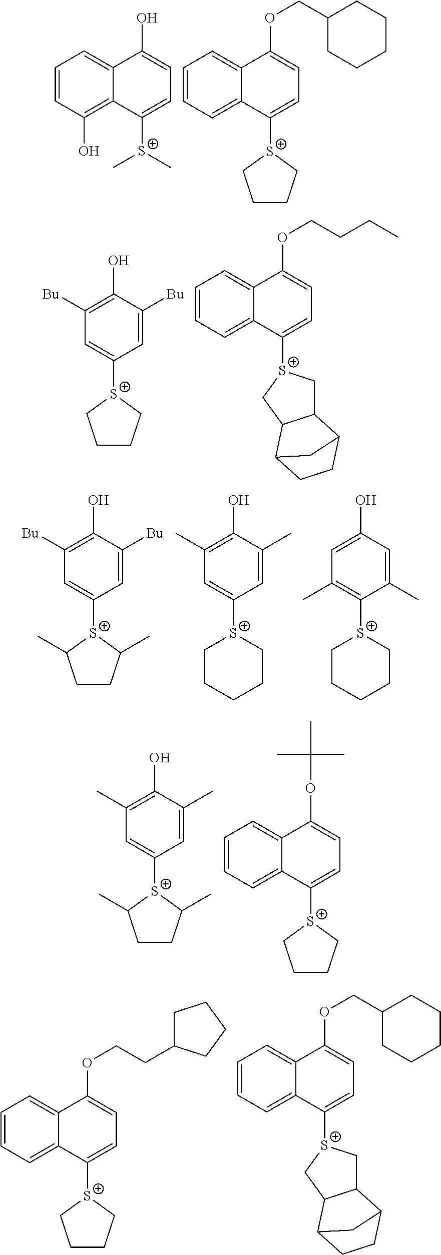

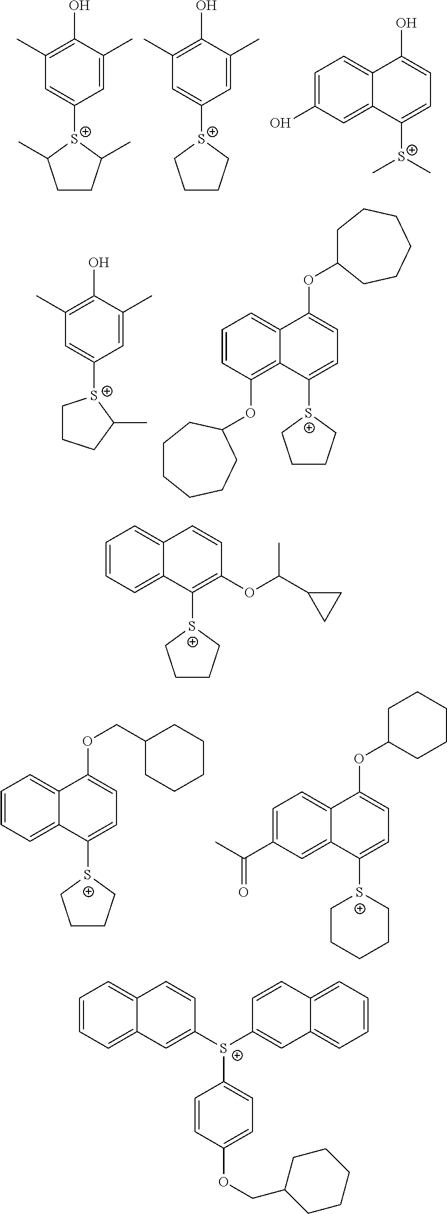

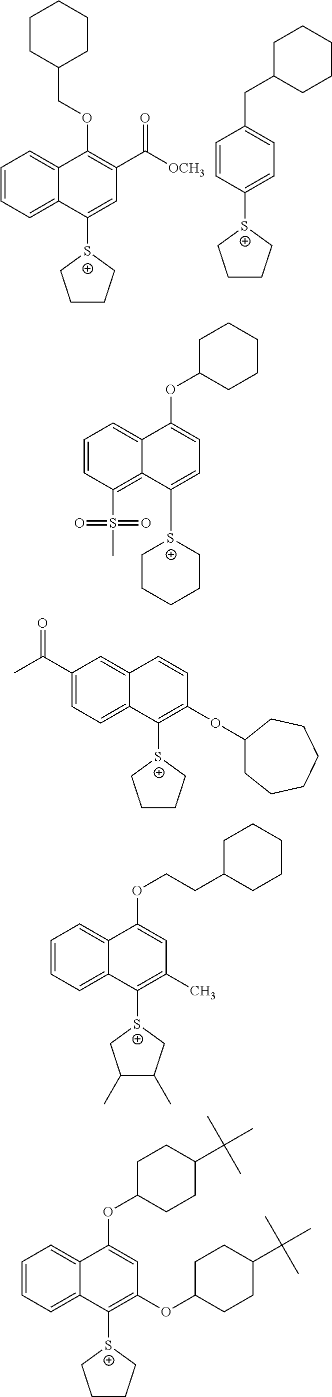

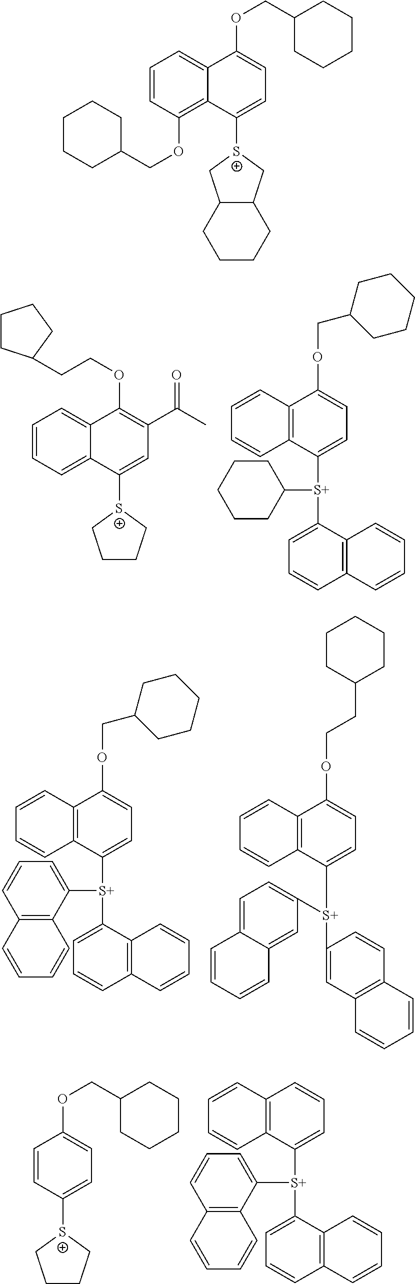

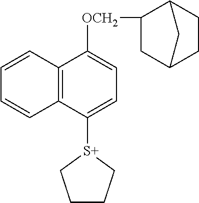

In formulae (ZII) and (ZIII), each of R₂₀₄ to R₂₀₇ independently represents an aryl group, an alkyl group or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure containing an oxygen atom, a nitrogen atom, a sulfur atom or the like. Examples of the aryl group having a heterocyclic structure include a pyrrole residue (a group formed by removing one hydrogen atom from a pyrrole), a furan residue (a group formed by removing one hydrogen atom from a furan), a thiophene residue (a group formed by removing one hydrogen atom from a thiophene), an indole residue (a group formed by removing one hydrogen atom from an indole), a benzofuran residue (a group formed by removing one hydrogen atom from a benzofuran) and a benzothiophene residue (a group formed by removing one hydrogen atom from a benzothiophene).

The alkyl group and cycloalkyl group of R₂₀₄ to R₂₀₇ are preferably a linear or branched alkyl group having a carbon number of 1 to 10 (e.g., methyl, ethyl, propyl, butyl, pentyl) and a cycloalkyl group having a carbon number of 3 to 10 (e.g., cyclopentyl, cyclohexyl, norbornyl).

The aryl group, alkyl group and cycloalkyl group of R₂₀₄ to R₂₀₇ may have a substituent. Examples of the substituent which the aryl group, alkyl group and cycloalkyl group of R₂₀₄ to R₂₀₇ may have include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group and a phenylthio group.

Z⁻ represents a non-nucleophilic anion, and examples thereof are the same as those of the non-nucleophilic anion of Z⁻ in formula (ZI).

Other examples of the acid generator include compounds represented by the following formulae (ZIV), (ZV) and (ZVI):

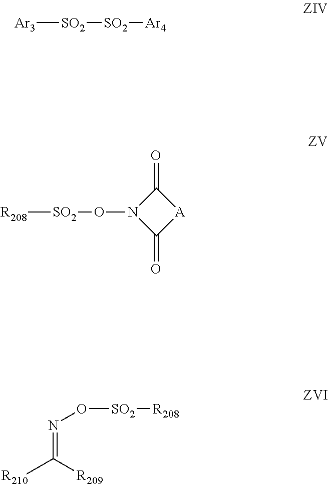

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI-1). Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI-2).

The alkylene group of A includes an alkylene group having a carbon number of 1 to 12 (e.g., methylene, ethylene, propylene, isopropylene, butylene, isobutylene); the alkenylene group of A includes an alkenylene group having a carbon number of 2 to 12 (e.g., ethynylene, propenylene, butenylene); and the arylene group of A includes an arylene group having a carbon number of 6 to 10 (e.g., phenylene, tolylene, naphthylene).

Among the acid generators, more preferred are the compounds represented by formulae (ZI) to (ZIII).

The acid generator is preferably a compound that generates an acid having one sulfonic acid group or imide group, more preferably a compound that generates a monovalent perfluoroalkanesulfonic acid, a compound that generates an aromatic sulfonic acid substituted with a monovalent fluorine atom or a fluorine atom-containing group, or a compound that generates an imide acid substituted with a monovalent fluorine atom or a fluorine atom-containing group, still more preferably a sulfonium salt of fluoro-substituted alkanesulfonic acid, fluorine-substituted benzenesulfonic acid, fluorine-substituted imide acid or fluorine-substituted methide acid. In particular, the acid generator which can be used is preferably a compound that generates a fluoro-substituted alkanesulfonic acid, a fluoro-substituted benzenesulfonic acid or a fluoro-substituted imide acid, where pKa of the acid generated is −1 or less, and in this case, the sensitivity is enhanced.

Out of the acid generators, particularly preferred examples are illustrated below.

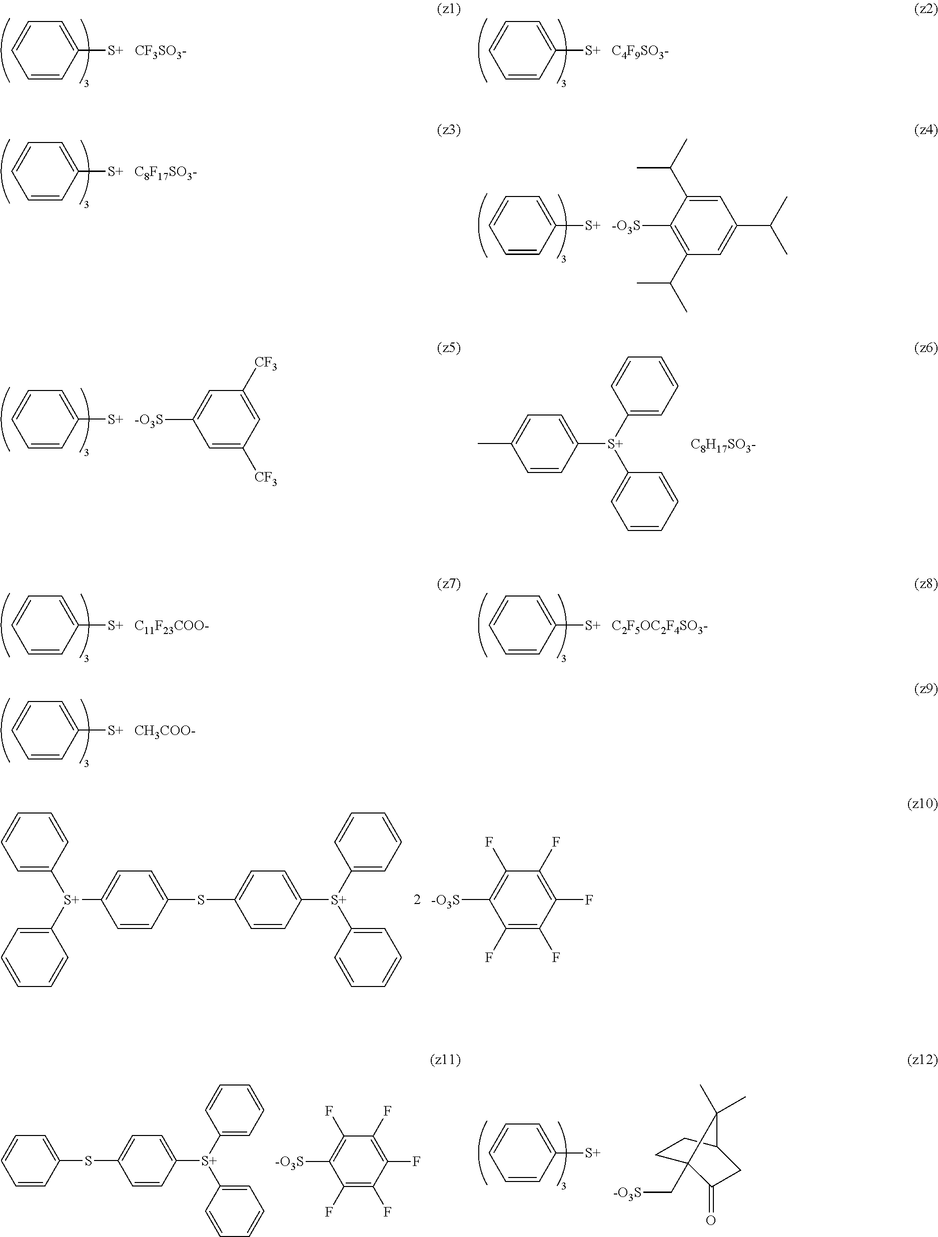

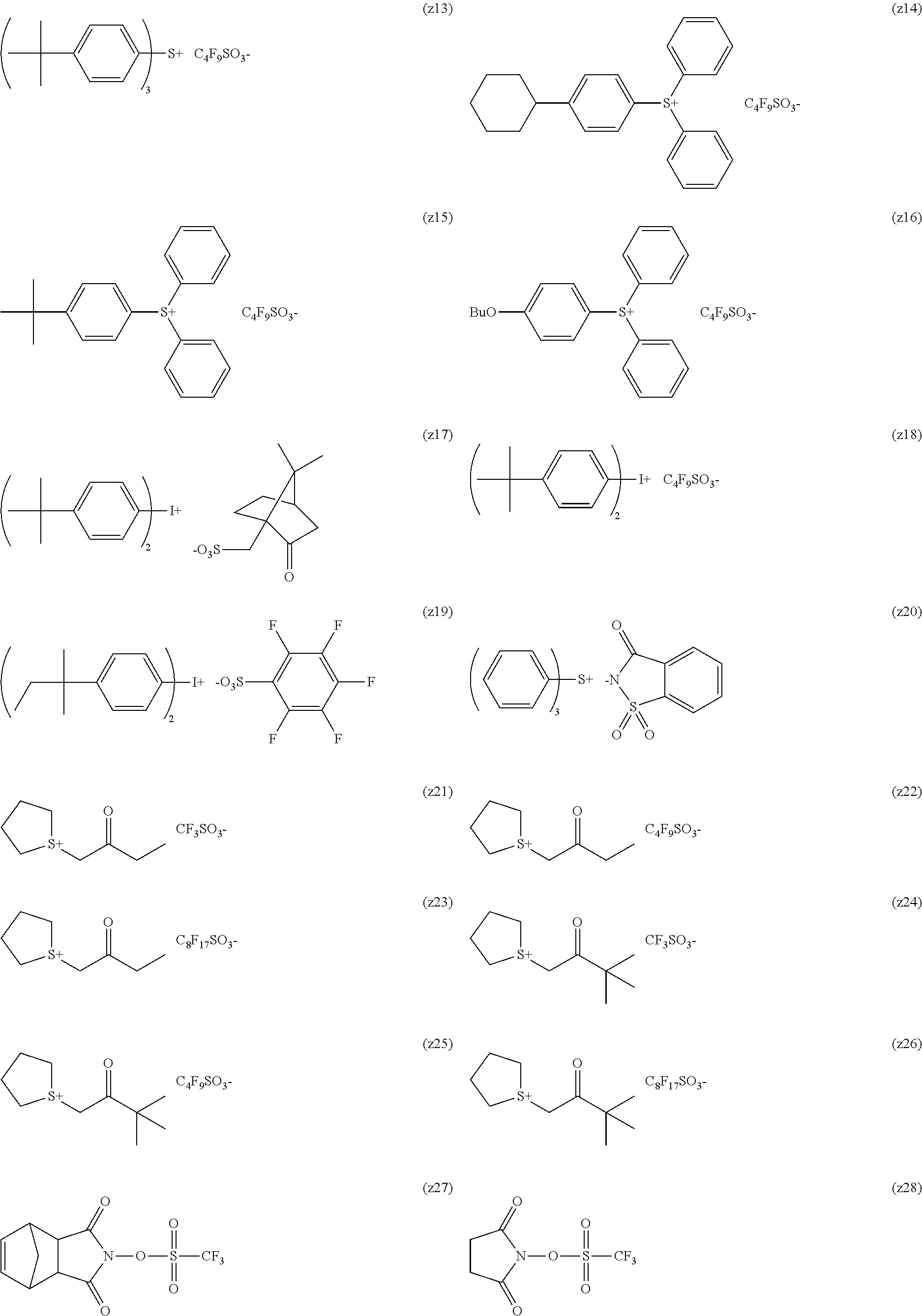

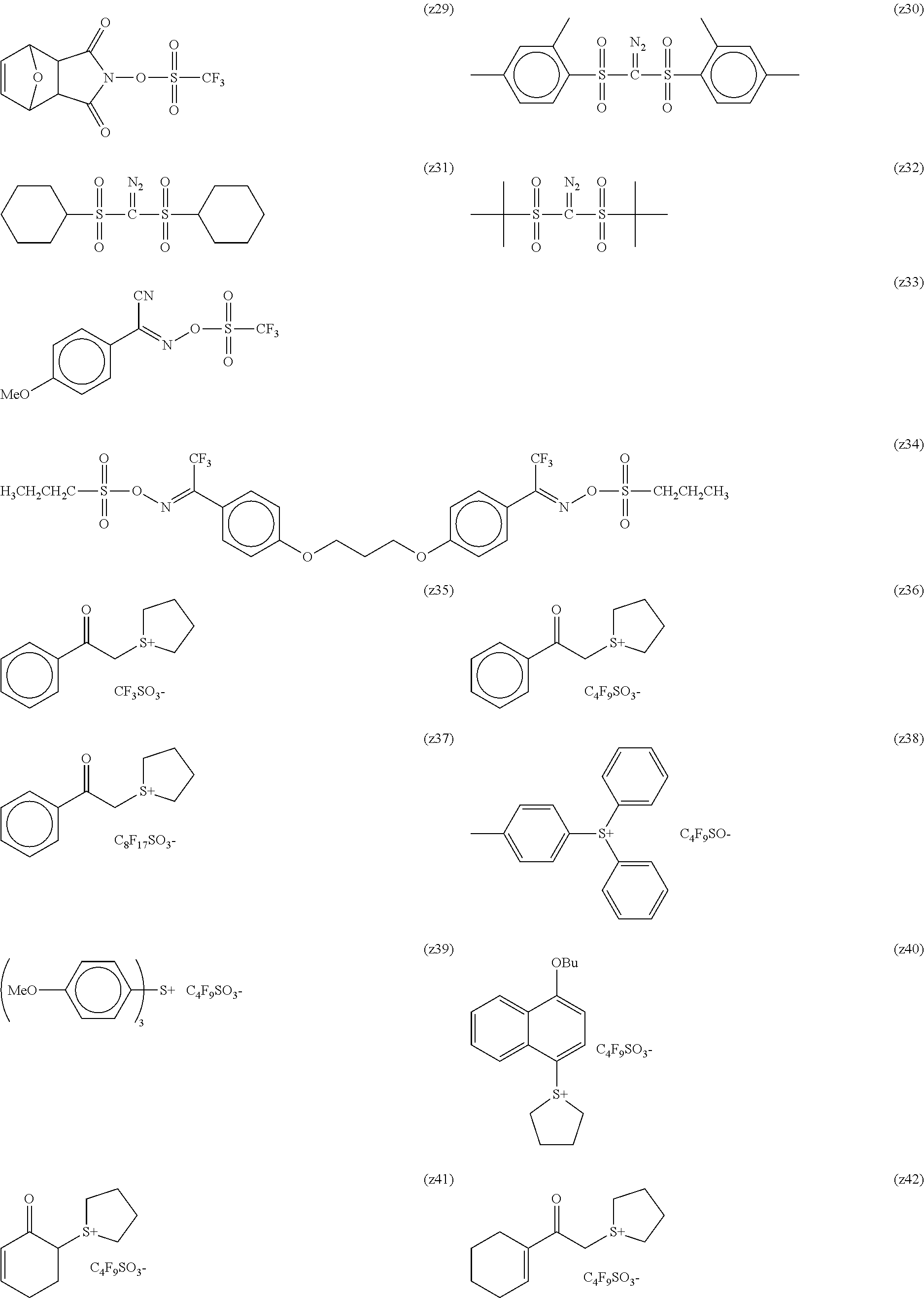

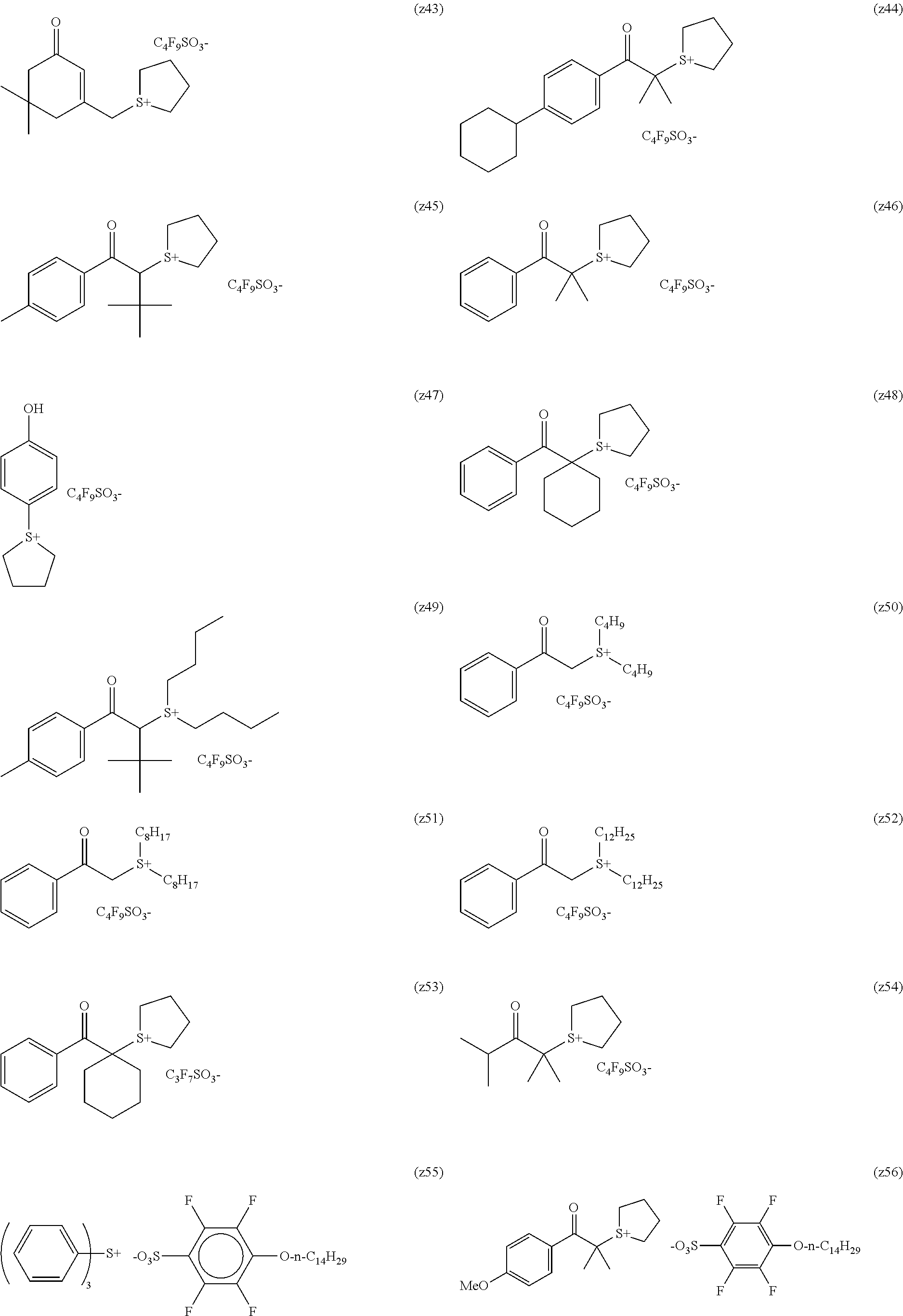

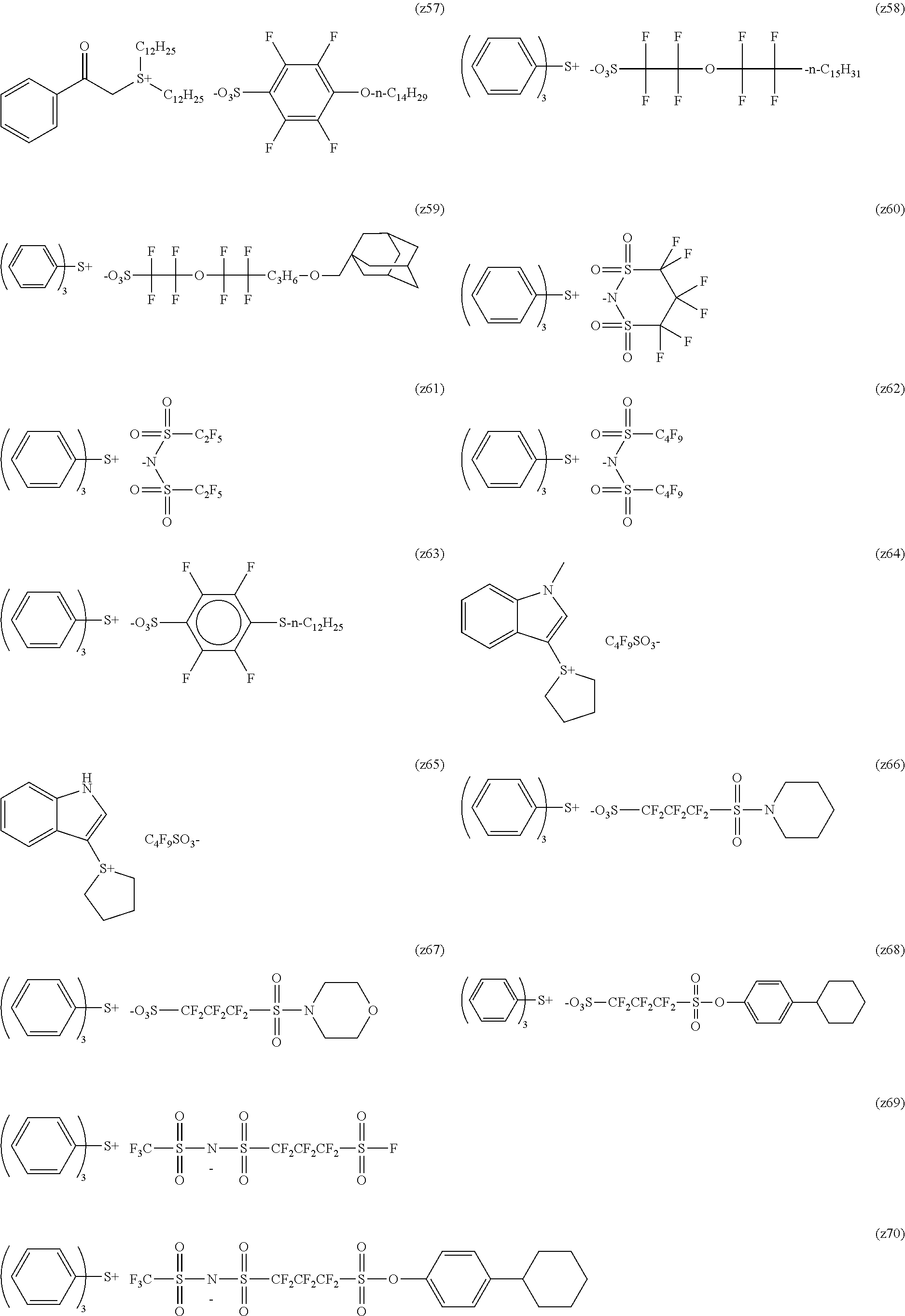

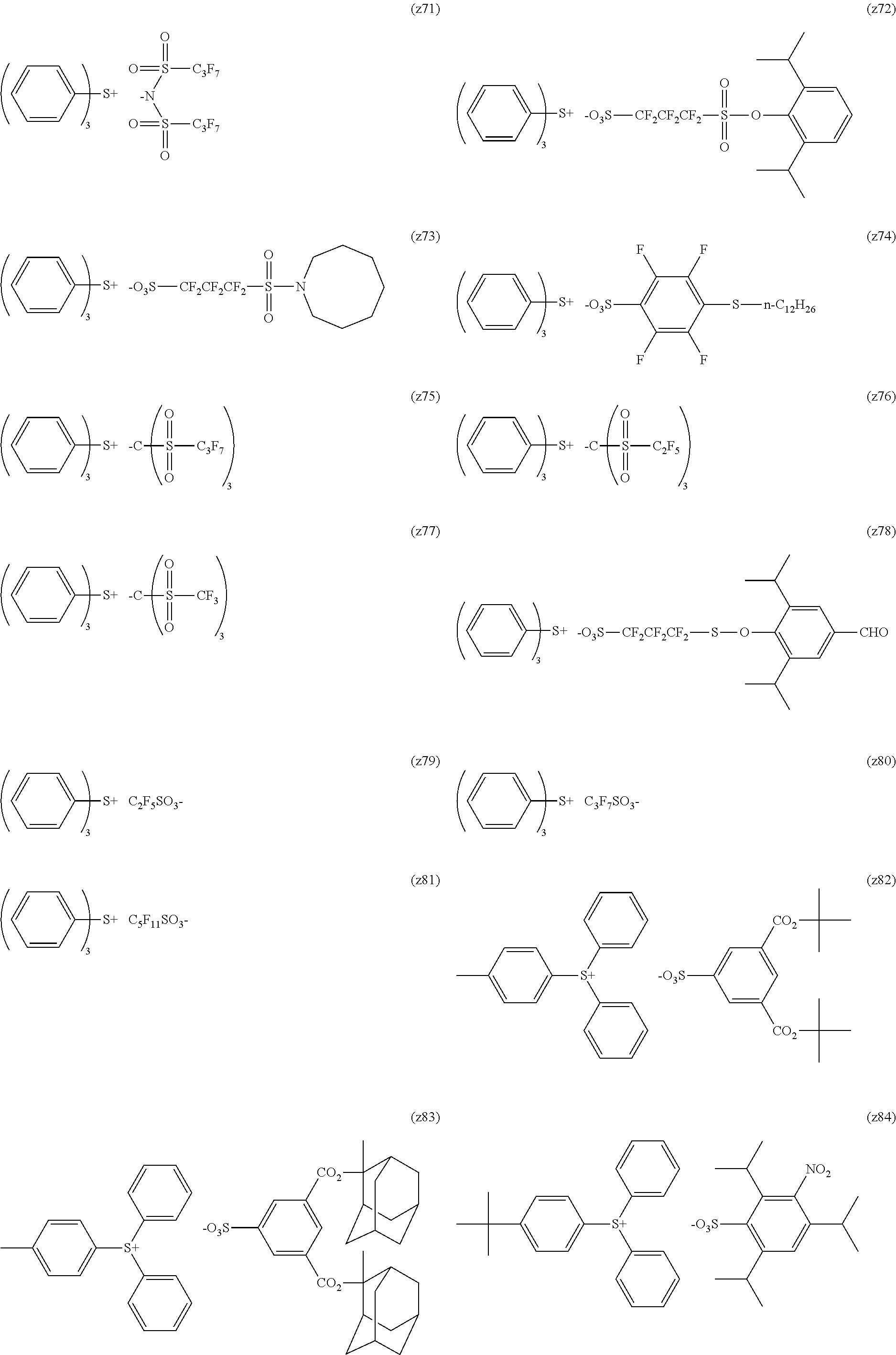

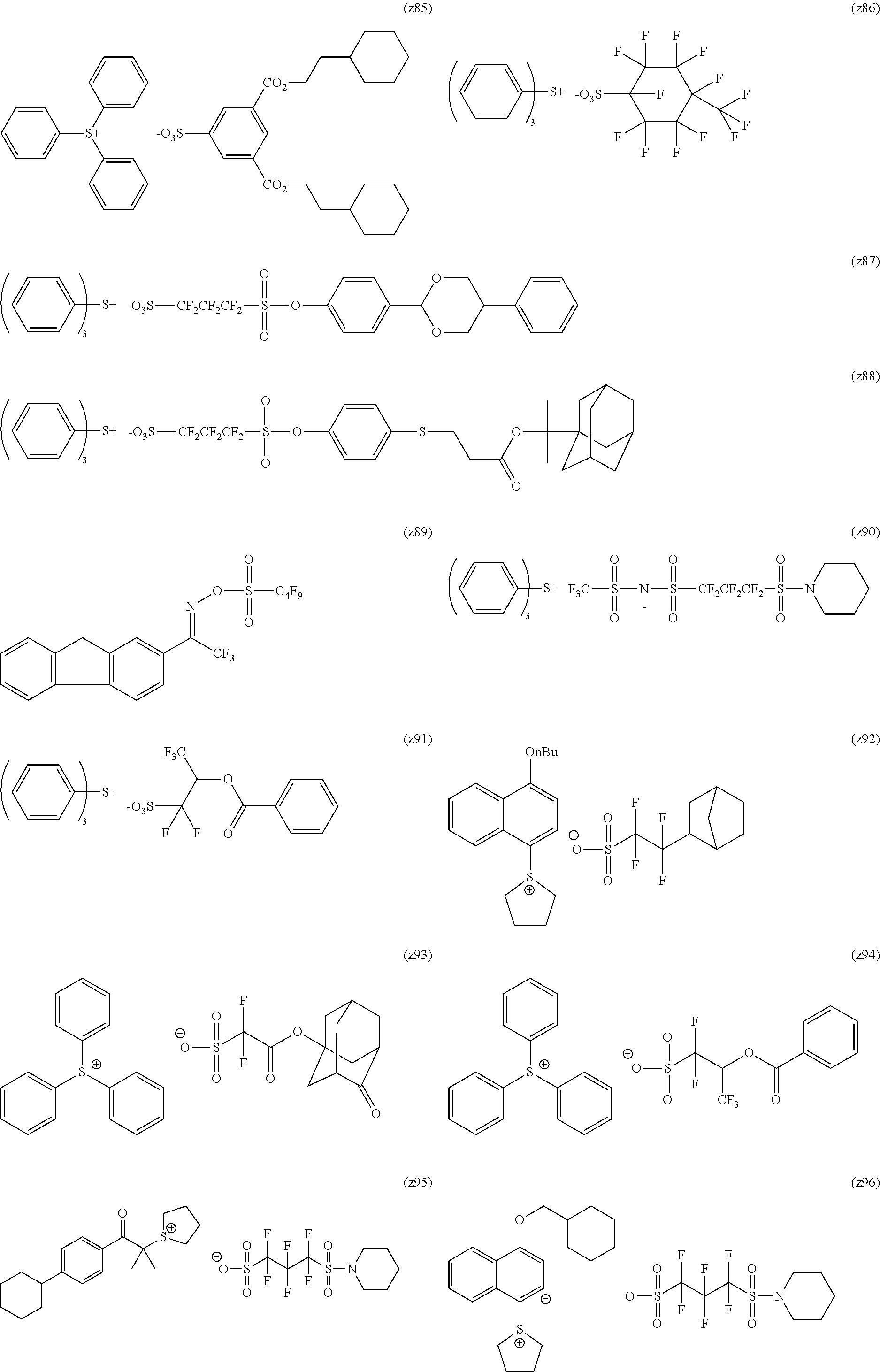

As for the acid generator, one kind of a compound may be used alone, or two or more kinds of compounds may be used in combination.

The content of the acid generator in the actinic ray-sensitive or radiation-sensitive resin composition is preferably from 0.1 to 30 mass %, more preferably from 5 to 30 mass %, still more preferably from 10 to 25 mass %, based on the entire solid content of the actinic ray-sensitive or radiation-sensitive resin composition.

### [3] (C) Hydrophobic Resin

The actinic ray-sensitive or radiation-sensitive resin composition of the present invention, particularly when applied to immersion exposure, may contain a hydrophobic resin having at least either a fluorine atom or a silicon atom (hereinafter sometimes referred to as a “hydrophobic resin (C)” or simply as a “resin (C)”). The hydrophobic resin (C) is unevenly distributed to the surface layer of the film and when the immersion medium is water, can enhance the static/dynamic contact angle on the resist film surface for water as well as the followability of the immersion liquid.

The hydrophobic resin (C) is, as described above, unevenly distributed to the interface but unlike a surfactant, need not have necessarily a hydrophilic group in the molecule and may not contribute to uniform mixing of polar/nonpolar substances.

The hydrophobic resin typically contains a fluorine atom and/or a silicon atom. The fluorine atom and/or silicon atom in the hydrophobic resin (C) may be contained in the main chain of the resin or may be contained in the side chain.

In the case of containing a fluorine atom, the hydrophobic resin (C) is preferably a resin having a fluorine atom-containing alkyl group, a fluorine atom-containing cycloalkyl group or a fluorine atom-containing aryl group, as a fluorine atom-containing partial structure.

The fluorine atom-containing alkyl group (preferably having a carbon number of 1 to 10, more preferably a carbon number of 1 to 4) is a linear or branched alkyl group with at least one hydrogen atom being replaced by a fluorine atom and may further have a substituent other than a fluorine atom.

The fluorine atom-containing cycloalkyl group is a monocyclic or polycyclic cycloalkyl group with at least one hydrogen atom being replaced by a fluorine atom and may further have a substituent other than a fluorine atom.

The fluorine atom-containing aryl group is an aryl group (e.g., phenyl, naphthyl) with at least one hydrogen atom being replaced by a fluorine atom and may further have a substituent other than a fluorine atom.

Preferred examples of the fluorine atom-containing alkyl group, fluorine atom-containing cycloalkyl group and fluorine atom-containing aryl group include groups represented by the following formulae (F2) to (F4), but the present invention is not limited thereto.

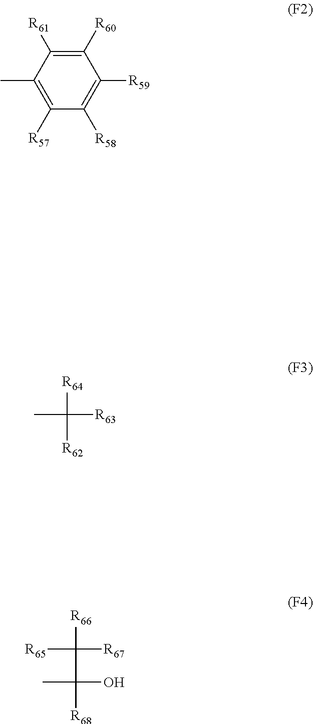

In formulae (F2) to (F4), each of R₅₇ to R₆₈ independently represents a hydrogen atom, a fluorine atom or a (linear or branched) alkyl group, provided that at least one of R₅₇ to R₆₁, at least one of R₆₂ to R₆₄ and at least one of R₆₅ to R₆₈ are independently a fluorine atom or an alkyl group (preferably having a carbon number of 1 to 4) with at least one hydrogen atom being replaced by a fluorine atom.

It is preferred that all of R₅₇ to R₆₁ and R₆₅ to R₆₇ are a fluorine atom. Each of R₆₂, R₆₃ and R₆₈ is preferably an alkyl group (preferably having a carbon number of 1 to 4) with at least one hydrogen atom being replaced by a fluorine atom, more preferably a perfluoroalkyl group having a carbon number of 1 to 4. R₆₂ and R₆₃ may combine with each other to form a ring.

Specific examples of the group represented by formula (F2) include p-fluorophenyl group, pentafluorophenyl group and 3,5-di(trifluoromethyl)phenyl group.

Specific examples of the group represented by formula (F3) include trifluoromethyl group, pentafluoropropyl group, pentafluoroethyl group, heptafluorobutyl group, hexafluoroisopropyl group, heptafluoroisopropyl group, hexafluoro(2-methyl)isopropyl group, nonafluorobutyl group, octafluoroisobutyl group, nonafluorohexyl group, nonafluoro-tert-butyl group, perfluoroisopentyl group, perfluorooctyl group, perfluoro(trimethyl)hexyl group, 2,2,3,3-tetrafluorocyclobutyl group and perfluorocyclohexyl group. Among these, hexafluoroisopropyl group, heptafluoroisopropyl group, hexafluoro(2-methyl)isopropyl group, octafluoroisobutyl group, nonafluoro-tert-butyl group and perfluoroisopentyl group are preferred, and hexafluoroisopropyl group and heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

The fluorine-containing partial structure may be directly bonded to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

As for the repeating unit having a fluorine atom, those shown below are preferred.

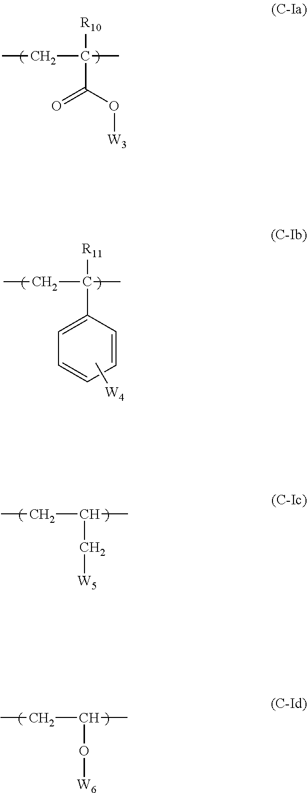

In the formulae, each of R₁₀ and R₁₁ independently represents a hydrogen atom, a fluorine atom or an alkyl group. The alkyl group is preferably a linear or branched alkyl group having a carbon number of 1 to 4 and may have a substituent, and the alkyl group having a substituent includes, in particular, a fluorinated alkyl group.

Each of W₃ to W₆ independently represents an organic group having at least one or more fluorine atoms. Specific examples thereof include the atomic groups of (F2) to (F4).

Other than these, the hydrophobic resin (C) may contain a unit shown below as the repeating unit having a fluorine atom.

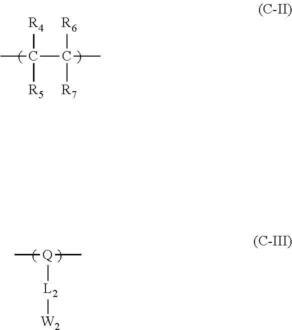

In the formulae, each of R₄ to R₇ independently represents a hydrogen atom, a fluorine atom or an alkyl group. The alkyl group is preferably a linear or branched alkyl group having a carbon number of 1 to 4 and may have a substituent, and the alkyl group having a substituent includes, in particular, a fluorinated alkyl group.

However, at least one of R₄ to R₇ represents a fluorine atom. A pair of R₄ and R₅ or a pair of R₆ and R₇ may form a ring.

W₂ represents an organic group containing at least one fluorine atom. Specific examples thereof include the atomic groups of (F2) to (F4).

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combining a plurality of these groups.

Q represents an alicyclic structure. The alicyclic structure may have a substituent and may be monocyclic or polycyclic, and in the case of polycyclic, the structure may be crosslinked. The monocyclic structure is preferably a cycloalkyl group having a carbon number of 3 to 8, and examples thereof include a cyclopentyl group, a cyclohexyl group, a cyclobutyl group and a cyclooctyl group. Examples of the polycyclic structure include a group containing a bicyclo, tricyclo or tetracyclo structure having a carbon number of 5 or more. A cycloalkyl group having a carbon number of 6 to 20 is preferred, and examples thereof include an adamantyl group, a norbornyl group, a dicyclopentyl group, a tricyclodecanyl group and a tetracyclododecyl group. A part of carbon atoms in the cycloalkyl group may be substituted with a heteroatom such as oxygen atom. In particular, Q is preferably, for example, a norbornyl group, a tricyclodecanyl group or a tetracyclododecyl group.

Specific examples of the repeating unit having a fluorine atom are illustrated below, but the present invention is not limited thereto.

In specific examples, X₁ represents a hydrogen atom, —CH₃, —F or —CF₃. X₂ represents —F or —CF₃.

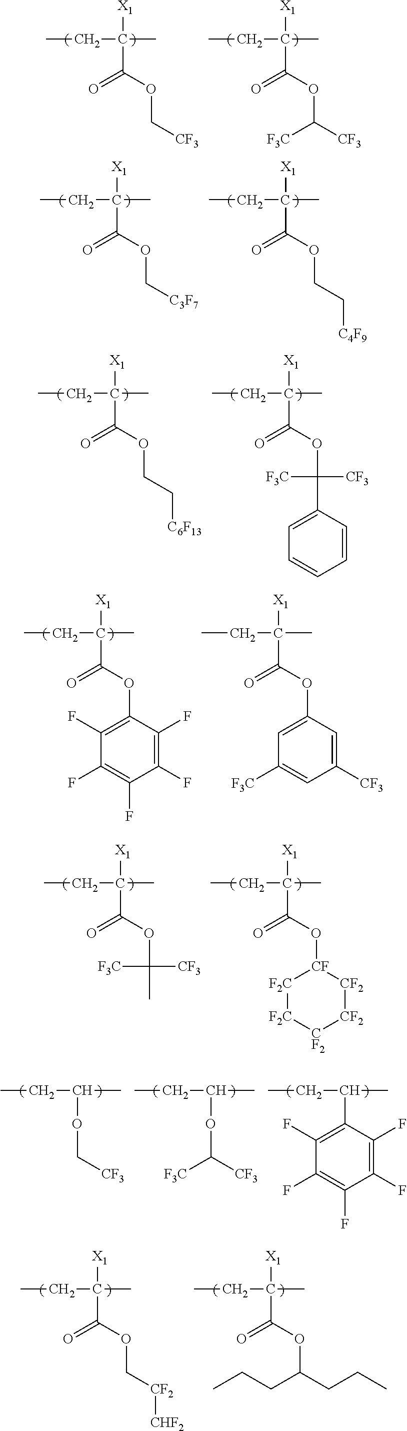

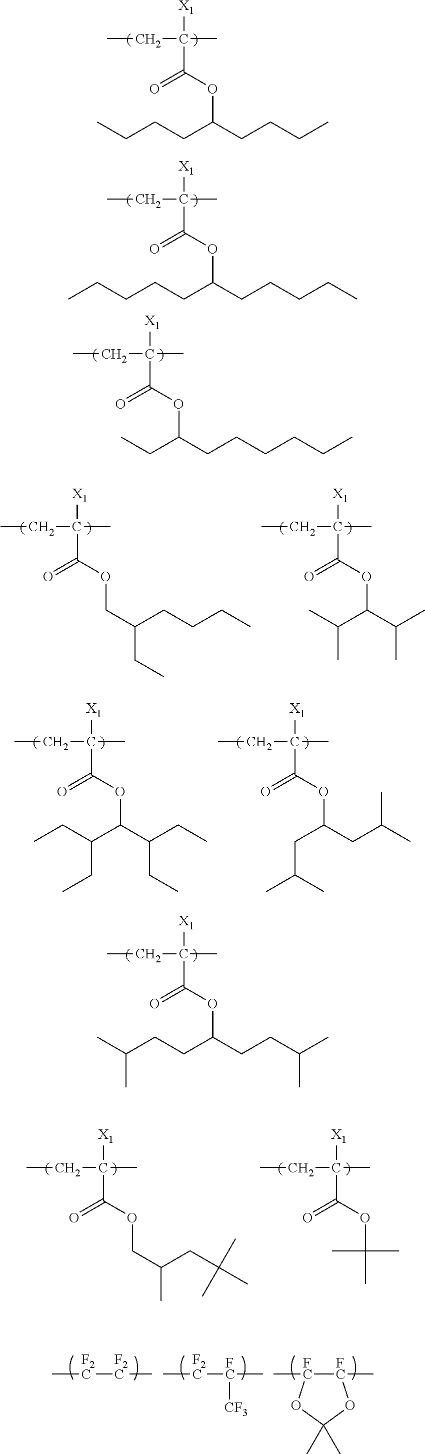

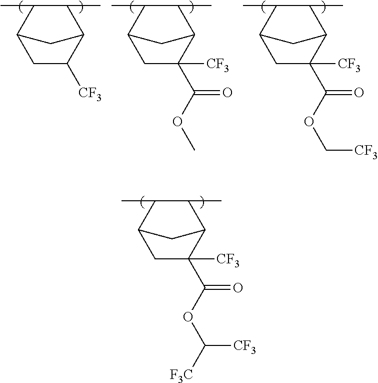

The hydrophobic resin (C) may contain a silicon atom. A resin having an alkylsilyl structure (preferably a trialkylsilyl group) or a cyclic siloxane structure, as a silicon atom-containing partial structure, is preferred.

Specific examples of the alkylsilyl structure and cyclic siloxane structure include groups represented by the following formulae (CS-1) to (CS-3):

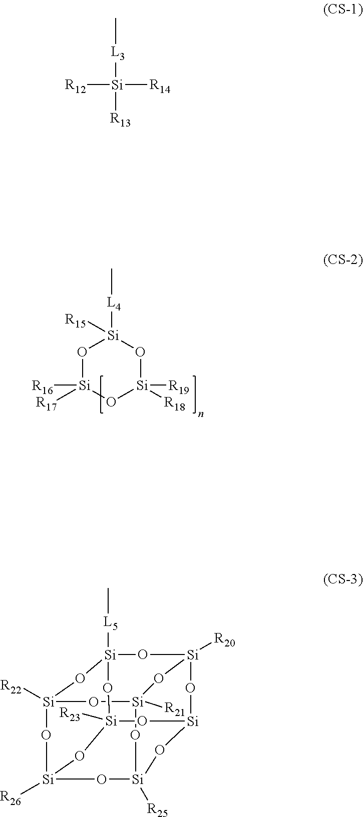

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group includes a sole group selected from the group consisting of an alkylene group, a phenylene group, an ether bond, a thioether bond, a carbonyl group, an ester bond, an amide bond, a urethane bond and a urea bond, and a combination of two or more thereof (preferably having a total carbon number of 12 or less).

n represents an integer of 1 to 5. n is preferably an integer of 2 to 4.

Specific examples of the repeating unit having a group represented by formulae (CS-1) to (CS-3) are illustrated below, but the present invention is not limited thereto. In specific examples, X₁ represents a hydrogen atom, —CH₃, —F or —CF₃.

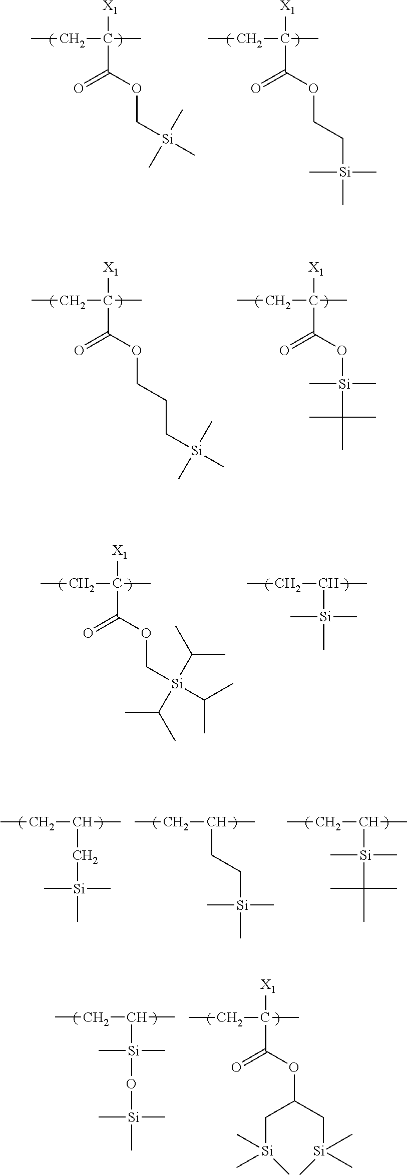

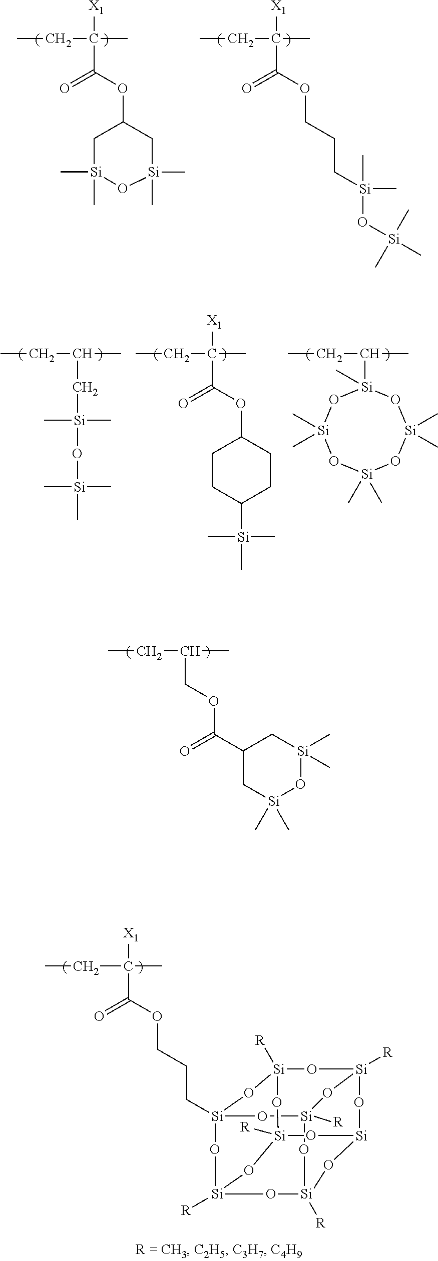

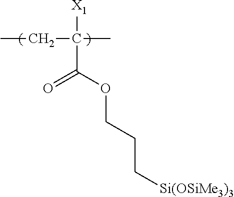

Furthermore, the hydrophobic resin (C) may contain at least one group selected from the group consisting of the following (x) to (z):

(x) an alkali-soluble group,

(y) a group capable of decomposing by the action of an alkali developer to increase the solubility in an alkali developer (hereinafter sometimes referred to as a “polarity converting group”), and

(z) a group capable of decomposing by the action of an acid.

Examples of the alkali-soluble group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group.

Preferred alkali-soluble groups are a fluorinated alcohol group (preferably hexafluoroisopropanol), a sulfonimide group and a bis(alkylcarbonyl)methylene group.

Examples of the repeating unit having (x) an alkali-soluble group include a repeating unit where an alkali-soluble group is directly bonded to the main chain of the resin, such as repeating unit by an acrylic acid or a methacrylic acid, and a repeating unit where an alkali-soluble group is bonded to the main chain of the resin through a linking group, and an alkali-soluble group may also be introduced into the terminal of the polymer chain by using an alkali-soluble group-containing polymerization initiator or chain transfer agent at the polymerization. All of these cases are preferred. The repeating unit having (x) an alkali-soluble group may contain at least either a fluorine atom or a silicon atom.

The content of the repeating unit having (x) an alkali-soluble group is preferably from 1 to 50 mol %, more preferably from 3 to 35 mol %, still more preferably from 5 to 20 mol %, based on all repeating units in the hydrophobic resin (C).

Specific examples of the repeating unit having (x) an alkali-soluble group are illustrated below, but the present invention is not limited thereto. In the formulae, Rx represents hydrogen atom, CH₃, CF₃ or CH₂OH.

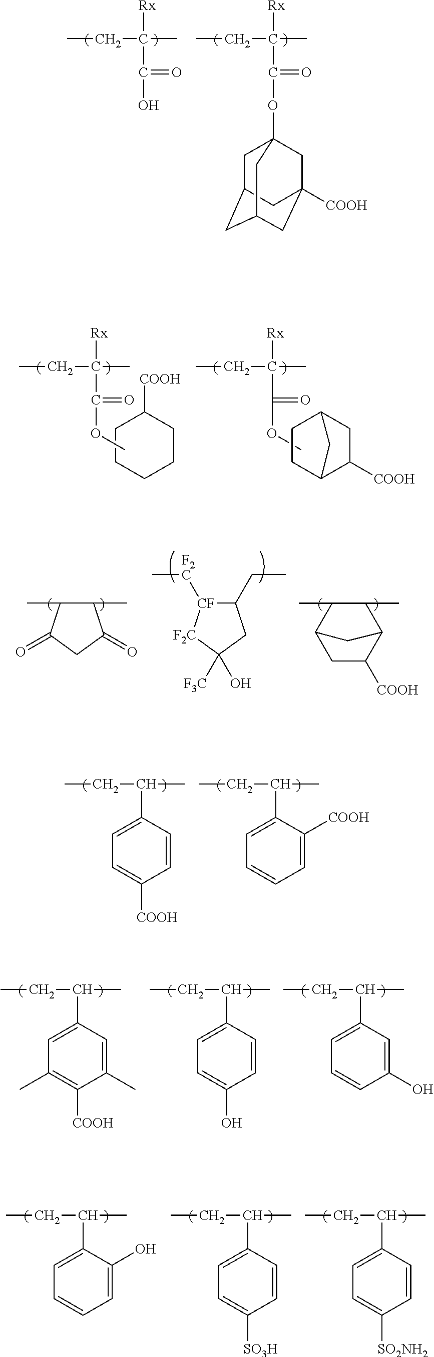

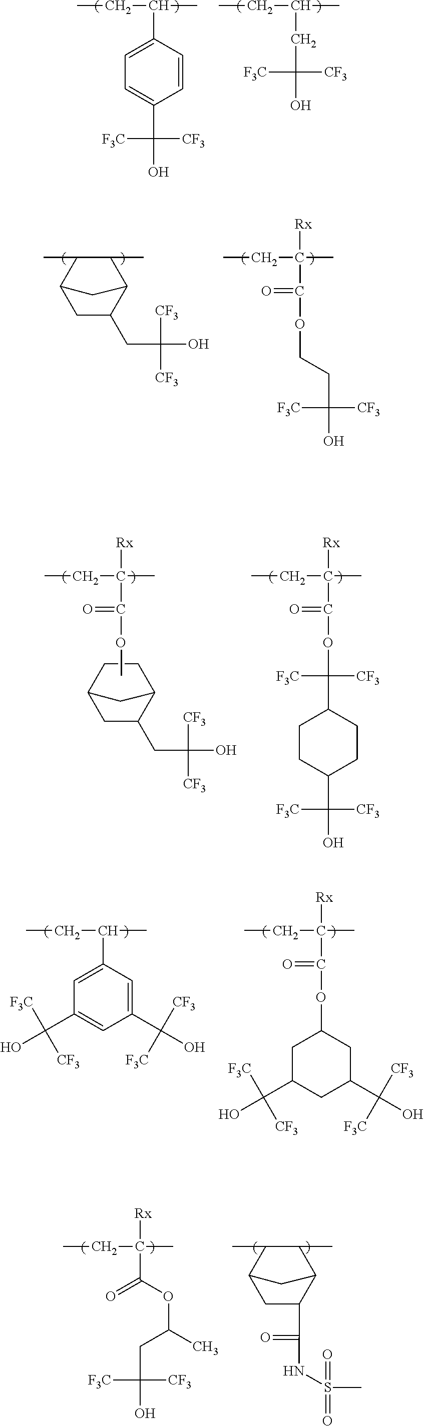

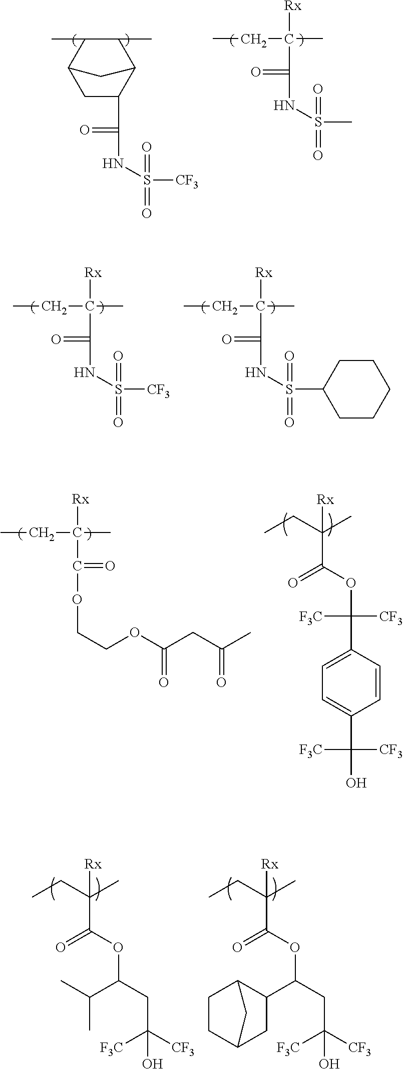

Examples of the group (y) capable of decomposing by the action of an alkali developer to increase the solubility in an alkali developer (polarity converting group (y)) include a lactone group, a carboxylic acid ester group (—COO—), an acid anhydride group (—C(O)OC(O)—), an acid imide group (—NHCONH—), a carboxylic acid thioester group (—COS—), a carbonic acid ester group (—OC(O)O—), a sulfuric acid ester group (—OSO₂O—) and a sulfonic acid ester group (—SO₂O—), with a lactone group being preferred.

The actinic ray-sensitive or radiation-sensitive resin composition of the present invention preferably contains (Cy) a resin having at least either a fluorine atom or a silicon atom and containing (cy) a repeating unit having at least one polarity converting group (y). The resin (Cy) has hydrophobicity, and addition of the resin (Cy) is preferred particularly from the standpoint of reducing the development defect. Incidentally, an ester group directly bonded to the main chain of the repeating unit as in an acrylate is poor in the function of decomposing by the action of an alkali developer to increase the solubility in an alkali developer and is not included in the polarity converting group of the present invention.

As for the polarity converting group (y), both a configuration where the polarity converting group is contained in a repeating unit composed of an acrylic acid ester or a methacrylic acid ester and thereby is introduced into the side chain of the resin, and a configuration where the polarity converting group (y) is introduced into the terminal of the polymer chain by using a polymerization initiator or chain transfer agent containing the polarity converging group (y) at the polymerization, are preferred.

Specific examples of the repeating unit (cy) having (y) a polarity converting group include the specific examples of the repeating unit having a partial structure represented by formula (II) and the lactone structure-containing repeating unit (for example, a repeating unit represented by formula (AII′)) except for the repeating unit above, which are described in the resin (A).

The repeating unit (cy) includes, for example, a repeating unit represented by formula (K0):

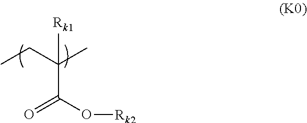

In the formula, Rₖ₁ represents a hydrogen atom, a halogen atom, a hydroxyl group, an alkyl group, a cycloalkyl group, an aryl group, or a polarity converting group-containing group.

Rₖ₂ represents an alkyl group, a cycloalkyl group, an aryl group, or a polarity converting group-containing group.

However, at least either one of Rₖ₁ and Rₖ₂ represents a polarity converting group-containing group.

The polarity converting group is, as described above, a group capable of decomposing by the action of an alkali developer to increase the solubility in an alkali developer. The polarity converting group is preferably a group X in a partial structure represented by formula (KA-1) or (KB-1):

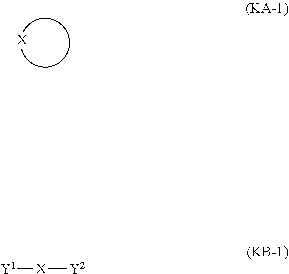

In formulae (KA-1) and (KB-1), X represents a carboxylic acid ester group: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, or a sulfonic acid ester group: —SO₂O—.

Each of Y¹ and Y², which may be the same or different, represents an electron-withdrawing group.

Incidentally, the repeating unit (cy) has a preferred group capable of increasing the solubility in an alkali developer by containing a group having a partial structure represented by formula (KA-1) or (KB-1), but as in the case of the partial structure represented by formula (KA-1) or the partial structure represented by formula (KB-1) where Y¹ and Y² are monovalent, when the partial structure does not have a bond, the group having the partial structure is a group having a monovalent or higher valent group formed by removing at least one arbitrary hydrogen atom in the partial structure.

The partial structure represented by formula (KA-1) or (KB-1) is connected to the main chain of the resin (Cy) at an arbitrary position through a substituent.

The partial structure represented by formula (KA-1) is a structure forming a ring structure together with the group as X.

In formula (KA-1), X is preferably a carboxylic acid ester group (that is, a case of forming a lactone ring structure as KA-1), an acid anhydride group or a carbonic acid ester group, more preferably a carboxylic acid ester group.

The ring structure represented by formula (KA-1) may have a substituent and, for example, may have nka substituents Zₖₐ₁.

Zₖₐ₁ represents, when a plurality of Zₖₐ₁'s are present, each independently represents, a halogen atom, an alkyl group, a cycloalkyl group, an ether group, a hydroxyl group, an amide group, an aryl group, a lactone ring group or an electron-withdrawing group.

Zₖₐ₁'s may combine with each other to form a ring. Examples of the ring formed by combining Zₖₐ₁'s with each other include a cycloalkyl ring and a heterocyclic ring (e.g., cyclic ether ring, lactone ring).

nka represents an integer of 0 to 10 and is preferably an integer of 0 to 8, more preferably an integer of 0 to 5, still more preferably an integer of 1 to 4, and most preferably an integer of 1 to 3.

The electron-withdrawing group as Zₖₐ₁ has the same meaning as the electron-withdrawing group of Y¹ and Y² described later. The electron-withdrawing group above may be substituted with another electron-withdrawing group.

Zₖₐ₁ is preferably an alkyl group, a cycloalkyl group, an ether group, a hydroxyl group or an electron-withdrawing group, more preferably an alkyl group, a cycloalkyl group or an electron-withdrawing group. The ether group is preferably an ether group substituted, for example, with an alkyl group or a cycloalkyl group, that is, an alkyl ether group. The electron-withdrawing group has the same meaning as above.

Examples of the halogen atom as Zₖₐ₁ include a fluorine atom, a chlorine atom, a bromine atom and an iodine atom, with a fluorine atom being preferred.

The alkyl group as Zₖₐ₁ may have a substituent and may be either linear or branched. The linear alkyl group is preferably an alkyl group having a carbon number of 1 to 30, more preferably from 1 to 20, and examples thereof include a methyl group, an ethyl group, an n-propyl group, an n-butyl group, a sec-butyl group, a tert-butyl group, an n-pentyl group, an n-hexyl group, an n-heptyl group, an n-octyl group, an n-nonyl group and an n-decanyl group. The branched alkyl group is preferably an alkyl group having a carbon number of 3 to 30, more preferably from 3 to 20, and examples thereof include an i-propyl group, an i-butyl group, a tert-butyl group, an i-pentyl group, a tert-pentyl group, an i-hexyl group, a tert-hexyl group, an i-heptyl group, a tert-heptyl group, an i-octyl group, a tert-octyl group, an i-nonyl group and a tert-decanoyl group. An alkyl group having a carbon number of 1 to 4, such as methyl group, ethyl group, n-propyl group, i-propyl group, n-butyl group, i-butyl group and tert-butyl group, is preferred.

The cycloalkyl group as Zₖₐ₁ may have a substituent and may be monocyclic or polycyclic, and in the case of polycyclic, the cycloalkyl group may be crosslinked. That is, in this case, the cycloalkyl group may have a bridged structure.

The monocyclic cycloalkyl group is preferably a cycloalkyl group having a carbon number of 3 to 8, and examples thereof include a cyclopropyl group, a cyclopentyl group, a cyclohexyl group, a cyclobutyl group and a cyclooctyl group.

Examples of the polycyclic cycloalkyl group include a group having a bicyclo, tricyclo or tetracyclo structure and having a carbon number of 5 or more. A cycloalkyl group having a carbon number of 6 to 20 is preferred, and examples thereof include an adamantyl group, a norbornyl group, an isoboronyl group, a camphanyl group, a dicyclopentyl group, an α-pinel group, a tricyclodecanyl group, a tetracyclododecyl group and an androstanyl group.

These cycloalkyl groups include, for example, those represented by the following formulae. Incidentally, a part of carbon atoms in the cycloalkyl group may be replaced by a heteroatom such as oxygen atom.

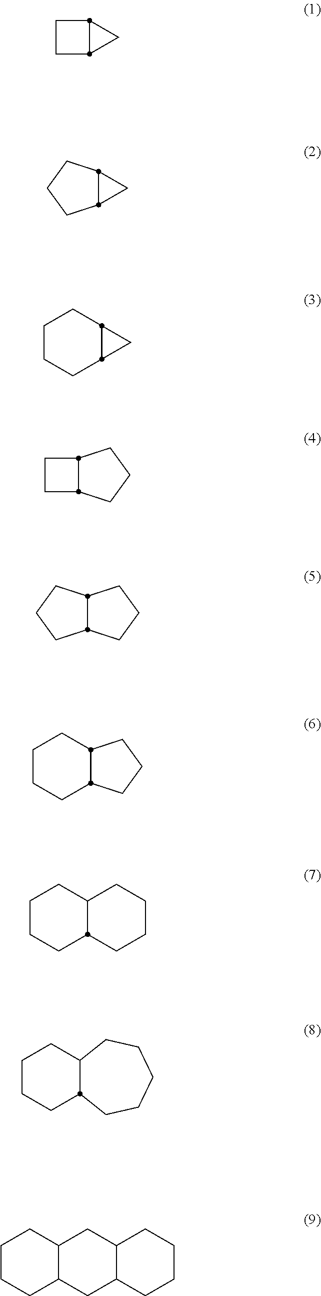

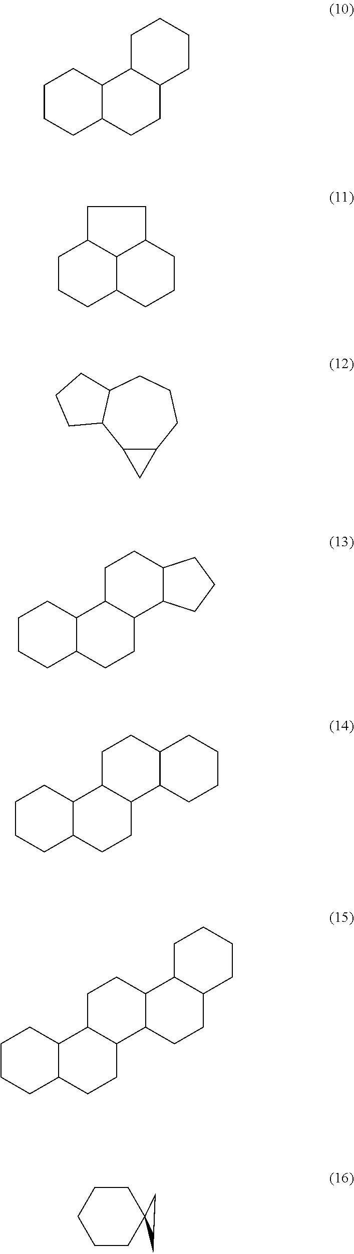

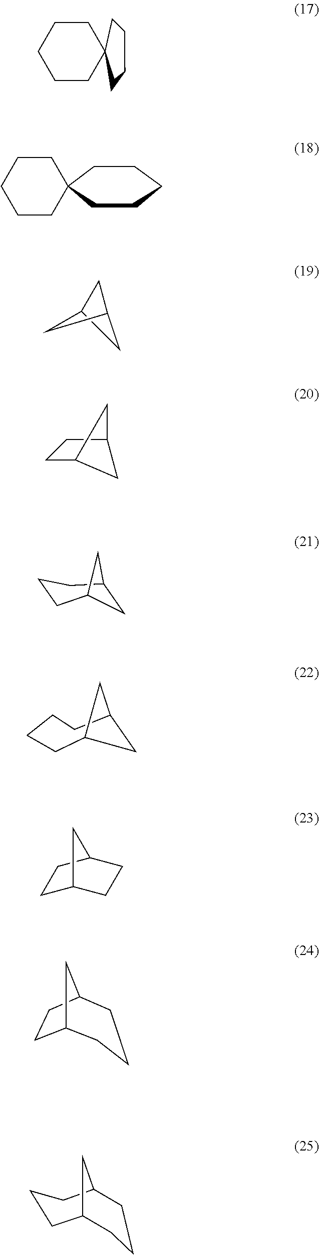

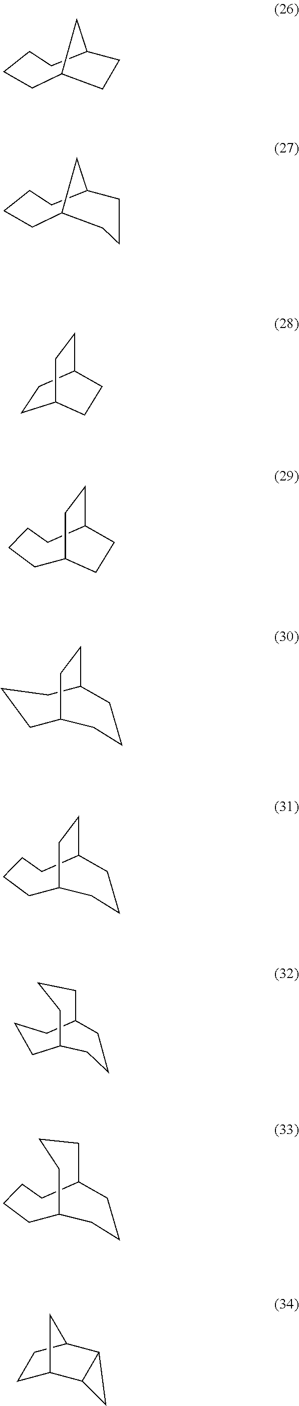

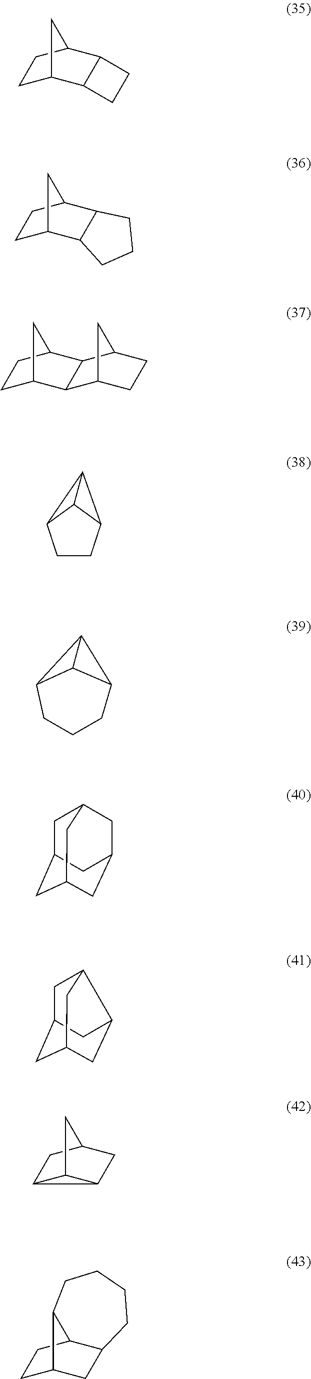

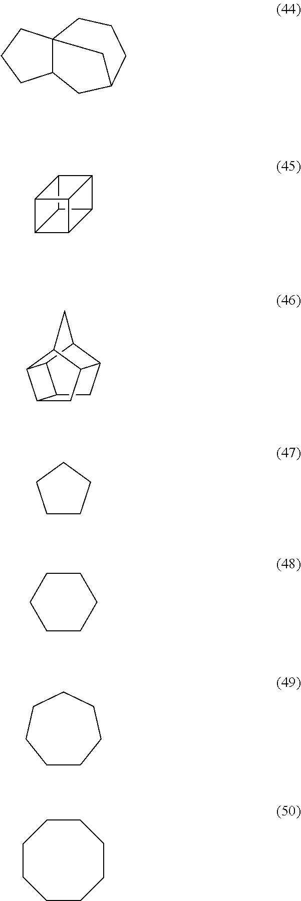

The alicyclic moiety is preferably an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group or a cyclododecanyl group, more preferably an adamantyl group, a decalin group, a norbornyl group, a cedrol group, a cyclohexyl group, a cycloheptyl group, a cyclooctyl group, a cyclodecanyl group, a cyclododecanyl group or a tricyclodecanyl group.

The substituent of the alicyclic structure includes an alkyl group, a halogen atom, a hydroxyl group, an alkoxy group, a carboxyl group and an alkoxycarbonyl group. The alkyl group is preferably a lower alkyl group such as methyl group, ethyl group, propyl group, isopropyl group and butyl group, more preferably a methyl group, an ethyl group, a propyl group or an isopropyl group. The alkoxy group is preferably an alkoxy group having a carbon number of 1 to 4, such as methoxy group, ethoxy group, propoxy group and butoxy group. Examples of the substituent which the alkyl group and alkoxy group may have include a hydroxyl group, a halogen atom and an alkoxy group (preferably having a carbon number of 1 to 4).

The groups above may further have a substituent, and examples of the further substituent include a hydroxyl group, a halogen atom (e.g., fluorine, chlorine, bromine, iodine), a nitro group, a cyano group, the above-described alkyl group, an alkoxy group such as methoxy group, ethoxy group, hydroxyethoxy group, propoxy group, hydroxypropoxy group, n-butoxy group, isobutoxy group, sec-butoxy group and tert-butoxy group, an alkoxycarbonyl group such as methoxycarbonyl group and ethoxycarbonyl group, an aralkyl group such as benzyl group, phenethyl group and cumyl group, an aralkyloxy group, an acyl group such as formyl group, acetyl group, butyryl group, benzoyl group, cianamyl group and valeryl group, an acyloxy group such as butyryloxy group, the above-described alkenyl group, an alkenyloxy group such as vinyloxy group, propenyloxy group, allyloxy group and butenyloxy group, the above-described aryl group, an aryloxy group such as phenoxy group, and an aryloxycarbonyl group such as benzoyloxy group.

It is preferred that X in formula (KA-1) is a carboxylic acid ester group and the partial structure represented by formula (KA-1) is a lactone ring, and the lactone ring is preferably a 5- to 7-membered lactone ring.

In this connection, as in (KA-1-1) to (KA-1-17) shown below, another ring structure is preferably fused to a 5- to 7-membered lactone ring that is the partial structure represented by formula (KA-1), in the form of forming a bicyclo or spiro structure.

Examples of the peripheral ring structure with which the ring structure represented by formula (KA-1) may combine include those in (KA-1-1) to (KA-1-17) shown below and structures based on these structures.

The structure containing the lactone ring structure represented by formula (KA-1) is more preferably a structure represented by any one of the following (KA-1-1) to (KA-1-17). The lactone structure may be bonded directly to the main chain. Preferred structures are (KA-1-1), (KA-1-4), (KA-1-5), (KA-1-6), (KA-1-13), (KA-1-14) and (KA-1-17).

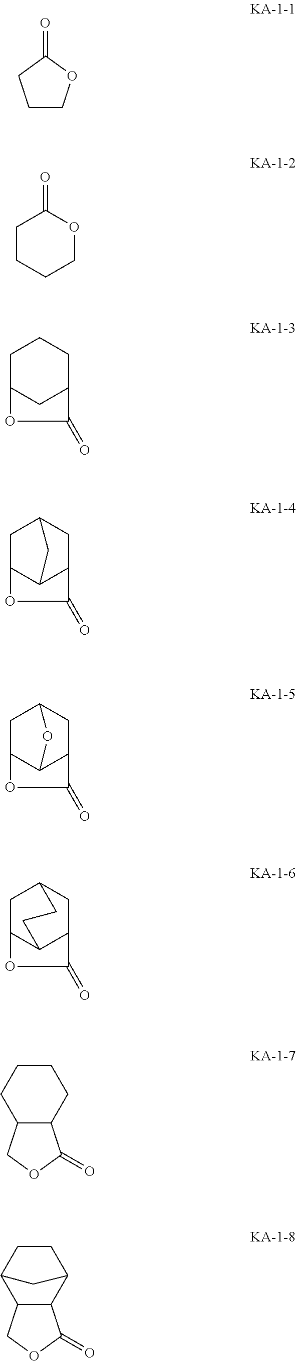

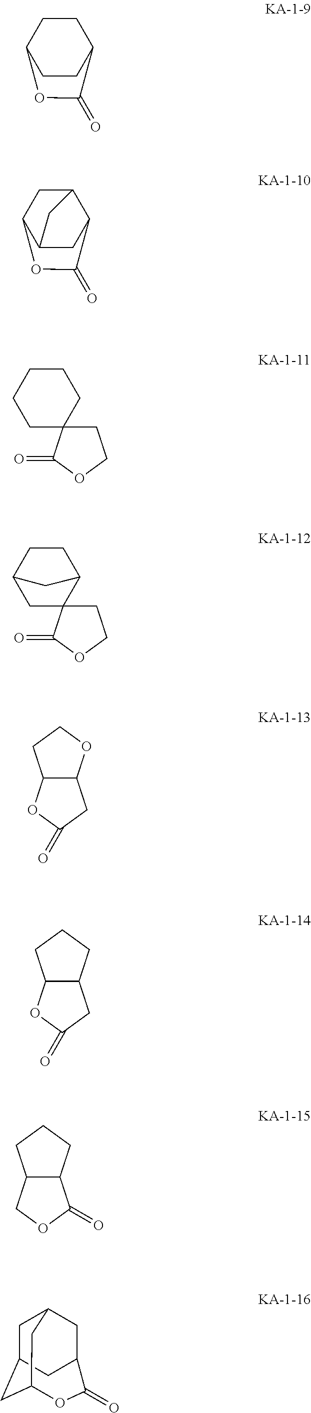

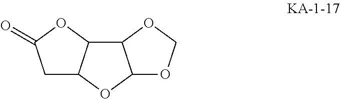

The structure containing the above-described lactone ring structure may or may not have a substituent. Preferred examples of the substituent are the same as those of the substituent Zₖₐ₁ which the ring structure represented by formula (KA-1) may have.

In formula (KB-1), X is preferably a carboxylic acid ester group (—COO—).

In formula (KB-1), each of Y¹ and Y² independently represents an electron-withdrawing group.

The electron-withdrawing group is a partial structure represented by the following formula (EW). In formula (EW), * indicates a bond directly bonded to (KA-1) or a bond directly bonded to X in (KB-1).

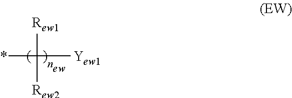

In formula (EW), n_{ew} is a repetition number of the linking group represented by —C(R_{ew1})(R_{ew2})— and represents an integer of 0 or 1. In the case where n_{ew} is 0, this indicates that the bond is a single bond and Y_{ew1} is directly bonded.

Y_{ew1} is a halogen atom, a cyano group, a nitrile group, a nitro group, a halo(cyclo)alkyl or haloaryl group represented by —C(R_{f1})(R_{f2})—R_{f3} described later, an oxy group, a carbonyl group, a sulfonyl group, a sulfinyl group, or a combination thereof. The electron-withdrawing group may be, for example, a structure shown below. The term “halo(cyclo)alkyl group” indicates an alkyl or cycloalkyl group that is at least partially halogenated, and the “haloaryl group” indicates an aryl group that is at least partially halogenated. In the following structural formulae, each of R_{ew3} and R_{ew4} independently represents an arbitrary structure. The partial structure represented by formula (EW) has an electron-withdrawing group regardless of what structure R_{ew3} or R_{ew4} may take, and each of R_{ew3} and R_{ew4} may be connected, for example, to the main chain of the resin but is preferably an alkyl group, a cycloalkyl group or an alkyl fluoride group.

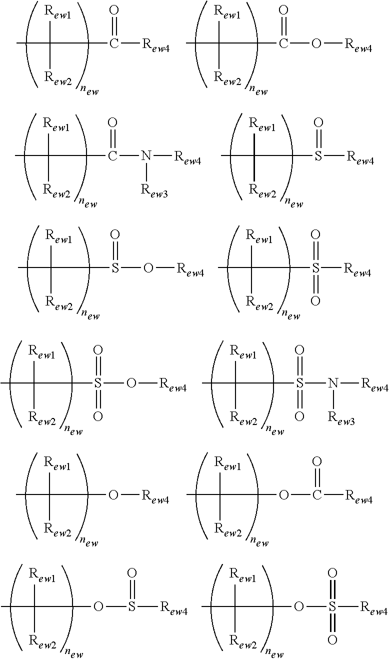

In the case where Y_{ew1} is a divalent or higher valent group, the remaining bond forms bonding to an arbitrary atom or substituent. At least any one group of Y_{ew1}, R_{ew1} and R_{ew2} may be connected to the main chain of the resin (Cy) through a further substituent.

Y_{ew1} is preferably a halogen atom or a halo(cyclo)alkyl or haloaryl group represented by —C(R_{f1})(R_{f2})—R_{f3}.

Each of R_{ew1} and R_{ew2} independently represents an arbitrary substituent, for example, represents a hydrogen atom, an alkyl group, a cycloalkyl group or an aryl group.

At least two members out of R_{ew1}, R_{ew2} and Y_{ew1} may combine with each other to form a ring.

R_{f1} represents a halogen atom, a perhaloalkyl group, a perhalocycloalkyl group or a perhaloaryl group and is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group, and R_{f2} and R_{f3} may combine to form a ring. Examples of the organic group include an alkyl group, a cycloalkyl group and an alkoxy group. R_{f2} is preferably the same group as R_{f1} or combines with R_{f3} to form a ring.

R_{f1} to R_{f3} may combine to form a ring, and examples of the ring formed include a (halo)cycloalkyl ring and a (halo)aryl ring.

Examples of the (halo)alkyl group in R_{f1} to R_{f3} include the alkyl groups in Zₖₐ₁ described above and halogenated structures thereof.

Examples of the (per)halocycloalkyl group and (per)haloaryl group in R_{f1} to R_{f3} or in the ring formed by combining R_{f2} and R_{f3} include a structure formed by halogenation of the cycloalkyl group in Zₖₐ₁ described above, preferably a fluorocycloalkyl group represented by —C₍ₙ₎F₍₂ₙ₋₂₎H, and a perfluoroaryl group represented by —C₍ₙ₎F₍ₙ₋₁₎, wherein the carbon number n is not particularly limited but is preferably from 5 to 13, more preferably 6.

The ring which may be formed by combining at least two members of R_{ew1}, R_{ew2} and Y_{ew1} with each other is preferably a cycloalkyl group or a heterocyclic group, and the heterocyclic group is preferably a lactone ring group. Examples of the lactone ring include structures represented by formulae (KA-1) to (KA-1-17).

Incidentally, the repeating unit (cy) may have a plurality of partial structures represented by formula (KA-1), a plurality of partial structures represented by formula (KB-1), or both a partial structure of formula (KA-1) and a partial structure of formula (KB-1).

In this connection, the partial structure of formula (KA-1) may partially or entirely serve also as the electron-withdrawing group of Y¹ or Y² in formula (KB-1). For example, in the case where X in formula (KA-1) is a carboxylic acid ester group, the carboxylic acid ester group may function as an electron-withdrawing group of Y¹ or Y² in formula (KB-1).

The repeating unit (cy) may be (cy′) a repeating unit having at least either a fluorine atom or a silicon atom and a polarity converting group on the same side chain, (cy*) a repeating unit having a polarity converting group and having neither a fluorine atom nor a silicon atom, or (cy″) a repeating unit having a polarity converting group on one side chain and having at least either a fluorine atom or a silicon atom on a side chain different from the side chain above in the same repeating unit, but the resin (Cy) preferably contains a repeating unit (cy′) as the repeating unit (cy).

In the case where the resin (Cy) contains the repeating unit (cy*), the resin is preferably a copolymer with a repeating unit having at least either a fluorine atom or a silicon atom (a repeating unit (c1) described later). Also, in the repeating unit (cy″), the side chain having a polarity converting group and the side chain having at least either a fluorine atom or a silicon atom are preferably bonded to the same carbon atom in the main chain, that is, have a positional relationship as in the following formula (K1).

In the formula, B1 represents a partial structure having a group capable of increasing the solubility in an alkali developer, and B2 represents a partial structure having at least either a fluorine atom or a silicon atom.

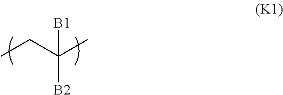

Also, in the repeating unit (cy*) and the repeating unit (cy″), the polarity converting group is more preferably a partial structure represented by —COO— in the structure of formula (KA-1).

The repeating unit (cy) may be a repeating unit having a partial structure shown below.

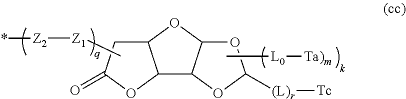

In formula (cc), Z₁ represents a single bond, an ether bond, an ester bond, an amide bond, a urethane bond or a urea bond, and when a plurality of Z₁'s are present, these may be the same or different. Z₁ is preferably an ester bond.

Z₂ represents a chain or cyclic alkylene group and when a plurality of Z₂'s are present, these may be the same or different. Z₂ is preferably an alkylene group having a carbon number of 1 or 2 or a cycloalkylene group having a carbon number of 5 to 10.

Each Ta independently represents an alkyl group, a cycloalkyl group, an alkoxy group, a nitrile group, a hydroxyl group, an amide group, an aryl group or an electron-withdrawing group (having the same meaning as the electron-withdrawing group of Y¹ and Y² in formula (KB-1)) and is preferably an alkyl group, a cycloalkyl group or an electron-withdrawing group, more preferably an electron-withdrawing group. When a plurality of Ta's are present, Ta's may combine with each other to form a ring.

Each L₀ independently represents a single bond or an (m+1)-valent hydrocarbon group (preferably having a carbon number of 20 or less) and is preferably a single bond. The single bond as L₀ is formed when m is 1. The (m+1)-valent hydrocarbon group as L₀ represents an (m+1)-valent hydrocarbon group formed by removing m−1 arbitrary hydrogen atoms from, for example, an alkylene group, a cycloalkylene group, a phenylene group or a combination thereof.

Each L independently represents a carbonyl group, a carbonyloxy group or an ether group.

Tc represents a hydrogen atom, an alkyl group, a cycloalkyl group, a nitrile group, a hydroxyl group, an amide group, an aryl group or an electron-withdrawing group (having the same meaning as the electron-withdrawing group of Y¹ and Y² in formula (KB-1)).

* represents a bond to the main or side chain of the resin. That is, a partial structure represented by formula (cc) may be directly bonded to the main chain, or a partial structure represented by formula (cc) may be bonded to the side chain of the resin. In this connection, the bond to the main chain is a bond to an atom present in the bond constituting the main chain, and the bond to the side chain is a bond to an atom present in the portion except for the bond constituting the main chain.

m represents an integer of 1 to 28 and is preferably an integer of 1 to 3, more preferably 1.

k represents an integer of 0 to 2 and is preferably 1.

q is a repetition number of the group (Z₂—Z₁) and represents an integer of 0 to 5, preferably from 0 to 2.

r represents an integer of 0 to 5.

Incidentally, the above-described -L₀-(Ta)ₘ may be substituted in place of -(L)ᵣ-Tc.

It is also preferred to have a fluorine atom at the terminal of sugar lactone or have a fluorine atom on a side chain different from the side chain on the sugar lactone side within the same repeating unit (corresponding to the repeating unit (cy″)).

The carbon number of the chain alkylene group as Z₂ is, in the case of a linear alkylene group, preferably from 1 to 30, more preferably from 1 to 20, and in the case of a branched alkylene group, preferably from 3 to 30, more preferably from 3 to 20. Specific examples of the chain alkylene group as R₂ include specific examples of the alkyl group as Zₖₐ₁ above where one arbitrary hydrogen atom is removed.

The cyclic alkylene group as Z₂ is preferably a cyclic alkylene group having a carbon number of 3 to 8, and specific examples thereof include the cycloalkyl group as Zₖₐ₁ above where one arbitrary hydrogen atom is removed.

The preferred carbon numbers and specific examples of the alkyl group and cycloalkyl group as Ta and Tc are the same as those described above for the alkyl group and cycloalkyl group as Zₖₐ₁.

The alkoxy group as Ta is preferably an alkoxy group having a carbon number of 1 to 8, and examples thereof include a methoxy group, an ethoxy group, a propoxy group and a butoxy group.

The aryl group as Ta and Tc is preferably an aryl group having a carbon number of 6 to 12, and examples thereof include a phenyl group and a naphthyl group.

The preferred carbon numbers and specific examples of the alkylene group and cycloalkylene group as L₀ are the same as those described above for the chain alkylene group and cyclic alkylene group as Z₂.

As for the more specific structure of the repeating unit (cc), repeating units having a partial structure shown below are preferred.

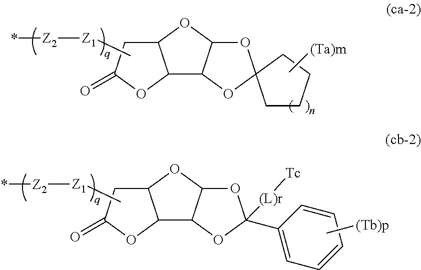

In formulae (ca-2) and (cb-2), n represents an integer of 0 to 11 and is preferably an integer of 0 to 5, more preferably 1 or 2.

p represents an integer of 0 to 5 and is preferably an integer of 0 to 3, more preferably 1 or 2.

Each Tb independently represents an alkyl group, a cycloalkyl group, an alkoxy group, a nitrile group, a hydroxyl group, an amide group, an aryl group or an electron-withdrawing group (having the same meaning as the electron-withdrawing group of Y¹ and Y² in formula (KB-1)) and is preferably an alkyl group, a cycloalkyl group or an electron-withdrawing group. When a plurality of Tb's are present, Tb's may combine with each other to form a ring.

* represents a bond to the main or side chain of the resin. That is, a partial structure represented by formula (ca-2) or (cb-2) may be directly bonded to the main chain, or a partial structure represented by formula (ca-2) or (cb-2) may be bonded to the side chain of the resin.

Z₁, Z₂, Ta, Tc, L, *, m, q and r have the same meanings as those in formula (cc) and preferred embodiments are also the same.

The repeating unit (cy) may be a repeating unit having a partial structure represented by formula (KY-0):

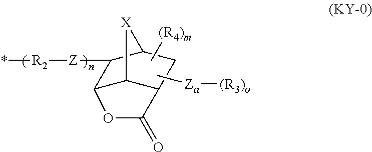

In formula (KY-0), R₂ represents a chain or cyclic alkylene group and when a plurality of R₂'s are present, these may be the same or different.

R₃ represents a linear, branched or cyclic hydrocarbon group where a part or all of hydrogen atoms on the constituent carbons are replaced by a fluorine atom. When a plurality of R₃'s are present, these may be the same or different.

R₄ represents a halogen atom, a cyano group, a hydroxy group, an amide group, an alkyl group, a cycloalkyl group, an alkoxy group, a phenyl group, an acyl group, an alkoxycarbonyl group or a group represented by R—C(═O)— or R—C(═O)O— (wherein R represents an alkyl group or a cycloalkyl group). When a plurality of R₄'s are present, these may be the same or different, and two or more R₄'s may combine to form a ring.

X represents an alkylene group, an oxygen atom or a sulfur atom.

Each of Z and Za represents a single bond, an ether bond, an ester bond, an amide bond, a urethane bond or a urea bond and when a plurality of Z's or Za's are present, each Z or Za may be the same as or different from each other Z or Za.

* represents a bond to the main or side chain of the resin.

o is the number of substituents and represents an integer of 1 to 7.

m is the number of substituents and represents an integer of 0 to 7.

n is a repetition number and represents an integer of 0 to 5.

The structure of —R₂—Z— is preferably a structure represented by —(CH₂)ₗ—COO— (wherein l represents an integer of 1 to 5).

The preferred carbon number range and specific examples of the chain or cyclic alkylene group as R₂ are the same as those described for the chain alkylene group and cyclic alkylene group in Z₂ of formula (cc).

The carbon number of the linear, branched or cyclic hydrocarbon group as R₃ is, in the case of a linear hydrocarbon group, preferably from 1 to 30, more preferably from 1 to 20; in the case of a branched hydrocarbon group, preferably from 3 to 30, more preferably from 3 to 20; and in the case of a cyclic hydrocarbon group, from 6 to 20. Specific examples of R₃ include specific examples of the alkyl group and cycloalkyl group as Zₖₐ₁ above.

The preferred carbon numbers and specific examples of the alkyl group and cycloalkyl group as R₄ and R are the same as those described above for the alkyl group and cycloalkyl group as Zₖₐ₁.

The acyl group as R₄ is preferably an acyl group having a carbon number of 2 to 6, and examples thereof include a formyl group, an acetyl group, a propionyl group, a butyryl group, an isobutyryl group, a valeryl group and a pivaloyl group.

The alkyl moiety in the alkoxy group and alkoxycarbonyl group as R₄ includes a linear, branched or cyclic alkyl moiety, and the preferred carbon number and specific examples of the alkyl moiety are the same as those described above for the alkyl group and cycloalkyl group as Zₖₐ₁.

The alkylene group as X includes a chain or cyclic alkylene group, and the preferred carbon number and specific examples thereof are the same as those described for the chain alkylene group and cyclic alkylene group as R₂.

As for the specific structure of the repeating unit (cy), the repeating unit also includes repeating units having a partial structure shown below.

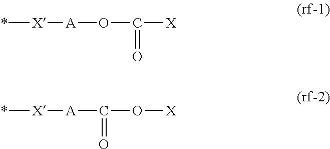

In formulae (rf-1) and (rf-2), X′ represents an electron-withdrawing substituent and is preferably a carbonyloxy group, an oxycarbonyl group, a fluorine atom-substituted alkylene group or a fluorine atom-substituted cycloalkylene group.

A represents a single bond or a divalent linking group represented by —C(Rx)(Ry)—, wherein each of Rx and Ry independently represents a hydrogen atom, a fluorine atom, an alkyl group (preferably having a carbon number of 1 to 6; which may be substituted with a fluorine atom or the like), or a cycloalkyl group (preferably having a carbon number of 5 to 12; which may be substituted with a fluorine atom or the like). Each of Rx and Ry is preferably a hydrogen atom, an alkyl group or a fluorine atom-substituted alkyl group.

X represents an electron-withdrawing group and specific examples thereof include those electron-withdrawing groups as Y¹ and Y² above. Among these, an alkyl fluoride group, a cycloalkyl fluoride group, an aryl group substituted with fluorine or an alkyl fluoride group, and an aralkyl group substituted with fluorine or an alkyl fluoride group are preferred.

* represents a bond to the main or side chain of the resin, that is, a bond which is bonded to the main chain of the resin through a single bond or a linking group.

Incidentally, when X′ is a carbonyloxy group or an oxycarbonyl group, A is not a single bond.

The polarity converting group is decomposed by the action of an alkali developer to effect polarity conversion, whereby the receding contact angle with water of the resin composition film after alkali development can be decreased. Decrease in the receding contact angle with water of the film after alkali development is preferred from the standpoint of suppressing the development defect.

The receding contact angle with water of the resin composition film after alkali development is preferably 50° or less, more preferably 40° or less, still more preferably 35° or less, and most preferably 30° or less, at a temperature of 23±3° C. and a humidity of 45±5%.

The receding contact angle is a contact angle measured when a contact line recedes on the liquid droplet-substrate interface, and this is generally known to be useful in simulating the mobility of a liquid droplet in the dynamic state. In a simple manner, the receding contact angle can be defined as a contact angle at the time of the liquid droplet interface receding when a liquid droplet ejected from a needle tip is landed on a substrate and then the liquid droplet is again suctioned into the needle. In general, the receding contact angle can be measured by a contact angle measuring method called an expansion/contraction method.

The above-described receding contact angle of the film after alkali development is the contact angle measured on the film described below by an expansion/contraction method employed in Examples later. That is, an organic antireflection film, ARC29A (produced by Nissan Chemical Industries, Ltd.), is applied on a silicon wafer (8 inches in diameter) and baked at 205° C. for 60 seconds to form a 98 nm-thick antireflection film, the composition of the present invention is applied thereon and baked at 120° C. for 60 seconds to form a film having a thickness of 120 nm, this film is developed with an aqueous tetramethylammonium hydroxide solution (2.38 mass %) for 30 seconds, rinsed with pure water and spin-dried, and the contact angle of the obtained film is measured by the expansion/contraction method.

The hydrolysis rate of the resin (Cy) for an alkali developer is preferably 0.001 nm/sec or more, more preferably 0.01 nm/sec or more, still more preferably 0.1 nm/sec or more, and most preferably 1 nm/sec or more.

The hydrolysis rate of the resin (Cy) for an alkali developer is the rate at which the thickness of a resin film formed of only the resin (Cy) decreases when treated with TMAH (an aqueous tetramethylammonium hydroxide solution) (2.38 mass %) at 23° C.

The repeating unit (cy) is more preferably a repeating having at least two or more polarity converting groups.

In the case where the repeating unit (cy) has at least two polarity converting groups, the repeating unit preferably has a group containing a partial structure having two polarity converting groups represented by the following formula (KY-1). Incidentally, when the structure represented by formula (KY-1) does not have a bond, this is a group containing a monovalent or greater valent group formed by removing at least one arbitrary hydrogen atom from the structure.

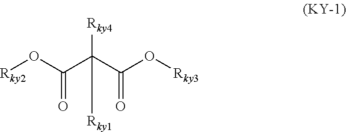

In formula (KY-1), each of R_{ky1} and R₄₄ independently represents a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group. Alternatively, R_{ky1} and R₄₄ may be bonded to the same atom to form a double bond. For example, R_{ky1} and R_{ky4} may be bonded to the same oxygen atom to form a part (═O) of a carbonyl group.

Each of R_{ky2} and R_{ky3} independently represents an electron-withdrawing group, or while R_{ky1} and R_{ky2} combine to form a lactone ring, R_{ky3} is an electron-withdrawing group. The lactone ring formed is preferably a structure of (KA-1-1) to (KA-1-17). Examples of the electron-withdrawing group is the same as those for Y¹ and Y² in formula (KB-1), and a halogen atom and a halo(cyclo)alkyl or haloaryl group represented by —C(R_{f1})(R_{f2})—R_{f3} described above are preferred. Preferably, R_{ky3} is a halogen atom or a halo(cyclo)alkyl or haloaryl group represented by —C(R_{f1})(R_{f2})—R_{f3}, and R_{ky2} combines with R_{ky1} to form a lactone ring or is an electron-withdrawing group containing no halogen atom.

R_{ky1}, R_{ky2} and R_{ky4} may combine with each other to form a monocyclic or polycyclic structure.

Specific examples of R_{ky1} and R_{ky4} include the same groups as those for Zₖₐ₁ in formula (KA-1).

The lactone ring formed by combining R_{ky1} and R_{ky2} is preferably a structure of (KA-1-1) to (KA-1-17). Examples of the electron-withdrawing group are the same as those for Y¹ and Y² in formula (KB-1).

The structure represented by formula (KY-1) is preferably a structure represented by the following formula (KY-2). Here, the structure represented by formula (KY-2) is a group having a monovalent or higher valent group formed by removing at least one arbitrary hydrogen atom from the structure.

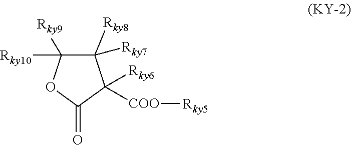

In formula (KY-2), each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group.

Two or more members of R_{ky6} to R_{ky10} may combine with each other to form a monocyclic or polycyclic structure.

R_{ky5} represents an electron-withdrawing group. Examples of the electron-withdrawing group are the same as those for Y¹ and Y² above, and a halogen atom and a halo(cyclo)alkyl or haloaryl group represented by —C(R_{f1})(R_{f2})—R_{f3} are preferred.

Specific examples of R_{ky5} to R_{ky10} include the same groups as those for Zₖₐ₁ in formula (KA-1).

The structure represented by formula (KY-2) is preferably a partial structure represented by the following formula (KY-3):

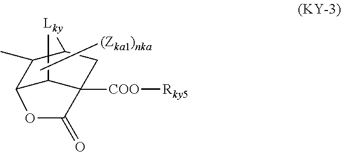

In formula (KY-3), Zₖₐ₁ and nka have the same meanings as in formula (KA-1). R_{ky5} has the same meaning as in formula (KY-2).

L_{ky} represents an alkylene group, an oxygen atom or a sulfur atom. Examples of the alkylene group of L_{ky} include a methylene group and an ethylene group. L_{ky} is preferably an oxygen atom or a methylene group, more preferably a methylene group.

The repeating unit (cy) is not limited as long as it is a repeating unit obtained by polymerization such as addition polymerization, condensation polymerization and addition condensation, but this repeating unit is preferably a repeating unit obtained by addition polymerization of a carbon-carbon double bond. Examples thereof include an acrylate-based repeating unit (including a system having a substituent at the α- or β-position), a styrene-based repeating unit (including a system having a substituent at the α- or β-position), a vinyl ether-based repeating unit, a norbornene-based repeating unit, and a maleic acid derivative (such as maleic anhydride, its derivative, and maleimide) repeating unit. An acrylate-based repeating unit, a styrene-based repeating unit, a vinyl ether-based repeating unit and a norbornene-based repeating unit are preferred, an acrylate-based repeating unit, a vinyl ether-based repeating unit and a norbornene-based repeating unit are more preferred, and an acrylate-based repeating unit is most preferred.

In the case where the repeating unit (cy) is a repeating unit having at least either a fluorine atom or a silicon atom (that is, a repeating unit corresponding to the repeating unit (cy′) or (cy″)), examples of the fluorine atom-containing partial structure in the repeating unit (cy) are the same as those in the repeating unit (c1) described later, and the groups represented by formula (F2) to (F4) described above are preferred. Also, examples of the silicon atom-containing partial structure in the repeating unit (cy) are the same as those in the repeating unit (c1) described later, and the groups represented by formulae (CS-1) to (CS-3) described above are preferred.

In the resin (Cy), the content of the repeating unit (cy) is preferably from 10 to 100 mol %, more preferably from 20 to 99 mol %, still more preferably from 30 to 97 mol %, and most preferably from 40 to 95 mol %, based on all repeating units in the resin (Cy).

The content of the repeating unit (cy′) is preferably from 10 to 100 mol %, more preferably from 20 to 100 mol %, still more preferably from 30 to 100 mol %, and most preferably from 40 to 100 mol %, based on all repeating units in the resin (Cy).

The content of the repeating unit (cy*) is preferably from 5 to 70 mol %, more preferably from 5 to 60 mol %, still more preferably from 10 to 50 mol %, and most preferably from 10 to 40 mol %, based on all repeating units in the resin (Cy). The content of the repeating unit having at least either a fluorine atom or a silicon atom, which is used together with the repeating unit (cy*), is preferably from 10 to 95 mol %, more preferably from 15 to 85 mol %, still more preferably from 20 to 80 mol %, and most preferably from 25 to 75 mol %, based on all repeating units in the resin (Cy).

The content of the repeating unit (cy″) is preferably from 10 to 100 mol %, more preferably from 20 to 100 mol %, still more preferably from 30 to 100 mol %, and most preferably from 40 to 100 mol %, based on all repeating units in the resin (Cy).

Specific examples of the repeating unit (cy) having a group capable of increasing the solubility in an alkali developer are illustrated below, but the present invention is not limited thereto.

Ra represents a hydrogen atom, a fluorine atom, a methyl group or a trifluoromethyl group.

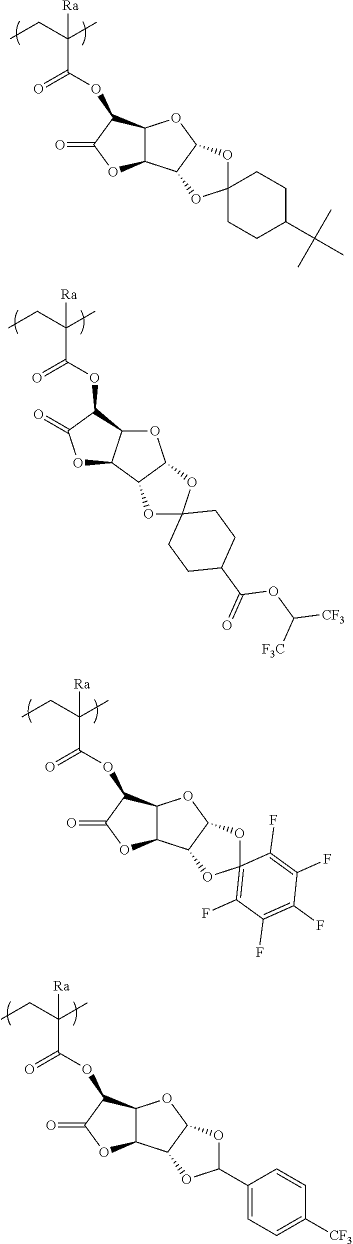

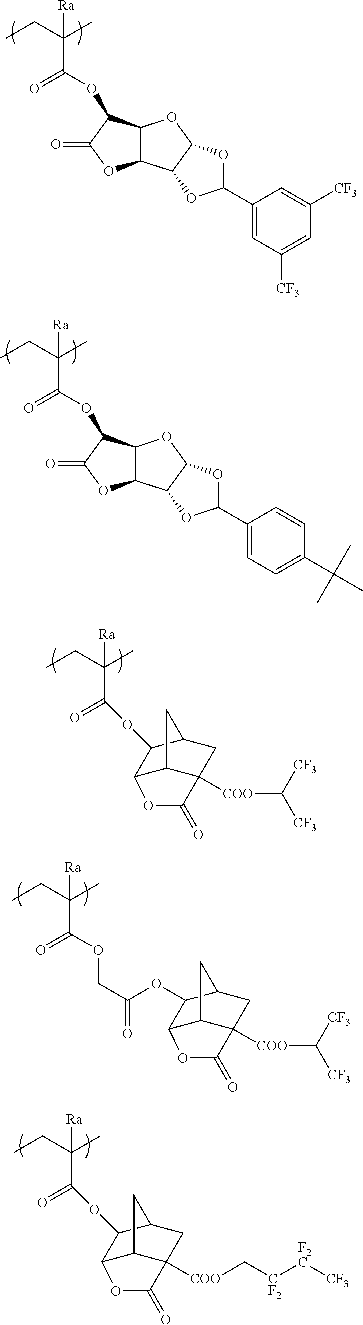

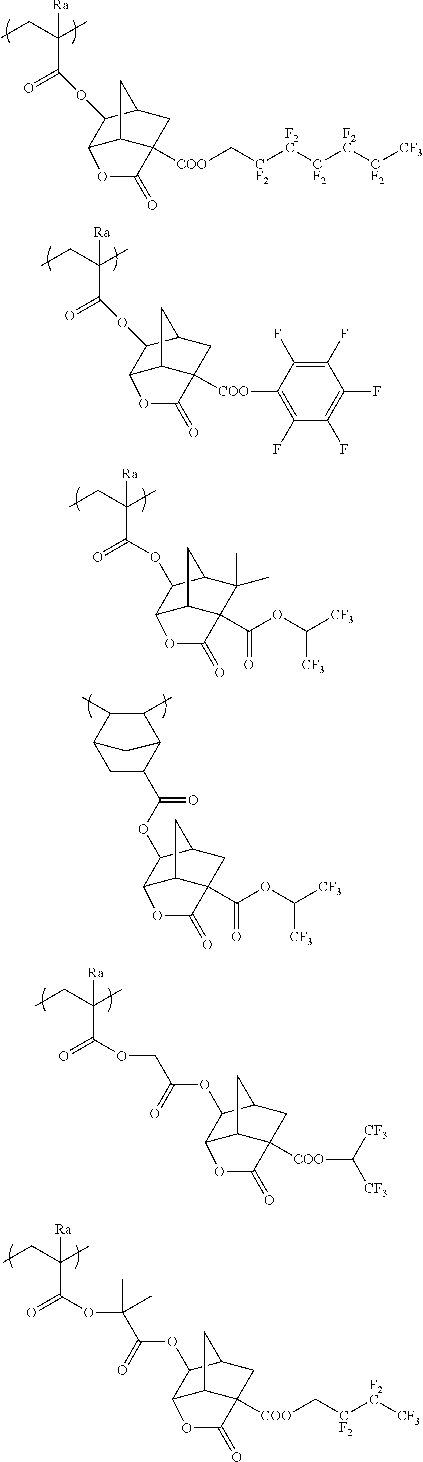

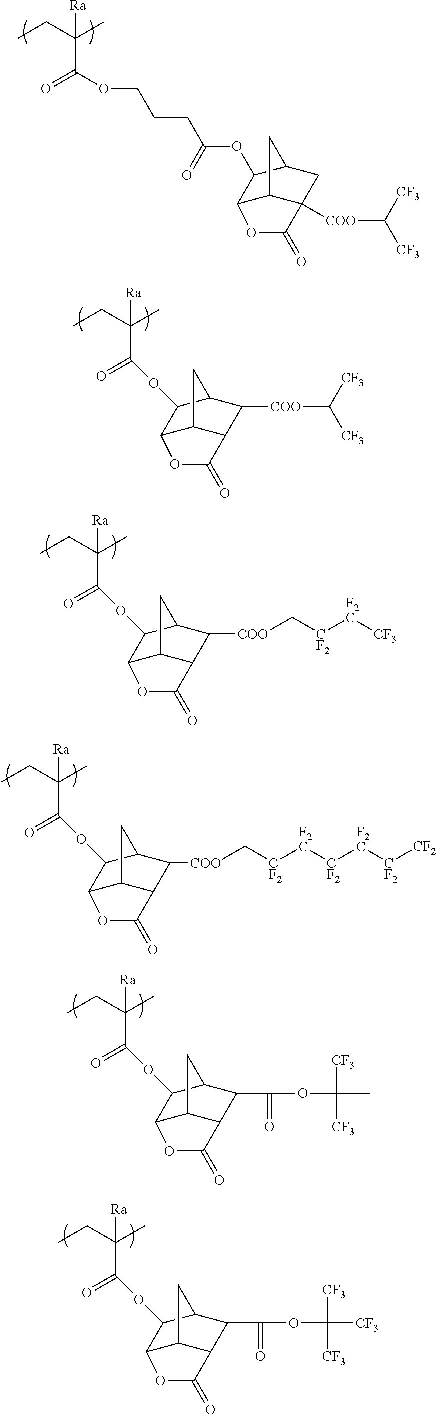

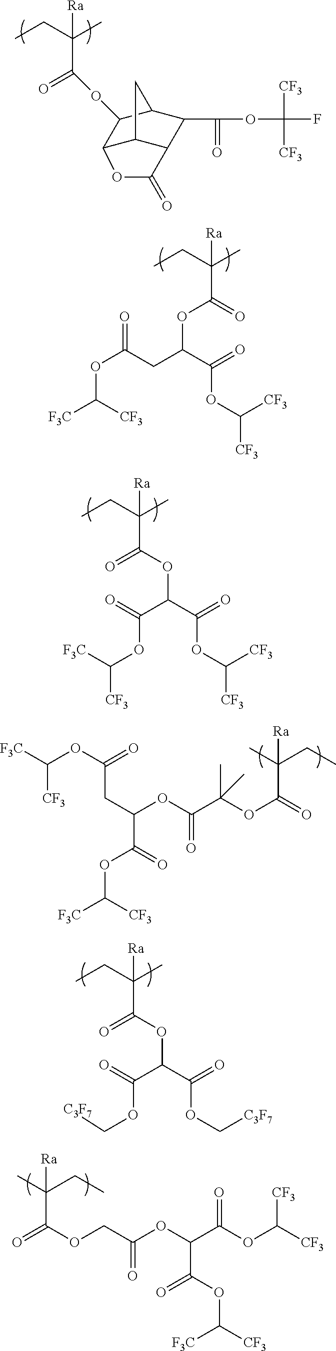

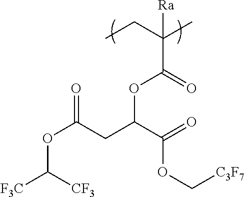

The resin (Cy) may further contain (c1) a repeating unit having at least either a fluorine atom or a silicon atom, which is different from the repeating units (cy′) and (cy″).

Examples of the fluorine atom-containing partial structure in the repeating unit (c1) are the same as those described above, and the groups represented by formulae (F2) to (F4) described above are preferred.

Examples of the silicon atom-containing partial structure in the repeating unit (c1) are the same as those described above, and the groups represented by formulae (CS-1) to (CS-3) described above are preferred.

The repeating unit (c1) having at least either a fluorine atom or a silicon atom is preferably a (meth)acrylate-based repeating unit.

Specific examples of the repeating unit (c1) are the same as specific examples of the repeating unit having a fluorine atom and the repeating unit having a group represented by formulae (CS-1) to (CS-3), but the present invention is not limited thereto.

Examples of the repeating unit having (z) a group capable of decomposing by the action of an acid, contained in the hydrophobic resin (C), are the same as those of the repeating unit having an acid-decomposable group described for the resin (A). The repeating unit having (z) a group capable of decomposing by the action of an acid may contain at least either a fluorine atom or a silicon atom. In the hydrophobic resin (C), the content of the repeating unit having (z) a group capable of decomposing by the action of an acid is preferably from 1 to 80 mol %, more preferably from 10 to 80 mol %, still more preferably from 20 to 60 mol %, based on all repeating units in the resin (C).

The hydrophobic resin (C) may further contain a repeating unit represented by the following formula (III):

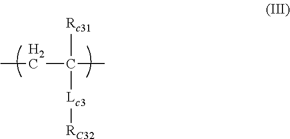

In formula (III), R₁₃₁ represents a hydrogen atom, an alkyl group (which may be substituted with fluorine), a cyano group or a —CH₂—O—R_{ac2} group, wherein R_{ac2} represents a hydrogen atom, an alkyl group or an acyl group. R_{c31} is preferably a hydrogen atom, a methyl group, a hydroxymethyl group or a trifluoromethyl group, more preferably a hydrogen atom or a methyl group.

R_{c32} represents a group having an alkyl group, a cycloalkyl group, an alkenyl group, a cycloalkenyl group or an aryl group. Each of these groups may be substituted with a fluorine atom- or silicon atom-containing group.

L_{c3} represents a single bond or a divalent linking group.

In formula (III), the alkyl group of R_{c32} is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The aryl group is preferably an aryl group having a carbon number of 6 to 20, more preferably a phenyl group or a naphthyl group, and each of these groups may have a substituent.

R_{c32} is preferably an unsubstituted alkyl group or a fluorine atom-substituted alkyl group.

The divalent linking group of Lₑ₃ is preferably an alkylene group (preferably having a carbon number of 1 to 5), an oxy group, a phenylene group or an ester bond (a group represented by —COO—).

It is also preferable that the hydrophobic resin (C) further contains a repeating unit represented by the following formula (CII-AB):

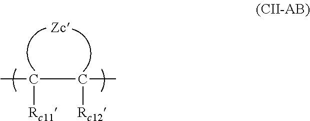

In formula (CII-AB), each of R_{c11}′ and R_{c12}′ independently represents a hydrogen atom, a cyano group, a halogen atom or an alkyl group.

Z_{c}′ represents an atomic group for forming an alicyclic structure containing two carbon atoms (C—C) to which Z_{c}′ is bonded.

In the case where each group in the repeating units represented by formulae (III) and (CII-AB) is substituted with a fluorine atom- or silicon atom-containing group, the repeating unit corresponds also to the repeating unit (c1).

Specific examples of the repeating units represented by formulae (III) and (CII-AB) are illustrated below, but the present invention is not limited thereto. In the formulae, Ra represents H, CH₃, CH₂OH, CF₃ or CN. Incidentally, the repeating unit where Ra is CF₃ corresponds also to the repeating unit (c1).

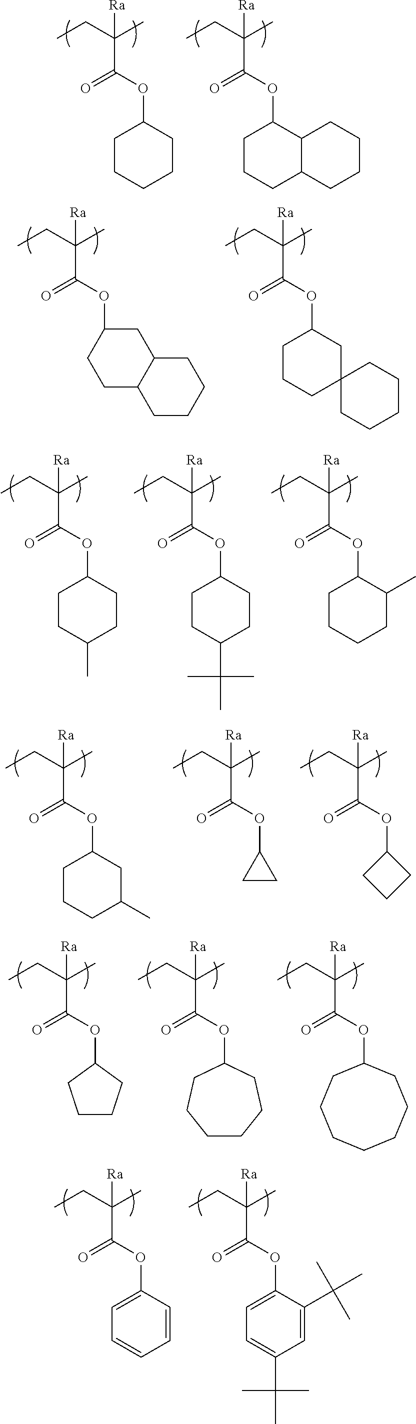

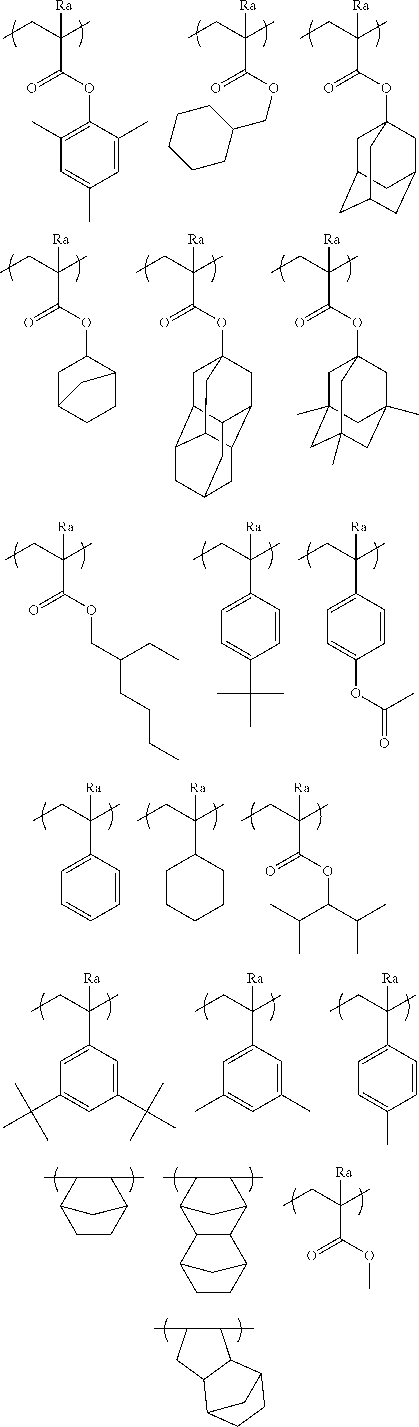

In the case where the hydrophobic resin (C) contains a fluorine atom, the fluorine atom content is preferably from 5 to 80 mass %, more preferably from 10 to 80 mass %, based on the weight average molecular weight of the hydrophobic resin (C). Also, the fluorine atom-containing repeating unit preferably accounts for 10 to 100 mol %, more preferably from 30 to 100 mol %, based on all repeating units contained in the hydrophobic resin (C).

In the case where the hydrophobic resin (C) contains a silicon atom, the silicon atom content is preferably from 2 to 50 mass %, more preferably from 2 to 30 mass %, based on the weight average molecular weight of the hydrophobic resin (C). Also, the silicon atom-containing repeating unit preferably accounts for 10 to 100 mol %, more preferably from 20 to 100 mol %, based on all repeating units contained in the hydrophobic resin (C).

The standard polystyrene-equivalent weight average molecular of the hydrophobic resin (C) is preferably from 1,000 to 100,000, more preferably from 1,000 to 50,000, still more preferably from 2,000 to 15,000.

As for the hydrophobic resin (C), one kind of a resin may be used, or a plurality of kinds of resins may be used in combination.

The content of the hydrophobic resin (C) in the composition is preferably from 0.01 to 10 mass %, more preferably from 0.05 to 8 mass %, still more preferably from 0.1 to 5 mass %, based on the entire solid content in the composition of the present invention.

In the hydrophobic resin (C), similarly to the resin (A), it is of course preferred that the content of impurities such as metal is small, but also, the content of residual monomers or oligomer components is preferably from 0.01 to 5 mass %, more preferably from 0.01 to 3 mass %, still more preferably from 0.05 to 1 mass %. When these conditions are satisfied, a resist composition free from extraneous substances in the liquid or change with aging of sensitivity or the like can be obtained. Furthermore, in view of resolution, resist profile, side wall of resist pattern, roughness and the like, the molecular weight distribution (Mw/Mn, sometimes referred to as “dispersity”) is preferably from 1 to 5, more preferably from 1 to 3, still more preferably from 1 to 2.

As for the hydrophobic resin (C), various commercially available products may be used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred.

The reaction solvent, the polymerization initiator, the reaction conditions (e.g., temperature, concentration) and the purification method after reaction are the same as those described for the resin (A), but in the synthesis of the hydrophobic resin (C), the concentration in reaction is preferably from 30 to 50 mass %.

Specific examples of the hydrophobic resin (C) are illustrated below. Also, the molar ratio of repeating units (corresponding to repeating units starting from the left), weight average molecular weight and dispersity of each resin are shown in Tables 1 and 2 later.

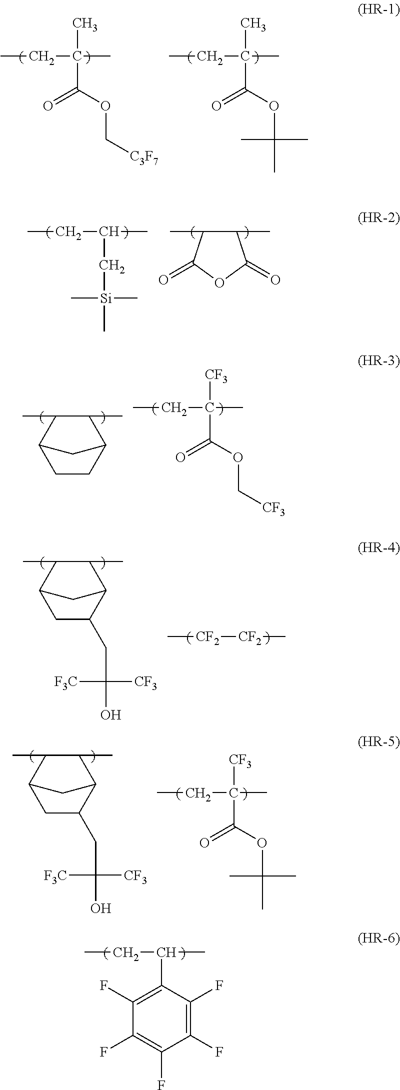

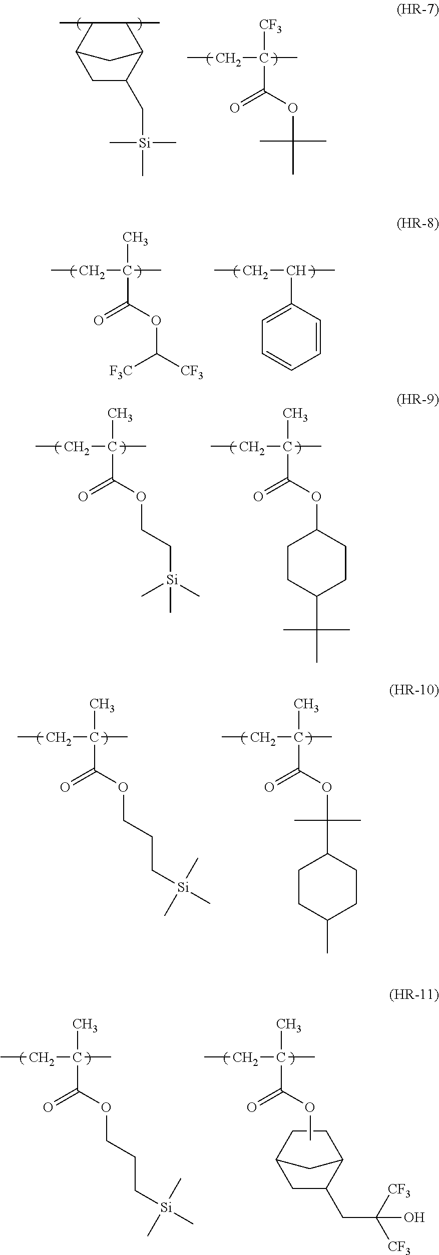

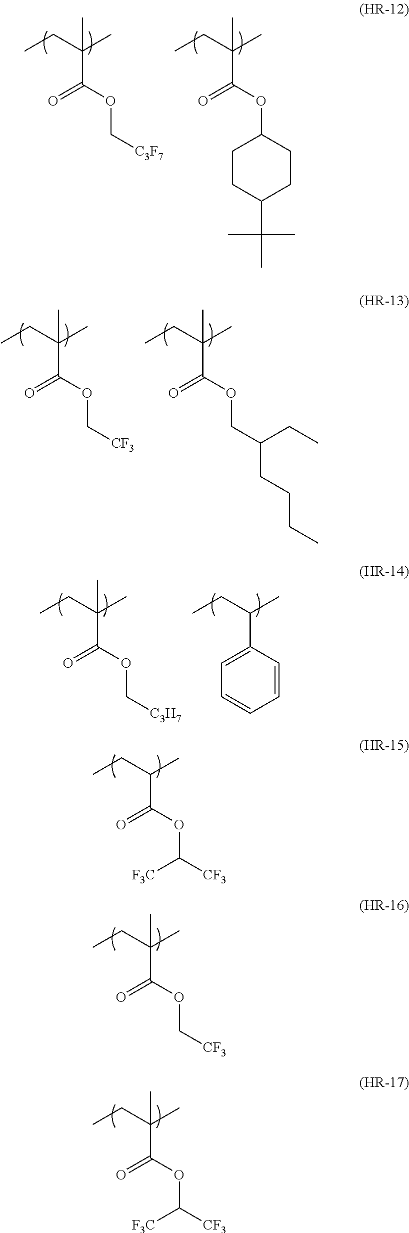

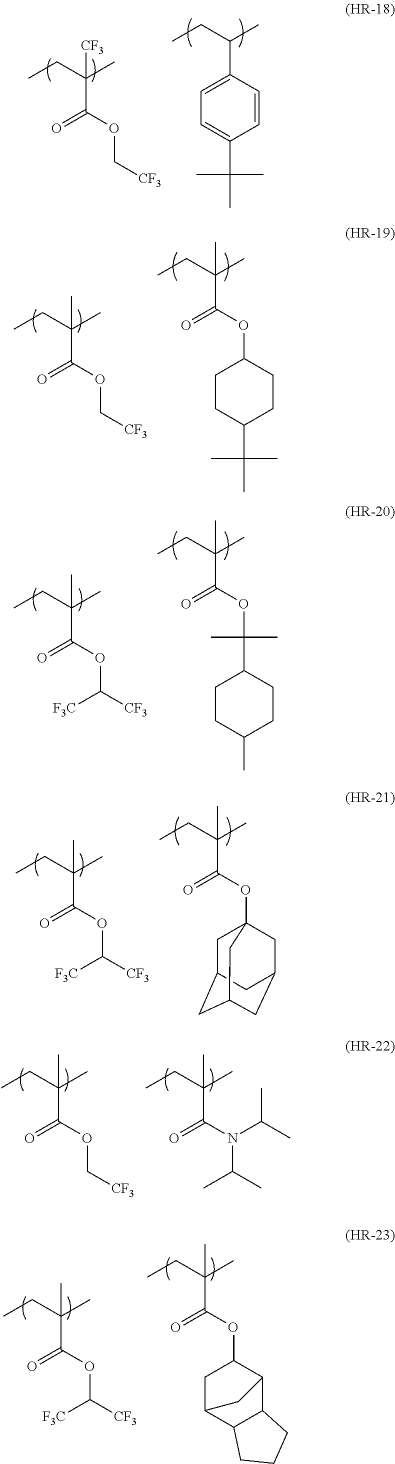

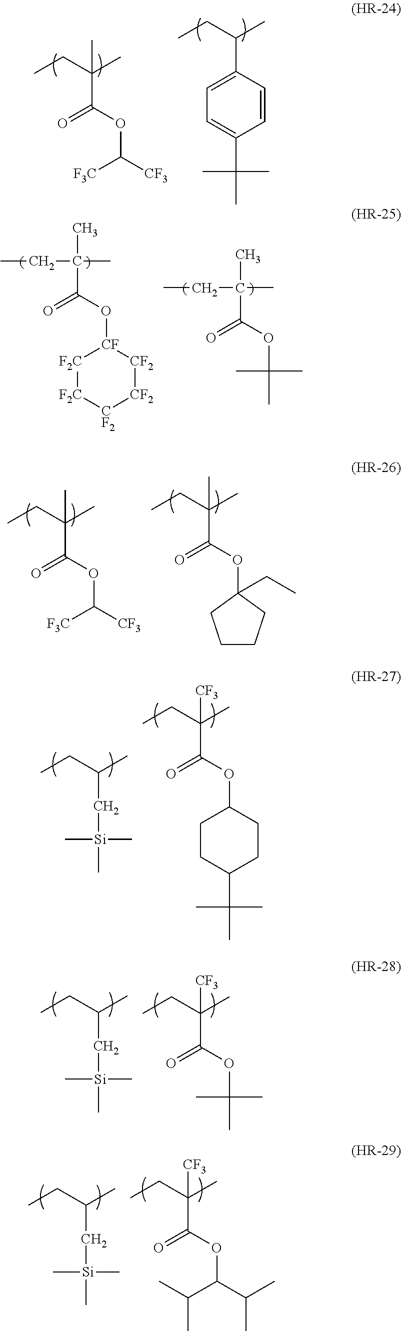

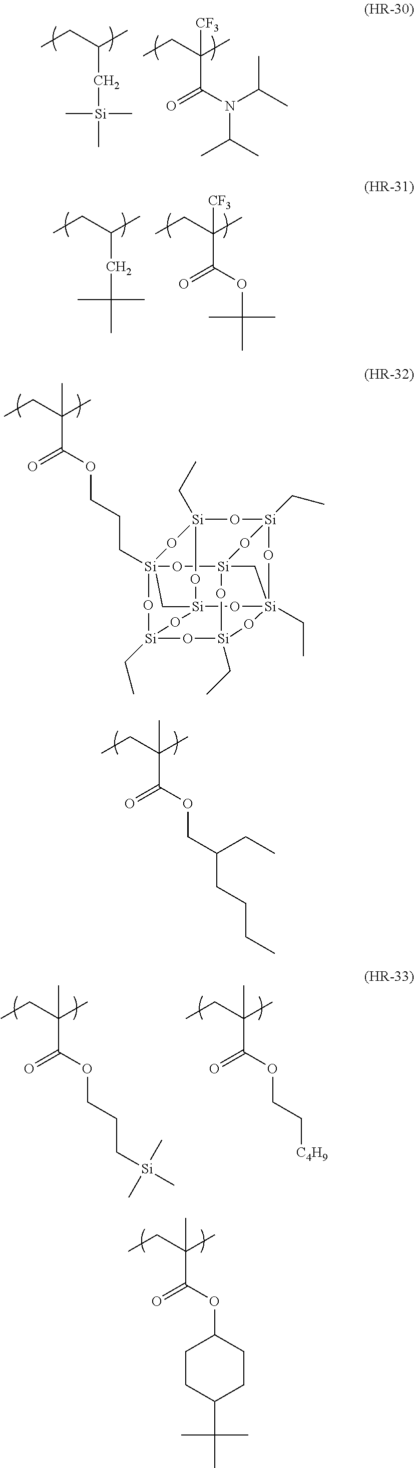

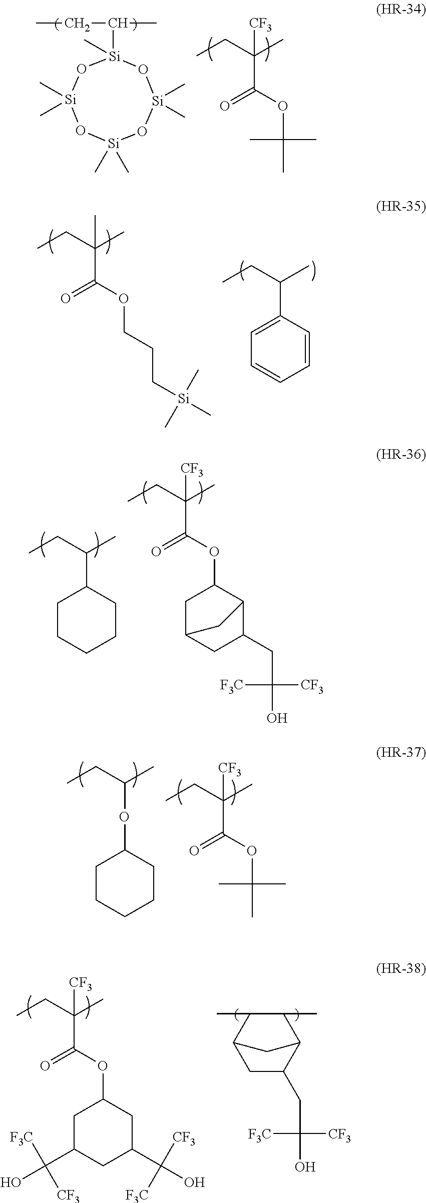

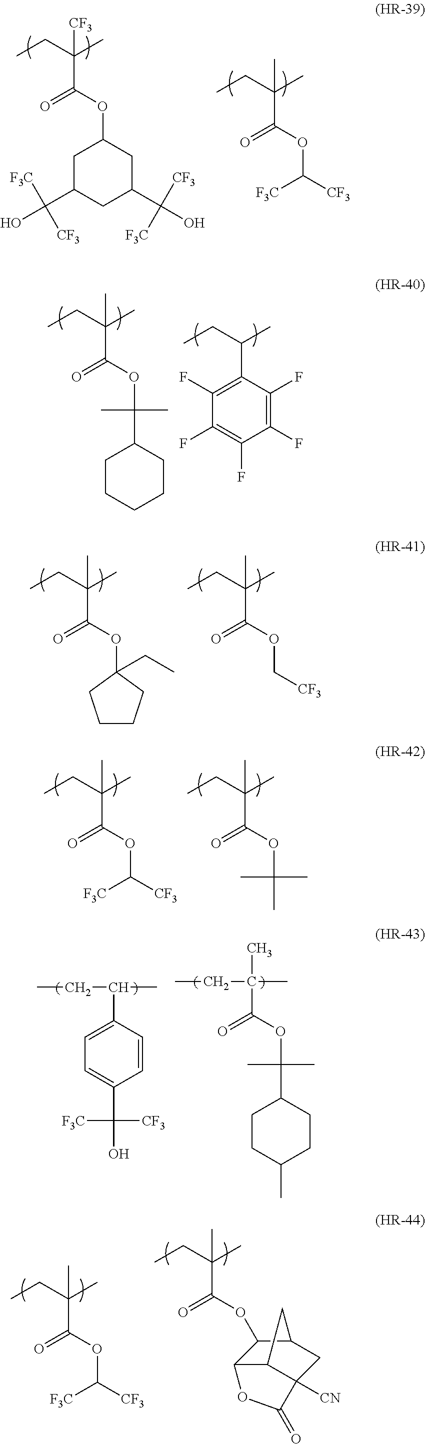

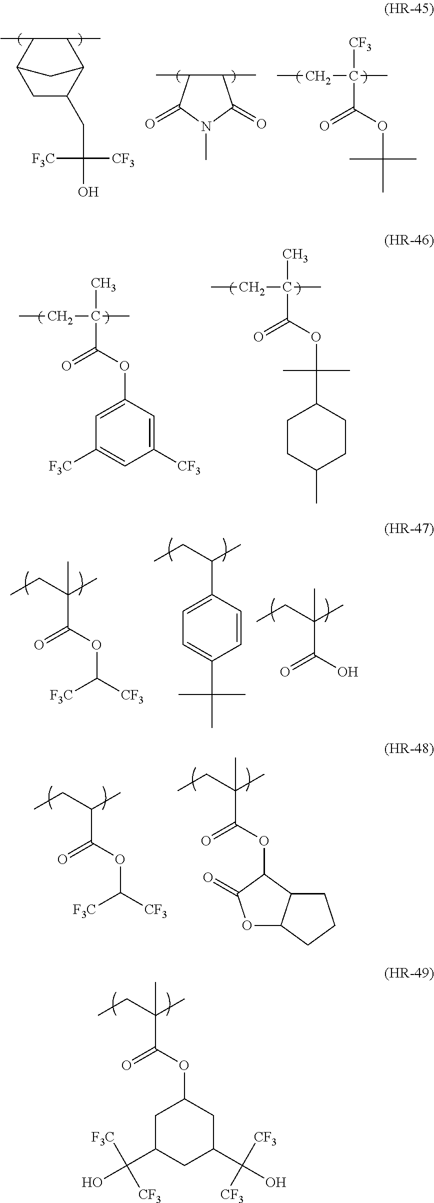

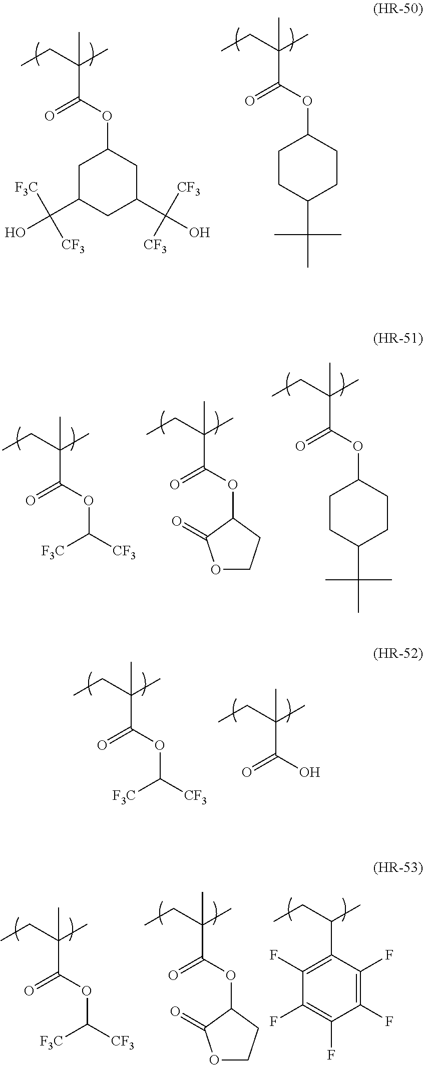

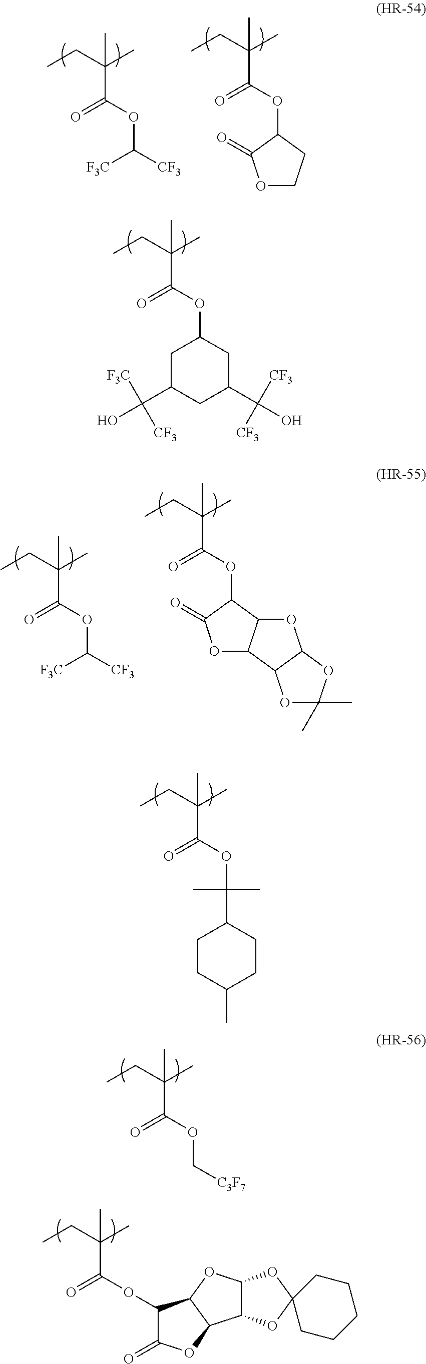

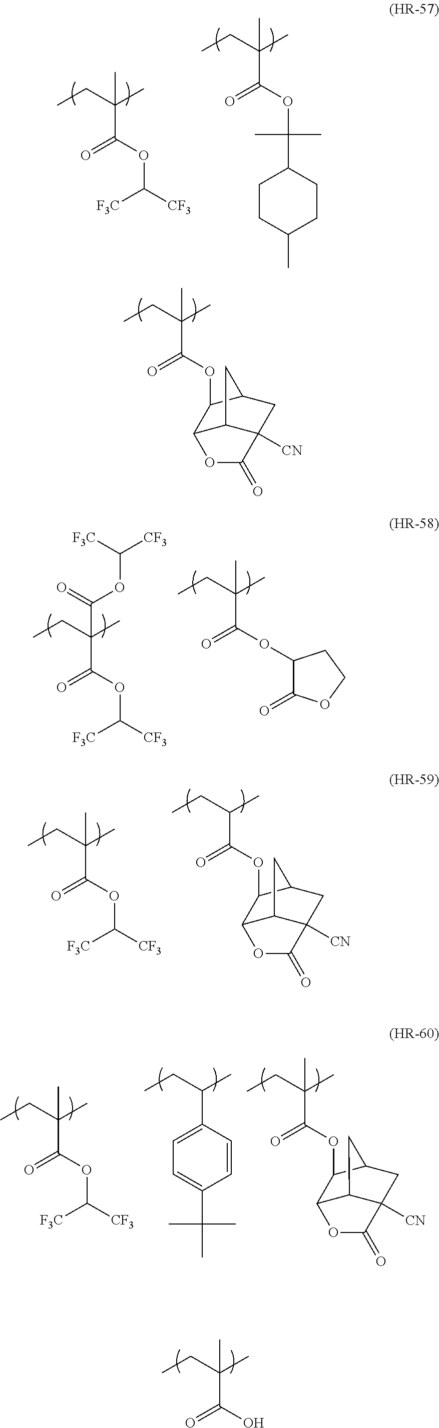

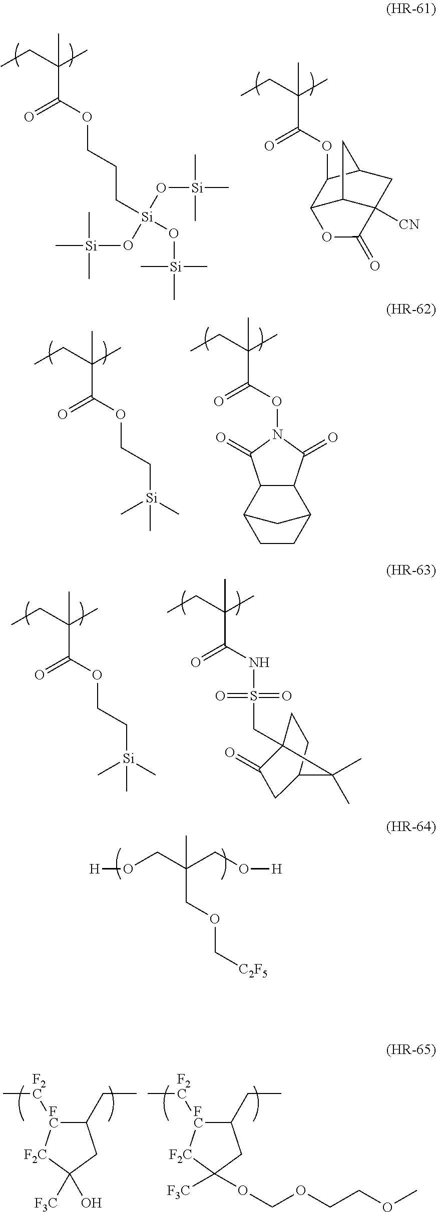

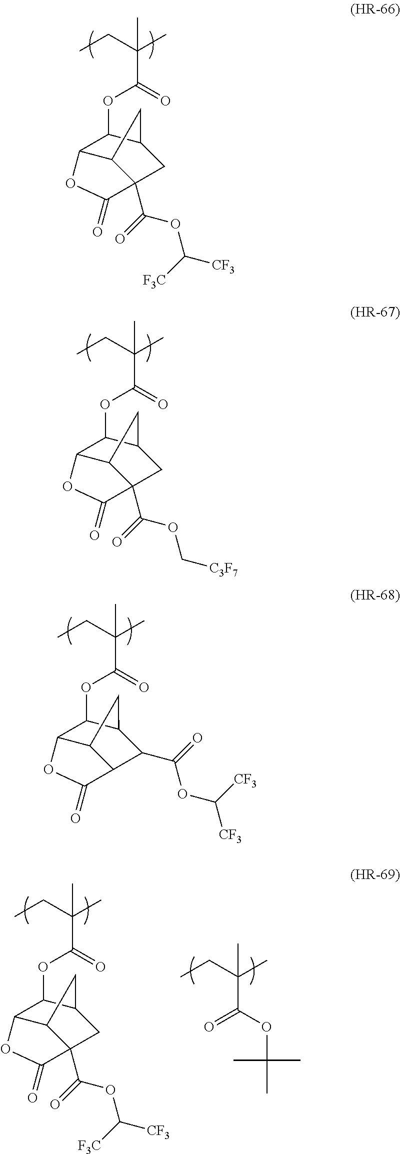

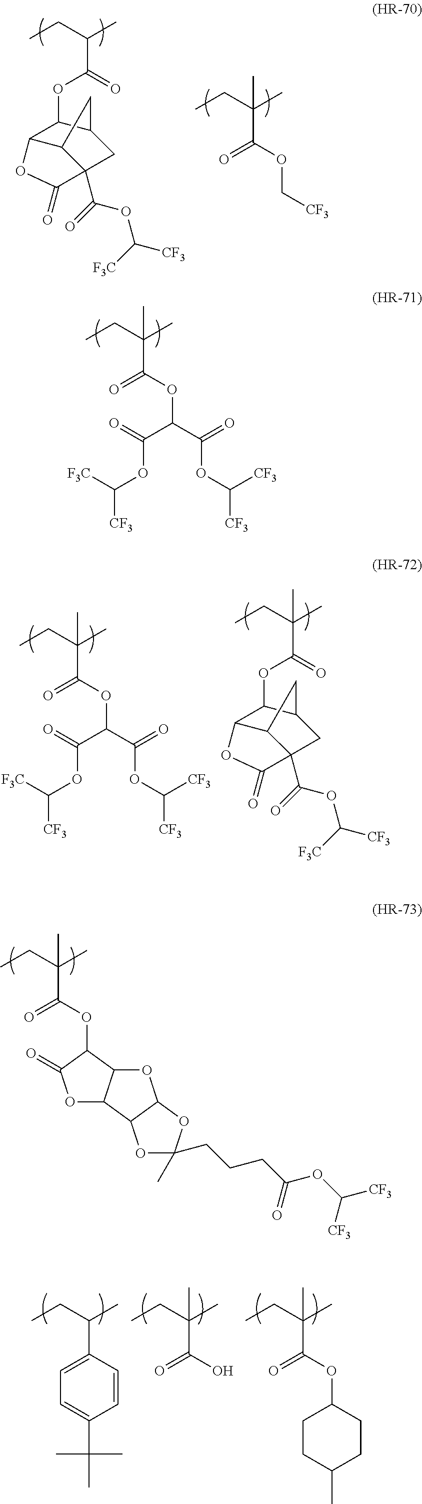

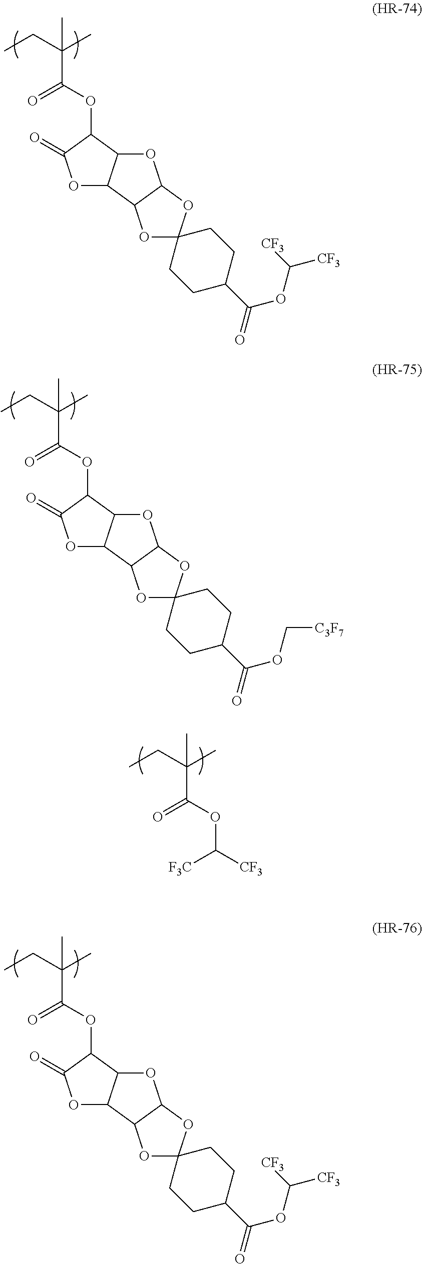

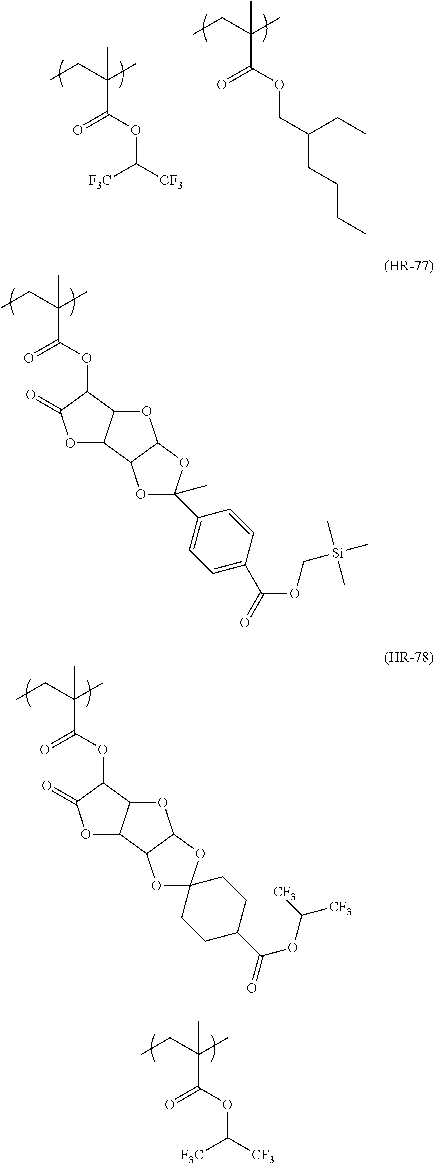

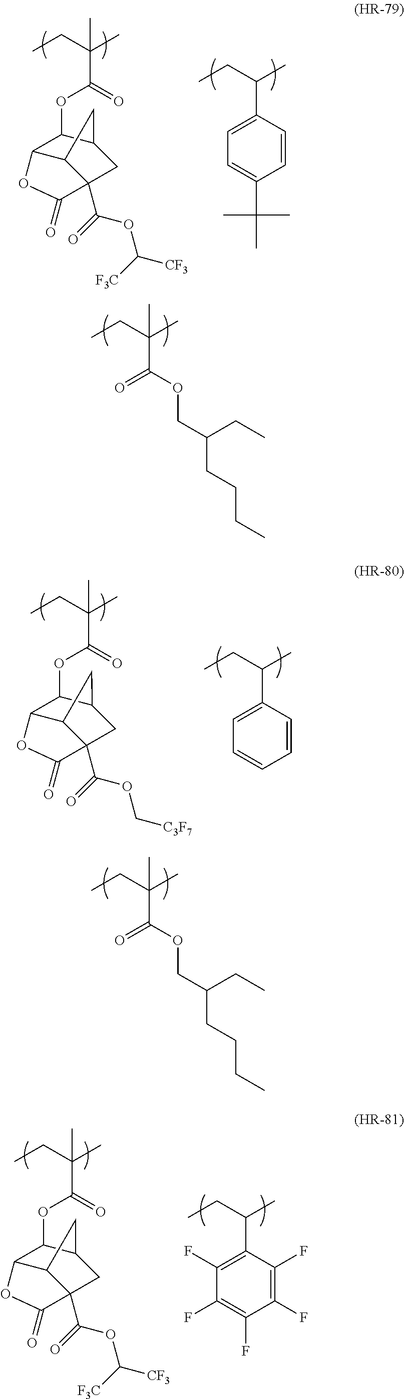

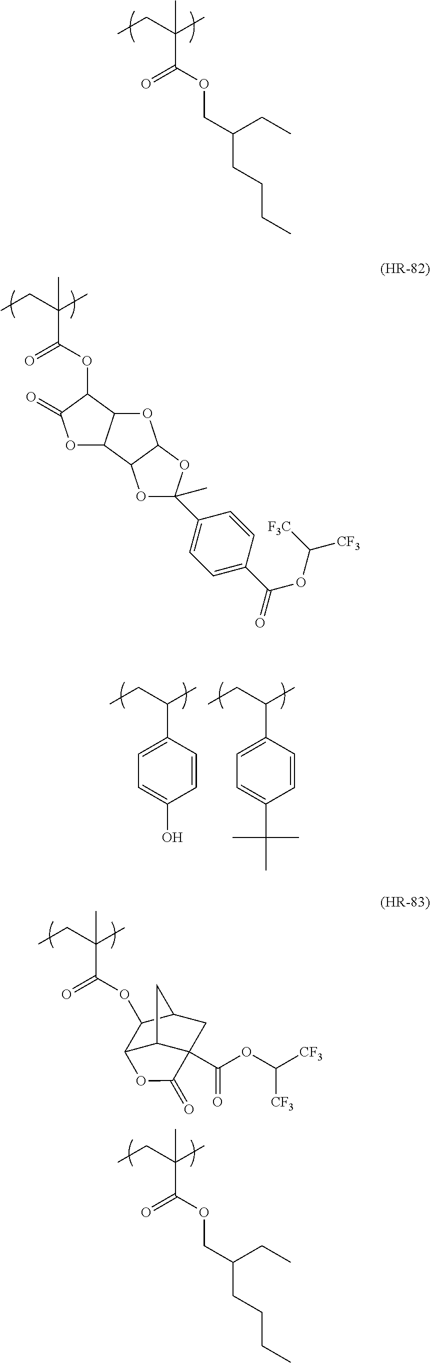

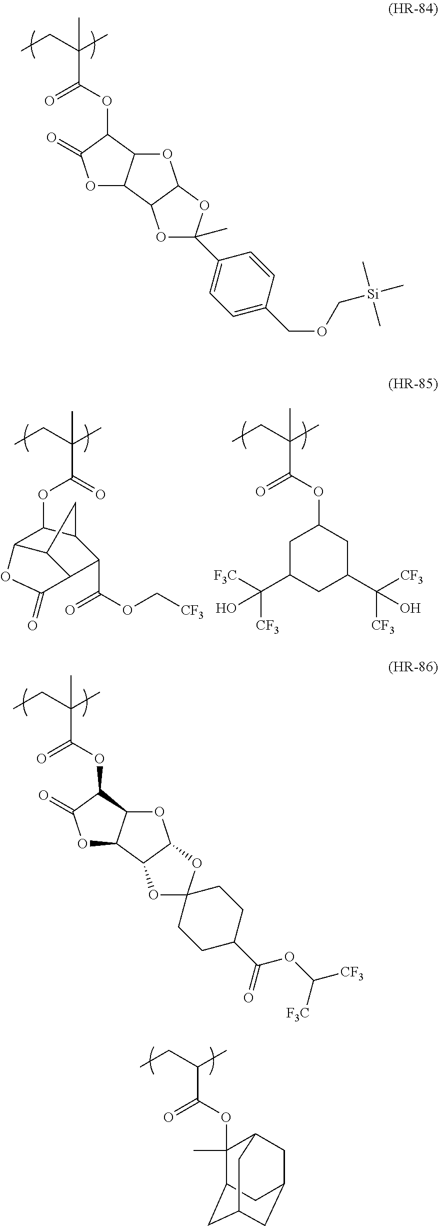

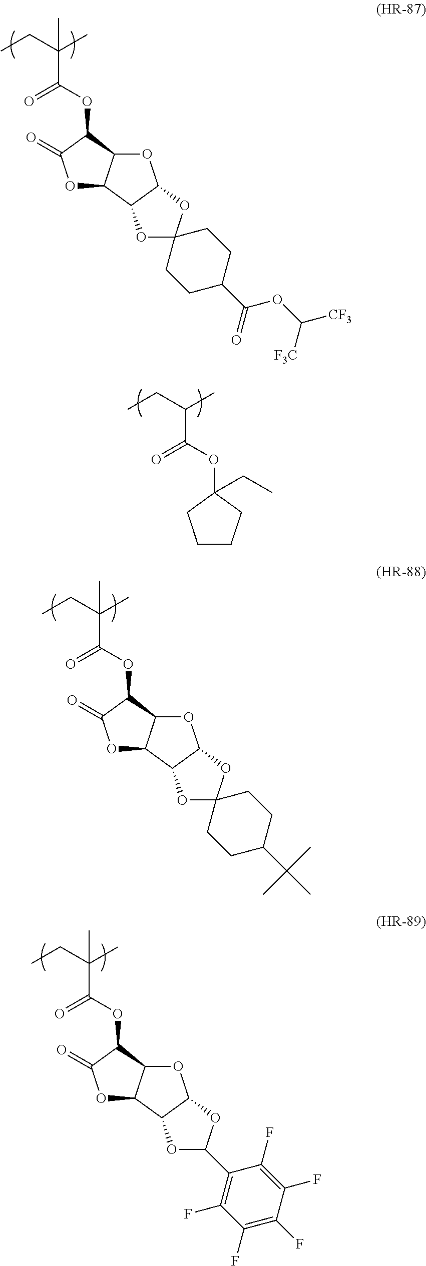

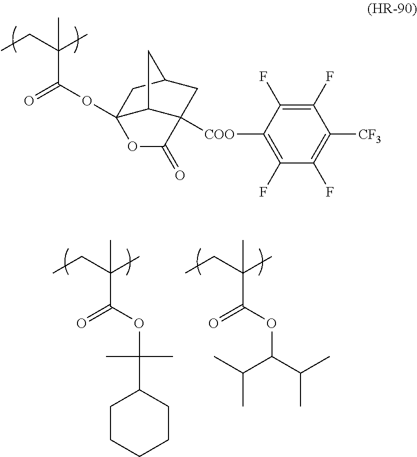

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 2

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |
| HR-81 | 80/18/2 | 6000 | 1.5 |
| HR-82 | 50/20/30 | 5000 | 1.3 |
| HR-83 | 90/10 | 8000 | 1.4 |
| HR-84 | 100 | 9000 | 1.6 |
| HR-85 | 80/20 | 15000 | 1.6 |
| HR-86 | 70/30 | 4000 | 1.42 |
| HR-87 | 60/40 | 8000 | 1.32 |
| HR-88 | 100 | 3800 | 1.29 |
| HR-89 | 100 | 6300 | 1.35 |
| HR-90 | 50/40/10 | 8500 | 1.51 |

### [4] Solvent

Examples of the solvent which can be used at the time of preparing the actinic ray-sensitive or radiation-sensitive resin composition by dissolving the above-described components include an organic solvent such as alkylene glycol, alkylene glycol monoalkyl ether carboxylate, alkylene glycol monoalkyl ether, alkyl lactate ester, alkyl alkoxypropionate, cyclic lactone (preferably having a carbon number of 4 to 10), monoketone compound (preferably having a carbon number of 4 to 10) which may contain a ring, alkylene carbonate, alkyl alkoxyacetate, alkyl pyruvate, alkyl acetate, amide-based solvent and dialkyl sulfoxide.

Preferred examples of the alkylene glycol include ethylene glycol and propylene glycol.

Preferred examples of the alkylene glycol monoalkyl ether carboxylate include propylene glycol monomethyl ether acetate (PGMEA, another name: 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate and ethylene glycol monoethyl ether acetate.

Preferred examples of the alkylene glycol monoalkyl ether include propylene glycol monomethyl ether (PGME, another name: 1-methoxy-2-propanol), propylene glycol monoethyl ether, propylene glycol monopropyl ether, propylene glycol monobutyl ether, ethylene glycol monomethyl ether and ethylene glycol monoethyl ether.

Preferred examples of the alkyl lactate ester include methyl lactate, ethyl lactate, propyl lactate and butyl lactate.

Preferred examples of the alkyl alkoxypropionate include ethyl 3-ethoxypropionate, methyl 3-methoxypropionate, methyl 3-ethoxypropionate and ethyl 3-methoxypropionate.

Preferred examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

Preferred examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

Preferred examples of the alkylene carbonate include propylene carbonate, vinylene carbonate, ethylene carbonate and butylene carbonate.

Preferred examples of the alkyl alkoxyacetate include 2-methoxyethyl acetate, 2-ethoxyethyl acetate, 2-(2-ethoxyethoxy)ethyl acetate, 3-methoxy-3-methylbutyl acetate and 1-methoxy-2-propyl acetate.

Preferred examples of the alkyl pyruvate include methyl pyruvate, ethyl pyruvate and propyl pyruvate.

Preferred examples of the alkyl acetate include ethyl acetate and butyl acetate.

Preferred examples of the amide-based solvent include N-methyl-2-pyrrolidone, N,N-dimethylacetamide, N,N-dimethylformamide, hexamethylphosphoric triamide and 1,3-dimethyl-2-imidazolidinone.

Preferred examples of the dialkyl sulfoxide include dimethyl sulfoxide and diethyl sulfoxide.

The solvent that can be preferably used includes a solvent having a boiling point of 130° C. or more under atmospheric pressure, and specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate and propylene carbonate.

In the present invention, one of these solvents may be used alone, or two or more kinds thereof may be used in combination.

In the present invention, a mixed solvent prepared by mixing a solvent containing a hydroxyl group in the structure and a solvent containing no hydroxyl group may be used as the organic solvent.

The solvent containing a hydroxyl group and the solvent containing no hydroxyl group may be appropriately selected from the compounds illustrate above, but the solvent containing a hydroxyl group is preferably an alkylene glycol, an alkylene glycol monoalkyl ether, an alkyl lactate or the like, and examples thereof include ethylene glycol, ethylene glycol monomethyl ether, ethylene glycol monoethyl ether, propylene glycol, propylene glycol monomethyl ether, propylene glycol monoethyl ether and ethyl acetate. Among these, propylene glycol monomethyl ether and ethyl lactate are preferred.

The solvent containing no hydroxyl group is preferably an alkylene glycol monoalkyl ether carboxylate, an alkyl alkoxypropionate, a monoketone compound that may contain a ring, a cyclic lactone, an alkyl acetate, an amide-based solvent, a dialkyl sulfoxide or the like, and examples thereof include propylene glycol monomethyl ether acetate, ethyl ethoxypropionate, 2-heptanone, γ-butyrolactone, cyclohexanone, butyl acetate, N-methylpyrrolidone, N,N-dimethylacetamide and dimethylsulfoxide. Among these, propylene glycol monomethyl ether acetate, ethyl ethoxypropionate, 2-heptanone, γ-butyrolactone, cyclohexanone and butyl acetate are preferred, and propylene glycol monomethyl ether acetate, ethyl ethoxypropionate and 2-heptanone are most preferred.

The mixing ratio (by mass) of the solvent containing a hydroxyl group to the solvent containing no hydroxyl group is from 1/99 to 99/1, preferably from 10/90 to 90/10, more preferably from 20/80 to 60/40. A mixed solvent in which the solvent containing no hydroxyl group is contained in a ratio of 50 mass % or more is particularly preferred in view of coating uniformity.

The solvent preferably contains propylene glycol monomethyl ether acetate and is preferably a single solvent of propylene glycol monomethyl ether acetate or a mixed solvent of two or more kinds of solvents containing propylene glycol monomethyl ether acetate.

### [5] Basic Compound

The actinic ray-sensitive or radiation-sensitive resin composition of the present invention preferably contains a basic compound so as to reduce the change in performance with aging from exposure to heating.

Preferred basic compounds include a basic compound having a structure represented by the following formulae (A) to (E):

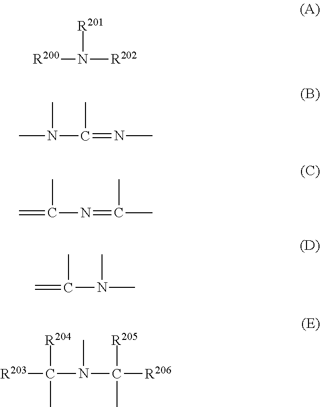

In formulae (A) to (E), each of R²⁰⁰, R²⁰¹ and R²⁰², which may be the same or different, represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine together to form a ring.

Each of R²⁰³, R²⁰⁴, R²⁰⁵ and R²⁰⁶, which may be the same or different, represents an alkyl group having a carbon number of 1 to 20.

As for the alkyl group, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

The alkyl group in formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, benzimidazole and 2-phenylbenzimidazole. Examples of the compound having a diazabicyclo structure include 1,4-diazabicyclo[2,2,2]octane, 1,5-diazabicyclo[4,3,0]non-5-ene and 1,8-diazabicyclo[5,4,0]undeca-7-ene. Examples of the compound having an onium hydroxide structure include a tetrabutylammonium hydroxide, a triarylsulfonium hydroxide, a phenacylsulfonium hydroxide and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure becomes a carboxylate, and examples thereof include an acetate, an adamantane-1-carboxylate and a perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline and N,N-dihexylaniline. Examples of the alkylamine derivative having a hydroxyl group and/or an ether bond include ethanolamine, diethanolamine, triethanolamine, N-phenyldiethanolamine and tris(methoxyethoxyethyl)amine. Examples of the aniline derivative having a hydroxyl group and/or an ether bond include N,N-bis(hydroxyethyl)aniline.

Other preferred basic compounds include a phenoxy group-containing amine compound, a phenoxy group-containing ammonium salt compound, a sulfonic acid ester group-containing amine compound and a sulfonic acid ester group-containing ammonium salt compound.

As for the amine compound, a primary, secondary or tertiary amine compound can be used, and an amine compound where at least one alkyl group is bonded to the nitrogen atom is preferred. The amine compound is more preferably a tertiary amine compound. In the amine compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom in addition to the alkyl group. The amine compound preferably has an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

As for the ammonium salt compound, a primary, secondary, tertiary or quaternary ammonium salt compound can be used, and an ammonium salt compound where at least one alkyl group is bonded to the nitrogen atom is preferred. In the ammonium salt compound, as long as at least one alkyl group (preferably having a carbon number of 1 to 20) is bonded to the nitrogen atom, a cycloalkyl group (preferably having a carbon number of 3 to 20) or an aryl group (preferably having a carbon number of 6 to 12) may be bonded to the nitrogen atom in addition to the alkyl group. The ammonium salt compound preferably has an oxygen atom in the alkyl chain to form an oxyalkylene group. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

Examples of the anion of the ammonium salt compound include a halogen atom, a sulfonate, a borate and a phosphate, with a halogen atom and a sulfonate being preferred. The halogen atom is preferably chloride, bromide or iodide, and the sulfonate is preferably an organic sulfonate having a carbon number of 1 to 20. Examples of the organic sulfonate include an alkylsulfonate having a carbon number of 1 to 20 and an arylsulfonate. The alkyl group of the alkylsulfonate may have a substituent, and examples of the substituent include fluorine, chlorine, bromine, an alkoxy group, an acyl group and an aryl group. Specific examples of the alkylsulfonate include methanesulfonate, ethanesulfonate, butanesulfonate, hexanesulfonate, octane sulfonate, benzylsulfonate, trifluoromethanesulfonate, pentafluoroethanesulfonate and nonafluorobutanesulfonate. The aryl group of the arylsulfonate includes a benzene ring, a naphthalene ring and an anthracene ring. The benzene ring, naphthalene ring and anthracene ring may have a substituent, and the substituent is preferably a linear or branched alkyl group having a carbon number of 1 to 6, or a cycloalkyl group having a carbon number of 3 to 6. Specific examples of the linear or branched alkyl group and cycloalkyl group include methyl, ethyl, n-propyl, isopropyl, n-butyl, i-butyl, tert-butyl, n-hexyl and cyclohexyl. Other examples of the substituent include an alkoxy group having a carbon number of 1 to 6, a halogen atom, cyano, nitro, an acyl group and an acyloxy group.

The phenoxy group-containing amine compound and the phenoxy group-containing ammonium salt compound are an amine compound or ammonium salt compound having a phenoxy group at the terminal opposite the nitrogen atom of the alkyl group. The phenoxy group may have a substituent. Examples of the substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group and an aryloxy group. The substitution site of the substituent may be any of 2- to 6-positions, and the number of substituents may be any in the range of 1 to 5.

The compound preferably has at least one oxyalkylene group between the phenoxy group and the nitrogen atom. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The sulfonic acid ester group in the amine compound having a sulfonic acid ester group and the ammonium salt compound having a sulfonic acid ester group may be any of an alkylsulfonic acid ester, a cycloalkylsulfonic acid ester and an arylsulfonic acid ester. In the case of an alkylsulfonic acid ester, an alkyl group having a carbon number of 1 to 20 is preferred; in the case of a cycloalkylsulfonic acid ester, a cycloalkyl group having a carbon number of 3 to 20 is preferred; and in the case of an arylsulfonic acid ester, an aryl group having a carbon number of 6 to 12 is preferred. The alkylsulfonic acid ester, cycloalkylsulfonic acid ester and arylsulfonic acid ester may have a substituent, and the substituent is preferably a halogen atom, a cyano group, a nitro group, a carboxyl group, a carboxylic acid ester group or a sulfonic acid ester group.

The compound preferably has at least one oxyalkylene group between the sulfonic acid ester group and the nitrogen atom. The number of oxyalkylene groups within the molecule is 1 or more, preferably from 3 to 9, more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The compounds shown below are also preferred as the basic compound.

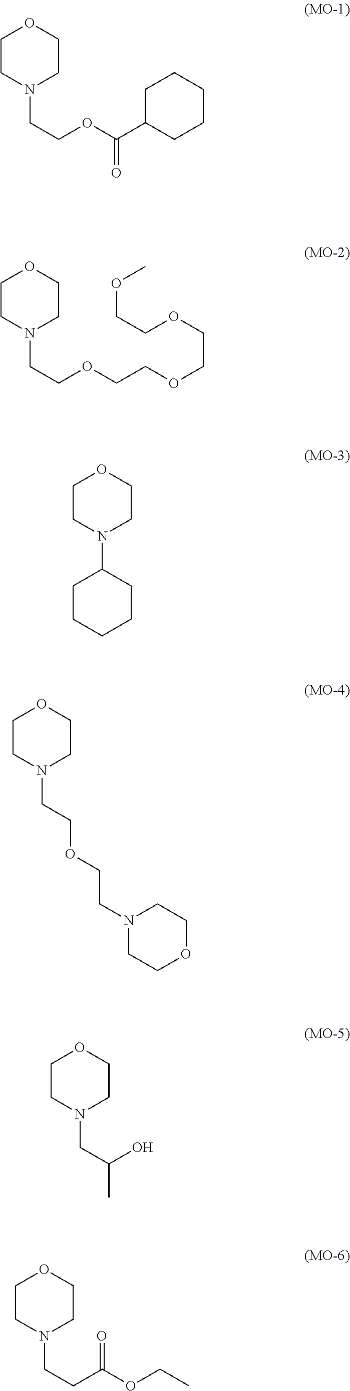

One of these basic compounds is used alone, or two or more thereof are used in combination.

The composition of the present invention may or may not contain a basic compound, but in the case of containing a basic compound, the amount thereof is usually from 0.001 to 10 mass %, preferably from 0.01 to 5 mass %, based on the solid content of the actinic ray-sensitive or radiation-sensitive resin composition.

The ratio between the acid generator and the basic compound used in the composition is preferably acid generator/basic compound (by mol)=from 2.5 to 300. That is, the molar ratio is preferably 2.5 or more in view of sensitivity and resolution and preferably 300 or less from the standpoint of suppressing the reduction in resolution due to thickening of the resist pattern with aging after exposure until heat treatment. The acid generator/basic compound (by mol) is more preferably from 5.0 to 200, still more preferably from 7.0 to 150.

Such a basic compound is preferably used, based on (D) a low molecular compound having a group capable of leaving by the action of an acid, in a molar ratio of (D) a low molecular compound having a group capable of leaving by the action of an acid/a basic compound=from 100/0 to 10/90, more preferably (D) a low molecular compound having a group capable of leaving by the action of an acid/a basic compound=from 100/0 to 30/70, still more preferably (D) a low molecular compound having a group capable of leaving by the action of an acid/a basic compound=from 100/0 to 50/50.

Incidentally, the basic compound as used herein does not include (D) a low molecular compound having a group capable of leaving by the action of an acid when this is also a basic compound.

### [6] (D) Low Molecular Compound Having a Group Capable of Leaving by the Action of an Acid

The composition of the present invention may contain (D) a low molecular compound having a group capable of leaving by the action of an acid (hereinafter, sometimes referred to as a “low molecular compound (D)” or “compound (D)”). The group capable of leaving by the action of an acid is not particularly limited but is preferably an acetal group, a carbonate group, a carbamate group, a tertiary ester group, a tertiary hydroxyl group or a hemiaminal ether group, more preferably a carbamate group or a hemiaminal ether group.

The molecular weight of the low molecular compound having a group capable of leaving by the action of an acid is preferably from 100 to 1,000, more preferably from 100 to 700, still more preferably from 100 to 500.

The low molecular compound (D) is preferably an amine derivative having on the nitrogen atom a group capable of leaving by the action of an acid.

The low molecular compound (D) may have a protective group-containing carbamate group on the nitrogen atom. The protective group constituting the carbamate group can be represented by the following formula (d-1):

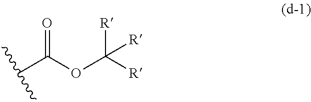

In formula (d-1), each R′ independently represents a hydrogen atom, a linear or branched alkyl group, a cycloalkyl group, an aryl group, an aralkyl group or an alkoxyalkyl group. Two R's may combine with every other to form a ring.

R′ is preferably a linear or branched alkyl group, a cycloalkyl group or an aryl group, more preferably a linear or branched alkyl group or a cycloalkyl group.

Specific structures of the group represented by formula (d-1) are illustrated below.

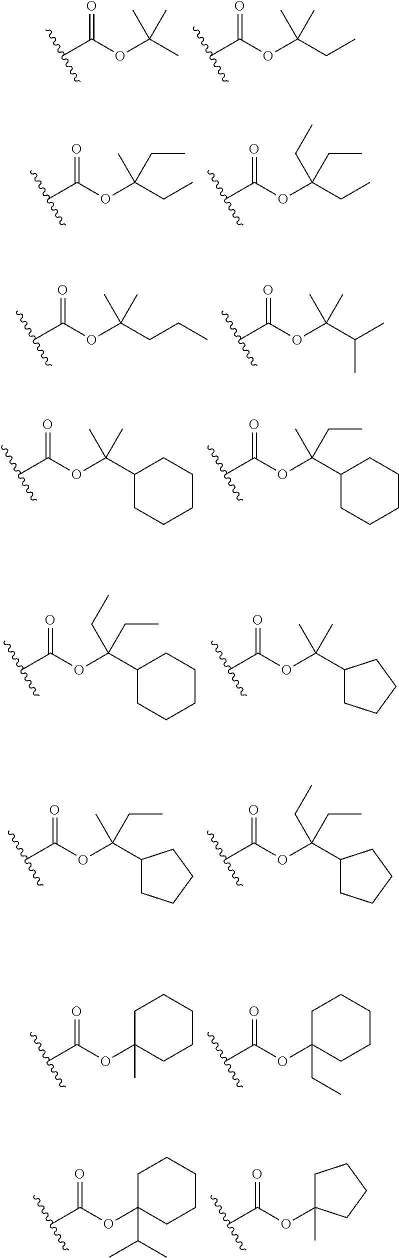

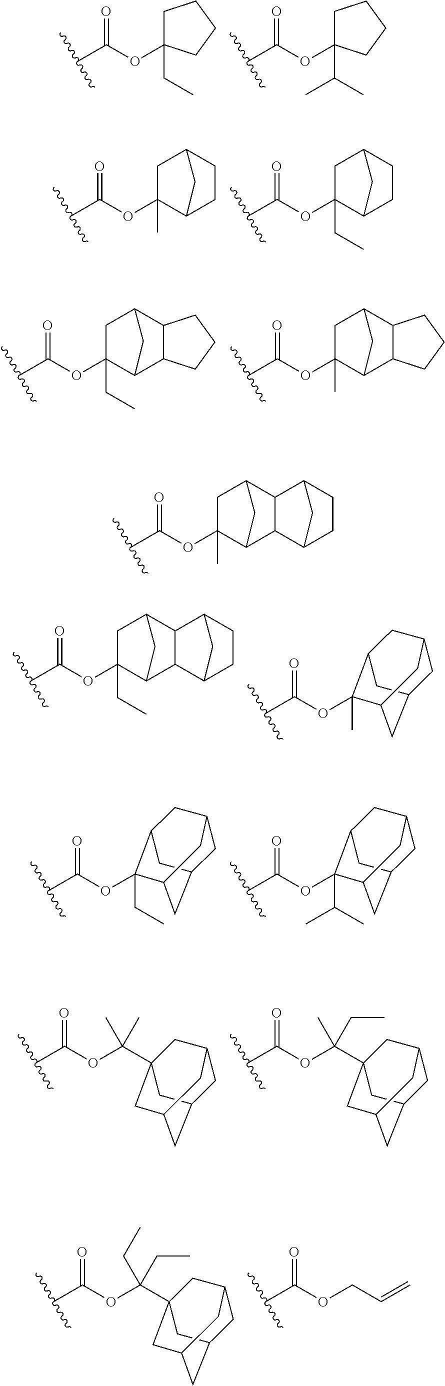

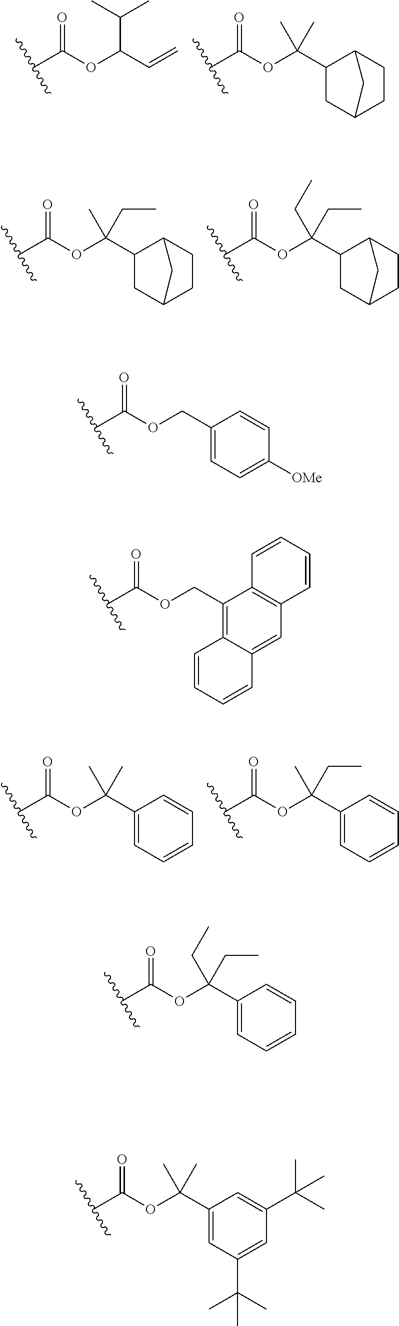

The low molecular compound (D) may also be composed by arbitrarily combining the above-described basic compound and the structure represented by formula (d-1).

The low molecular compound (D) is more preferably a compound having a structure represented by the following formula (A).

Incidentally, the low molecular compound (D) may be a compound corresponding to the above-described basic compound as long as it is a low molecular compound having a group capable of leaving by the action of an acid.

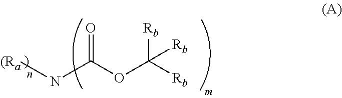

In formula (A), each Ra independently represents a hydrogen atom, an alkyl group, a cycloalkyl group, an aryl group or an aralkyl group. Also, when n=2, two Ra's may be the same or different, and two Ra's may combine with each other to form a heterocyclic hydrocarbon group (preferably having a carbon number of 20 or less) or a derivative thereof.

Each Rb independently represents a hydrogen atom, an alkyl group, a cycloalkyl group, an aryl group or an aralkyl group.

Two Rb's may combine to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In formula (A), each of the alkyl group, cycloalkyl group, aryl group and aralkyl group of Ra and Rb may be substituted with a functional group such as hydroxyl group, cyano group, amino group, pyrrolidino group, piperidino group, morpholino group and oxo group, an alkoxy group or a halogen atom.

Examples of the alkyl group, cycloalkyl group, aryl group and aralkyl group (each of these alkyl group, cycloalkyl group, aryl group and aralkyl group may be substituted with the above-described functional group, an alkoxy group or a halogen atom) of Ra and Rb include:

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more groups of cycloalkyl group such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydrofuran, tetrahydropyran, indole, indoline, quinoline, perhydroquinoline, indazole and benzimidazole, or a group where the group derived from a heterocyclic compound is substituted with one or more kinds of or one or more groups of linear or branched alkyl group or aromatic compound-derived group; a group where the group derived from a linear or branched alkane or the group derived from a cycloalkane is substituted with one or more kinds of or one or more groups of aromatic compound-derived group such as phenyl group, naphthyl group and anthracenyl group; and a group where the substituent above is substituted with a functional group such as hydroxyl group, cyano group, amino group, pyrrolidino group, piperidino group, morpholino group and oxo group.

Examples of the divalent heterocyclic hydrocarbon group (preferably having a carbon number of 1 to 20) formed by combining Ra's with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more groups of linear or branched alkane-derived group, cycloalkane-derived group, aromatic compound-derived group, heterocyclic compound-derived group, and functional group such as hydroxyl group, cyano group, amino group, pyrrolidino group, piperidino group, morpholino group and oxo group.

Specific examples particularly preferred in the present invention include N-tert-butoxycarbonyldi-n-octylamine, N-tert-butoxycarbonyldi-n-nonylamine, N-tert-butoxycarbonyldi-n-decylamine, N-tert-butoxycarbonyldicyclohexylamine, N-tert-butoxycarbonyl-1-adamantylamine, N-tert-butoxycarbonyl-2-adamantylamine, N-tert-butoxycarbonyl-N-methyl-1-adamantylamine, (S)-(−)-1-(tert-butoxycarbonyl)-2-pyrrolidinemethanol, (R)-(+)-1-(tert-butoxycarbonyl)-2-pyrrolidinemethanol, N-tert-butoxycarbonyl-4-hydroxypiperidine, N-tert-butoxycarbonylpyrrolidine, N-tert-butoxycarbonylmorpholine, N-tert-butoxycarbonylpiperazine, N,N-di-tert-butoxycarbonyl-1-adamantylamine, N,N-di-tert-butoxycarbonyl-N-methyl-1-adamantylamine, N-tert-butoxycarbonyl-4,4′-diaminodiphenylmethane, N,N′-di-tert-butoxycarbonylhexamethylenediamine, N,N,N′,N′-tetra-tert-butoxycarbonylhexamethylenediamine, N,N′-di-tert-butoxycarbonyl-1,7-diaminoheptane, N,N′-di-tert-butoxycarbonyl-1,8-diaminooctane, N,N′-di-tert-butoxycarbonyl-1,9-diaminononane, N,N-di-tert-butoxycarbonyl-1,10-diaminodecane, N,N′-di-tert-butoxycarbonyl-1,12-diaminododecane, N,N′-di-tert-butoxycarbonyl-4,4′-diaminodiphenylmethane, N-tert-butoxycarbonylbenzimidazole, N-tert-butoxycarbonyl-2-methylbenzimidazole and N-tert-butoxycarbonyl-2-phenylbenzimidazole.

Specific examples of the low molecular compound (D) particularly preferred in the present invention are illustrated below, but the present invention is not limited thereto.

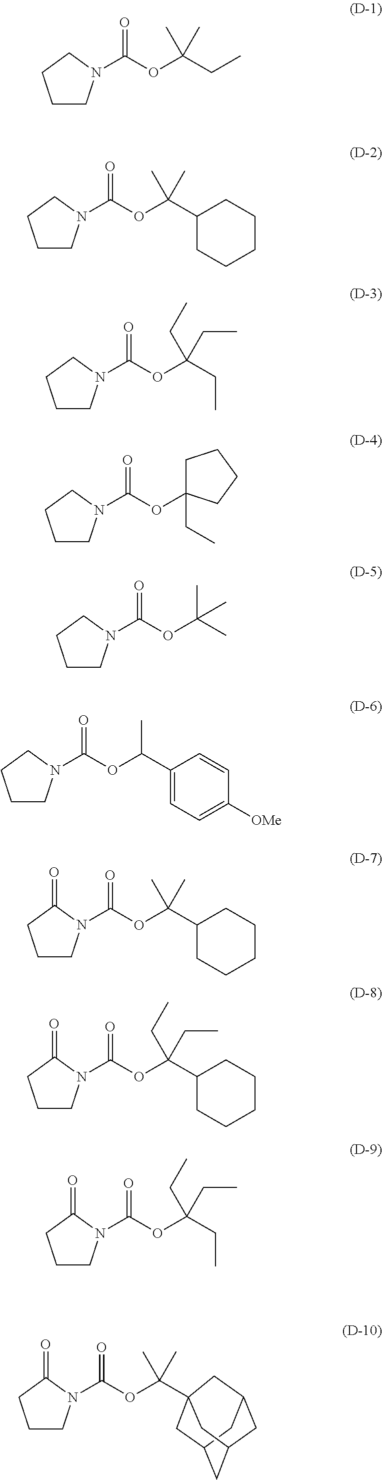

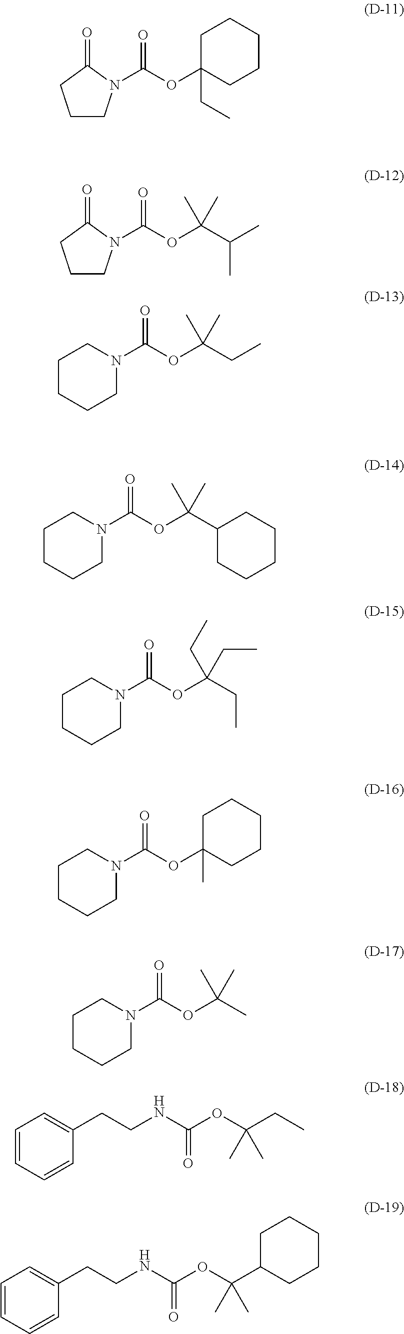

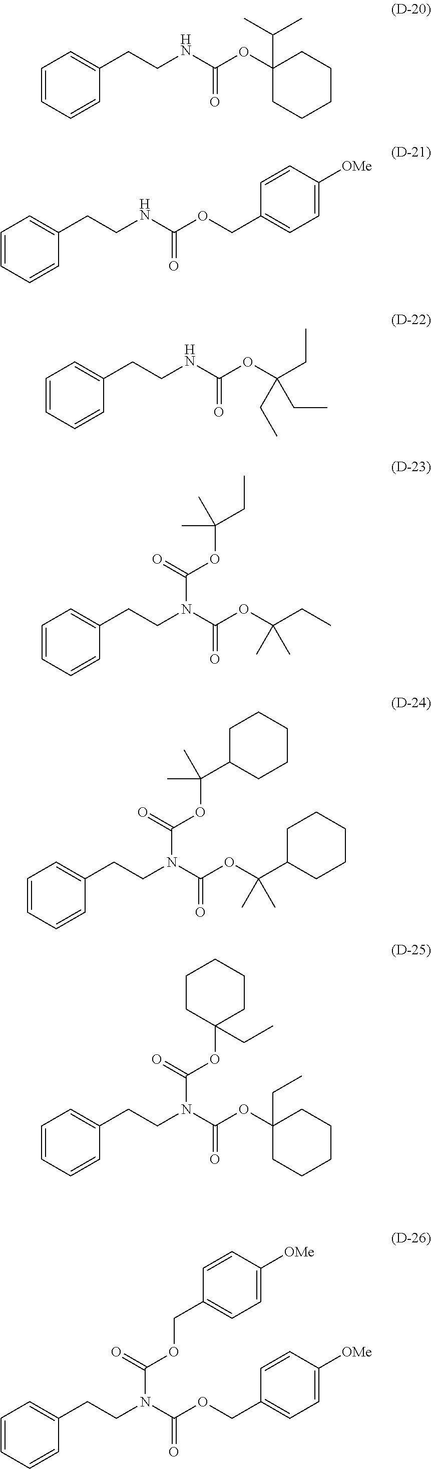

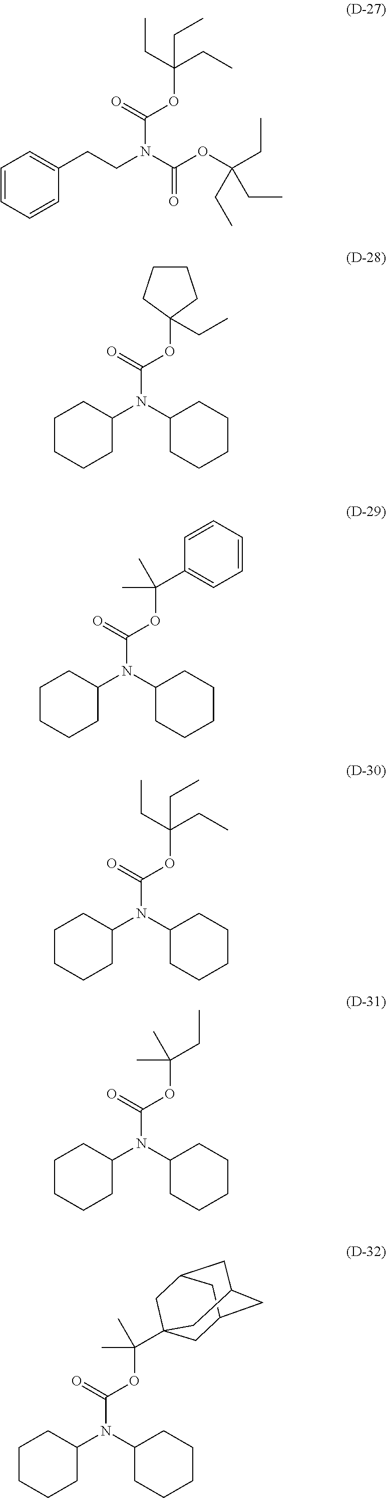

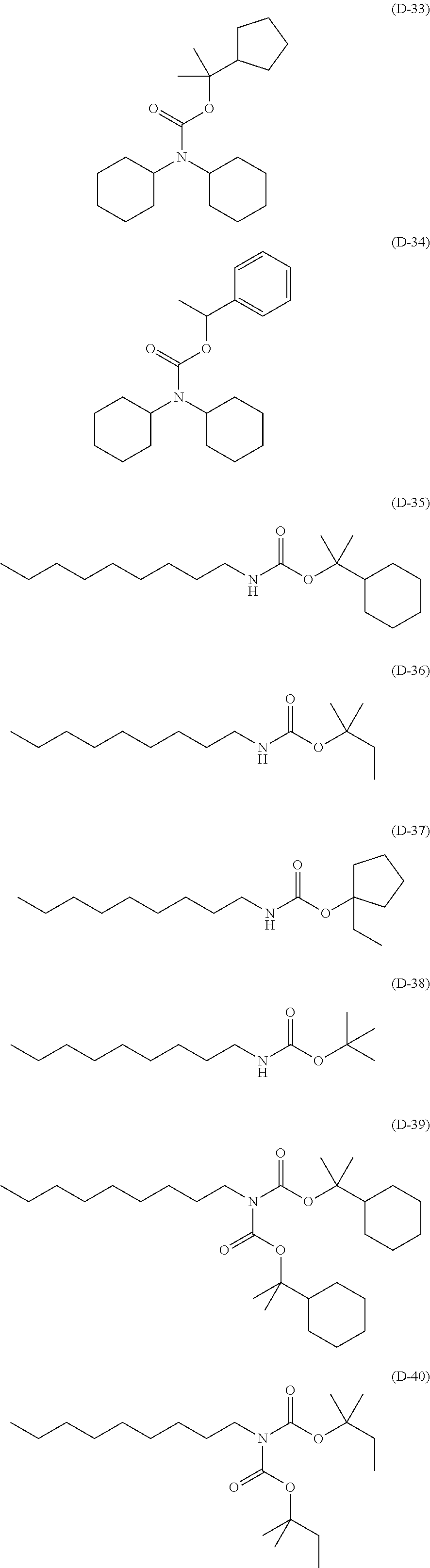

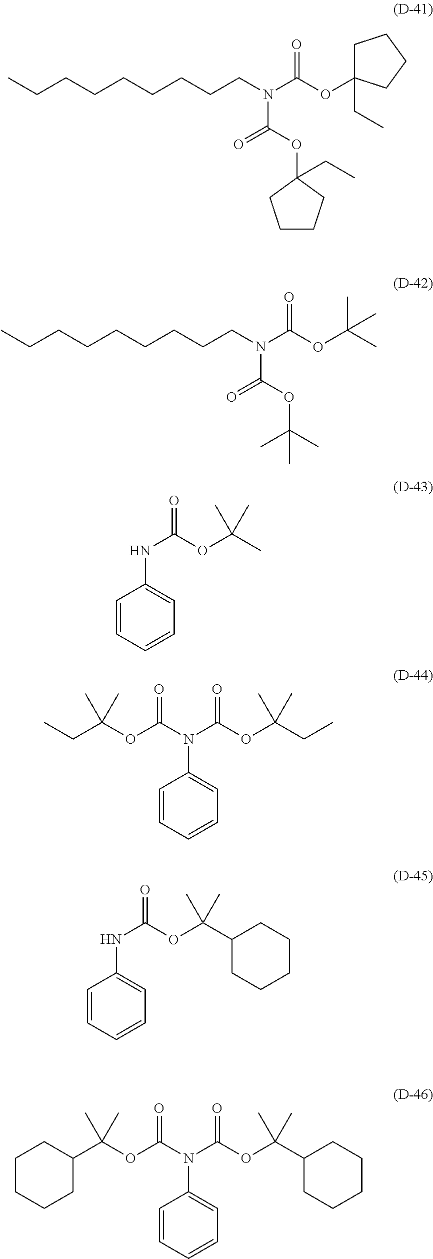

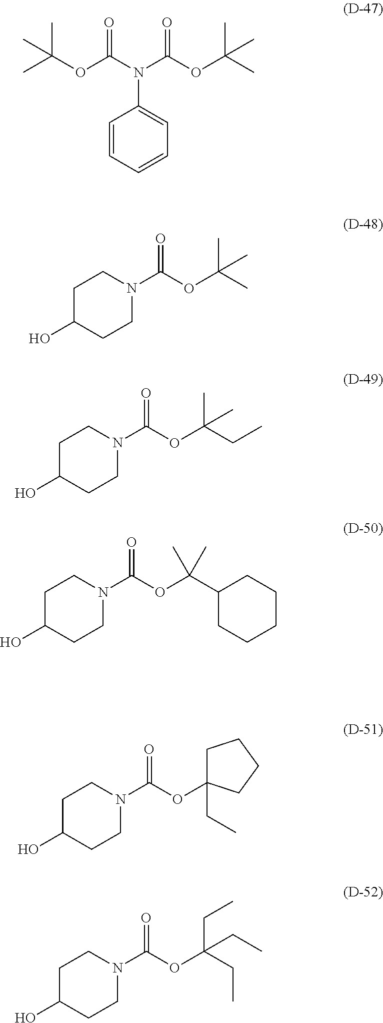

The compound represented by formula (A) can be easily synthesized from a commercially available amine by the method described, for example, in Protective Groups in Organic Synthesis, 4th edition. A most general method is a method of causing a dicarbonic acid ester or a haloformic acid ester to act on a commercially available amine to obtain the compound. In the following formulae, X represents a halogen atom, and Ra and Rb have the same meanings as Ra and Rb in formula (A).

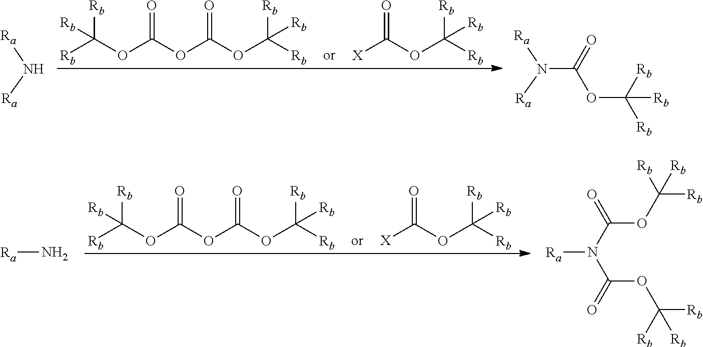

In the present invention, as for the (D) low molecular compound having a group capable of leaving by the action of an acid, one kind of a compound may be used alone, or two or more kinds of compounds may be mixed and used.

The composition of the present invention may or may not contain (D) a low molecular compound having a group capable of leaving by the action of an acid, but in the case of containing the low molecular compound (D), the content thereof is usually from 0.001 to 20 mass %, preferably from 0.001 to 10 mass %, more preferably from 0.01 to 5 mass %, based on the entire solid compound of the composition combined with the basic compound.

The ratio between the acid generator and the (D) low molecular compound having a group capable of leaving by the action of an acid, used in the composition, is preferably acid generator/[(D) low molecular compound having a group capable of leaving by the action of an acid+basic compound] (by mol)=from 2.5 to 300. That is, the molar ratio is preferably 2.5 or more in view of sensitivity and resolution and preferably 300 or less from the standpoint of suppressing the reduction in resolution due to thickening of the resist pattern with aging after exposure until heat treatment. The acid generator/[(D) low molecular compound having a group capable of leaving by the action of an acid+basic compound] (by mol) is more preferably from 5.0 to 200, still more preferably from 7.0 to 150.

### [7] Surfactant

The actinic ray-sensitive or radiation-sensitive resin composition of the present invention may or may not further contain a surfactant, but in the case of containing a surfactant, it is preferred to contain any one of fluorine-containing and/or silicon-containing surfactants (a fluorine-containing surfactant, a silicon-containing surfactant and a surfactant containing both a fluorine atom and a silicon atom), or two or more thereof.

By containing the above-described surfactant, the composition of the present invention can give a resist pattern enhanced in the sensitivity, resolution and adherence and reduced in the development defect when using an exposure light source with a wavelength of 250 nm or less, particularly a wavelength of 220 nm or less.

Examples of the fluorine-containing and/or silicon-containing surfactants include surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451. The following commercially available surfactants each may also be used as it is.

Examples of the commercially available surfactant which can be used include a fluorine-containing or silicon-containing surfactant such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by Dainippon Ink & Chemicals, Inc.); Surflon S-382, SC101, 102, 103, 104, 105 and 106 (produced by Asahi Glass Co., Ltd.); Troysol S-366 (produced by Troy Chemical); GF-300 and GF-150 (produced by Toagosei Chemical Industry Co., Ltd.); Surflon S-393 (produced by Seimi Chemical Co., Ltd.); EFtop EF121, EF122A, EF122B, RF122C, EF125M, EF135M, EF351, EF352, EF801, EF802 and EF601 (produced by JEMCO Inc.); PF636, PF656, PF6320 and PF6520 (produced by OMNOVA); and FTX-204Q 208G, 218G, 230G, 204D, 208D, 212D, 218D and 222D (produced by NEOS Co., Ltd.). In addition, polysiloxane polymer KP-341 (produced by Shin-Etsu Chemical Co., Ltd.) may also be used as the silicon-containing surfactant.

Other than those known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

The polymer having a fluoro-aliphatic group is preferably a copolymer of a fluoro-aliphatic group-containing monomer with a (poly(oxyalkylene)) acrylate and/or a (poly(oxyalkylene)) methacrylate, and the copolymer may have an irregular distribution or may be a block copolymer. Examples of the poly(oxyalkylene) group include a poly(oxyethylene) group, a poly(oxypropylene) group and a poly(oxybutylene) group. This group may also be a unit having alkylenes differing in the chain length within the same chain, such as block-linked poly(oxyethylene, oxypropylene and oxyethylene) and block-linked poly(oxyethylene and oxypropylene). Furthermore, the copolymer of a fluoro-aliphatic group-containing monomer and a (poly(oxyalkylene)) acrylate (or methacrylate) is not limited only to a binary copolymer but may also be a ternary or higher copolymer obtained by simultaneously copolymerizing two or more different fluoro-aliphatic group-containing monomers or two or more different (poly(oxyalkylene)) acrylates (or methacrylates).

Examples thereof include, as the commercially available surfactant, Megaface F178, F-470, F-473, F-475, F-476 and F-472 (produced by Dainippon Ink & Chemicals, Inc.) and further include a copolymer of a C₆F₁₃ group-containing acrylate (or methacrylate) with a (poly(oxyalkylene)) acrylate (or methacrylate), and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactant may also be used. Specific examples thereof include a nonionic surfactant such as polyoxyethylene alkyl ethers (e.g., polyoxyethylene lauryl ether, polyoxyethylene stearyl ether, polyoxyethylene cetyl ether, polyoxyethylene oleyl ether), polyoxyethylene alkylaryl ethers (e.g., polyoxyethylene octylphenol ether, polyoxyethylene nonylphenol ether), polyoxyethylene.polyoxypropylene block copolymers, sorbitan fatty acid esters (e.g., sorbitan monolaurate, sorbitan monopalmitate, sorbitan monostearate, sorbitan monooleate, sorbitan trioleate, sorbitan tristearate) and polyoxyethylene sorbitan fatty acid esters (e.g., polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate).

One of these surfactants may be used alone, or some of them may be used in combination.

In the case where the composition of the present invention contains a surfactant, the content of the surfactant is preferably from 0.0001 to 2 mass %, more preferably from 0.001 to 1 mass %, based on the entire solid content of the actinic ray-sensitive or radiation-sensitive resin composition (entire amount excluding the solvent).

On the other hand, by setting the amount added of the surfactant to 10 ppm or less based on the entire amount of the composition (excluding the solvent), the hydrophobic resin is more unevenly distributed to the surface, so that the resist film surface can be made more hydrophobic and the followability of water at the immersion exposure can be enhanced.

### [8] Onium Carboxylate

The actinic ray-sensitive or radiation-sensitive resin composition of the present invention may contain an onium carboxylate. Examples of onium carboxylate include sulfonium carboxylate, iodonium carboxylate and ammonium carboxylate. The onium carboxylate is preferably an iodonium salt or a sulfonium salt. Also, it is preferred that the carboxylate residue of the onium carboxylate does not contain an aromatic group and a carbon-carbon double bond. The anion moiety is preferably a linear or branched, monocyclic or polycyclic alkylcarboxylate anion having a carbon number of 1 to 30, more preferably the carboxylate anion in which the alkyl group is partially or entirely fluorine-substituted. The alkyl chain may contain an oxygen atom. Thanks to such a configuration, the transparency to light at a wavelength of 220 nm or less is ensured, the sensitivity and resolution are enhanced, and the iso/dense bias and exposure margin are improved.

Examples of the fluorine-substituted carboxylate anion include fluoroacetate, difluoroacetate, trifluoroacetate, pentafluoropropionate, heptafluorobutyrate, nonafluoropentanoate, perfluorododecanoate, perfluorotridecanoate, perfluorocyclohexanecarboxylate and 2,2-bistrifluoromethylpropionate anions.

Such an onium carboxylate can be synthesized by reacting a sulfonium hydroxide, iodonium hydroxide or ammonium hydroxide and a carboxylic acid with silver oxide in an appropriate solvent.

The composition of the present invention may or may not contain an onium carboxylate, but in the case of containing an onium carboxylate, the content thereof is generally from 0.1 to 20 mass %, preferably from 0.5 to 10 mass %, more preferably from 1 to 7 mass %, based on the entire solid content of the composition.

### [9] Other Additives

The actinic ray-sensitive or radiation-sensitive resin composition of the present invention may further contain, for example, a dye, a plasticizer, a photosensitizer, a light absorber, and a compound for accelerating dissolution in a developer (for example, a phenol compound having a molecular weight of 1,000 or less, or a carboxyl group-containing alicyclic or aliphatic compound), if desired.

The phenol compound having a molecular weight of 1,000 or less can be easily synthesized by one skilled in the art while referring to the method described, for example, in JP-A-4-122938, JP-A-2-28531, U.S. Pat. No. 4,916,210 and European Patent 219294.

Specific examples of the carboxyl group-containing alicyclic or aliphatic compound include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid and a cyclohexanedicarboxylic acid.

### [10] Pattern Forming Method

The composition of the present invention is preferably used in a film thickness of 30 to 250 nm, more preferably from 30 to 200 nm, from the standpoint of enhancing the resolution. Such a film thickness can be obtained by setting the solid content concentration in the composition to an appropriate range, thereby imparting an appropriate viscosity and enhancing the coatability and film-forming property.

The entire solid content concentration in the actinic ray-sensitive or radiation-sensitive resin composition is generally from 1 to 10 mass %, preferably from 1 to 8.0 mass %, more preferably from 1.0 to 6.0 mass %.

The composition of the present invention is used by dissolving the components above in a predetermined organic solvent, preferably in the above-described mixed solvent, filtering the solution, and applying it on a predetermined support as follows. The filter used for filtration is preferably a polytetrafluoroethylene-, polyethylene- or nylon-made filter having a pore size of 0.1 μm or less, more preferably 0.05 μm or less, still more preferably 0.03 μm or less.

For example, the actinic ray-sensitive or radiation-sensitive resin composition is applied on such a substrate (e.g., silicon/silicon dioxide-coated substrate) as used in the production of a precision integrated circuit device, by an appropriate coating method such as spinner or coater and dried to form a film (resist film).

The resist film is irradiated with an actinic ray or radiation through a predetermined mask, then preferably baked (heated), and subjected to development and rinsing, whereby a good pattern can be obtained.

The pattern forming method also preferably contains, after film formation, a pre-baking step (PB) before entering the exposure step.

Furthermore, the pattern forming method also preferably contains a post-exposure baking step (PEB) after the exposure step but before the development step.

As for the heating temperature, both PB and PEB are preferably performed at 70 to 150° C., more preferably at 80 to 140° C.

The heating time is preferably from 30 to 300 seconds, more preferably from 30 to 180 seconds, still more preferably from 30 to 90 seconds.

The heating can be performed using a device attached to an ordinary exposure/developing machine or may be performed using a hot plate or the like.

Thanks to baking, the reaction in the exposed area is accelerated, and the sensitivity and pattern profile are improved.

Examples of the actinic ray or radiation include infrared light, visible light, ultraviolet light, far ultraviolet light, extreme-ultraviolet light, X-ray and electron beam, but the radiation is preferably far ultraviolet light at a wavelength of 250 nm or less, more preferably 220 nm or less, still more preferably from 1 to 200 nm. Specific examples thereof include KrF excimer laser (248 nm), ArF excimer laser (193 nm), F₂ excimer laser (157 nm), EUV (13 nm), X-ray and electron beam, and ArF excimer laser, F₂ excimer laser, EUV and electron beam are preferred.

Before forming the resist film, an antireflection film may be previously provided by coating on the substrate.

The antireflection film used may be either an inorganic film type such as titanium, titanium dioxide, titanium nitride, chromium oxide, carbon and amorphous silicon, or an organic film type composed of a light absorber and a polymer material. As for the organic antireflection film, a commercially available organic antireflection film such as DUV30 Series and DUV-40 Series produced by Brewer Science, Inc. and AR-2, AR-3 and AR-5 produced by Shipley Co., Ltd. may be also used.

In the development step, an alkali developer is used as follows. As for the alkali developer of the actinic ray-sensitive or radiation-sensitive resin composition, an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine, can be used. Usually, a quaternary ammonium salt typified by an aqueous tetramethylammonium hydroxide solution (2.38 mass %) is used.

This alkali developer may be used after adding thereto alcohols and a surfactant each in an appropriate amount.

The alkali concentration of the alkali developer is usually from 0.1 to 20 mass %.

The pH of the alkali developer is usually from 10.0 to 15.0.

Furthermore, the alkaline aqueous solution may be used after adding thereto alcohols and a surfactant each in an appropriate amount.

As for the rinsing solution, pure water is used, and an appropriate amount of a surfactant may be added to the pure water before use.

After the development or rinsing, a treatment of removing the developer or rinsing solution adhering on the pattern by a supercritical fluid may be performed.

For the film formed using the actinic ray-sensitive or radiation-sensitive resin composition of the present invention, the exposure may also be performed by filling a liquid (immersion medium) having a refractive index higher than that of air between the film and the lens at the irradiation with an actinic ray or radiation (immersion exposure). By this exposure, the resolution can be enhanced. The immersion medium used may be any liquid as long as it has a refractive index higher than that of air, but pure water is preferred.

The immersion liquid used in the immersion exposure is described below.

The immersion liquid is preferably a liquid being transparent to light at the exposure wavelength and having as small a temperature coefficient of refractive index as possible in order to minimize the distortion of an optical image projected on the resist film. Particularly, when the exposure light source is an ArF excimer laser (wavelength: 193 nm), water is preferably used in view of easy availability and easy handleability in addition to the above-described aspects.

Furthermore, a medium having a refractive index of 1.5 or more can also be used from the standpoint that the refractive index can be more enhanced. This medium may be either an aqueous solution or an organic solvent.

In the case of using water as the immersion liquid, for the purpose of decreasing the surface tension of water and increasing the surface activity, an additive (liquid) which does not dissolve the resist film on a wafer and at the same time, gives only a negligible effect on the optical coat at the undersurface of the lens element, may be added in a small ratio.

The additive is preferably an aliphatic alcohol having a refractive index nearly equal to that of water, and specific examples thereof include methyl alcohol, ethyl alcohol and isopropyl alcohol. By adding an alcohol having a refractive index nearly equal to that of water, even when the alcohol component in water is evaporated and its content concentration is changed, the change in the refractive index of the entire liquid can be advantageously made very small. On the other hand, if a substance opaque to light at 193 nm or an impurity greatly differing in the refractive index from water is intermixed, this incurs distortion of the optical image projected on the resist film. Therefore, the water used is preferably distilled water. Pure water obtained by further filtering the distilled water through an ion exchange filter or the like may also be used.

The electrical resistance of water used as the immersion liquid is preferably 18.3 MQcm or more, and TOC (total organic carbon) is preferably 20 ppb or less. Also, the water is preferably subjected to a deaeration treatment.

The lithography performance can be enhanced by raising the refractive index of the immersion liquid. From such a standpoint, an additive for raising the refractive index may be added to water, or heavy water (D₂O) may be used in place of water.

In the case where the film formed using the composition of the present invention is exposed through an immersion medium, the hydrophobic resin (C) described above may be further added, if desired. The receding contact angle on the surface is enhanced by the addition of the hydrophobic resin (C). The receding contact angle of the film is preferably from 60 to 90°, more preferably 70° or more.

In the immersion exposure step, the immersion liquid must move on a wafer following the movement of an exposure head that is scanning the wafer at a high speed and forming an exposure pattern. Therefore, the contact angle of the immersion liquid for the resist film in a dynamic state is important, and the resist is required to have a performance of allowing a liquid droplet to follow the high-speed scanning of an exposure head with no remaining.

In order to prevent the film from directly contacting with the immersion liquid, a film (hereinafter, sometimes referred to as a “topcoat”) sparingly soluble in an immersion liquid may be provided between the film formed using the composition of the present invention and the immersion liquid. The functions required of the topcoat are suitability for coating as an overlayer of the resist, transparency to radiation, particularly, radiation having a wavelength of 193 nm, and sparing solubility in the immersion liquid. The topcoat is preferably unmixable with the resist and capable of being uniformly applied as an overlayer of the resist.

In view of transparency to light at 193 nm, the topcoat is preferably an aromatic-free polymer.

Specific examples of such a polymer include a hydrocarbon polymer, an acrylic acid ester polymer, a polymethacrylic acid, a polyacrylic acid, a polyvinyl ether, a silicon-containing polymer and a fluorine-containing polymer. The above-described hydrophobic resin (C) is suitable also as the topcoat. If impurities are dissolved out into the immersion liquid from the topcoat, the optical lens is contaminated. In this viewpoint, residual monomer components of the polymer is preferably little contained in the topcoat.

On peeling off the topcoat, a developer may be used or a releasing agent may be separately used. The releasing agent is preferably a solvent less permeating the film. From the standpoint that the peeling step can be performed simultaneously with the development step of the film, the topcoat is preferably peelable with an alkali developer and from the standpoint of peeling with an alkali developer, the topcoat is preferably acidic, but in view of non-intermixing with the film, the topcoat may be neutral or alkaline.

The difference in the refractive index between the topcoat and the immersion liquid is preferably null or small. In this case, the resolution can be enhanced. In the case where the exposure light source is an ArF excimer laser (wavelength: 193 nm), water is preferably used as the immersion liquid and therefore, the topcoat for ArF immersion exposure preferably has a refractive index close to the refractive index (1.44) of water. Also, in view of transparency and refractive index, the topcoat is preferably a thin film.

The topcoat is preferably unmixable with the film and further unmixable with the immersion liquid. From this standpoint, when the immersion liquid is water, the solvent used for the topcoat is preferably a medium that is sparingly soluble in the solvent used for the composition of the present invention and is insoluble in water. Furthermore, when the immersion liquid is an organic solvent, the topcoat may be either water-soluble or water-insoluble.

### EXAMPLES

The present invention is described below by referring to Examples, but the present invention should not be construed as being limited thereto.

### Synthesis Example 1

### Synthesis of Resin A

In a nitrogen stream, a mixed solvent of propylene glycol monomethyl ether acetate (PGMEA, another name: 1-methoxy-2-acetoxypropane)/propylene glycol monomethyl ether (PGME, another name: 1-methoxy-2-propanol)=26.6 g/6.6 g was charged into a three-neck flask and heated at 85° C. To this solvent, a solution prepared by dissolving 12.61 g, 3.54 g, 5.89 g and 1.63 g of the following compounds starting from the left, respectively, and polymerization initiator V-601 (produced by Wako Pure Chemical Industries, Ltd., 1.497 g) in a mixed solvent of PGMEA/PGME=49.2 g/12.3 g, was added dropwise over 6 hours. After the completion of dropwise addition, the reaction was further allowed to proceed at 85° C. for 2 hours. The resulting reaction solution was left standing to cool and then added dropwise to a mixed solution of 600 g of heptane/250 g of ethyl acetate over 20 minutes, and the powder precipitated was collected by filtration and dried to obtain 20.1 g of Resin A. The weight average molecular weight of Resin A was 10,100 in terms of standard polystyrene, and the dispersity (Mw/Mn) was 1.53.

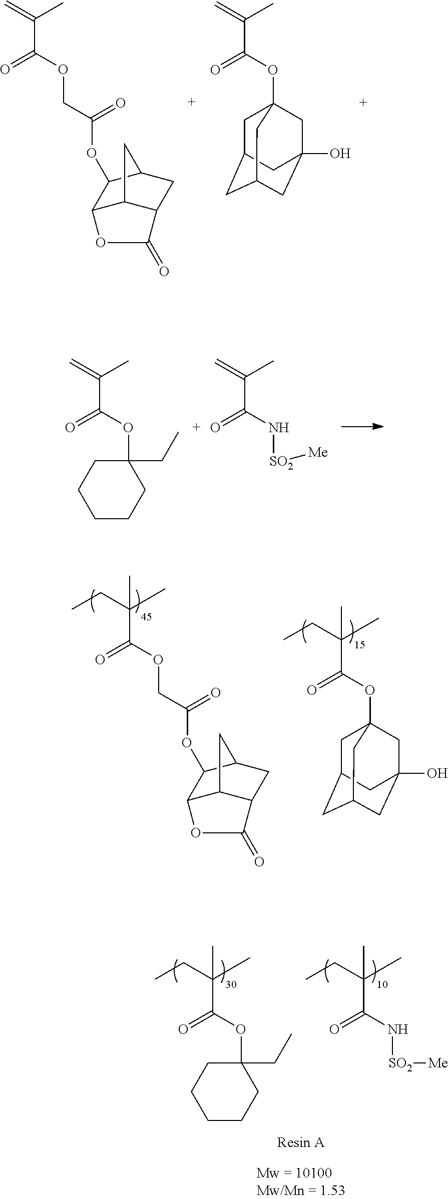

Resins B to N shown below were synthesized in the same manner as in Synthesis Example 1. Here, Resins A to K are the resin of the present invention containing both a repeating unit represented by formula (I) and a repeating unit having a partial structure represented by formula (II). On the other hand, Resins L to N are a comparative resin containing only either one of these repeating units.

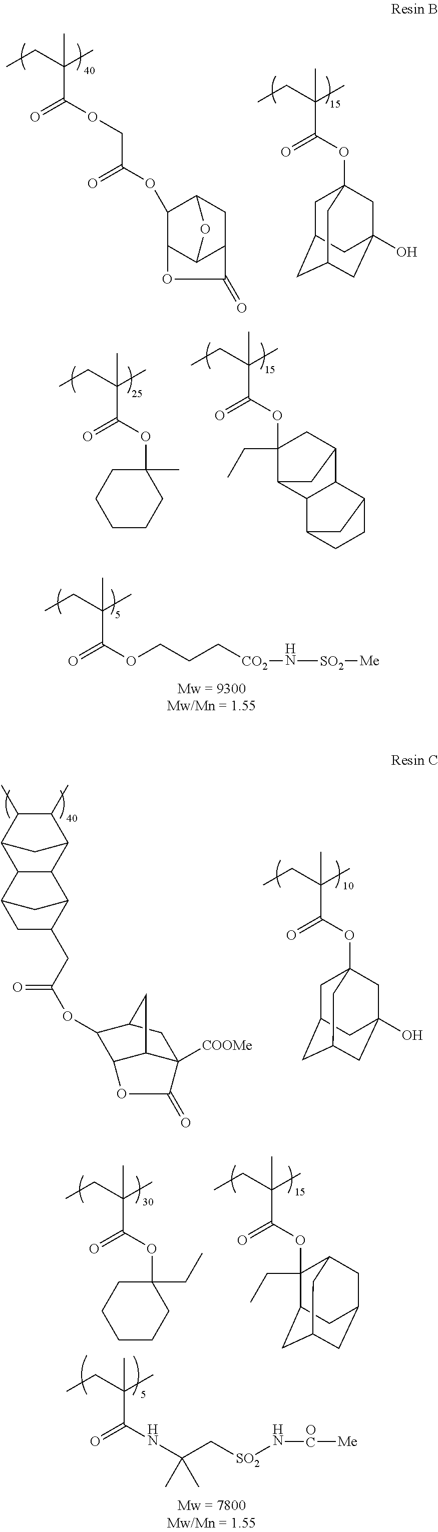

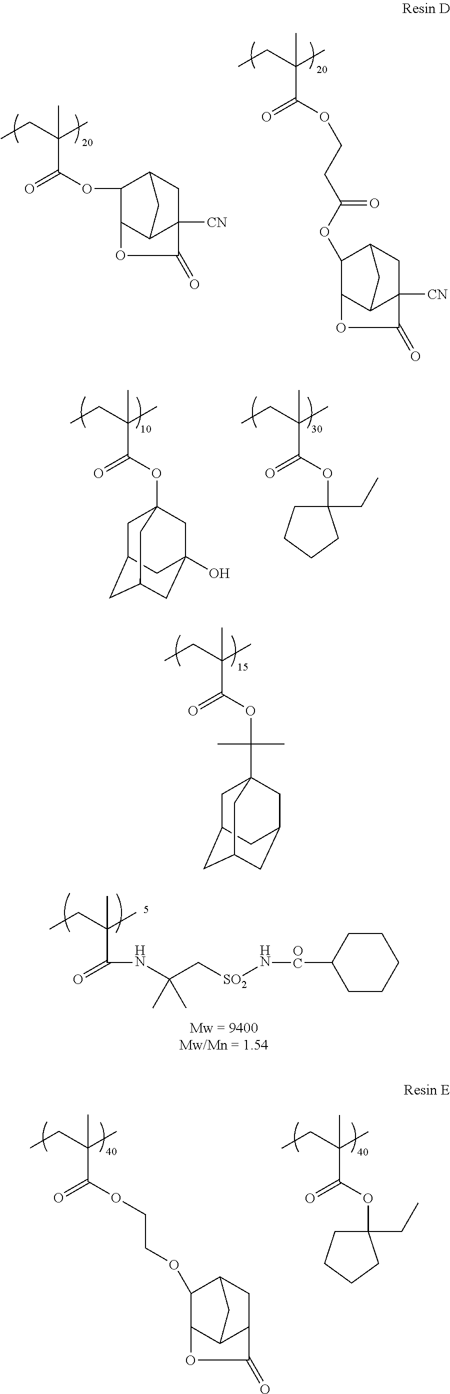

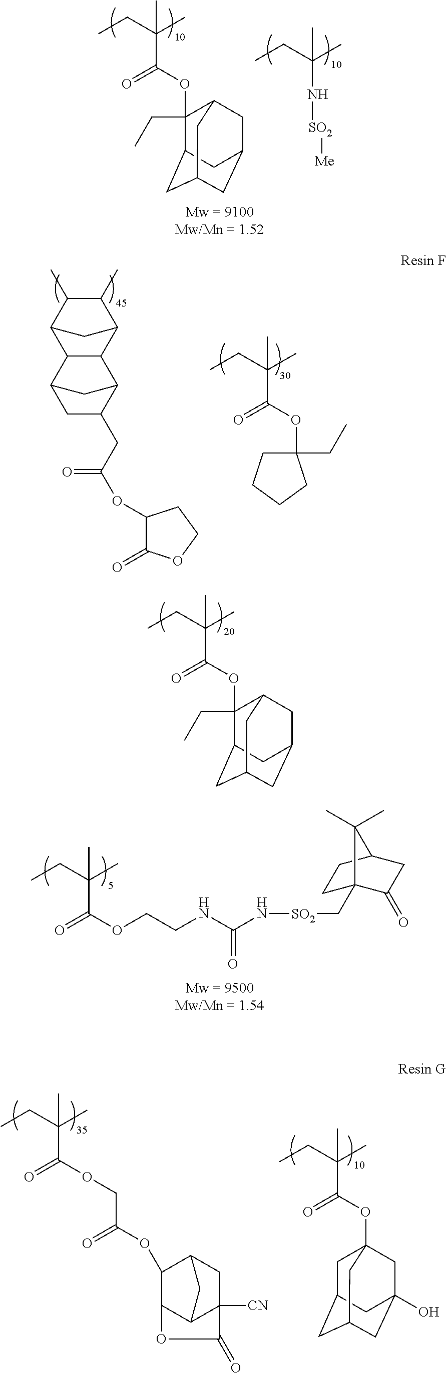

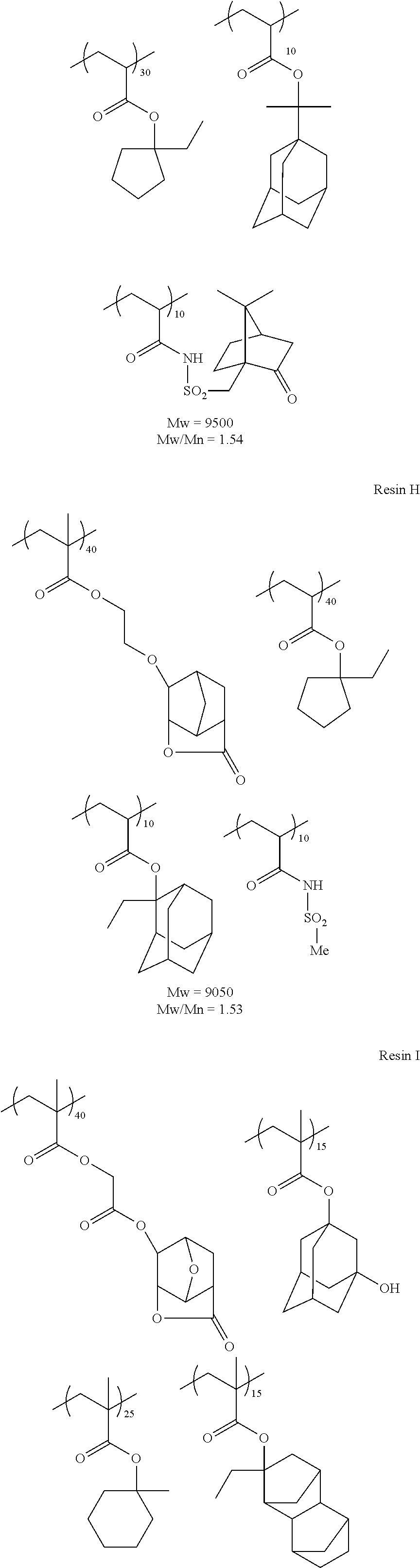

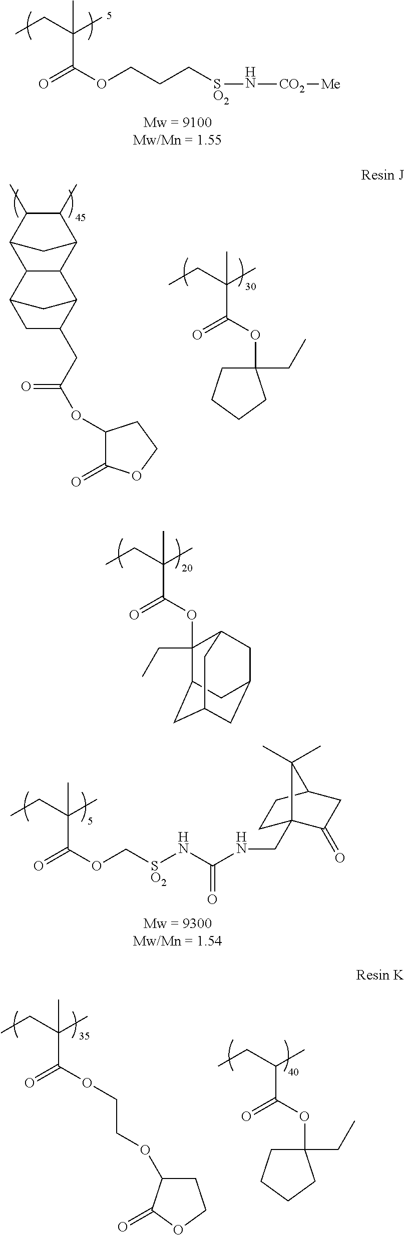

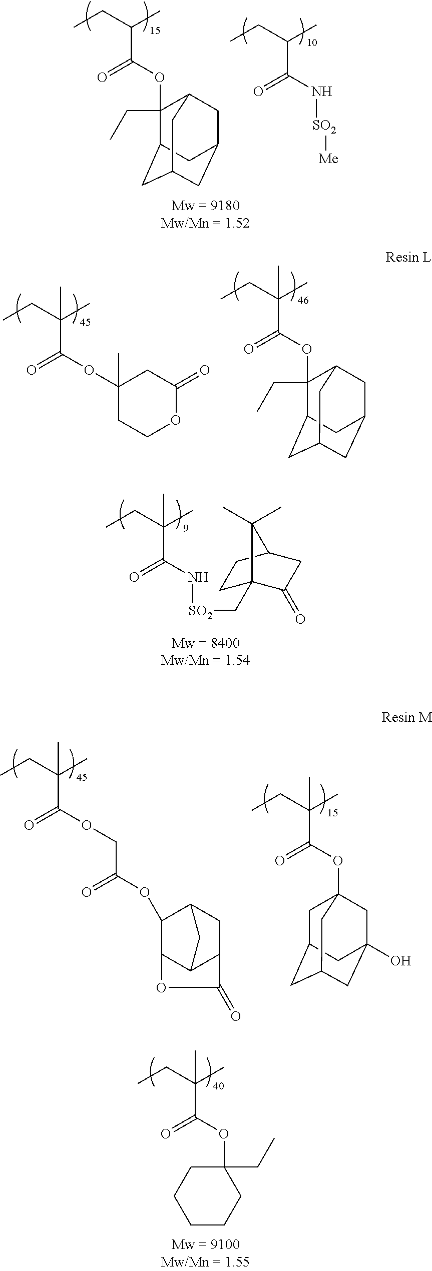

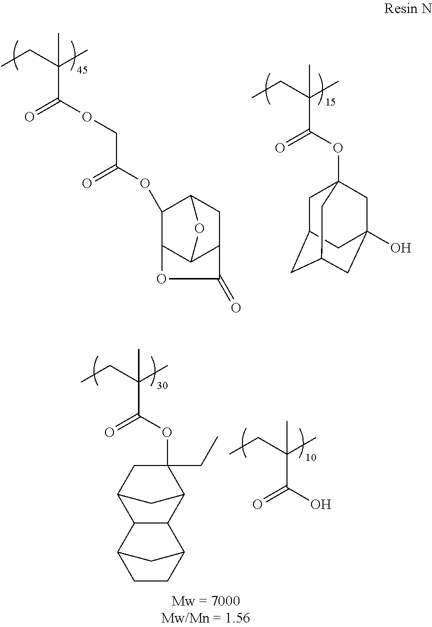

### Synthesis Example 2

### Synthesis of Hydrophobic Resin HR-69

Compound (1) shown below was synthesized by the method described in International Publication No. 07/037,213, pamphlet.

150.00 Gram of water was added to 35.00 g of Compound (1), and 27.30 g of NaOH was further added. The mixture was stirred for 9 hours under heating and refluxing conditions. The resulting reaction solution was made acidic by adding hydrochloric acid and then extracted with ethyl acetate. The organic layers were combined and concentrated to obtain 36.90 g of Compound (2) (yield: 93%).

¹H-NMR (400 MHz in (CD₃)₂CO): σ (ppm)=1.56-1.59 (1H), 1.68-1.72 (1H), 2.13-2.15 (1H), 2.13-2.47 (2H), 3.49-3.51 (1H), 3.68 (1H), 4.45-4.46 (1H).

Subsequently, 200 ml of CHCl₃ was added to 20.00 g of Compound (2), and 50.90 g of 1,1,1,3,3,3-hexafluoroisopropyl alcohol and 30.00 g of 4-dimethylaminopyridine were further added, followed by stirring. To the resulting solution, 22.00 g of 1-ethyl-3-(3-dimethylaminopropyl)carbodiimide hydrochloride was added, and the mixture was stirred for 3 hours. This reaction solution was added to 500 ml of 1 N HCl to stop the reaction, and the organic layer was washed further with 1 N HCl and then washed with water. The obtained organic layer was concentrated to obtain 30.00 g of Compound (3) (yield: 85%).

¹H-NMR (400 MHz in (CD₃)₂CO): σ (ppm)=1.62 (1H), 1.91-1.95 (1H), 2.21-2.24 (1H), 2.45-2.53 (2H), 3.61-3.63 (1H), 3.76 (1H), 4.32-4.58 (1H), 6.46-6.53 (1H).

Thereafter, 300.00 g of toluene was added to 15.00 g of Compound (3), and 3.70 g of methacrylic acid and 4.20 g of p-toluenesulfonic acid monohydrate were further added. The mixture was refluxed for 15 hours while azeotropically removing the water produced, and the resulting reaction solution was concentrated. The concentrate was purified by column chromatography to obtain 11.70 g of Compound (4) (yield: 65%).

¹H-NMR (400 MHz in (CD₃)₂CO): σ (ppm)=1.76-1.79 (1H), 1.93 (3H), 2.16-2.22 (2H), 2.57-2.61 (1H), 2.76-2.81 (2H), 3.73-3.74 (1H), 4.73 (1H), 4.84-4.86 (1H), 5.69-5.70 (1H), 6.12 (1H), 6.50-6.56 (1H).

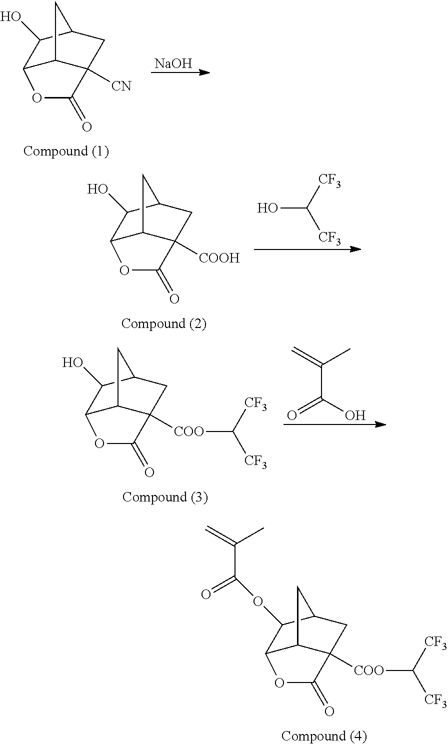

In a nitrogen stream, 6.4 g of propylene glycol monomethyl ether acetate (PGMEA) was charged into a three-neck flask and heated at 80° C. Thereto, a solution prepared by dissolving 17.5 g of Compound (4), 4.0 g of tert-butyl methacrylate, and polymerization initiator V-601 (produced by Wako Pure Chemical Industries, Ltd.) in a ratio of 5.0 mol % based on the monomers, in 58.0 g of PGMEA was added dropwise over 4 hours. After the completion of dropwise addition, the reaction was further allowed to proceed at 80° C. for 4 hours. The resulting reaction solution was left standing to cool and then added dropwise to a mixed solution of 1,300 g of methanol/150 g of distilled water over 20 minutes, and the powder precipitated was collected by filtration and dried to obtain 15.2 g of Resin (HR-69).

The weight average molecular weight of Resin (HR-69) was 8,000 in terms of standard polystyrene, and the dispersity (Mw/Mn) was 1.3.

### <Preparation of Resist Composition>

The components shown in Table 3 below were dissolved in a solvent to prepare a solution having a solid content concentration of 4 mass %, and the obtained solution was filtered through a polyethylene filter having a pore size of 0.05 μm to prepare an actinic ray-sensitive or radiation-sensitive resin composition (positive resist composition). The positive resist compositions prepared were evaluated by the following methods, and the results are shown together in Table 3.

Incidentally, in Table 3, when the positive resist composition contains a hydrophobic resin (C), the mode of addition is denoted by “added”, and when the positive resist composition does not contain a hydrophobic resin (C) and after the formation of a resist film, a topcoat protective film containing a hydrophobic resin (C) is formed as an overlayer, the mode of addition is denoted by “TC”.

### <Preparation of Topcoat Composition>

In Table 3, when the addition mode of the hydrophobic resin is “TC”, the hydrophobic resin was dissolved in diisopentyl ether to obtain a solution having an entire solid content concentration of 4 mass %, and this solution was filtered through a polyethylene filter having a pore size of 0.05 μm to prepare a topcoat composition.

TABLE 3

| | | | Basic | Hydrophobic Resin | | | | | |
|---|---|---|---|---|---|---|---|---|---|
| | | Acid | Compound/ | (35 mg), | | | | Pattern | Iso/Dens |
| | Resin | Generator | Compound (D) | Added or Topcoat | Surfactant | Solvent | DOF | Collapse | e Bias |
| | (10 g) | (g) | (0.4 g) | (TC) | (g) | (mass ratio) | (μm) | (nm) | (nm) |
| Example 1 | A | PAG-1 (2.2) | APCA | none | W-4 (0.01) | S1 = 100 | 0.13 | 39.3 | 115 |
| Example 2 | B | PAG-1 (2.2) | DBA | none | W-2 (0.02) | S1/S4/S6 = | 0.08 | 42.1 | 70 |
| | | | | | | 80/5/15 | | | |
| Example 3 | C | PAG-1 (2.2) | PBI | none | W-1 (0.01) | S1/S6 = 95/5 | 0.09 | 41.2 | 85 |
| Example 4 | D | PAG-1 (2.2) | DIA | none | W-4 (0.01) | S1/S3 = 90/10 | 0.10 | 40.6 | 90 |
| Example 5 | E | PAG-1 (2.2) | APCA | none | W-4 (0.01) | S1/S5 = 80/20 | 0.11 | 40.4 | 100 |
| Example 6 | F | PAG-1 (2.2) | DBA | none | W-4 (0.01) | S1/S4/S6 = | 0.07 | 42.8 | 65 |
| | | | | | | 80/5/15 | | | |
| Example 7 | G | PAG-1 (2.2) | PEA | none | W-3 (0.03) | S1 = 100 | 0.15 | 38.5 | 135 |
| Example 8 | A | PAG-2 (2.1) | TEA | HR-26, added | W-3 (0.02) | S1 = 100 | 0.14 | 28.5 | 130 |
| Example 9 | B | PAG-2 (2.2) | APCA | HR-53, added | none | S1/S3 = 90/10 | 0.09 | 31.2 | 80 |
| Example 10 | D | PAG-2 (2.1) | APCA | HR-47, added | W-4 (0.01) | S1 = 100 | 0.11 | 29.5 | 95 |
| Example 11 | G | PAG-2 (2.3) | APCA | HR-47, added | W-4 (0.01) | S1 = 100 | 0.16 | 27.4 | 140 |
| Example 12 | A | PAG-3 (1.9) | APCA | HR-47, added | W-4 (0.01) | S1/S5 = 60/40 | 0.14 | 29.2 | 135 |
| Example 13 | B/D | PAG-3 (2.0) | TPSA | HR-47, added | W-4 (0.01) | S1 = 100 | 0.08 | 32.2 | 70 |
| | (8 g/2 g) | | | | | | | | |
| Example 14 | D | PAG-3 (1.9) | DBA/PEA | HR-47, added | W-4 (0.01) | S1 = 100 | 0.10 | 30.5 | 85 |
| | | | (0.2 g/0.2 g) | | | | | | |
| Example 15 | G | PAG-3 (1.8) | APCA | HR-49, TC | W-4 (0.01) | S1/S3 = 90/10 | 0.15 | 28.4 | 140 |
| Example 16 | A | PAG-4 (2.1) | PBI | HR-28, added | W-4 (0.01) | S1 = 100 | 0.13 | 29.2 | 120 |
| Example 17 | B | PAG-4 (2.1) | TMEA | HR-53, added | W-4 (0.01) | S1/S3 = 90/10 | 0.08 | 32.1 | 65 |
| Example 18 | D | PAG-4 (2.0) | PEA | HR-47, added | W-4 (0.01) | S1/S5 = 60/40 | 0.10 | 30.6 | 90 |
| Example 19 | G | PAG-4 (2.0) | APCA | HR-49, TC | W-3 (0.02) | S1/S3 = 90/10 | 0.15 | 28.6 | 140 |
| Example 20 | A | PAG-5 (2.3) | APCA | HR-47, added | W-3 (0.01) | S1/S3 = 90/10 | 0.16 | 26.5 | 145 |
| Example 21 | B | PAG-5 (2.3) | APCA | HR-47, added | W-4 (0.01) | S1/S2/S3 = | 0.11 | 29.2 | 105 |
| | | | | | | 85/5/10 | | | |
| Example 22 | D | PAG-5 (2.3) | DBA/APCA | HR-47, added | W-5 (0.01) | S1 = 100 | 0.13 | 27.3 | 120 |
| | | | (0.2 g/0.2 g) | | | | | | |
| Example 23 | G | PAG-5 (2.4) | PEA | HR-47, added | none | S1 = 100 | 0.18 | 25.2 | 145 |
| Example 24 | A | PAG-6 (2.1) | TEA | HR-53, added | W-4 (0.01) | S1/S3 = 90/10 | 0.15 | 27.6 | 140 |
| Example 25 | B | PAG-6 (2.1) | TMEA | HR-26, added | W-2 (0.02) | S1/S2/S3 = | 0.10 | 30.1 | 90 |
| | | | | | | 85/5/10 | | | |
| Example 26 | D | PAG-6 (2.1) | PEA | HR-26, added | W-4 (0.01) | S1/S3 = 90/10 | 0.12 | 28.4 | 110 |
| Example 27 | A/G | PAG-6 (2.1) | APCA | HR-26, added | W-3 (0.01) | S1/S6 = 80/20 | 0.17 | 26.3 | 155 |
| | (5 g/5 g) | | | | | | | | |
| Example 28 | A | PAG-1/PAG-2 | DBA | HR-47, added | W-2 (0.02) | S1 = 100 | 0.13 | 29.2 | 120 |
| | | (1.0/1.2) | | | | | | | |
| Example 29 | B | PAG-1/PAG-5 | PBI | HR-53, added | W-1 (0.005) | S1/S3 = 90/10 | 0.11 | 29.1 | 95 |
| | | (0.9/1.3) | | | | | | | |
| Example 30 | D | PAG-1/PAG-6 | DIA | HR-26, added | W-1 (0.005) | S1 = 100 | 0.12 | 27.1 | 115 |
| | | (1.2/0.9) | | | | | | | |
| Example 31 | A/G | PAG-3/PAG-5 | APCA | HR-47, added | none | S1 = 100 | 0.17 | 25.5 | 150 |
| | (5 g/5 g) | (1.3/1.3) | | | | | | | |
| Example 32 | G | PAG-4/PAG-5 | APCA | HR-47/HR-69 | none | S1/S3 = 90/10 | 0.17 | 25.4 | 155 |
| | | (1.2/1.0) | | (15 mg/20 mg), added | | | | | |
| Example 33 | G | PAG-4/PAG-5 | APCA | HR-69, added | none | S1/S3 = 90/10 | 0.17 | 25.5 | 145 |
| | | (1.2/1.0) | | | | | | | |
| Example 34 | D | PAG-1/PAG-6 | DIA | HR-26, added | W-1 (0.005) | S1 = 100 | 0.10 | 26.8 | 95 |
| | | (1.2/0.9) | | | | | | | |
| Example 35 | H | PAG-1 (2.2) | APCA | HR-26, added | W-4 (0.01) | S1/S5 = 80/20 | 0.10 | 30.8 | 90 |
| Example 36 | I | PAG-1/PAG-2 | DBA | HR-47, added | W-2 (0.02) | S1 = 100 | 0.13 | 29.3 | 120 |
| | | (1.0/1.2) | | | | | | | |
| Example 37 | J | PAG-1 (2.2) | DBA | HR-47, added | W-4 (0.01) | S1/S4/S6 = | 0.08 | 32.7 | 75 |
| | | | | | | 80/5/15 | | | |
| Example 38 | K | PAG-1 (2.2) | APCA | none | W-4 (0.01) | S1/S5 = 80/20 | 0.08 | 42.4 | 75 |
| Comparative | L | PAG-1 (2.2) | APCA | none | W-4 (0.01) | S1 = 100 | 0.03 | 50.5 | 25 |
| Example 1 | | | | | | | | | |
| Comparative | M | PAG-1 (2.2) | APCA | none | W-4 (0.01) | S1 = 100 | 0.03 | 55.2 | 25 |
| Example 2 | | | | | | | | | |
| Comparative | N | PAG-1 (2.2) | APCA | none | W-4 (0.01) | S1 = 100 | 0.04 | 60.2 | 30 |
| Example 3 | | | | | | | | | |
| Comparative | M | PAG-1 (2.2) | APCA | HR-47, added | W-4 (0.01) | S1 = 100 | 0.04 | 45.2 | 30 |
| Example 4 | | | | | | | | | |

Abbreviations in Table 3 are as follows.

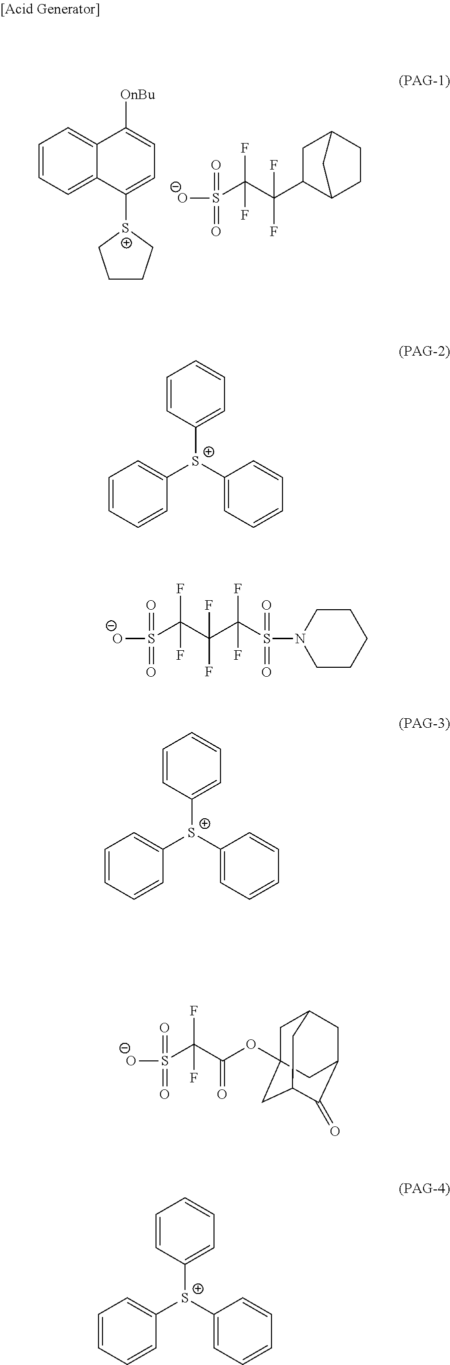

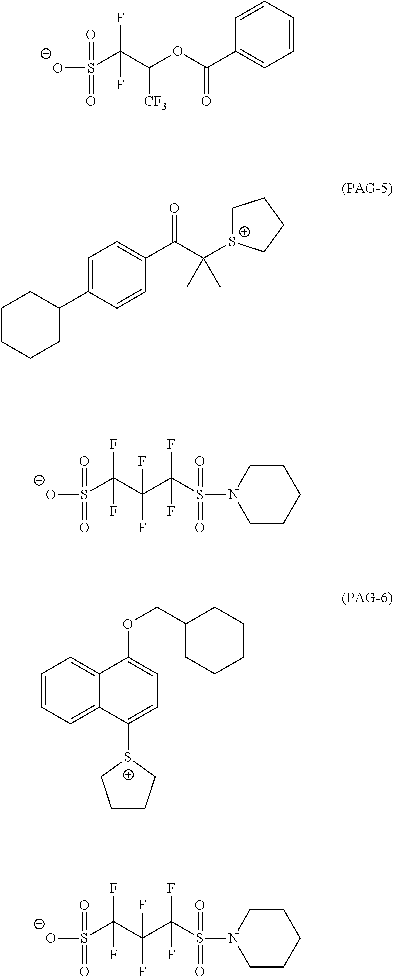

### [Basic Compound]

TPSA: Triphenylsulfonium acetate

### DIA: 2,6-Diisopropylaniline

### TEA: Triethanolamine

### DBA: N,N-Dibutylaniline

### PBI: 2-Phenylbenzimidazole

### TMEA: Tris(methoxyethoxyethyl)amine

### PEA: N-Phenyldiethanolamine

[(D) Low molecular compound having a group capable of leaving by the action of an acid]
APCA: 4-Hydroxy-1-tert-butoxycarbonylpiperidine (compound shown below)

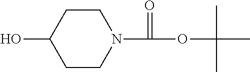

### [Hydrophobic Resin]

The hydrophobic resins denoted by abbreviations in Table 3 are the same as those in specific examples above of the hydrophobic resin (C).

### [Surfactant]

W-1: Megaface F176 (produced by Dainippon Ink & Chemicals, Inc.) (fluorine-containing)
W-2: Megaface R08 (produced by Dainippon Ink & Chemicals, Inc.) (fluorine- and silicon-containing)
W-3: Troysol S-366 (produced by Troy Chemical)
W-4: PF656 (produced by OMNOVA, fluorine-containing)
W-5: PF6320 (produced by OMNOVA, fluorine-containing)

### [Solvent]

S1: Propylene glycol monomethyl ether acetate

### S2: γ-Butyrolactone

### S3: Cyclohexanone

S4: Propylene carbonate
S5: Propylene glycol monomethyl ether
S6: Ethyl lactate

### (Exposure Condition 1: Examples 1 to 7 and 38 and Comparative Examples 1 to 3: ArF Dry Exposure)

An organic antireflection film, ARC29A (produced by Nissan Chemical Industries, Ltd.), was applied on a silicon wafer and baked at 205° C. for 60 seconds to form a 78 nm-thick antireflection film, and the positive resist composition prepared above was applied thereon and baked at 130° C. for 60 seconds to form a resist film having a thickness of 120 nm. The obtained wafer was exposed through a 6% halftone mask having a 1:1 line-and-space pattern with a line width of 75 nm by using an ArF excimer laser scanner (PAS5500/1100, manufactured by ASML, NA: 0.75). Thereafter, the wafer was heated at 90° C. for 60 seconds, developed with an aqueous tetramethylammonium hydroxide solution (2.38 mass %) for 30 seconds, rinsed with pure water and spin-dried to obtain a resist pattern.

### (Exposure Condition 2: Examples 8 to 14, 16 to 18 and 20 to 37 and Comparative Example 4: ArF Immersion Exposure)

An organic antireflection film, ARC29SR (produced by Nissan Chemical Industries, Ltd.), was applied on a silicon wafer and baked at 205° C. for 60 seconds to form a 95 nm-thick antireflection film, and the positive resist composition prepared was applied thereon and baked at 85° C. for 60 seconds to form a resist film having a thickness of 100 nm. The obtained wafer was exposed through a 6% halftone mask having a 1:1 line-and-space pattern with a line width of 48 nm by using an ArF excimer laser immersion scanner (XT-1700Fi, manufactured by ASML, NA: 1.20, σo/σi=0.94/0.74). As for the immersion liquid, ultrapure water was used. Thereafter, the wafer was heated at 90° C. for 60 seconds, developed with an aqueous tetramethylammonium hydroxide solution (2.38 mass %) for 30 seconds, rinsed with pure water and spin-dried to form a resist pattern.

### (Exposure Condition 3: Examples 15 and 19: ArF Immersion Exposure)

A resist pattern was formed in the same manner as in Exposure Condition 2 except that after the formation of the resist film having a thickness of 100 nm but before exposure in Exposure Condition 2, a topcoat composition prepared using the hydrophobic resin shown in Table 3 was applied on the resist film and baked at 115° C. for 60 seconds to form a topcoat film having a thickness of 0.05 μm.

### <Evaluation Method>

### [Defocus Latitude (Evaluation of DOF)]

The exposure dose and the depth of focus for reproducing a 75-nm line/75-nm space mask pattern in Exposure Condition 1 and reproducing a 48-nm line/48-nm space mask pattern in Exposure Conditions 2 and 3 were taken as an optimal exposure dose and an optimal depth of focus, respectively. The depth of focus was changed (defocused) while keeping the exposure dose at the optimal exposure dose, and the range of the depth of focus allowing a pattern size of ±10% of the above-described line width (that is, 75 nm±10% in Exposure Condition 1, and 48 nm±10% in Exposure Conditions 2 and 3) was observed. A larger value indicates a wider defocus latitude and is better.

### [Evaluation of Pattern Collapse]

The exposure dose for reproducing a 75-nm line/75-nm space mask pattern in Exposure Condition 1 and reproducing a 48-nm line/48-nm space mask pattern in Exposure Conditions 2 and 3 was taken as an optimal exposure dose and when the line width of the line pattern formed was reduced by increasing the exposure dose from the optimal exposure dose, a limiting minimum line width allowing the pattern to be resolved without collapse was used for the evaluation. A smaller value indicates that a finer pattern is resolved without collapse, revealing less occurrence of pattern collapse and higher resolution.

### [Iso/Dense Bias]

With respect to a line-and-space 1:1 pattern (dense pattern) and a line-and-space 1:10 isolated line pattern (sparse pattern) each having a line width of 75 nm in Exposure Condition 1 and a line width of 48 nm in Exposure Conditions 2 and 3, the overlapped range of the defocus latitude allowing the above-described line width±10% (that is, 75 nm±10% in Exposure Condition 1, and 48 nm±10% in Exposure Conditions 2 and 3) was determined. A larger range indicates better performance in terms of iso/dense bias.

As seen from the results in Table 3, in Examples employing a resin copolymerized using, as essential components, both a repeating unit having a specific lactone structure and a repeating unit having a specific sulfonamide structure, the DOF, pattern collapse and iso/dense bias are improved, compared with Comparative Examples 1 to 4 using a resin containing only either one of those repeating units. In particular, compared with Comparative Example 3 using Comparative Resin N containing a repeating unit having a specific lactone structure and a methacrylic acid unit as a repeating unit having an alkali-soluble group, the pattern collapse is, among others, improved in Examples using the resin of the present invention.

According to the present invention, an actinic ray-sensitive or radiation-sensitive resin composition improved in the DOF, pattern collapse and iso/dense bias, and a resist film and a pattern forming method each using the composition, can be provided.

This application is based on Japanese patent application JP 2010-056741, filed on Mar. 12, 2010, the entire content of which is hereby incorporated by reference, the same as if set forth at length.

What is claimed is:

1. An actinic ray-sensitive or radiation-sensitive resin composition, comprising:
(A) a resin containing a repeating unit represented by formula (I) and a repeating unit having a partial structure represented by formula (II), and being capable of increasing a solubility of the resin (A) in an alkali developer by an action of an acid; and
(B) a compound capable of generating an acid upon irradiation with an actinic ray or radiation: 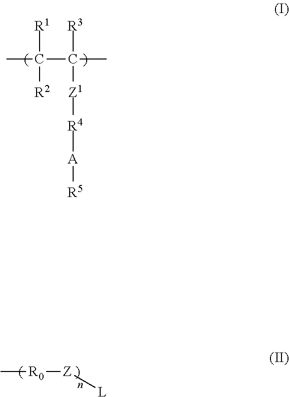
wherein
in formula (I), each of R¹ to R³ independently represents a hydrogen atom, an alkyl group, a halogen atom or a cyano group;
Z¹ represents a single bond, an ether bond, an ester bond, an amide bond, an alkylene group, or a divalent group formed by combining two or more members selected from the group consisting of a single bond, an ether bond, an ester bond, an amide bond and an alkylene group;
R⁴ represents a single bond, an alkylene group, an arylene group, or a divalent group formed by combining two or more members selected from the group consisting of a single bond, an alkylene group and an arylene group;
R⁵ represents an alkyl group, an alicyclic hydrocarbon group-containing group, an aryl group or an aralkyl group; and
A represents any one of functional groups (a1) to (a7), where in the functional groups (a1) to (a7), *1 indicates that the bond is connected to R⁴, and *2 indicates that the bond is connected to R⁵: 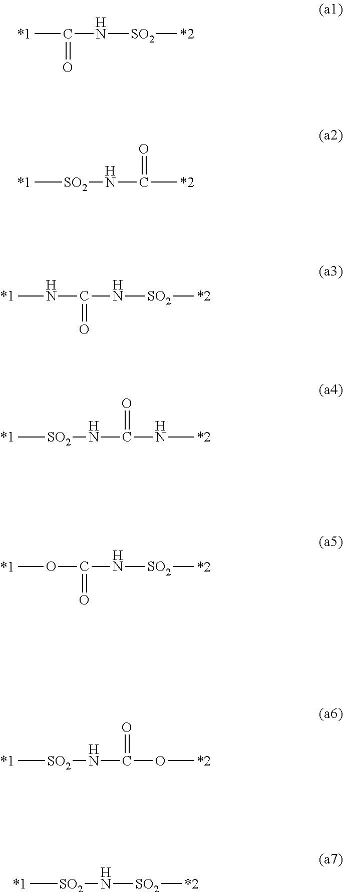
in formula (II), L represents a monovalent organic group having a lactone structure;
R₀ represents an alkylene group, a cycloalkylene group, or a combination of these groups, and when a plurality of R₀'s are present, the plurality of R₀'s may be the same or different;
Z represents an ether bond, an ester bond, an amide bond, a urethane bond or a urea bond, and when a plurality of Z's are present, the plurality of Z's may be the same or different; and
n indicates a repetition number and represents an integer of 1 to 5.

2. The actinic ray-sensitive or radiation-sensitive resin composition according to claim 1,
wherein, in the formula (I), A is any one of the functional groups (a1) to (a6).

3. The actinic ray-sensitive or radiation-sensitive resin composition according to claim 2,
wherein, in the formula (I), A is the functional group (a1) or (a2).

4. The actinic ray-sensitive or radiation-sensitive resin composition according to claim 1,
wherein the repeating unit represented by the formula (I) is a repeating unit represented by formula (I-1): 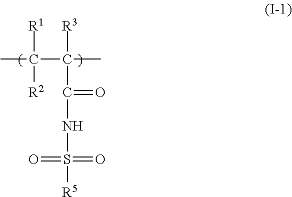
wherein R¹, R², R³ and R⁵ have the same meanings as R¹, R², R³ and R⁵ in the formula (I).

5. The actinic ray-sensitive or radiation-sensitive resin composition according to claim 1,
wherein, in the formula (I), each of R¹ and R² represents a hydrogen atom and R³ represents a hydrogen atom or an alkyl group.

6. The actinic ray-sensitive or radiation-sensitive resin composition according to claim 1,
wherein, in the formula (I), R⁵ represents an alkyl group or a cycloalkyl group.

7. The actinic ray-sensitive or radiation-sensitive resin composition according to claim 1,
wherein the repeating unit having a partial structure represented by the formula (II) is a repeating unit represented by formula (II-1) or (II-2): 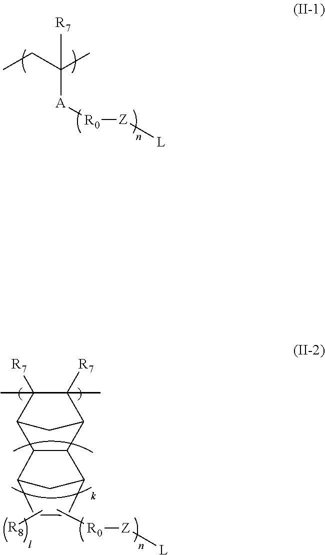
wherein R₇ represents a hydrogen atom, a halogen atom or an alkyl group, and two R₇'s in formula (II-2) may be the same or different;
A represents an ester bond or an amide bond;
R₈ represents a hydrocarbon group, and when a plurality of R₈'s are present, the plurality of Rₛ's may be the same or different;
k represents an integer of 0 to 2;
l represents an integer of 0 to 19; and
L, R₀, Z and n have the same meanings as L, R₀, Z and n in the formula (II).

8. The actinic ray-sensitive or radiation-sensitive resin composition according to claim 7,
wherein the repeating unit having a partial structure represented by the formula (II) is a repeating unit represented by the formula (II-1).

9. The actinic ray-sensitive or radiation-sensitive resin composition according to claim 8,
wherein the repeating unit represented by the formula (II-1) is a repeating unit represented by formula (II-3): 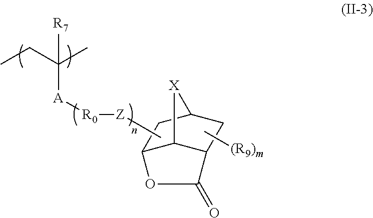
wherein R₇, A, R₀, Z and n have the same meanings as R₇, A, R₀, Z and n in the formula (II-1);
R₉ represents an alkyl group, a cycloalkyl group, an alkoxycarbonyl group or a cyano group, and when a plurality of R₉'s are present, the plurality of R₉'s may be the same or different and two R₉'s may combine to form a ring;
X represents an alkylene group, an oxygen atom or a sulfur atom; and
m indicates the number of substituents and represents an integer of 0 to 5.

10. The actinic ray-sensitive or radiation-sensitive resin composition according to claim 1,
wherein, in the formula (II), R₀ is an alkylene group.

11. The actinic ray-sensitive or radiation-sensitive resin composition according to claim 1,
wherein, in the formula (II), Z is an ether bond or an ester bond.

12. The actinic ray-sensitive or radiation-sensitive resin composition according to claim 1,
wherein, in the formula (II), n is 1.

13. The actinic ray-sensitive or radiation-sensitive resin composition according to claim 1, which further comprises:
(C) a hydrophobic resin.

14. The actinic ray-sensitive or radiation-sensitive resin composition according to claim 13,
wherein the hydrophobic resin (C) contains at least either a fluorine atom or a silicon atom.

15. A resist film, which is formed from the actinic ray-sensitive or radiation-sensitive resin composition according to claim 1.

16. A pattern forming method, comprising: steps of exposing and developing the resist film according to claim 15.

17. The pattern forming method according to claim 16,
wherein the exposure in the step of exposing the resist film is an immersion exposure.
